(19) United States
(12) Patent Application Publication
(10) Pub. No.: US 2015/0378257 A1
(43) Pub. Date: Dec. 31, 2015

(54) PATTERN FORMING METHOD, ACTINIC RAY-SENSITIVE OR RADIATION-SENSITIVE RESIN COMPOSITION, METHOD OF MANUFACTURING ELECTRONIC DEVICE, AND ELECTRONIC DEVICE

(71) Applicant: FUJIFILM CORPORATION, TOKYO (JP)

(72) Inventors: SHUHEI YAMAGUCHI, SHIZUOKA (JP); JUNICHI ITO, SHIZUOKA (JP); HIDENORI TAKAHASHI, SHIZUOKA (JP)

(21) Appl. No.: 14/852,630

(22) Filed: Sep. 14, 2015

Related U.S. Application Data
(63) Continuation of application No. PCT/JP2014/053795, filed on Feb. 18, 2014.

(30) Foreign Application Priority Data
Mar. 14, 2013 (JP) 2013-052275

(51) Int. Cl. G03F 7/038; G03F 7/32; G03F 7/004; G03F 7/20

(52) U.S. Cl. CPC G03F 7/038; G03F 7/20; G03F 7/325; G03F 7/0045

(57) ABSTRACT

According to one example of the present application, there is provided a pattern forming method including: (i) forming a film by using an actinic ray-sensitive or radiation-sensitive resin composition containing (A) a specific resin and (B) a compound capable of generating an acid upon irradiation with an actinic ray or radiation; (ii) exposing the film; and (iii) developing the film exposed, by using an organic solvent-containing developer to form a negative pattern.

### CROSS REFERENCE TO RELATED APPLICATION(S)

This is a continuation of International Application No. PCT/JP2014/053795 filed on Feb. 18, 2014, and claims priority from Japanese Patent Application No. 2013-052275 filed on Mar. 14, 2013, the entire disclosures of which are incorporated herein by reference.

### BACKGROUND

1. Technical Field

The present invention relates to a pattern forming method, an actinic ray-sensitive or radiation-sensitive resin composition, a method of manufacturing an electronic device, and an electronic device. More specifically, the present invention relates to a pattern forming method suitable for a manufacturing process of a semiconductor such as an IC, a manufacture of a liquid crystal and a circuit board such as a thermal head, and furthermore, other lithography processes of photofabrication, an actinic ray-sensitive or radiation-sensitive resin composition, a method of manufacturing an electronic device, and an electronic device. In particular, the present invention relates to a pattern forming method suitable for exposure in an ArF exposure apparatus and an ArF liquid immersion projection exposure apparatus as well as an EUV exposure apparatus which uses far-ultraviolet rays having a wavelength of 300 nm or less as a light source, an actinic ray-sensitive or radiation-sensitive resin composition, a method of manufacturing an electronic device, and an electronic device.

2. Background Art

Since a resist for a KrF excimer laser (248 nm) was developed, a pattern forming method using chemical amplification has been used in order to complement desensitization caused by light absorption. For example, in a positive-type chemical amplification method, first, a photoacid-generating agent included in an exposed portion decomposes upon irradiation with light and generates an acid. Thereafter, in a process such as post exposure bake (PEB), and the like, an alkali-insoluble group included in the photosensitive composition is changed to an alkali-soluble group by the catalytic action of the generated acid. Subsequently, development is performed using, for example, an alkaline solution. Accordingly, the exposed portion is removed, so that a desired pattern is obtained.

In the above method, various alkaline developers have been suggested as an alkaline developer. For example, as the alkaline developer, a water-based alkaline developer with 2.38% by mass of TMAH (tetramethylammonium hydroxide aqueous solution) is universally used.

In the positive type chemical amplification method, providing a group degraded by an acid via a polycyclic hydrocarbon group as a spacer to the polymer backbone has been attempted, from the viewpoint of a resolution, a dry etching resistance improvement, a pattern forming performance improvement (for example, Japanese Patent No. 3390702, Japanese Patent Application Laid-Open No. 2008-58538, Japanese Patent Application Laid-Open No. 2010-254639, Japanese Patent Application Laid-Open No. 2010-256873, and Japanese Patent Application Laid-Open No. 2000-122295).

Further, in the positive type chemical amplification method, a method for using an acid-decomposable resin containing a specific tertiary ester unit having a cyclic ether structure has been known from the viewpoint of a swelling, a pattern shape and a LWR (International Publication No. 2007/094473, Japanese Patent No. 2010-102033, and Japanese Patent No. 2012-181272).

Further, in order to make semiconductor elements finer, a wavelength of an exposure light source has been shortened and a projection lens with a high numerical aperture (high NA) has been used, and thus an exposure machine using an ArF excimer laser having a wavelength of 193 nm as a light source has been currently developed. As a technique for further improving resolution, a method (that is, a liquid immersion method) of filling a liquid having a high refractive index (hereinafter, also referred to as a “liquid for liquid immersion”) between a projection lens and a sample has been proposed. In addition, EUV lithography that performs exposure with ultraviolet rays having a shorter wavelength (13.5 nm) has also been proposed.

However, it is very difficult to find an appropriate combination of a resist composition, a developer, a rinse liquid and the like required to form a pattern having comprehensively excellent performance.

Recently, a pattern forming method using a developer including an organic solvent has also been developed (see, for example, Japanese Patent No. 2008-292975 and Japanese Patent No. 2010-197619). For example, Japanese Patent No. 2008-292975 and Japanese Patent No. 2010-197619 discloses a pattern forming method including a process of coating, on a substrate, a resist composition of which solubility increases with respect to an alkaline developer and solubility decreases with respect to an organic solvent developer upon irradiation with an actinic ray or radiation, an exposure process, and a development process using the organic solvent developer. According to this method, it is possible to stably form a fine pattern with high accuracy.

However, in the pattern forming methods as described above, there is need to further improve roughness performance, uniformity of a local pattern dimension, and exposure latitude, and suppress film reduction under development.

An object of the present invention is to provide a pattern forming method, an actinic ray-sensitive or radiation-sensitive resin composition used therefor, a method of manufacturing an electronic device using same, and an electronic device, which are excellent in roughness performance such as line width roughness, uniformity of a local pattern dimension, and exposure latitude and which may suppress film thickness reduction, so called film reduction, of the pattern portion formed during development.

### SUMMARY

The present invention has the following configuration, and the problems of the present invention are accordingly solved.

[1] A pattern forming method including:

(i) forming a film by using an actinic ray-sensitive or radiation-sensitive resin composition containing (A) a resin containing a repeating unit (p) having a structure in which a polar group is protected by a leaving group capable of decomposing and leaving by an action of an acid, and (B) a compound capable of generating an acid upon irradiation with an actinic ray or radiation;

(ii) exposing the film; and

(iii) developing the film exposed, by using an organic solvent-containing developer to form a negative pattern,

wherein the repeating unit (p) contains a repeating unit (p1) having a structure in which a hydrogen atom in a carboxyl group is substituted by a leaving group capable of decomposing and leaving by the action of an acid, and

the leaving group in the repeating unit (p1) contains a group having a polar group and a quaternary carbon atom directly bonded to the —COO— group in the carboxyl group.

[2] The pattern forming method according to [1],

wherein a molecular weight of a leaving product produced from the repeating unit (p1) by the action of an acid is 250 or less.

[3] The pattern forming method according to [1] or [2],

wherein a content of the repeating unit (p) is 55 mol % or more based on a total repeating unit of the resin (A).

[4] The pattern forming method according to any one of [1] to [3],

wherein a content of the repeating unit (p) is 80 mol % or more based on a total repeating unit of the resin (A).

[5] The pattern forming method according to any one of [1] to [4],

wherein the polar group contained in the leaving group is a hydroxyl group, a keto group, a cyano group, a sulfoxide group, a sulfonyl group, a sulfonamide group, a nitro group, an amide group, a urethane group, a carbonate group, a carboxylic acid group, an ether group, a thioether group, a lactone ring, a sultone ring, or a group formed by combining two or more thereof.

[6] The pattern forming method according to any one of [1] to [5],

wherein a weight average molecular weight of the resin (A) is 15,000 or more.

[7] The pattern forming method according to any one of [1] to [6],

wherein the compound (B) is a compound capable of generating an organic acid represented by Formula (V) or (VI) upon irradiation with actinic rays or radiation:

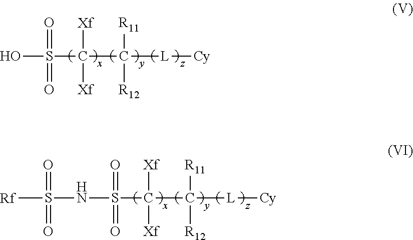

wherein in Formulas,

each Xf independently represents a fluorine atom or an alkyl group substituted with at least one fluorine atom,

each L independently represents a divalent linking group,

each of R₁₁ and R₁₂ independently represents a hydrogen atom, a fluorine atom or an alkyl group,

Cy represents a cyclic organic group,

Rf is a group containing a fluorine atom,

x represents an integer of 1 to 20,

y represents an integer of 0 to 10, and

z represents an integer of 0 to 10.

[8] The pattern forming method according to any one of [1] to [7],

wherein the resin (A) is a resin having, as the repeating unit (p1), a repeating unit represented by Formula (p1a), (p1b) or (p1c):

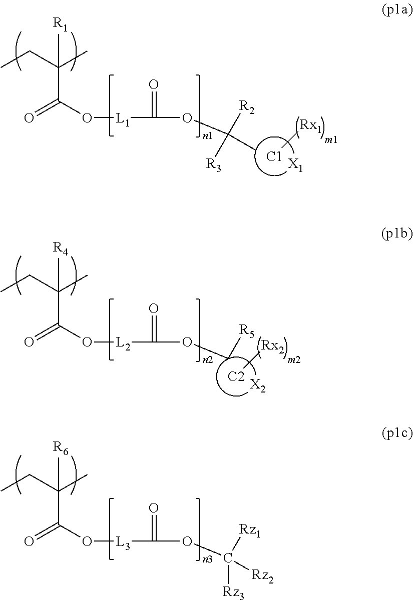

wherein in Formula (p1a),

R₁ represents a hydrogen atom, an alkyl group, a halogen atom, a cyano group or an alkyloxy carbonyl group,

each of R₂ and R₃ independently represents an alkyl group or a cycloalkyl group,

L₁ represents an alkylene group in which some of carbon atoms may be substituted with an ether group,

C1 represents a cyclic hydrocarbon group, and

X₁ represents, in the cyclic hydrocarbon group, a single bond, an ether group, a thioether group, an ester group, a sulfonate ester group, an amide group, a sulfonamide group or a keto group,

Rx₁ represents, as the polar group contained in the leaving group in the repeating unit (p1), a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed by combining two or more thereof,

n₁ represents an integer of 0 to 3, and

m₁ represents an integer of 0 to 3, provided that when m₁ is 0, X₁ represents, as the polar group contained in the leaving group in the repeating unit (p1), an ether group, a thioether group, an ester group, a sulfonate ester group, an amide group, a sulfonamide group or a keto group,

in Formula (p1 b), R₄ represents a hydrogen atom, an alkyl group, a halogen atom, a cyano group or an alkyloxycarbonyl group,

R₅ represents an alkyl group or a cycloalkyl group,

L₂ represents an alkylene group in which some of carbon atoms may be substituted with an ether group,

C2 represents a cyclic hydrocarbon group,

X₂ represents, in the cyclic hydrocarbon group, a single bond, an ether group, a thioether group, an ester group, a sulfonate ester group or a keto group,

Rₓ₂ represents, as the polar group contained in the leaving group in the repeating unit (p1), a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed in combination of two or more thereof,

n₂ represents an integer of 0 to 3, and

m₂ represents an integer of 0 to 3, provided that when m₂ is 0, X₂ represents, the polar group contained in the leaving group in the repeating unit (p1), an ether group, a thioether group, an ester group, a sulfonate ester group, an amide group, a sulfonamide group, or a keto group,

in Formula (p1c), R₆ represents a hydrogen atom, an alkyl group, a halogen atom, a cyano group or an alkyloxycarbonyl group,

R₅ represents an alkyl group or a cycloalkyl group,

L₃ represents an alkylene group that some of carbon atoms may be substituted with an ether group,

each of R_{z1} to R_{z3} independently represents an alkyl group, provided that at least one of R_{z1} to R_{z3} has, as the polar group contained in the leaving group in the repeating unit (p1), a hydroxyl group, a keto group, a cyano group, a sulfoxide group, a sulfonyl group, a sulfonamide group, a nitro group, an amide, an urethane group, a carbonate group, a carboxylic acid group, an ether group or a thioether group, and

n₃ represents an integer of 0 to 3.

[9] The pattern forming method according to any one of [1] to [8],

wherein the actinic ray-sensitive or radiation-sensitive resin composition further contains a compound (N′) having a basic functional group or an ammonium group, and a group capable of generating an acidic functional group upon irradiation with actinic ray or radiation.

[10] The pattern forming method according to any one of [1] to [9],

wherein the developer is a developer containing at least one organic solvent selected from the group consisting of a ketone-based solvent, an ester-based solvent, an alcohol-based solvent, an amide-based solvent and an ether-based solvent.

[11] An actinic ray-sensitive or radiation-sensitive resin composition, for use in a pattern forming method for forming a negative pattern by developing a film with an organic solvent-containing developer, the resin composition including:

(A) a resin having a repeating unit (p) having a structure in which a polar group is protected with a leaving group capable of decomposing and leaving by an action of an acid; and

(B) a compound capable of generating an acid upon irradiation with actinic ray or radiation,

wherein the repeating unit (p) contains a repeating unit (p1) having a structure in which a hydrogen atom in a carboxyl group is substituted by a leaving group capable of decomposing and leaving by the action of an acid, and

the leaving group in the repeating unit (p1) contains a group having a polar group and a quaternary carbon atom directly bonded to the —COO— group in the carboxyl group.

[12] A method of manufacturing an electronic device including the pattern forming method according to any one of [1] to [10].

[13] An electronic device manufactured from the method of manufacturing an electronic device according to [12].

According to the present invention, it is possible is to provide a pattern forming method, which is excellent in roughness performance such as line width roughness, uniformity of a local pattern dimension, and exposure latitude so that film thickness reduction, so called film reduction, of the pattern portion formed during development may be suppressed, an actinic ray-sensitive or radiation-sensitive resin composition used therefor, a method of manufacturing an electronic device using the same, and an electronic device.

### DETAILED DESCRIPTION OF EXEMPLARY EMBODIMENTS

Hereinafter, embodiments of the present invention will be described in detail.

In the representation of a group (atomic group) in the present specification, the representation which does not describe the substitution and unsubstitution includes a group having no substituent and a group having no substituent. For example, “an alkyl group” includes not only an alkyl group having no substituent (unsubstituted alkyl group) but also an alkyl group having a substituent (substituted alkyl group).

In the present specification, the term “actinic ray” or “radiation” refers to, for example, a bright line spectrum of a mercury lamp, a far-ultraviolet rays typified by excimer laser, an extreme-ultraviolet ray (EUV light), an X-ray, an electron beam (EB) and the like. Also, in the present invention, the term “light” refers to an actinic ray or radiation.

Further, in the present specification, unless otherwise indicated, the term “exposure” includes not only exposure with a mercury lamp, a far-ultraviolet ray typified by excimer laser, an extreme-ultraviolet ray, an X-ray, EUV light and the like, but also lithography with a particle beam such as an electron beam and an ion beam.

The pattern forming method of the present invention is a pattern forming method including:

(i) forming a film by an actinic ray-sensitive or radiation-sensitive resin composition containing (A) a resin having a repeating unit (p) having a structure in which a polar group is protected by a leaving group capable of decomposing and leaving by an action of an acid, and (B) a compound capable of generating an acid upon irradiation with an actinic ray or radiation;

(ii) a process of exposing the film; and

(iii) a process of developing the exposed film by using an organic solvent-containing developer to form a negative pattern,

wherein the repeating unit (p) contains a repeating unit (p1) having a structure in which a hydrogen atom in a carboxyl group is substituted with a leaving group capable of decomposing and leaving by the action of an acid; and the leaving group in the repeating unit (p1) has a group having a polar group and a quaternary carbon atom directly bonded to the —COO— group in the carboxyl group.

The reason that the pattern forming method of the present invention is excellent in roughness performance such as line width roughness, exposure latitude and uniformity of a local pattern dimension, and may suppress film thickness reduction, so called film reduction, of the pattern part formed during development, is not clear, but is assumed as follows.

In general, in the negative pattern forming method using an organic solvent-containing developer (organic developer), dissolution contrast to the exposed portion and the unexposed portion is low, the pattern boundary portion is partially dissolved, thereby aggravating exposure latitude and uniformity of a local pattern dimension, and further it is easy to occur film thickness reduction, so called film reduction, of the pattern portion.

In contrast, the resin (A) used in the present invention has a structure in which a leaving group in which a hydrogen atom in the carboxylic acid is substituted with a leaving group capable of decomposing and leaving by the action of an acid and at the same time has a repeating unit (p1) in which the leaving group has a polar group. The repeating unit (p1) has a low solubility in the organic solvent-containing developer, as compared to a conventionally available acid-decomposable repeating unit. Hence, when it remains without decomposing the repeating unit (p1) in the exposed portion or when it remains in the film as a decomposition product by decomposing with an acid generated by exposure, the dissolution rate of an organic developer in the exposed portion is not increased. Consequently, it is assumed that it is possible to suppress film reduction of the pattern portion. Further, it is believed that roughness performance, uniformity of a local pattern dimension, and exposure latitude are improved.

In addition, the leaving group in the repeating unit (p1) has a quaternary carbon atom directly bonded to —COO— group in the carboxyl group. That is, the resin (A) has the repeating unit (p1) which has a tertiary ester type of acid-decomposable group and thus it is difficult for the resin (A) to perform acid decomposition reaction (reaction in which the leaving group is capable of leaving) in the weak exposed area as compared to the case of using a resin having an acetal-type of acid-decomposable group. Further, the dissolution contrast to the developer with the exposed part and the non-exposed part is low. As a result, it is considered that the resin (A) is excellent in roughness performance, uniformity of local pattern dimension and exposure latitude and may suppress the film thickness reduction.

Hereinafter, an actinic ray-sensitive or radiation-sensitive resin composition that may be used in the present invention will be described.

The actinic ray-sensitive or radiation-sensitive resin composition according to the present invention is used particularly in a negative-type development (development in which solubility in the developer upon exposure is decreased, and thus the exposed portion remains as a pattern, and the unexposed portion is removed). That is, the actinic ray-sensitive or radiation-sensitive resin composition according to the present invention may be used as an actinic ray-sensitive or radiation-sensitive resin composition for organic solvent development, which is used in developing a film with an organic solvent-containing developer. Here, the term “for organic solvent development” refers to a use that is applied to a process of developing a film using a developer including at least an organic solvent.

Accordingly, the present invention relates to an actinic ray-sensitive or radiation-sensitive resin composition used for the pattern forming method including a process of forming a negative pattern by developing a film with an organic solvent-containing developer containing (A) a resin which has a repeating unit (p) having a structure in which a polar group is protected with a leaving group capable of decomposing and leaving by an action of an acid, and (B) a compound which generates an acid upon irradiation with actinic ray or radiation, wherein the repeating unit (p) contains a repeating unit (p1) having a structure in which a leaving group in which a hydrogen atom in the carboxyl group is substituted with a leaving group capable of decomposing and leaving by the action of an acid; and the leaving group in the repeating unit (p1) has a group having a polar group and a quaternary carbon atom directly bonded to the —COO— group in the carboxyl group.

It is preferred that the actinic ray-sensitive or radiation-sensitive resin composition of the present invention is typically a resist composition and preferably a negative resist composition (that is, a resist composition for organic solvent development). In addition, the composition according to the present invention is typically a chemical amplification resist composition.

[1] Resin (A) which has a repeating unit (p) having a structure in which a polar group is protected with a leaving group capable of decomposing and leaving by an action of an acid.

The actinic ray-sensitive or radiation-sensitive resin composition of the present invention contains a resin (A) (hereinafter, also referred to as “acid-decomposable resin”) which has a repeating unit (p) having a structure (hereinafter, also referred to as “acid-decomposable group”) in which a polar group is protected with a leaving group capable of decomposing and leaving a polar group by an action of an acid.

Here, the resin (A) is a resin in which a polarity is increased by the action of an acid, thereby decreasing solubility in the organic solvent-containing developer. Also, the resin (A) is a resin in which the polarity is increased by the action of an acid, thereby increasing solubility in the alkali developer.

The polar group is not particularly limited as long as it is sparingly soluble or insoluble in the organic solvent-containing developer, but acidic groups (conventionally used as a resist developer, a group capable of dissociating in 2.38% by mass of tetramethylamonium hydroxide aqueous solution) such as a phenolic hydroxyl group, a carboxyl group, a fluorinated alcohol group (preferably hexafluoroisopropanol group), a sulfonate group, a sulfonamide group, a sulfonylimide group, an (alkylsulfonyl) (alkylcarbonyl)methylene group, (alkylsulfonyl)(alkylcarbonyl)imide group, a bis(alkylcarbonyl)methylene group, bis(alkylcarbonyl)imide group, a bis(alkyl sulfonyl) methylene group, bis(alkylsulfonyl)imide group, or a tris(alkylcarbonyl)methylene group, or an alcoholic hydroxyl group.

Further, the alcoholic hydroxyl group refers to a hydroxyl group other than a hydroxyl group (phenolic hydroxyl group) bonded directly to the aromatic ring as a hydroxyl group bonded to a hydrocarbon group, and excludes an aliphatic alcohol substituted with an electron withdrawing group such as a fluorine atom at α-position of the hydroxyl group (for example, fluorinated alcohol group (hexafluoroisopropanol group, etc.)). The alcoholic hydroxyl group is preferably a hydroxyl group having pKa of 12 or more and 20 or less.

Preferred examples of the polar group may include a carboxyl group, a fluorinated alcohol group (preferably, hexafluoroisopropanol group), or a sulfonic acid group.

A preferred group as the acid-decomposable group is a group substituted by a group in which a hydrogen atom in these groups is capable of leaving by the acid.

Examples of the group capable of leaving from the acid may include —C(R₃₆)(R₃₇)(R₃₈), —C(R₃₆)(R₃₇)(OR₃₉), —C(R₀₁)(R₀₂)(OR₃₉) and the like.

In the formula, each of R₃₆ to R₃₉ independently represents an alkyl group, a cycloalkyl group, an aryl group, an aralkyl group or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁ and R₀₂ is preferably an alkyl group having 1 to 8 carbon atoms, and examples thereof may include a methyl group, an ethyl group, a propyl group, a n-butyl group, a sec-butyl group, a hexyl group, an octyl group and the like.

The cycloalkyl group of R₃₆ to R₃₉, R₀₁ and R₀₂ may be monocyclic or polycyclic. The carbon number is preferably 3 to 20.

The aryl group of R₃₆ to R₃₉, R₀₁ and R₀₂ is preferably an aryl group having 6 to 10 carbon atoms, and examples thereof may include a phenyl group, a naphthyl group, an anthryl group and the like.

The aralkyl group of R₃₆ to R₃₉, R₀₁ and R₀₂ is preferably an aralkyl group having 7 to 12 carbon atoms, and examples thereof may include a benzyl group, a phenethyl group, a naphthylmethyl group and the like.

The alkenyl group of R₃₆ to R₃₉, R₀₁ and R₀₂ is preferably an alkenyl group having 2 to 8 carbon atoms, and examples thereof may include a vinyl group, an allyl group, a butenyl group, a cyclohexenyl group and the like.

The ring formed by R₃₆ and R₃₇ bonded to each other is preferably a cycloalkyl group (monocyclic or polycyclic). The cycloalkyl group is preferably a monocyclic cycloalkyl group such as a cyclopentyl group or a cyclohexyl group, or a polycyclic cycloalkyl group such as a norbornyl group, a tetracyclodecanyl group, tetracyclododecanyl group, or an adamantyl group, more preferably a monocyclic cycloalkyl group having 5 to 6 carbon atoms, and particularly preferably a monocyclic cycloalkyl group having 5 carbon atoms.

The acid-decomposable group is preferably a cumyl ester group, an enol ester group, an acetal ester group, a tertiary alkyl ester group and the like, and more preferably a tertiary alkyl ester group.

In the present invention, the repeating unit (p) having an acid-decomposable group contains a repeating unit (p1) having a structure in which the hydrogen atom in the carboxyl group is substituted with a leaving group capable of decomposing and leaving by the action of an acid. That is, the resin (A) has the repeating unit (p1) as the repeating unit (p) having an acid-decomposable group. Here, the leaving group in the repeating unit (p1) is a group having a polar group and a quaternary carbon atom directly bonded to the —COO— group in the carboxyl group.

The polar group possessed by the leaving group in the repeating unit (p1) is not particularly limited, but examples thereof may also be the same as those described above with regard to the polar groups in the acid-decomposable group. Preferred are a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group, a lactone ring, a sultone ring, or a combination thereof.

The leaving group in the repeating unit (p1) may include, for example, —C(R₅₁) (R₅₂) (R₅₃) and the like.

In the formula, each of R₅₁ to R₅₃ independently represents an alkyl group, a cycloalkyl group, an aryl group, an aralkyl group or an alkenyl group. R₅₁ and R₅₂ may be bonded to each other to form a ring. However, when R₅₁, R₅₂, R₅₃ and R₅₁ and R₅₂ are bonded to each other to form a ring, at least one of the corresponding rings has a polar group, and specific examples and preferred examples are the same as those as described above.

The alkyl group of R₅₁ to R₅₃ is preferably an alkyl group having 1 to 8 carbon atoms, and specific examples thereof are the same as those described with regard to the alkyl groups of R₃₆ to R₃₉, R₀₁ and R₀₂.

The cycloalkyl group of R₅₁ to R₅₃ may be a monocyclic type or a polycyclic type, preferably having 3 to 20 carbon atoms, and specific examples thereof are the same as those described with regard to the cycloalkyl groups of R₃₆ to R₃₉, R₀₁ and R₀₂.

The aryl group of R₅₁ to R₅₃ is preferably an aryl group having 6 to 10 carbon atoms, and specific examples thereof are the same as those described with regard to the aryl groups of R₃₆ to R₃₉, R₀₁ and R₀₂.

The aralkyl group of R₅₁ to R₅₃ is preferably an aralkyl group having 7 to 12 carbon atoms, and specific examples thereof are the same as those described with regard to the aralkyl group of R₃₆ to R₃₉, R₀₁ and R₀₂.

The alkenyl groups of R₅₁ to R₅₃ is preferably an alkenyl group having 2 to 8 carbon atoms, and specific examples thereof are the same as those described with regard to the alkenyl group of R₃₆ to R₃₉, R₀₁ and R₀₂.

The ring formed by bonding of R₅₁ and R₅₂ is preferably a cycloalkyl group (monocyclic or polycyclic), and specific examples thereof are the same as those described with regard to the ring formed by R₃₆ and R₃₇ bonded to each other.

The resin (A) is preferably a resin having a repeating unit represented by Formulas (p1a), (p1b) or (p1c) as the repeating unit (p1).

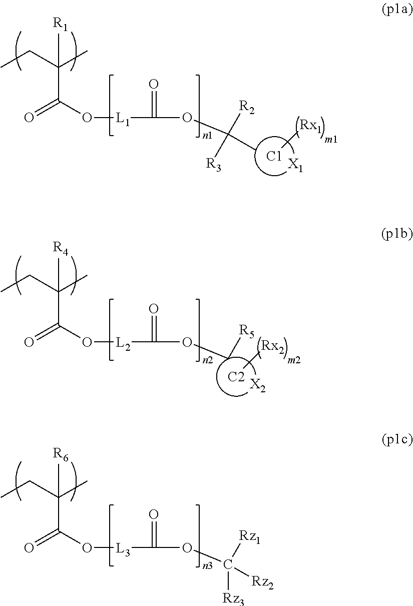

In Formula (p1a), R₁ is a hydrogen atom, an alkyl group, a halogen atom, a cyano group or an alkyloxy carbonyl group. Each of R₂ and R₃ independently represents an alkyl group or a cycloalkyl group. L₁ represents an alkylene group in which some of carbon atoms may be substituted by an ether group. C1 represents a cyclic hydrocarbon group, and X₁ represents a single bond in the cyclic hydrocarbon group, an ether group, a thioether group, an ester group, a sulfonate ester group, an amide group, a sulfonamide group or a keto group.

Rx₁ is a polar group possessed by the leaving group in the repeating unit (p1) and represents a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed in combination of two or more of the above groups. n₁ represents an integer of 0 to 3.

m₁ represents an integer of 0 to 3. However, when m₁ is 0, X₁ is a polar group possessed by the leaving group in the repeating unit (p1) and represents an ether group, a thioether group, an ester group, a sulfonate ester group, an amide group, a sulfonamido group or a keto group.

In Formula (p1b), R₄ represents a hydrogen atom, an alkyl group, a halogen atom, a cyano group or an alkyloxycarbonyl group. R₅ represents an alkyl group or a cycloalkyl group. L₂ represents an alkylene group in which some of carbon atoms may be substituted by an ether group, C2 represents a cyclic hydrocarbon group, and X₂ represents a single bond in the cyclic hydrocarbon group, an ether group, a thioether group, an ester group, a sulfonate ester group or a keto group.

Rₓ₂ is a polar group possessed by the leaving group in the repeating unit (p1) and represents a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed in combination of two or more of the above groups.

n₂ represents an integer of 0 to 3.

m₂ represents an integer of 0 to 3. However, when m₂ is 0, X₂ is a polar group possessed by the leaving group in the repeating unit (p1) and represents an ether group, a thioether group, an ester group, a sulfonate ester group, an amide group, a sulfonamido group, or a keto group.

In Formula (p1c), R₆ represents a hydrogen atom, an alkyl group, a halogen atom, a cyano group or an alkyloxycarbonyl group. R₅ represents an alkyl group or a cycloalkyl group. L₃ represents an alkylene group that some of carbon atoms may be substituted by an ether group, and each of R_{z1} to R_{z3} independently represents an alkyl group.

However, at least one of R_{z1} to R_{z3} is a polar group possessed by the leaving group in the repeating unit (p1) and represents a hydroxyl group, a keto group, a cyano group, a sulfoxide group, a sulfonyl group, a sulfonamide group, a nitro group, an amide, an urethane group, a carbonate group, a carboxylic acid group, an ether group or a thioether group.

n₃ represents an integer of 0 to 3.

Alkyl group as R₁, R₄ and R₆ may have a substituent (for example, a fluorine atom, etc.).

The alkyl group as R₁, R₄ and R₆ is preferably an alkyl group having 1 to 3 carbon atoms and more preferably a methyl group.

The halogen atom as R₁, R₄ and R₆ is preferably a fluorine atom or a chlorine atom, and more preferably a fluorine atom.

The alkyloxycarbonyl group as R₁, R₄ and R₆ may have a substituent (for example, a fluorine atom, etc.). The alkyl group in the alkyloxycarbonyl group as R₁, R₄ and R₆ is preferably an alkyl group having 1 to 3 carbon atoms, and more preferably a methyl group.

The alkyl group as R₂, R₃ and R₅ is preferably an alkyl group having 1 to 8 carbon atoms, and specific examples thereof are the same as those described with regard to the alkyl groups of R₃₆ to R₃₉, R₀₁ and R₀₂.

The cycloalkyl group as R₂, R₃ and R₅ may be monocyclic or polycyclic. The carbon number is preferably 3 to 20.

The alkyl group of R_{z1} to R_{z3} may be a straight or branched group and preferably an alkyl group having 1 to 8 carbon atoms, and specific examples thereof are the same described with regard to the alkyl groups of R₃₆ to R₃₉, R₀₁ and R₀₂.

The alkylene group in which some carbon atoms of L₁ to L₃ may be substituted by an ether group is preferably an alkylene group having 1 to 6 carbon atoms, and preferably an alkylene group having 1 to 3 carbon atoms.

n₁, n₂ and n₃ are preferably 0 or 1, respectively.

The cyclic hydrocarbon group as C1 and C2 is preferably a cyclic hydrocarbon group having 3 to 10 carbon atoms, and more preferably a cyclic hydrocarbon group having 5 to 10 carbon atoms.

The cyclic hydrocarbon groups as C1 and C2, respectively, may have a substituent other than Rₓ₁ and Rₓ₂, and examples of the substituents may include an alkyl group (having 1 to 4 carbon atoms), a cycloalkyl group (having 3 to 8 carbon atoms), a halogen atom and the like.

The monovalent group represented by Rₓ₁ and Rₓ₂ may have a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed in combination of two or more thereof, and preferably a hydroxyl group, an alkyl carbonyl group, a cyano group, an alkyl sulfoxide group, an alkylsulfonyl group, an alkyl sulfonamide group, a nitro group, an alkyl amide group, an alkyl carbamoyl group, an alkyloxycarbonyl group, a carboxylic acid group, an alkoxy group or an alkylthio group. The carbon number in an alkylcarbonyl group, an alkyl sulfoxide group, an alkylsulfonyl group, an alkyl sulfonamide group, an alkyl amide group, an alkylcarbamoyl group, an alkyloxycarbonyloxy group, an alkoxy group and an alkylthio group is preferably 1 to 6 and more preferably 1 to 3.

The monovalent group represented by Rₓ₁ and Rₓ₂ is preferably a hydroxyl group, a keto group, a sulfoxide group, or a sulfonamide group. In this case, a hydroxyl group, an alkyl carbonyl group, an alkyl sulfoxide group, or an alkyl sulfone amide group is preferred.

m₁ and m₂ are preferably 0 or 1, respectively.

The molecular weight of the leaving product generated from the repeating unit (p1) by the action of an acid (if a plurality of leaving products are generated, weighted average value of the molecular weight by mole fraction (hereinafter, referred to as a molar average value)) is preferably 250 or less, more preferably 200 or less, and particularly preferably 150 or less. Thus, when forming the negative pattern, the film thickness reduction of the pattern portions may be further prevented by reducing the molecular weight of the leaving products so that the exposed portion remains as a pattern.

Here, the phrase “leaving products generated from the repeating unit (p1) by the action of an acid” corresponds to those capable of decomposing and leaving by the action of an acid, which corresponds to the group capable of decomposing and leaving by the action of an acid. For example, if the repeating unit (p1) is a top repeating unit in an example described below, it refers to alkene (specifically, represented by the following Formula) produced by the decomposition of 3-methyltetrahydrofuran site.

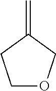

Also, there is no particular restriction on the lower limit of the molecular weight of the leaving products produced by the decomposition of the acid-decomposable group (the mole average value when the plurality of leaving products are is produced), but it is preferably 45 or more and more preferably 55 or more, from the viewpoint that the acid-decomposable group exerts its function.

The repeating unit (p1) may be used either alone or in combination of two or more thereof.

The content of the repeating unit (p1) is preferably 10 to 100 mol %, more preferably 30 to 98 mol %, still more preferably 55 to 95 mol %, and particularly preferably 80 to 90 mol %, based on the total repeating units of the resin (A).

Hereinafter, specific examples of the repeating unit (p1) will be shown, but the present invention is not limited thereto. In the following example, X represents a hydrogen atom, an alkyl group, a halogen atom, a cyano group or an alkyloxycarbonyl group.

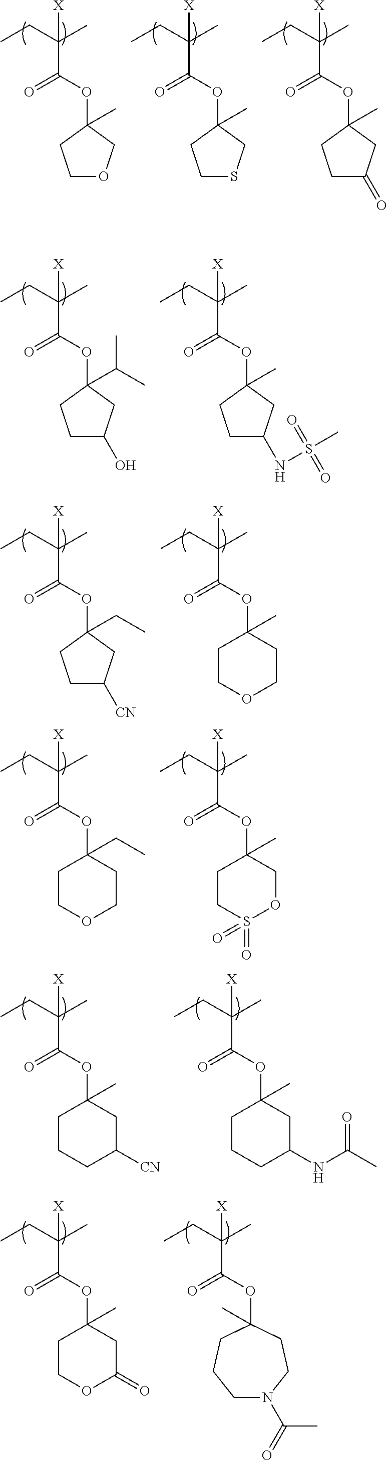

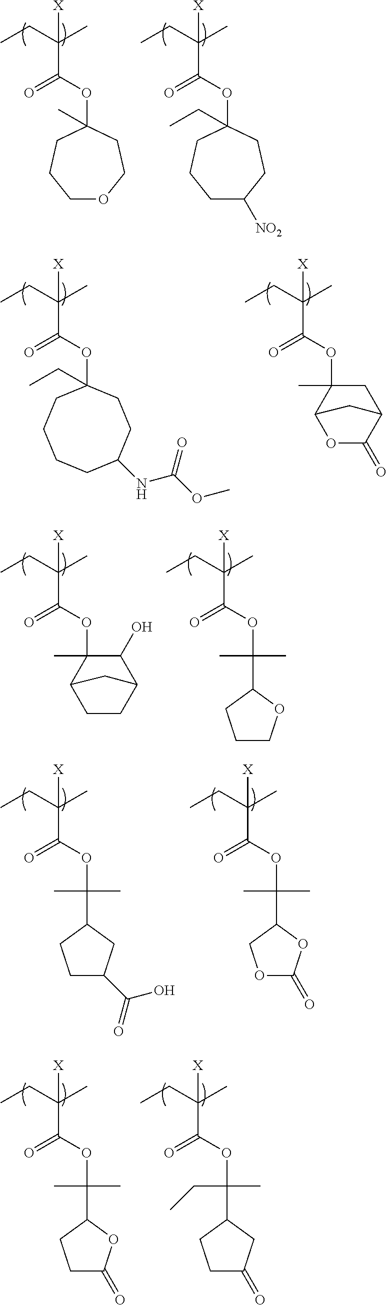

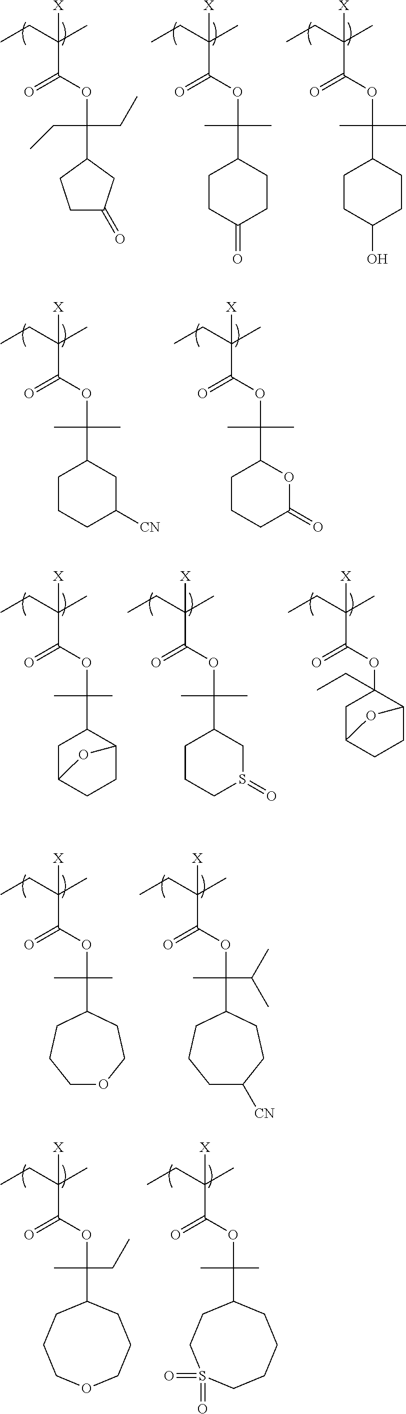

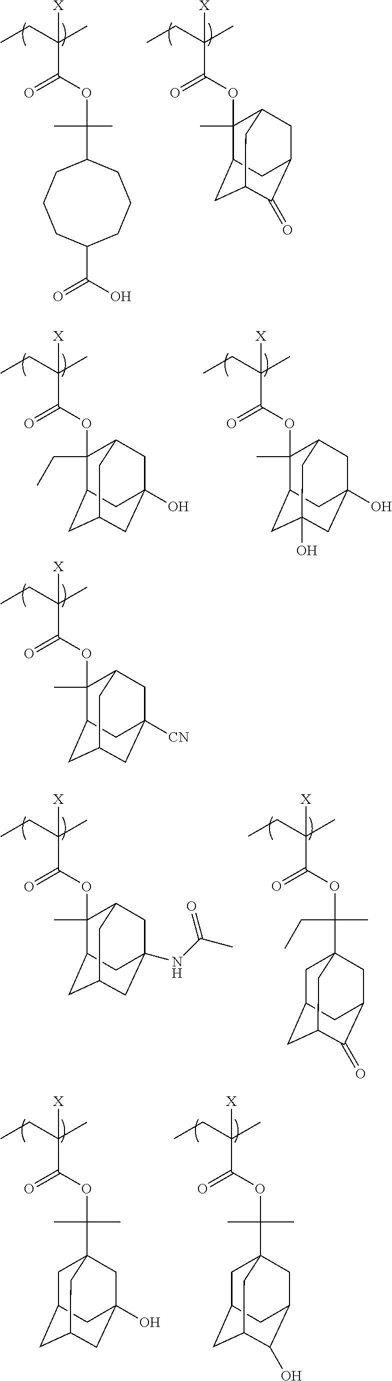

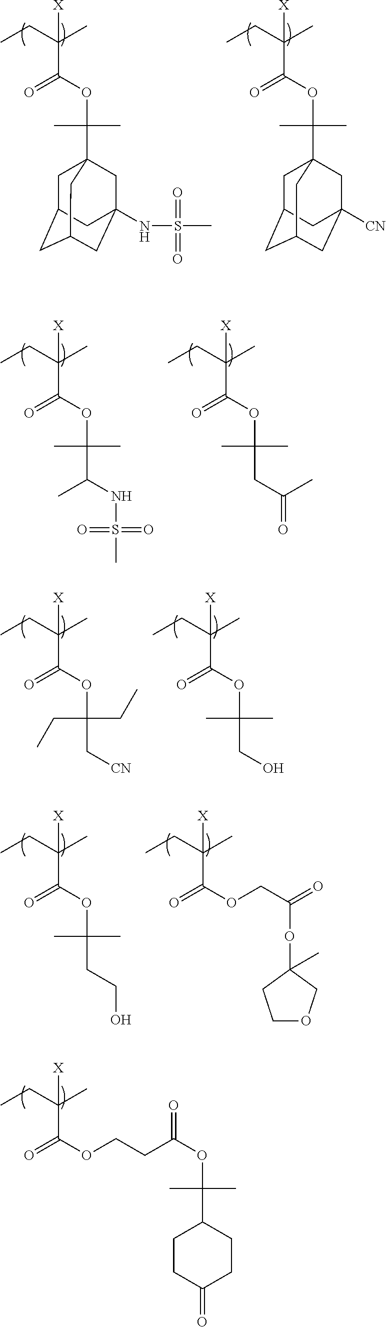

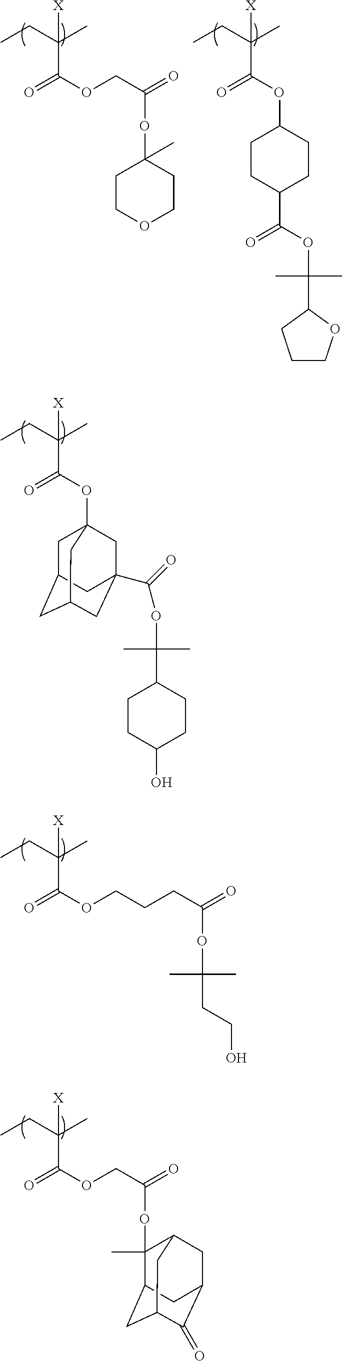

Also, the resin (A) is a repeating unit (p) having an acid-decomposable group and may have repeating units different from the repeating unit (p1) (hereinafter, also referred to as “other acid-decomposable repeating units”).

Other acid-decomposable repeating units may include, for example, a repeating unit represented by the following Formula (aI).

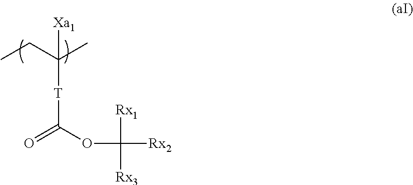

In Formula (aI),

Xa₁ represents a hydrogen atom, an alkyl group, a cyano group or a halogen atom.

T represents a single bond or a divalent linking group.

Each of Rx₁ to Rx₃ independently represents an alkyl group or a cycloalkyl group.

Two of Rx₁ to Rx₃ may be bonded to each other to form a ring structure.

The divalent linking group of T includes an alkylene group, —COO-Rt-group, —O-Rt-group, a phenylene group and the like. In the formula, Rt represents an alkylene group or a cycloalkylene group.

T represents preferably a single bond or —COO-Rt-group. Rt is preferably an alkylene group having 1 to 5 carbon atoms, and more preferably —CH₂— group, —(CH₂)₂— group or —(CH₂)₃— group. T is more preferably a single bond.

The alkyl group of Xₐ₁ may have a substituent, and examples of the substituent may include a hydroxyl group, or a halogen atom (preferably fluorine atom).

The alkyl group of Xₐ₁ is preferably those having 1 to 4 carbon atoms.

Xₐ₁ is preferably a hydrogen atom or a methyl group.

The alkyl group of Rₓ₁, Rₓ₂ and Rₓ₃ may be straight or branched and preferably a group having 1 to 4 carbon atoms.

The cycloalkyl group of Rₓ₁, Rₓ₂ and Rₓ₃ may be a monocyclic cycloalkyl group or a polycyclic cycloalkyl group.

The ring formed by two of Rₓ₁, Rₓ₂ and Rₓ₃ bonded to each other may be a monocyclic cycloalkyl ring or a polycyclic cycloalkyl ring, but a monocyclic cycloalkane ring having 5 or 6 carbon atoms is particularly preferred.

Each of Rₓ₁, Rₓ₂ and Rₓ₃ independently is preferably an alkyl group, and more preferably a straight or branched alkyl group having 1 to 4 carbon atoms.

The respective groups may have a substituent other than a polar group, and examples of the substituent may include an alkyl group (having 1 to 4 carbon atoms), a cycloalkyl group (having 3 to 8 carbon atoms), a halogen atom and the like, and the carbon number is preferably 8 or less. Among them, a group consisting of only hydrogen atoms and carbon atoms is more preferred, and a straight or branched alkyl group or cycloalkyl group is particularly preferred.

Specific examples of the repeating unit represented by Formula (aI) are shown below, but the present invention is not limited to these specific examples

In the specific examples, Rx represents a hydrogen atom, CH₃, CF₃, or CH₂OH. Rxa and Rxb represent an alkyl group having 1 to 4 carbon atoms, respectively. Xa₁ represents a hydrogen atom, CH₃, CF₃ or CH₂OH. Z represents a substituent other than the polar group, if a plurality of Z's is present, the plurality of Z's may be same or different. p represents 0 or a positive integer. Specific examples and preferred examples of Z are the same as specific examples and preferred examples of the substituent which may be possessed by each group, such as Rx₁ to Rx₃.

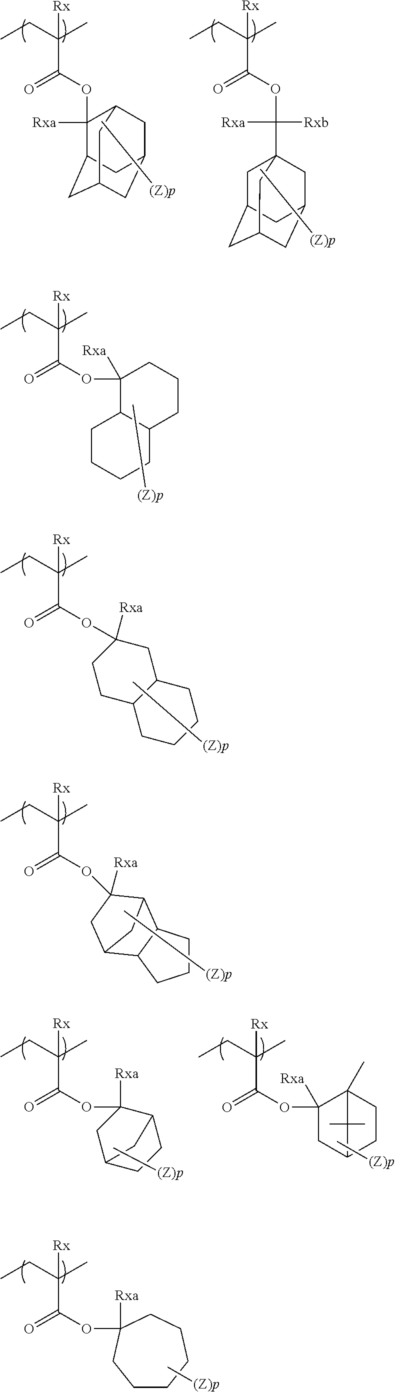

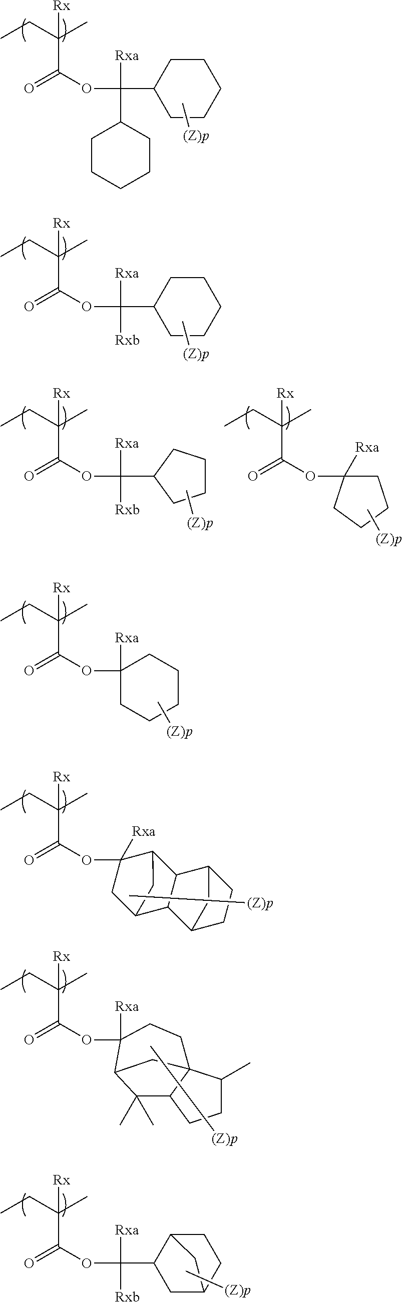

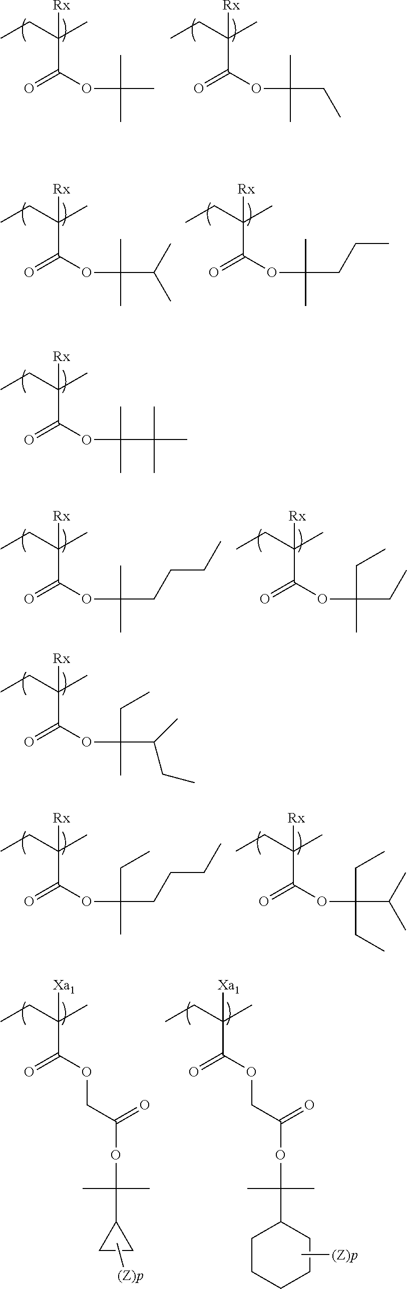

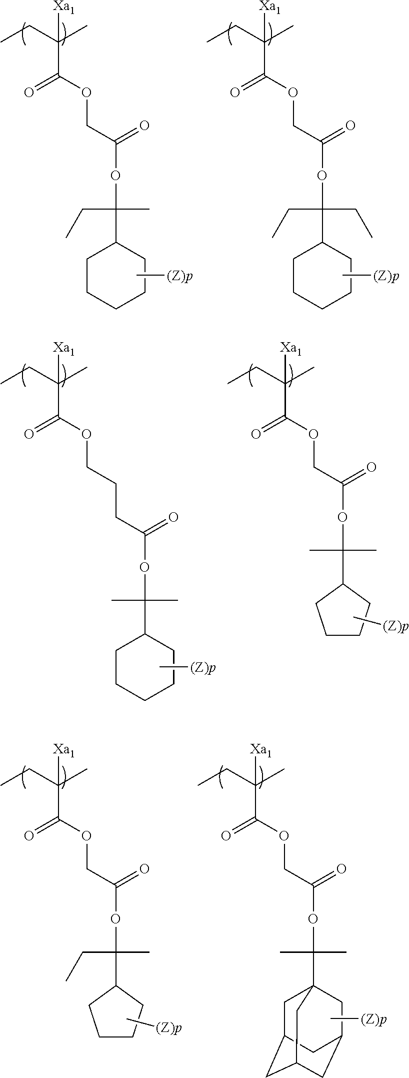

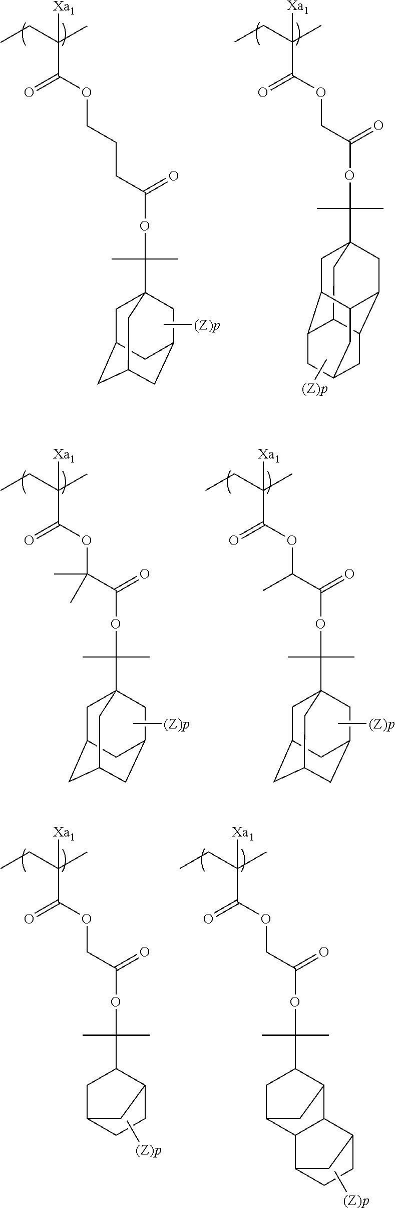

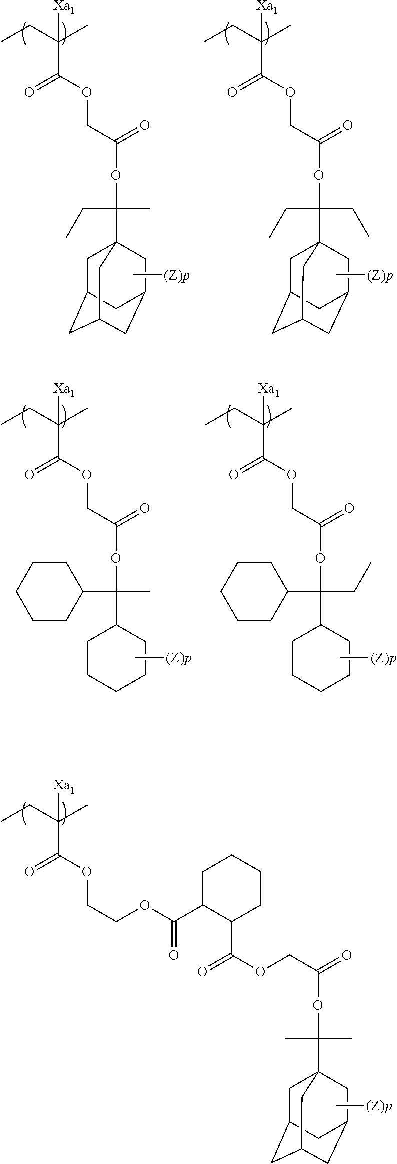

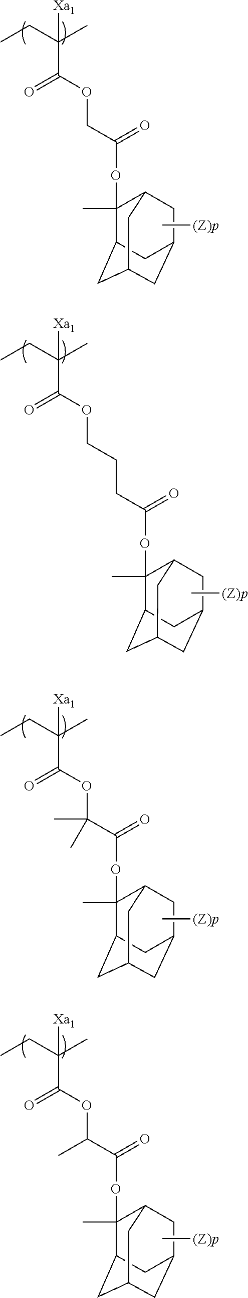

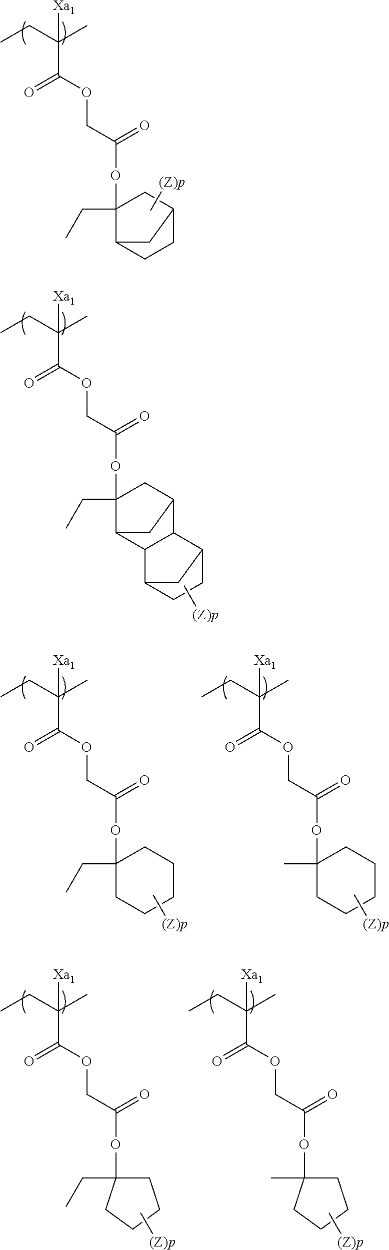

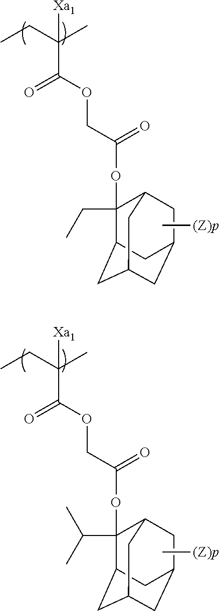

In the following specific example, Xa represents a hydrogen atom, an alkyl group, a cyano group or a halogen atom.

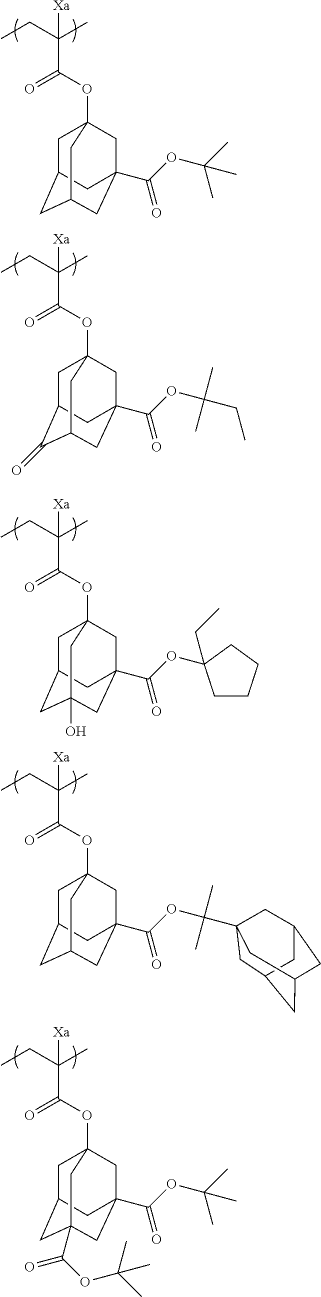

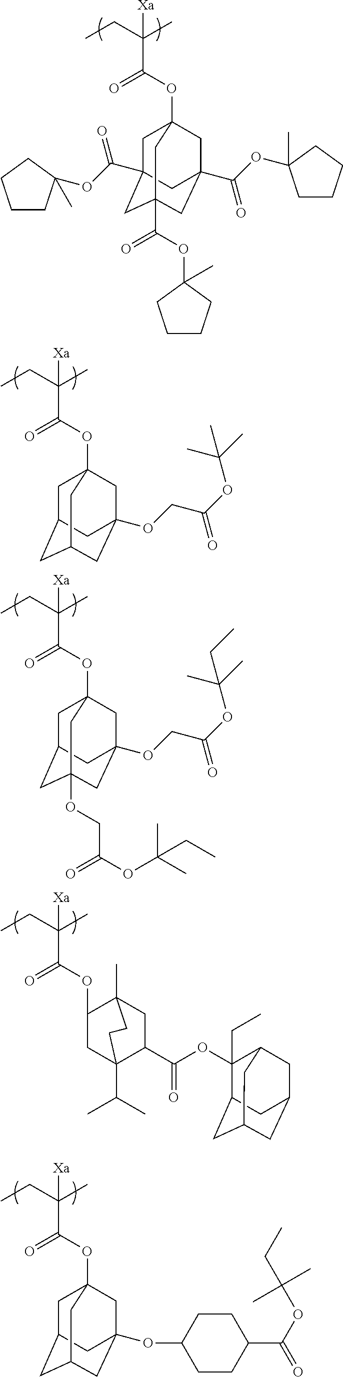

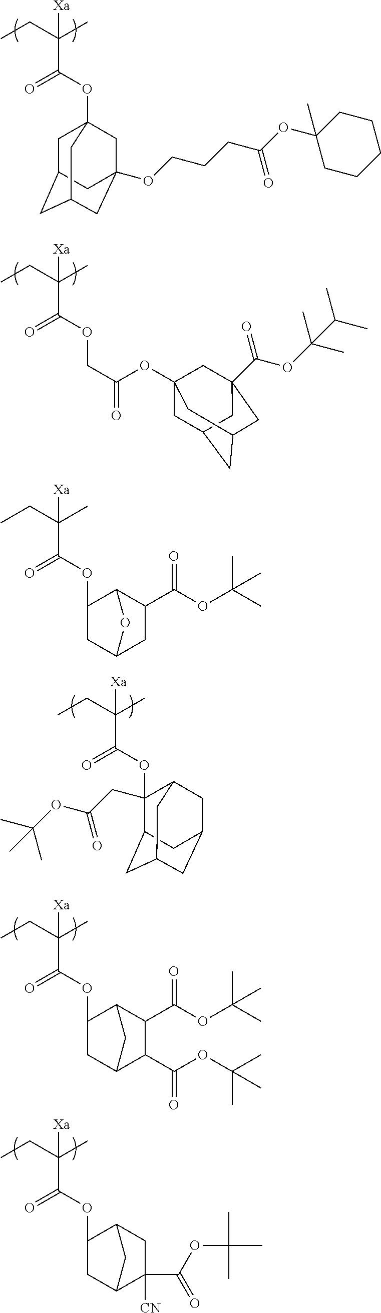

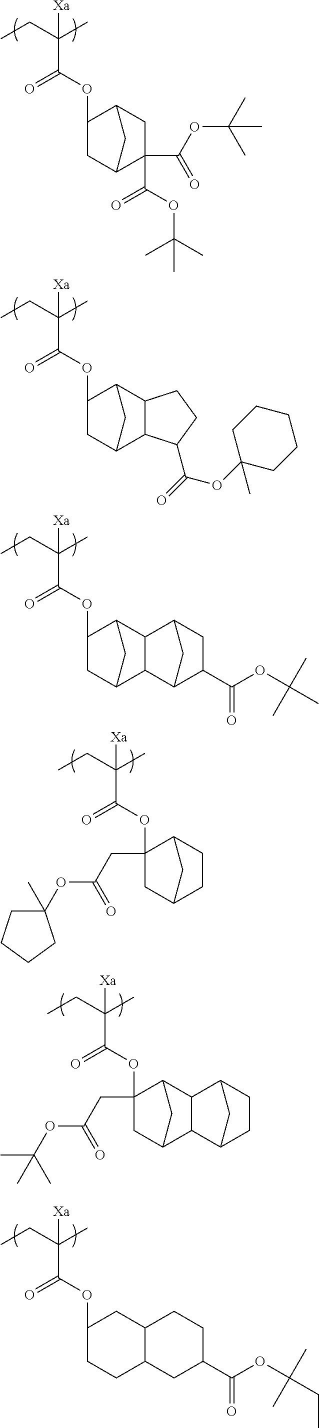

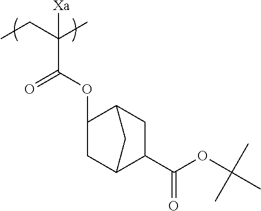

Further, the resin (A) may have repeating units capable of decomposing by the action of an acid to generate an alcoholic hydroxyl group as other acid-decomposable repeating units, as shown below.

In the following specific examples, Xₐ₁ represents a hydrogen atom, CH₃, CF₃ or CH₂OH.

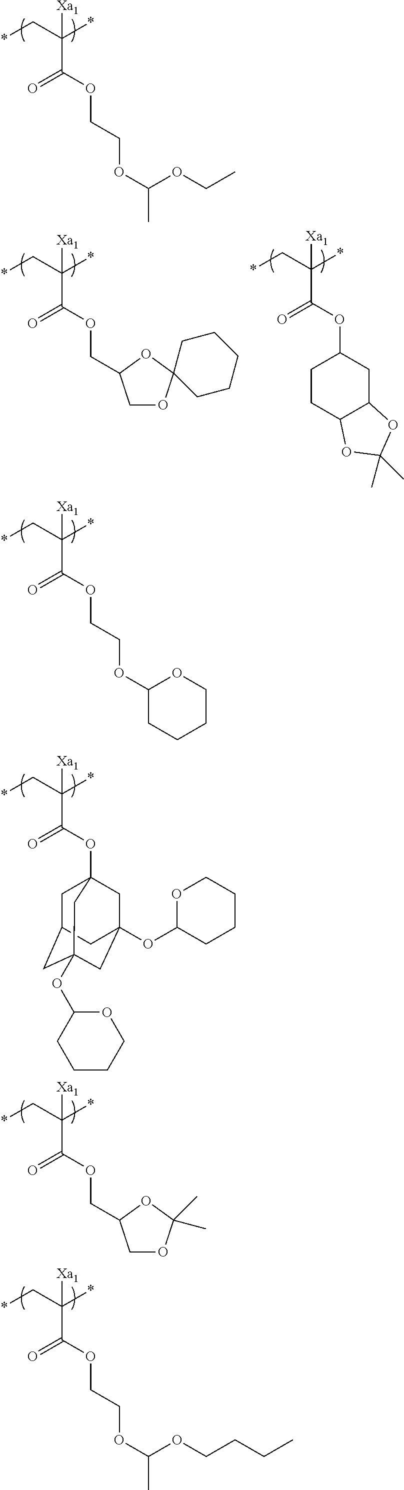

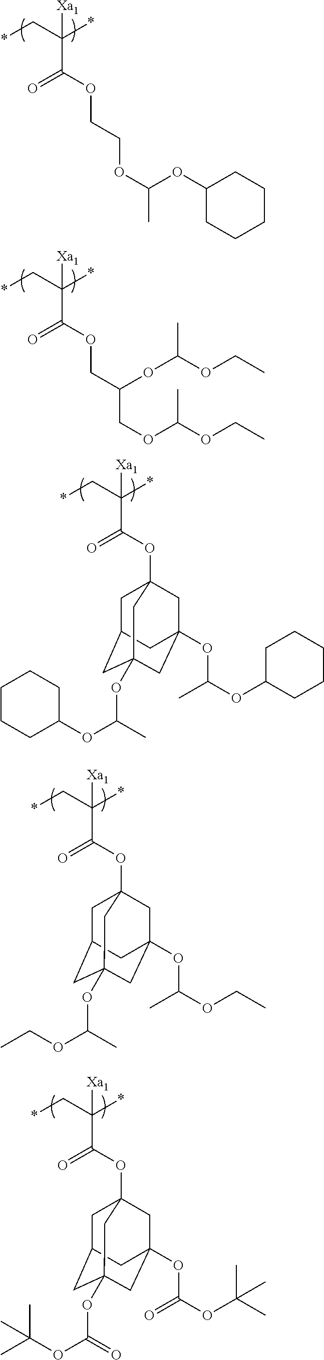

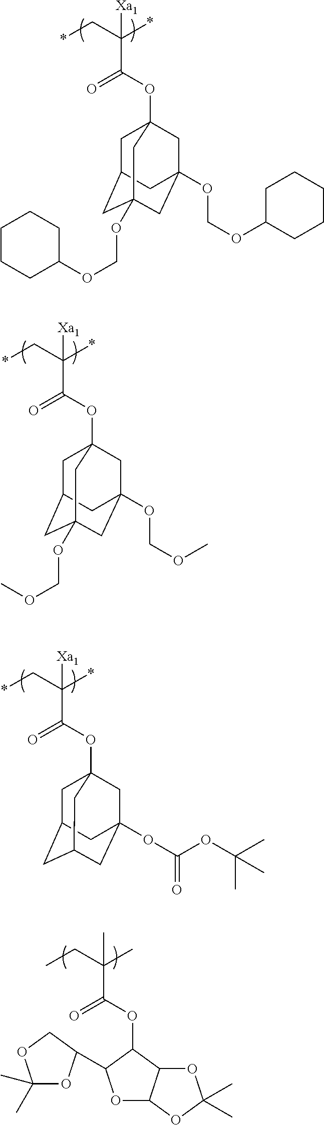

Other acid-decomposable repeating units may be used either alone or in combination of two or more thereof.

The content of the repeating unit (p) having an acid-decomposable group (if a plurality of repeating units (p) having an acid-decomposable group is present, the total thereof) in resin (P) is preferably 15 mol % or more, more preferably 20 mol % or more, still more preferably 55 mol % or more and particularly preferably 80 mol % or more, based on the total repeating units of the resin (P).

The content of the repeating unit (p) having an acid-decomposable group is preferably 100 mol % or less, more preferably 95 mol % or less and still more preferably 90 mol % or less, based on the total repeating units of the resin (A).

The resin (A) may contain a repeating unit having a lactone structure or a sultone structure.

As the group having a lactone structure or a sultone structure, any group may be used as long as the group has a lactone structure or a sultone structure, but a lactone structure having a 5- to 7-membered ring or a sultone structure having a 5- to 7-membered ring is preferred. A group in which another ring structure is condensed to a lactone structure having a 5- to 7-membered ring in the form of forming a bicyclo structure or a spiro structure, or a group in which another ring structure is condensed to a sultone structure having a 5- to 7-membered ring in the form of forming a bicyclo structure or a Spiro structure is more preferred. It is more preferred that the group has a repeating unit having a lactone structure represented by any one of the following Formulas (LC1-1) to (LC1-21) or a sultone structure represented by any one of the following Formulas (SL1-1) to (SL1-3). Further, the lactone structure or sultone structure may be bonded directly to the main chain. A preferred lactone structure is (LC1-1), (LC1-4), (LC1-5), (LC1-6), (LC1-13), (LC1-14) and (LC1-17), and particularly preferably (LC1-4). By using such a specific lactone structure, LER and the development defect are improved.

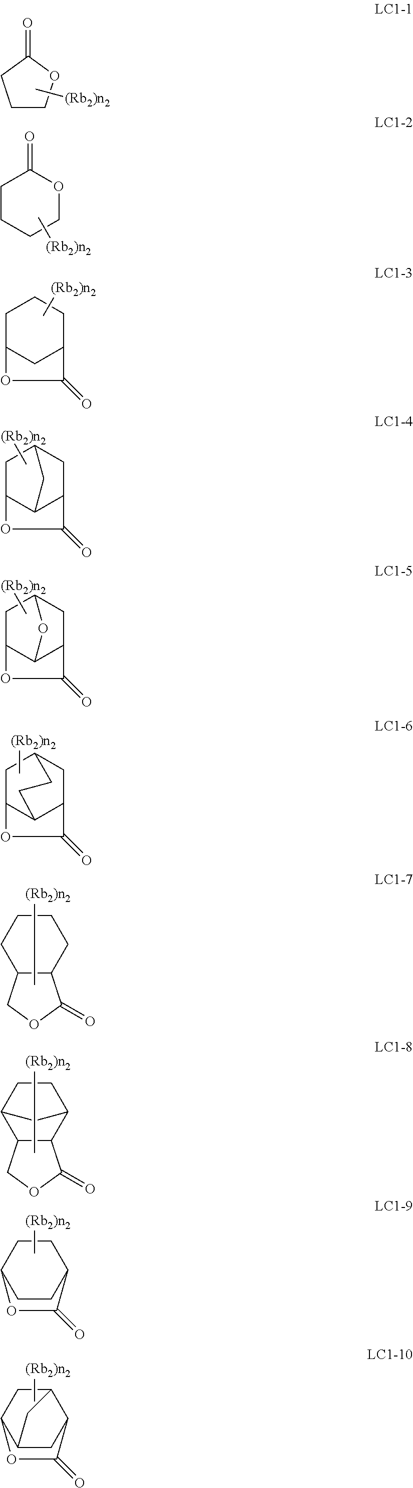

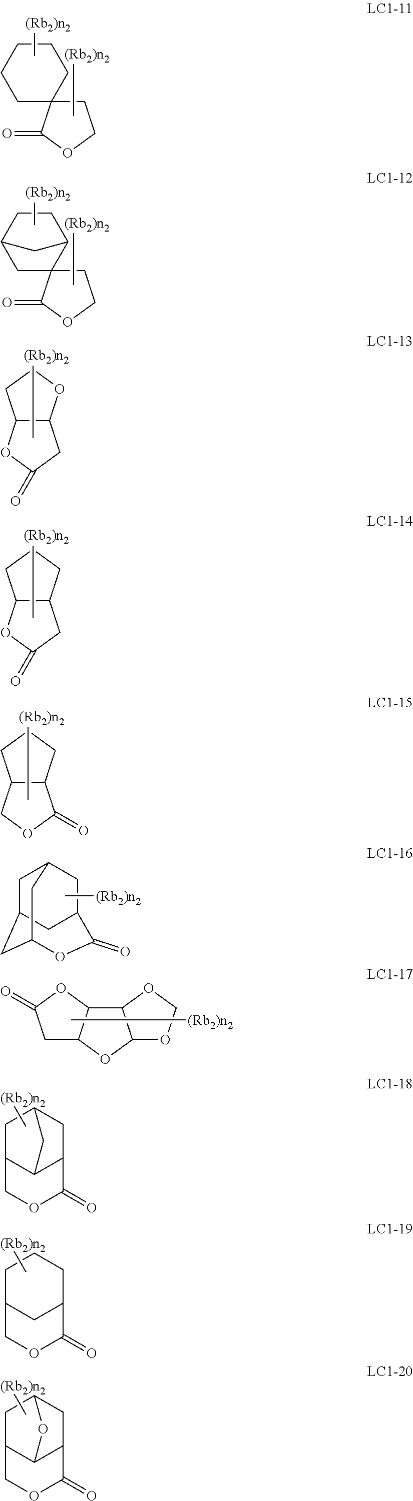

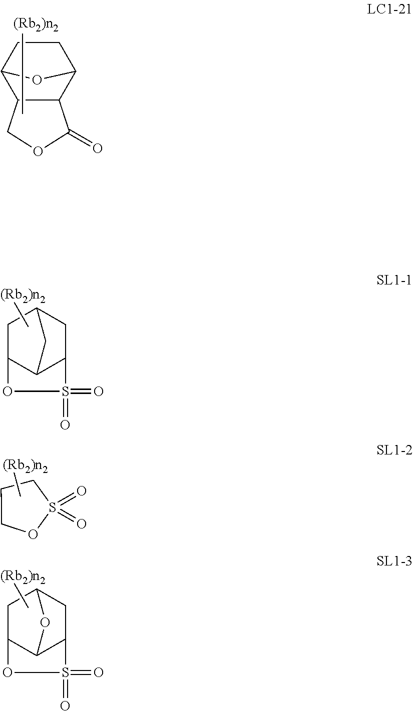

The lactone structure or sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group and the like. An alkyl group having 1 to 4 carbon atoms, a cyano group and an acid-decomposable group are more preferred. n₂ represents an integer of 0 to 4. When n₂ is 2 or more, a plurality of substituents (Rb₂) may be same or different, and the plurality of substituents (Rb₂) may be bonded to each other to form a ring.

The repeating unit having a lactone structure or a sultone structure usually has an optical isomer, and any optical isomer may be used. In addition, one kind of optical isomer may be used alone, or a plurality of optical isomers may be used in mixtures. When one kind of optical isomer is mainly used, the optical purity (ee) thereof is preferably 90% or more, and more preferably 95% or more.

Hereinafter, the repeating unit having a lactone structure or a sultone structure is preferably the repeating unit represented by the following Formula (III).

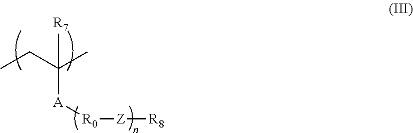

In Formula (III),

A represents an ester bond (a group represented by (—COO—) or an amide bond (a group represented by —CONH—).

When a plurality of R₀ is present, each R₀ independently represents an alkylene group, a cycloalkylene group, or a combination thereof.

When a plurality of Z is present, each Z independently represents a single bond, an ether bond, an ester bond, an amide bond, or an urethane bond
(Group represented by

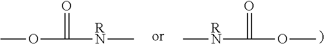

or an urea bond
(Group represented

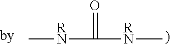

Here, each R independently represents a hydrogen atom, an alkyl group, a cycloalkyl group or an aryl group.

R₈ represents a monovalent organic group having a lactone structure or a sultone structure.

n is the repeating unit of the structure represented by —Rₒ—Z— and represents an integer of 0 to 5, preferably 0 or 1, and more preferably 0. When n is 0, —Rₒ—Z— is not present and n is a single bond.

R₇ represents a hydrogen atom, a halogen atom or an alkyl group.

The alkylene group or a cycloalkylene group of R₀ may have a substituent.

Z is preferably an ether bond, an ester bond and particularly preferably an ester bond.

The alkyl group of R₇ is preferably an alkyl group having 1 to 4 carbon atoms, a methyl group, more preferably a methyl group or an ethyl group and particularly preferably a methyl group.

The alkylene group, the cycloalkylene group in R₀, the alkyl group in R₇ may be substituted, respectively, and examples of the substituent may include a halogen atom such as a fluorine atom, a chlorine atom, or a bromine atom; an alkoxy group such as a mercapto group, a hydroxyl group, a methoxy group, an ethoxy group, an isopropoxy group, a t-butoxy group, a benzyl group; or an acyloxy group such as an acetyloxy group, a propionyl group and the lile.

R₇ is preferably a hydrogen atom, a methyl group, a trifluoromethyl group, or a hydroxymethyl group.

Preferred chain alkylene group in R₀ is preferably a chain alkylene group having 1 to 10 carbon atoms and more preferably 1 to 5 carbon atoms, and may include, for example, a methylene group, an ethylene group, a propylene group and the like. Preferred cycloalkylene group is a cycloalkylene group having 3 to 20 carbon atoms and examples thereof may include a cyclohexylene group, a cyclopentylene group, a norbornylene group, an adamantylene group and the like. In order to exhibit the effects of the present invention, a chain alkylene group is more preferred, and a methylene group is particularly preferred.

The monovalent organic group having a lactone structure or a sultone structure represented by R₈ is not limited as long as it has a lactone structure or a sultone structure. Specific examples thereof may include a lactone structure or a sultone structure represented by any one of (LC1-1) to (LC1-21) and, (SL1-1) to (SL1-3). Among them, a structure represented by (LC1-4) is particularly preferred. In addition, n₂ in (LC1-1) to (LC1-21) is more preferably 2 or less.

Also, R₈ is preferably a monovalent organic group having unsubstituted lactone structure or sultone structure, or a monovalent organic group having unsubstituted lactone structure or sultone structure having a methyl group, a cyano group or an alkoxycarbonyl group as a substituent, and more preferably a monovalent organic group having a lactone structure (cyano lactone) having a cyano group as the substituent.

Specific examples of the repeating unit having a group having a lactone structure or a sultone structure are shown below, but the present invention is not limited thereto.

(In the formulas, Rx represents H, CH₃, CH₂OH or CF₃)

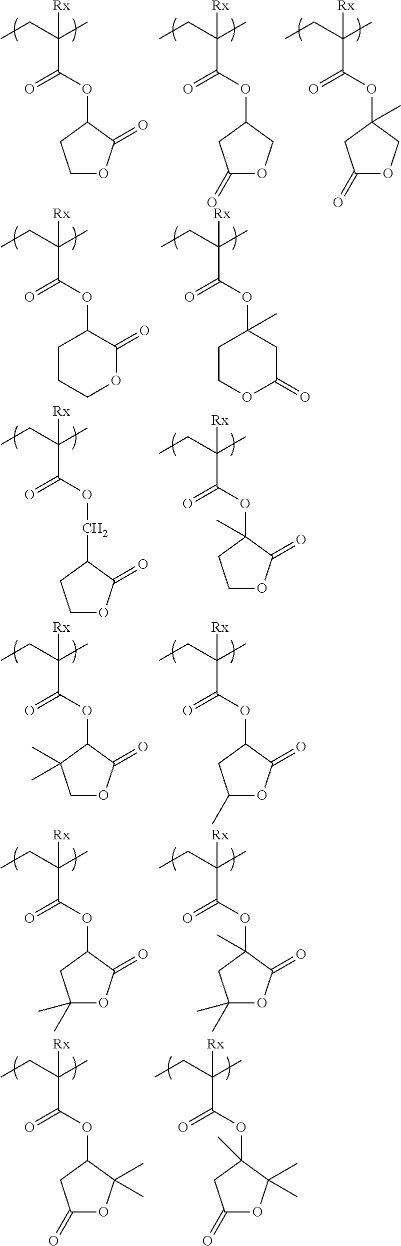

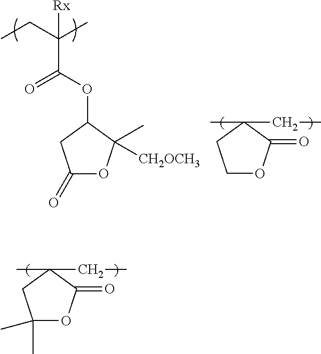

(In the formulas, Rx represents H, CH₃, CH₂OH or CF₃)

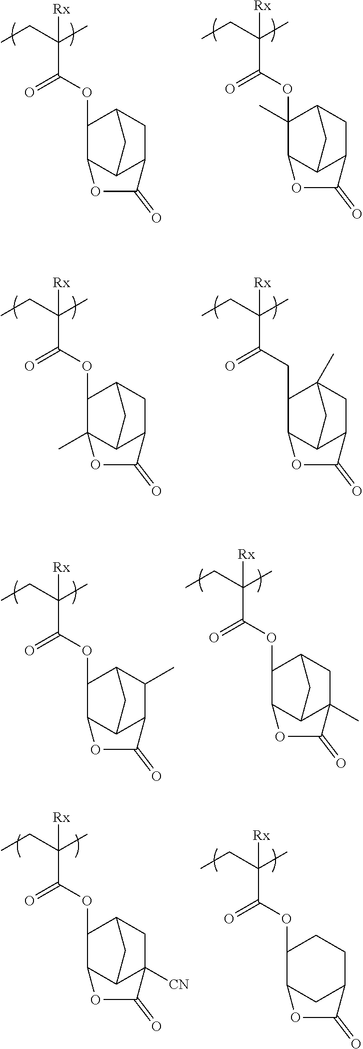

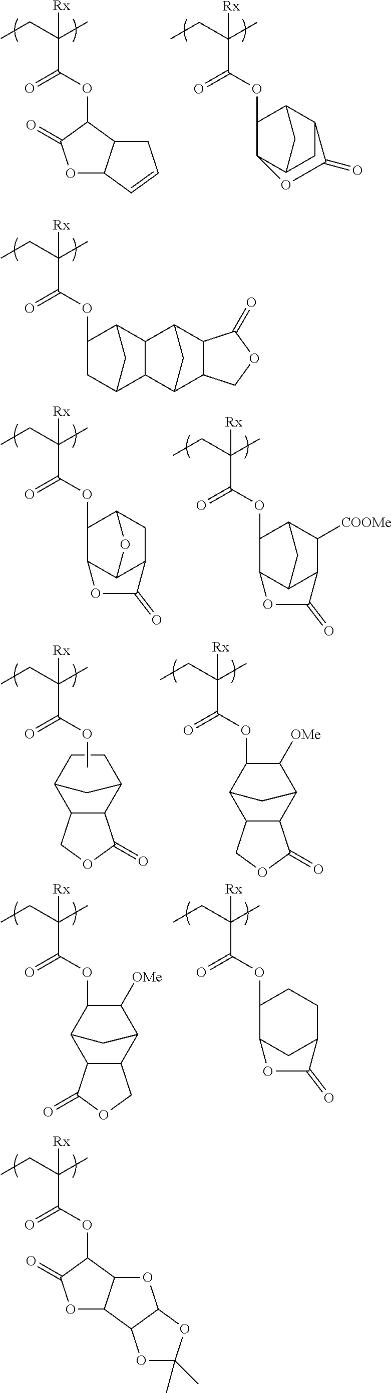

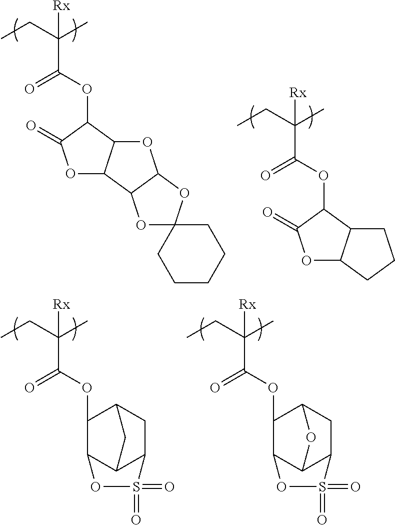

(In the formulas, Rx represents H, CH₃, CH₂OH or CF₃)

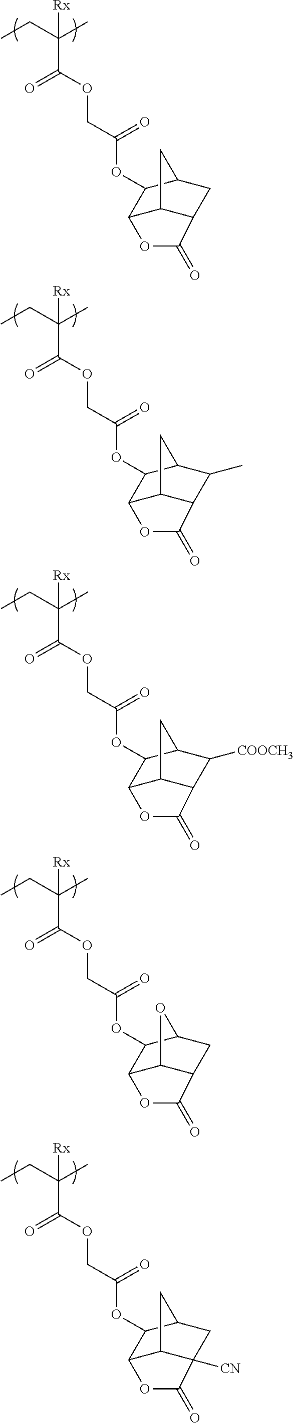

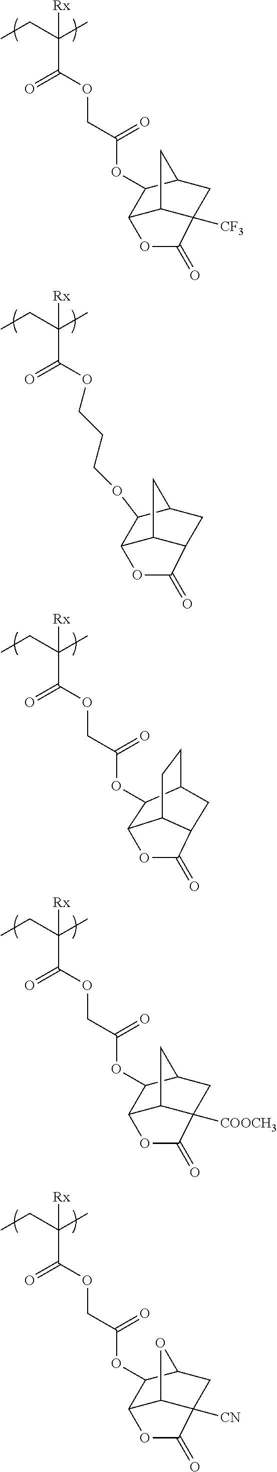

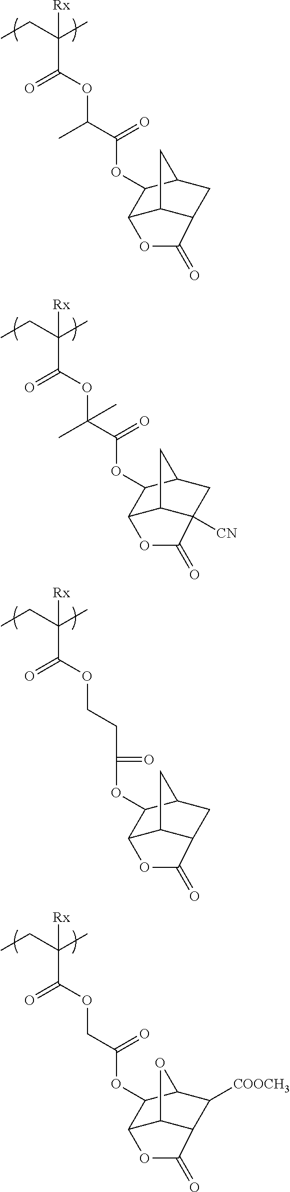

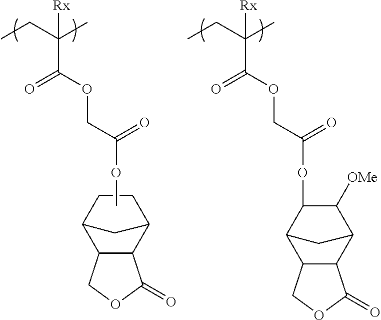

To enhance the effect of the present invention, it is also possible to use in combination of the repeating units having two or more lactone structures or sultone structures.

When the resin (A) contains a repeating unit having a lactone structure or a sultone structure, the content of the repeating unit having a lactone structure or a sultone structure is preferably 5 to 60 mol %, more preferably 5 to 55 mol % and still more preferably 10 to 50 mol %, based on the total repeating units of the resin (A).

Further, the resin (A) may have a repeating unit having a cyclic carbonate ester structure.

The repeating unit having a cyclic carbonate ester structure is preferably a repeating unit represented by the following Formula (A-1).

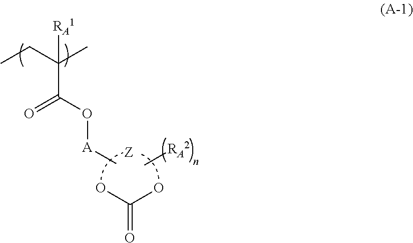

In Formula (A-1), R_{A}¹ represents a hydrogen atom or an alkyl group.

When R_{A}² are 2 or more, each R_{A}² independently represents a substituent.

A represents a single bond or a divalent linking group.

Z represents an atomic group forming a monocyclic or polycyclic structure such as the group represented by —O—C(═O)—O— in the formula.

n represents an integer of 0 or more.

Formula (A-1) will be described in detail below.

The alkyl group represented by R_{A}¹ may have a substituent such as a fluorine atom.

R_{A}¹ preferably represents a hydrogen atom, a methyl group or a trifluoromethyl group and more preferably a methyl group.

The substituent represented by R_{A}² is, for example, an alkyl group, a cycloalkyl group, a hydroxyl group, an alkoxy group, an amino group, or an alkoxycarbonyl amino group. Preferred is an alkyl group having 1 to 5 carbon atoms, and examples thereof may include a straight alkyl group having 1 to 5 carbon atoms; a branched alkyl group having 3 to 5 carbon atoms may be exemplified. The alkyl group may have a substituent such as a hydroxyl group.

n is an integer of 0 or more representing the number of substituents. n is preferably 0 to 4 and more preferably 0.

Examples of the divalent linking group represented by A may include an alkylene group, a cycloalkylene group, an ester bond, an amide bond, an ether bond, an urethane bond, an urea bond, or a combination thereof. The alkylene group is preferably an alkylene group having 1 to 10 carbon atoms and more preferably an alkylene group having 1 to 5 carbon atoms.

In one embodiment of the present invention, A is preferably a single bond or an alkylene group.

Examples of the monocyclic ring containing a —O—C(═O)—O—, represented by Z, may include a 5- to 7-membered ring in a cyclic carbonate ester represented by the following Formula (a) wherein n_{A}=2 to 4, preferably a 5- or 6-membered ring (n_{A}=2 or 3) and more preferably a 5-membered ring (n_{A}=2).

Examples of the polycyclic ring containing a —O—C(═O)—O—, represented by Z, may include a structure in which a cyclic carbonate ester represented by the following Formula (a) and two or more other ring structures are combined together to form a condensed ring, or a structure which forms forms a spiro ring. “Other ring structures” capable of forming a condensed ring or a spiro ring may be an alicyclic hydrocarbon group, or an aromatic hydrocarbon group, or a heterocyclic ring.

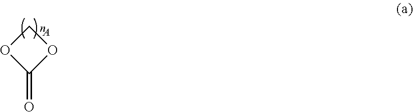

The resin (A) may contain one type of the repeating unit represented by Formula (A-1) or two or more types thereof

In the resin (A), the content of the repeating unit having a cyclic carbonate ester structure (preferably, the repeating unit represented by Formula (A-1)) is preferably 3 to 80 mol %, more preferably 3 to 60 mol %, and particularly preferably 3 to 50 mol %, based on the the total repeating units constituting the resin (A). By using such content, a developability, a low defectivity, a low LWR, a low PEB temperature dependence and a profile and the like as a resist may be improved.

Specific examples of the repeating unit represented by Formula (A-1) are shown below, but the present invention is not limited thereto.

Further, R_{A}¹ in the following specific examples has the same meaning as R_{A}¹ in Formula (A-1).

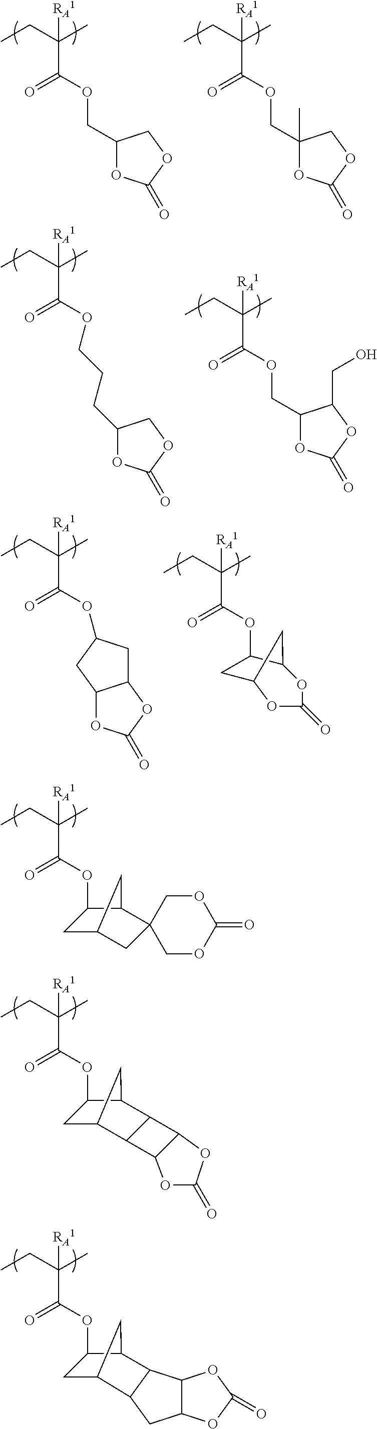

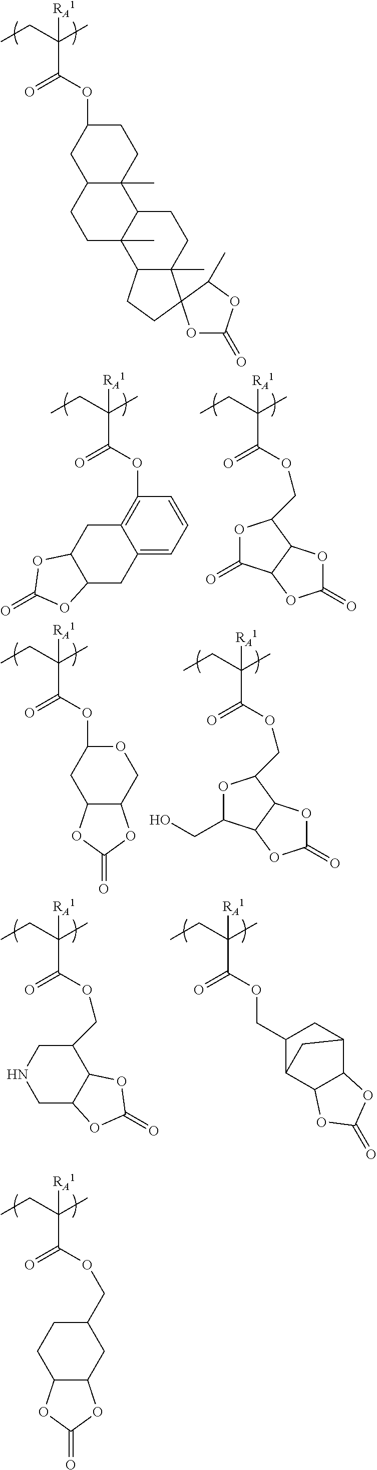

The resin (A) may have a repeating unit having a hydroxyl group, a cyano group or a carbonyl group. Thus, an adhesion of the substrate and an affinity to the developer are increased. The repeating unit having a hydroxyl group, a cyano group or a carbonyl group is preferably the repeating unit having an alicyclic hydrocarbon structure substituted with a hydroxyl group, a cyano group or a carbonyl group and more preferably has no acid-decomposable group.

Also, the repeating unit having an alicyclic hydrocarbon structure substituted with a hydroxyl group, a cyano group or a carbonyl group may preferably be that different from the repeating unit having an acid-decomposable group (i.e., a stable repeating unit to an acid is preferred).

In the alicyclic hydrocarbon structure substituted with a hydroxyl group, a cyano group or a carbonyl group, the alicyclic hydrocarbon structure is preferably an adamantyl group, a diadamantyl group, or a norbomane group.

More preferably, a repeating unit represented by any one of the following Formulas (AIIa) to (AIIc) may be exemplified.

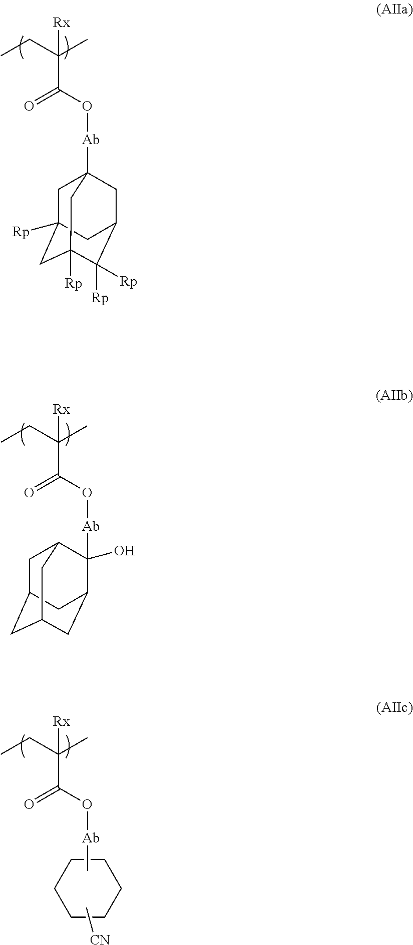

In the formulas, Rₓ represents a hydrogen atom, a methyl group, hydroxymethyl group, or a trifluoromethyl group.

Ab represents a single bond or a divalent linking group.

Examples of the divalent linking group represented by Ab may include an alkylene group, a cycloalkylene group, an ester bond, an amide bond, an ether bond, an urethane bond, an urea bond, or a combination thereof. The alkylene group is preferably an alkylene group having 1 to 10 carbon atoms, more preferably an alkylene group having 1 to 5 carbon atoms, and examples thereof may include a methylene group, an ethylene group, a propylene group, and the like.

In one embodiment of the present invention, Ab is preferably a single bond or an alkylene group.

Rp represents a hydrogen atom, a hydroxyl group or hydroxyalkyl group. A plurality of Rp's may be same as or different, but at least one of Rp's represents a hydroxyl group or a hydroxyalkyl group.

The resin (A) may or may not contain a repeating unit having a hydroxyl group, a cyano group or a carbonyl group, but when the resin (A) contains the repeating unit having a hydroxyl group, a cyano group or a carbonyl group, the content of the repeating unit having a hydroxyl group, a cyano group or a carbonyl group is preferably 1 to 40 mol %, more preferably 3 to 30 mol %, and still more preferably 5 to 25 mol %, based on the total repeating unit of the resin (A).

Specific examples of the repeating unit having a hydroxyl group, a cyano group or a carbonyl group are shown below, but the invention is not limited thereto.

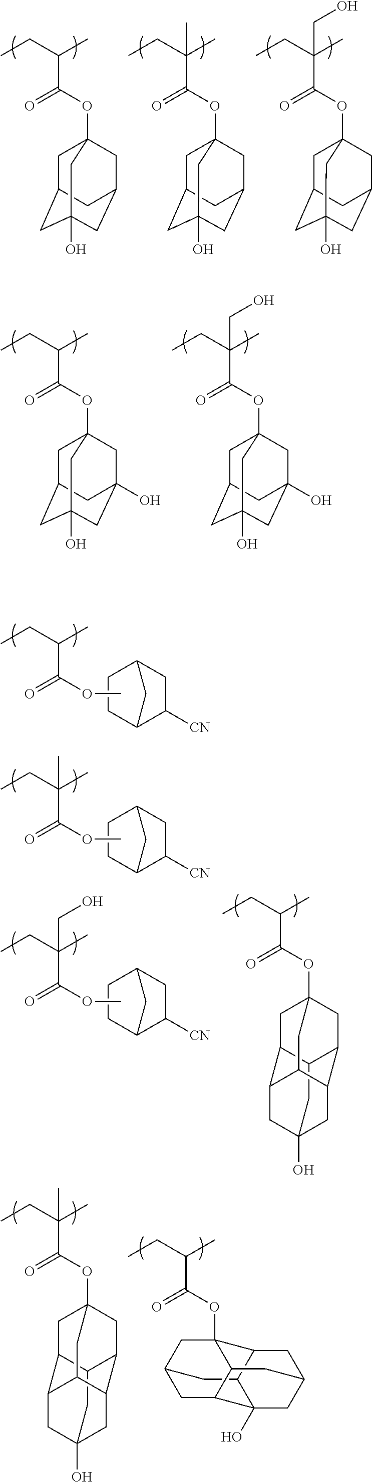

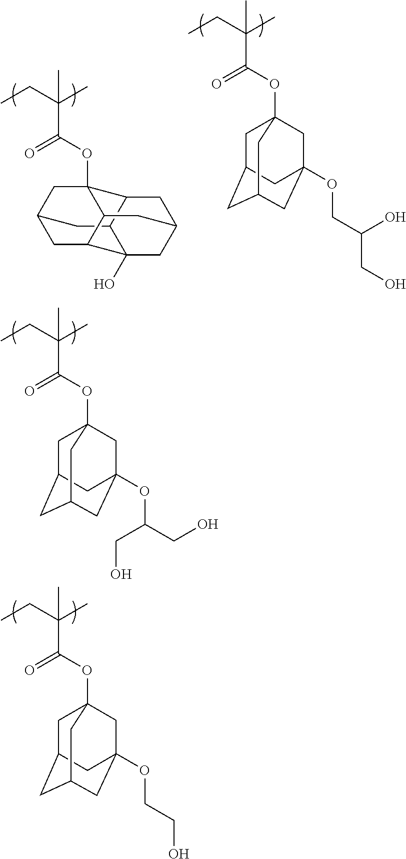

More preferably, a repeating unit represented by the following Formulas (AIIIa) or (AIIIb) may be exemplified.

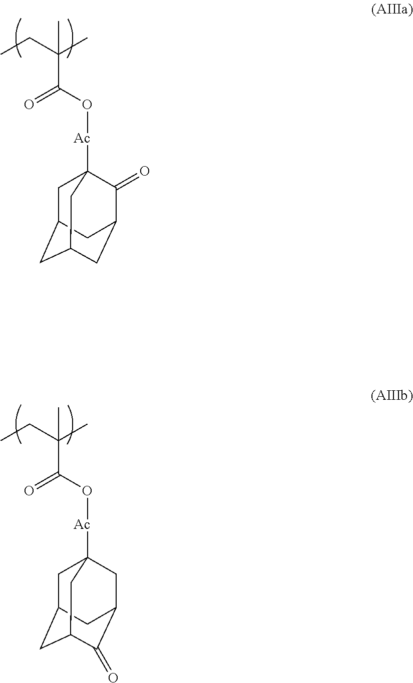

In Formulas (AIIIa) and (AIIIb), Ac represents a single bond or a divalent linking group, and preferred range is the same as those of Ab in the repeating unit represented by any one of the afore-mentioned Formulas (AIIa) to (AIIc).

Specific examples of the repeating unit represented by Formula (AIIIa) or (AIIIb) are exemplified below, but the present invention is not limited thereto.

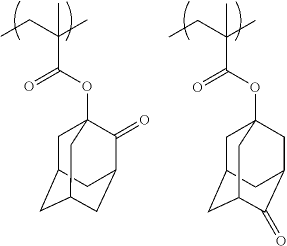

In addition, monomers or repeating units corresponding thereto described following [0011] of International Publication WO 2011/122336 may also be appropriately used.

The resin (A) may have a repeating unit having an acid group. Examples of the acid group may include a carboxyl group, a sulfonamide group, a sulfonylimide group, a bissulfonyl imide groups, a naphthol structure, an aliphatic alcohol group substituted with an electron withdrawing group at α-position (for example, hexafluoroisopropanol group) and the like, and more preferably a group having a repeating unit having a carboxyl group. Resolution for use in contact holes increases by containing a repeating unit having an acid group. As the repeating unit having an acid group, any of a repeating unit in which an acid group is bonded directly to the main chain of the resin such as a repeating unit having an acrylic acid or a methacrylic acid, or a repeating unit in which an acid group is bonded to the main chain of the resin via a linking group, and further a repeating unit which is introduced into the terminal group of the polymer chain by using an polymerization initiator or a chain transfer agent having an acid group is preferred. The linking group may have a monocyclic or polycyclic hydrocarbon structure. Particularly preferred is a repeating unit having an acrylic acid or methacrylic acid.

The resin (A) may or may not contain a repeating unit having an acid group, but in the case of containing the repeating unit having an acid group, the content thereof is preferably 25 mol % or less, and more preferably 20 mol % or less, based on the total repeating units of the resin (A). When the resin (A) contains a repeating unit having an acid group, the content of the repeating unit having an acid group in the resin (A) is usually 1 mol % or more.

Specific examples of the repeating unit having an acid group are shown below, but the invention is not limited thereto.

In the specific example, Rx represents H, CH₃, CH₂OH or CF₃.

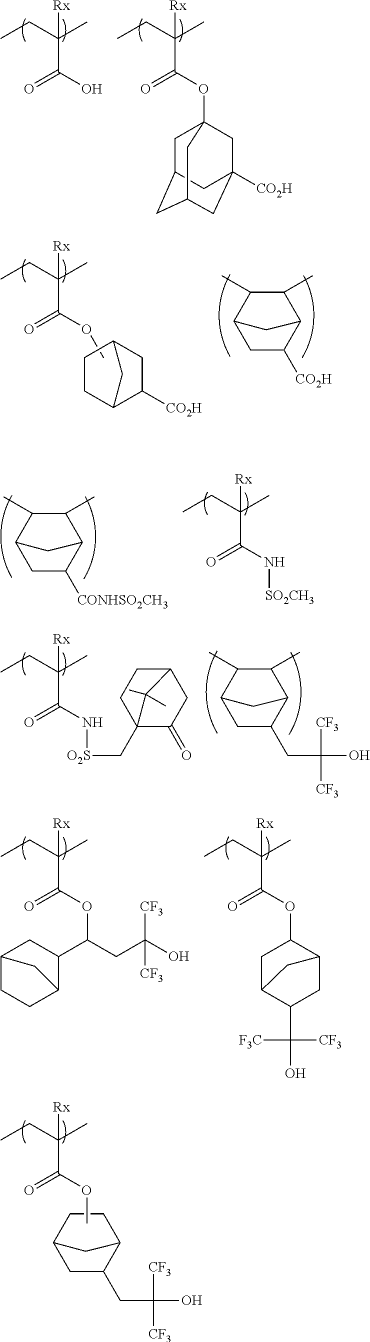

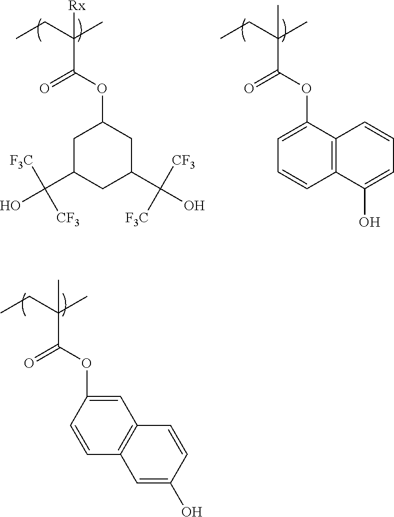

In the present invention, the resin (A) may have a repeating unit which further has an alicyclic hydrocarbon structure having no polar group (for example, the acid group, the hydroxyl group, and the cyano group) and does not exhibit an acid decomposability. Accordingly, elution of low molecular components from the resist film into the liquid for liquid immersion during the liquid immersion exposure may be reduced, and further, the solubility of the resin during the development using an organic solvent-containing developer may be appropriately adjusted. Examples of the repeating unit include a repeating unit represented by Formula (IV).

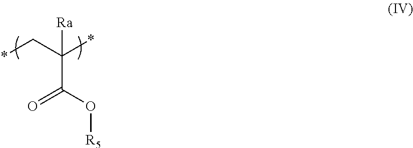

In Formula (IV), R₅ represents a hydrocarbon group having at least one cyclic structure and having no polar group.

Ra represents a hydrogen atom, an alkyl group or a —CH₂—O—Ra₂ group. In the formula, Ra₂ represents a hydrogen atom, an alkyl group or an acyl group. Ra is preferably a hydrogen atom, a methyl group, a hydroxymethyl group and a trifluoromethyl group, and particularly preferably a hydrogen atom and a methyl group.

The cyclic structure possessed by R₅ includes a monocyclic hydrocarbon group and a polycyclic hydrocarbon group. Examples of the monocyclic hydrocarbon group may include a cycloalkyl group having 3 to 12 carbon atoms, such as a cyclopentyl group, a cyclohexyl group, a cycloheptyl group, and a cyclooctyl group, and a cycloalkenyl group having 3 to 12 carbon atoms, such as a cyclohexenyl group. The monocyclic hydrocarbon group is preferably a monocyclic hydrocarbon group having 3 to 7 carbon atoms, and more preferably a cyclopentyl group or a cyclohexyl group.

The polycyclic hydrocarbon group includes a ring-aggregated hydrocarbon group and a crosslinked cyclic hydrocarbon group, and examples of the ring-aggregated hydrocarbon group include a bicyclohexyl group, a perhydronaphthalenyl group and the like. Examples of the crosslinked cyclic hydrocarbon ring include a bicyclic hydrocarbon ring such as a pinane ring, a bornane ring, a norpinane ring, a norbornane ring and a bicyclooctane ring (a bicyclo[2.2.2]octane ring, a bicyclo[3.2.1]octane ring and the like), a tricyclic hydrocarbon ring such as a homobrendane ring, an adamantine ring, a tricyclo[5.2.1.0^{2,6}]decane ring and a tricyclo[4.3.1.1^{2,5}]undecane ring, a tetracyclic hydrocarbon ring such as a tetracyclo[4.4.0.1^{2,5}.1^{7,10}]dodecane ring and a perhydro-1,4-methano-5,8-methanonaphthalene ring, and the like. Furthermore, the crosslinked cyclic hydrocarbon ring also includes a condensed cyclic hydrocarbon ring, for example, a condensed ring obtained by condensing a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring, and a perhydrophenalene ring.

Preferred examples of the crosslinked cyclic hydrocarbon ring may include a norbornyl group, an adamantyl group, a bicyclooctanyl group, a tricyclo[5,2,1,0^{2,6}]decanyl group and the like. More preferred examples of the crosslinked cyclic hydrocarbon ring may include a norbornyl group and an adamantyl group.

The alicyclic hydrocarbon groups may have a substituent, and preferred examples of the substituent may include a halogen atom, an alkyl group, a hydroxyl group with a hydrogen atom being substituted, an amino group with a hydrogen atom being substituted and the like. Preferred examples of the halogen atom may include a bromine atom, a chlorine atom and a fluorine atom, and preferred examples of the alkyl group may include a methyl group, an ethyl group, a n-butyl group and a t-butyl group. The aforementioned alkyl group may further have a substituent, and examples of the substituent, which the alkyl group may further have, may include a halogen atom, an alkyl group, a hydroxyl group with a hydrogen atom being substituted, and an amino group with a hydrogen atom being substituted.

Examples of the substituent for hydrogen atom may include an alkyl group, a cycloalkyl group, an aralkyl group, a substituted methyl group, a substituted ethyl group, an alkoxycarbonyl group, and an aralkyloxycarbonyl group. Preferred examples of the alkyl group may include an alkyl group having 1 to 4 carbon atoms, preferred examples of the substituted methyl group include a methoxymethyl group, a methoxythiomethyl group, a benzyloxymethyl group, a t-butoxymethyl group, and a 2-methoxyethoxymethyl group, examples of the substituted ethyl group may include a 1-ethoxy ethyl group and a 1-methyl-1-methoxyethyl group, preferred examples of the acyl group may include an aliphatic acyl group having 1 to 6 carbon atoms, such as a formyl group, an acetyl group, a propionyl group, a butyryl group, an isobutyryl group, a valeryl group, and a pivaloyl group, and examples of the alkoxycarbonyl group may include an alkoxycarbonyl group having from 1 to 4 carbon atoms and the like.

The resin (A) may or may not contain a repeating unit which has a polar group-free alicyclic hydrocarbon structure and does not exhibit acid decomposability, but when the resin (A) contains the repeating unit, the content of the repeating unit is preferably 1 to 50 mol %, and more preferably 5 to 50 mol %, based on the total repeating units of the resin (A).

Specific examples of the repeating unit, which has a polar group-free alicyclic hydrocarbon structure and does not exhibit acid decomposability, will be shown below, but the present invention is not limited thereto. In the formula, Ra represents H, CH₃, CH₂OH or CF₃.

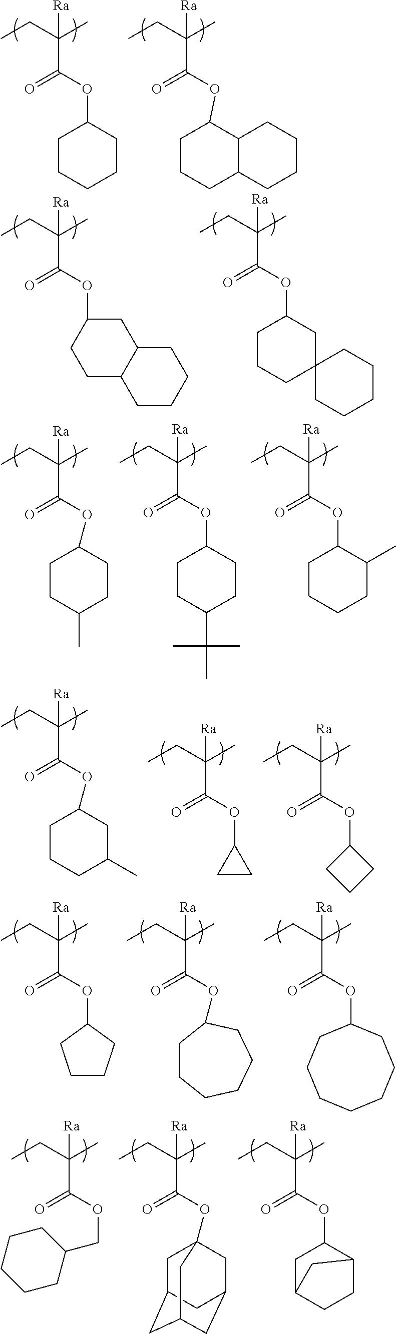

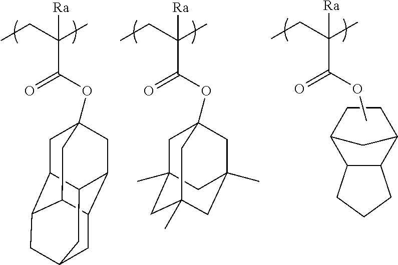

When a KrF excimer laser light, an electron beam, a X-ray or a wavelength 50 nm or less of high-energy ray (for example, EUV) are irradiated on the composition of the present invention, the resin (A) preferably has a repeating unit having an aromatic ring as represented by hydroxystyrene repeating unit.

The resin (A) used in the composition of the present invention may have, in addition to the above-described repeating structural units, various repeating structural units for the purpose of controlling the dry etching resistance, suitability for a standard developer, adhesion to a substrate, and a resist profile, and resolution, heat resistance, sensitivity and the like, which are properties generally required for an actinic ray-sensitive or radiation-sensitive resin composition.

Examples of the repeating structural units may include repeating structural units corresponding to the monomers described below, but are not limited thereto.

Accordingly, the performance required for the resin used in the composition according to the present invention, particularly

(1) solubility in a coating solvent,

(2) film-forming property (glass transition temperature),

(3) alkali developability,

(4) film reduction (selection of a hydrophilic, hydrophobic or alkali-soluble group)

(5) adhesion of unexposed portion to the substrate, and

(6) dry etching resistance, and the like may be finely adjusted.

Examples of the monomer include a compound having one addition-polymerizable unsaturated bond selected from acrylate esters, methacrylate esters, acrylamides, methacrylamides, allyl compounds, vinyl ethers, vinyl esters and the like.

Other than these, an addition-polymerizable unsaturated compound that is copolymerizable with the monomers corresponding to the above-described various repeating structural units may be copolymerized.

In the resin (A) used in the composition of the present invention, the molar ratio of respective repeating structural units contained is appropriately set in order to control dry etching resistance, suitability for a standard developer, adhesion to a substrate, and resist profile of the actinic ray-sensitive or radiation-sensitive resin composition, and further resolution, heat resistance, sensitivity and the like which are performances generally required for the actinic ray-sensitive or radiation-sensitive resin composition.

When the composition of the present invention is for ArF exposure, from the viewpoint of transparency to ArF light, the resin (A) used in the composition of the present invention preferably substantially has no aromatic ring (specifically, the ratio of a repeating unit having an aromatic group in the resin is preferably 5 mol % or less, more preferably 3 mol % or less, and ideally 0 mol %, that is, the resin has no aromatic group), and the resin (A) preferably has a monocyclic or polycyclic alicyclic hydrocarbon structure.

In the present invention, the form of the resin (A) may be any of a random type, a block type, a comb type and a star type. The resin (A) may be synthesized, for example, by radical, cationic or anionic polymerization of an unsaturated monomer corresponding to the structure. Also, after the polymerization using an unsaturated monomer corresponding to the precursor of the respective structure, it is also possible to obtain the resin of interest by performing a polymer reaction.

Further, when the composition of the present invention includes a resin (D) to be described below, the resin (A) preferably contains no fluorine atom and no silicon atom from the viewpoint of compatibility with the resin (D).

The resin (A) used in the composition of the present invention is preferably a resin in which all the repeating units consist of a (meth)acrylate-based repeating unit. In this case, a resin in which all the repeating units consist of a methacrylate-based repeating unit, a resin in which all the repeating units consist of an acrylate-based repeating unit, and a resin in which all the repeating units consist of a methacrylate-based repeating unit and an acrylate-based repeating unit may be used, but the acrylate-based repeating unit contains preferably 50 mol % or less of all the repeating units.

The resin (A) in the present invention may be synthesized by a conventional method (for example, radical polymerization). Examples of a general synthesis method may include a batch polymerization method of dissolving monomer species and an initiator in a solvent and heating the solution to perform the polymerization, a dropping polymerization method of adding dropwise a solution containing monomer species and an initiator to a heated solvent over 1 to 10 hours, and the like, but the dropping polymerization method is preferred. Examples of a reaction solvent may include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and further a solvent capable of dissolving the composition of the present invention, which will be described below, such as propylene glycol monomethyl ether acetate, propylene glycol monomethyl ether, and cyclohexanone. The polymerization is more preferably performed by using the same solvent as the solvent used in the photosensitive composition of the present invention. Accordingly, generation of particles during storage may be suppressed.

The polymerization reaction is preferably performed under an inert gas atmosphere such as nitrogen and argon. As the polymerization initiator, a commercially available radical initiator (azo-based initiator, peroxide, etc.) is used to initiate the polymerization. The radical initiator is preferably an azo-based initiator, and an azo-based initiator having an ester group, a cyano group or a carboxyl group is preferred. Preferred examples of the initiator may include azobisisobutyronitrile, azobisdimethylvaleronitrile, dimethyl 2,2′-azobis(2-methylpropionate) and the like. The initiator is added additionally or in parts, if desired, and after the completion of reaction, the reaction product is poured in a solvent, and a desired polymer is recovered by a powder or solid recovery method, or the like. The reaction concentration is 5 to 50% by mass, and preferably 10 to 30% by mass. The reaction temperature is usually 10° C. to 150° C., preferably 30° C. to 120° C., and more preferably 60° C. to 100° C.

After the completion of reaction, the reaction solution is allowed to cool to room temperature and purified. The purification may be performed by a conventional method, such as a liquid-liquid extraction method of applying water-washing or combining water-washing with an appropriate solvent to remove residual monomers or oligomer components, a purification method in a solution state, such as ultrafiltration of removing only those having a molecular weight not more than a specific molecular weight by virtue of extraction, a reprecipitation method of adding dropwise a resin solution in a poor solvent to solidify the resin in the poor solvent to remove residual monomers and the like, and a purification method in a solid state, such as washing of the resin slurry separated by filtration with a poor solvent.

For example, the resin is precipitated as a solid by contacting the reaction solution with a solvent (poor solvent) in which the resin is sparingly soluble or insoluble and which is in a volumetric amount of 10 times or less and preferably from 10 to 5 times the reaction solution.

The solvent (precipitation or reprecipitation solvent) used at the time of operating precipitation or reprecipitation from the polymer solution may be sufficient if the solvent is a poor solvent for the polymer, and the solvent may be appropriately selected from a hydrocarbon, a halogenated hydrocarbon, a nitro compound, ether, ketone, ester, carbonate, alcohol, carboxylic acid, water, and a mixed solvent including these solvents, according to the kind of the polymer, and may be used. Among these solvents, a solvent including at least alcohol (particularly, methanol or the like) or water is preferred as the precipitation or reprecipitation solvent.

The amount of the precipitation or reprecipitation solvent used may be appropriately selected in consideration of the efficiency, yield and the like, but in general, the amount is 100 to 10,000 parts by mass, preferably 200 to 2,000 parts by mass, and more preferably 300 to 1,000 parts by mass, based on 100 parts by mass of the polymer solution.

The temperature during the precipitation or reprecipitation may be appropriately selected in consideration the efficiency or operability but is usually 0 to 50° C., and preferably in the vicinity of room temperature (for example, approximately 20 to 35° C.). The precipitation or reprecipitation operation may be performed by a publicly known method such as batch system and continuous system using a commonly-used mixing vessel such as stirring tank.

The precipitated or reprecipitated polymer is usually subjected to commonly-used solid-liquid separation such as filtration and centrifugation, and then dried and used. The filtration is performed by using a solvent-resistant filter element, and preferably under pressure. The drying is performed under normal pressure or reduced pressure (preferably under reduced pressure) at a temperature of approximately 30 to 100° C. and preferably at a temperature of approximately 30 to 50° C.

Meanwhile, after the resin is once precipitated and separated, the resin may be dissolved in a solvent again and then brought into contact with a solvent in which the resin is sparingly soluble or insoluble. That is, there may be used a method including, after the completion of radical polymerization reaction, bringing the polymer into contact with a solvent in which the polymer is sparingly soluble or insoluble, to precipitate a resin (process a), separating the resin from the solution (process b), dissolving the resin in a solvent again to prepare a resin solution A (process c), and then bringing the resin solution A into contact with a solvent in which the resin is sparingly soluble or insoluble and which is in a volumetric amount of less than 10 times (volumetric amount of preferably 5 times or less) the resin solution A, to precipitate a resin solid (process d), and separating the precipitated resin (process e).

In addition, for suppressing the resin after preparation of the composition from aggregation or the like, as described in, for example, Japanese Patent Application Laid-open No. 2009-037108, a process of dissolving the synthesized resin in a solvent to prepare a solution, and heating the solution at approximately 30° C. to 90° C. for approximately 30 minutes to 4 hours may be added.

The weight average molecular weight of the resin (A) in the present invention is preferably 4,000 or more, more preferably 7,000 or more, and still more preferably 15,000 or more, in terms of polystyrene by the GPC method. Accordingly, it is possible to appropriately suppress the dissolution rate of the organic developer of the unexposed portion, thereby more easily obtaining the effect of the present invention.

The weight average molecular weight of the resin (A) in the present invention is preferably 200,000 or less, more preferably 50,000 or less, still more preferably 40, 0000 or less and particularly preferably 30,000 or less.

The polydispersity (molecular weight distribution) is usually in a range of 1.0 to 3.0, preferably 1.0 to 2.6, more preferably 1.0 to 2.0, and particularly preferably 1.4 to 2.0. The smaller the molecular weight distribution is, the better the resolution and resist shape are, and the smoother the side wall of the resist pattern is, and thus roughness is excellent.

Here, the weight average molecular weight and polydispersity of the resin represent the polystyrene based molecular weight and the polydispersity based thereon, determined by carrier, tetrahydrofuran (THF) or N-methyl-2-pyrrolidone (NMP), RI detection by connecting guard column: TOSOH TSK guard column MP (XL) 6.0 mm (ID)×4.0 cm (L), Column: TOSOH TSK gel Multipore HXL-M 7.8 mm (ID)×30.0 cm (L), in the apparatus: TOSOH HLC-8120GPC.

The content of the above-described repeating units in the resin (A) (mole fraction to the total repeating units of the resin (A)) may be calculated on the basis of integral ratio such as ¹H-NMR, ¹³C-NMR.

In the actinic ray-sensitive or radiation-sensitive resin composition of the present invention, the blending ratio of the resin (A) in the entire composition is preferably 30 to 99% by mass, and more preferably 60 to 95% by mass, based on the total solid content of the composition.

Furthermore, in the present invention, the resin (A) may be used either alone or in combination of a plurality thereof.

[2] Resin (A1) having a repeating unit (p), but having no repeating unit (p1) as the repeating unit (p)

The actinic ray-sensitive or radiation-sensitive resin composition of the present invention may contain a resin (A1) having a repeating unit (p) having the acid-decomposable group, but having no repeating unit (p1) as the repeating unit (p).

The content of the repeating unit (p) is preferably 20 to 70 mol %, and more preferably 30 to 65 mol %, based on the total repeating units of the resin (A1).

Resin (A1) may contain the repeating unit described as a repeating unit which may be possessed by the resin (A) in addition to the repeating unit (p). A preferred range of the content of these repeating units in the resin (A1) based on the total repeating units is the same as that described for the resin (A).

Further, a preferred range of each physical property value (for example, molecular weight and polydispersity) of the resin (A1) and the synthesis method of the resin (A1) are the same as those described for the resin (P).

The actinic ray-sensitive or radiation-sensitive resin composition of the present invention may or may not contain the resin (A1), but when the composition contains the resin (A1), the content of the resin (A1) is preferably 5 to 50% by mass, and more preferably 5 to 30% by mass, based on the total solid content of the composition.

The content of the resin (A1) is preferably 1 to 99 mass %, more preferably 1 to 70% by mass and particularly preferably 1 to 50 mass % with respect to the resin (A).

[3] Compound (B) capable of generating an acid upon irradiation with actinic ray or radiation

The composition of the present invention also contains a compound (B) capable of generating an acid upon irradiation with an actinic ray or radiation (hereinafter, also referred to as an “acid generator”). The compound (B) capable of generating an acid upon irradiation with an actinic ray or radiation is preferably a compound capable of generating an organic acid upon irradiation with an actinic ray or radiation.

The compound (B) capable of generating an acid upon irradiation with an actinic ray or radiation may be in the form of a low-molecular compound, or in the form of being incorporated into a portion of a polymer. In addition, the form of a low molecular compound and the form of being incorporated into a portion of a polymer may be used in combination.

When the compound (B) capable of generating an acid upon irradiation with an actinic ray or radiation is in the form of a low molecular compound, the molecular weight is preferably 3,000 or less, more preferably 2,000 or less, and still more preferably 1,000 or less.

When the compound (B) capable of generating an acid upon irradiation with an actinic ray or radiation is in the form of being incorporated into a portion of a polymer, the compound (B) may be incorporated into a portion of the above-described acid-decomposable resin, or may be incorporated into a resin different from the acid-decomposable resin.

In the present invention, the compound (B) capable of generating an acid upon irradiation with an actinic ray or radiation is preferably in the form of a low molecular compound.

The acid generator may be appropriately selected from a photo-initiator for cationic photopolymerization, a photo-initiator for radical photopolymerization, a photodecoloring agent for dyes, a photodiscoloring agent, or a publicly known compound capable of generating an acid upon irradiation with an actinic ray or radiation, which is used for microresist or the like, and a mixture thereof, and be used.

Examples thereof may include a diazonium salt, a phosphonium salt, a sulfonium salt, an iodonium salt, imidosulfonate, oxime sulfonate, diazodisulfone, disulfone, and o-nitrobenzyl sulfonate.

Among the acid generators, examples of preferred compounds may include compounds represented by the following Formulas (ZI), (ZII) and (ZIII).

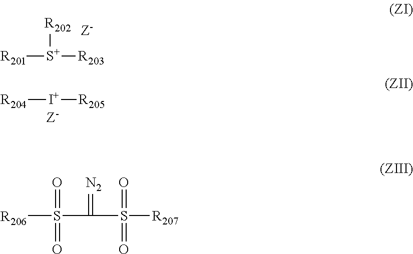

In Formula (ZI),

Each of R₂₀₁, R₂₀₂ and R₂₀₃ independently represents an organic group.

The carbon number of the organic group as R₂₀₁, R₂₀₂ and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond or a carbonyl group therein. Examples of the group formed by bonding of two of R₂₀₁ to R₂₀₃ may include an alkylene group.

Z⁻ represents a non-nucleophilic anion.

Examples of the non-nucleophilic anion as Z⁻ may include sulfonate anion, carboxylate anion, sulfonylimide anion, bis(alkylsulfonyl)imide anion, tris(alkylsulfonyl)methyl anion and the like.

The non-nucleophilic anion is an anion having an extremely low ability of causing a nucleophilic reaction and capable of suppressing the decomposition with time due to an intramolecular nucleophilic reaction. Accordingly, the stability of the resist composition with time is enhanced.

Examples of the sulfonate anion may include an aliphatic sulfonate anion, an aromatic sulfonate anion, a camphorsulfonate anion and the like.

Examples of the carboxylate anion may include an aliphatic carboxylate anion, an aromatic carboxylate anion, an aralkylcarboxylate anion and the like.

The aliphatic moiety in the aliphatic sulfonate anion and the aliphatic carboxylate anion may be an alkyl group or a cycloalkyl group and is preferably an alkyl group having 1 to 30 carbon atoms and a cycloalkyl group having 3 to 30 carbon atoms.

The aromatic group in the aromatic sulfonate anion and the aromatic carboxylate anion is preferably an aryl group having from 6 to 14 carbon atoms.

The alkyl group, the cycloalkyl group and the aryl group in the aliphatic sulfonate anion and the aromatic sulfonate anion may have a substituent. Examples of the substituent of the alkyl group, the cycloalkyl group and the aryl group in the aliphatic sulfonate anion and the aromatic sulfonate anion may include a nitro group, a halogen atom (a fluorine atom, a chlorine atom, a bromine atom and an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) and the like. Examples of the aryl group and the ring structure, which each group has, further include, as the substituent, an alkyl group (preferably having 1 to 15 carbon atoms) and a cycloalkyl group (preferably having 3 to 15 carbon atoms).

The aralkyl group in the aralkylcarboxylate anion is preferably an aralkyl group having 7 to 12 carbon atoms.

The alkyl group, the cycloalkyl group, the aryl group and the aralkyl group in the aliphatic carboxylate anion, the aromatic carboxylate anion and the aralkylcarboxylate anion may have a substituent. Examples of the substituent include the halogen atom, the alkyl group, the cycloalkyl group, the alkoxy group, the alkylthio group and the like in the aromatic sulfonate anion.

Examples of the sulfonylimide anion may include saccharin anion.

The alkyl group in the bis(alkylsulfonyl)imide anion and the tris(alkylsulfonyl)methide anion is preferably an alkyl group having 1 to 5 carbon atoms.

Two alkyl groups in the bis(alkylsulfonyl)imide anion may be linked to each other to form an alkylene group (preferably having 2 to 4 carbon atoms), and the alkylene group may be bonded to an imide group and two sulfonyl groups to form a ring. Examples of a substituent, which an alkylene group formed by linking two alkyl groups in the alkyl group and the bis(alkylsulfonyl)imide anion with each other may have, may include a halogen atom, an alkyl group substituted with a halogen atom, an alkoxy group, an alkylthio group, an alkyloxysulfonyl group, an aryloxysulfonyl group, a cycloalkylaryloxysulfonyl group and the like, and an alkyl group substituted with a fluorine atom is preferred.

Examples of the other non-nucleophilic anions may include fluorinated phosphate (for example, PF₆⁻), fluorinated boron (for example, BF₄⁻), fluorinated antimony (for example, SbF₆⁻) and the like.

The non-nucleophilic anion of Z⁻ is preferably an aliphatic sulfonate anion in which at least an α-position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms and a benzenesulfonate anion having a fluorine atom, and still more preferably a nonafluorobutanesulfonate anion, a perfluorooctanesulfonate anion, a pentafluorobenzenesulfonate anion and a 3,5-bis(trifluoromethyl)benzenesulfonate anion.

The acid generator is preferably a compound capable of generating an acid represented by the following Formula (V) or (VI) upon irradiation with an actinic ray or radiation. Since the acid generator is the compound capable of generating an acid represented by the following Formula (V) or (VI), the compound has a cyclic organic group, and thus the resolution and roughness performance may be more excellent.

The non-nucleophilic anion may be an anion capable of generating an organic acid represented by the following Formula (V) or (VI).

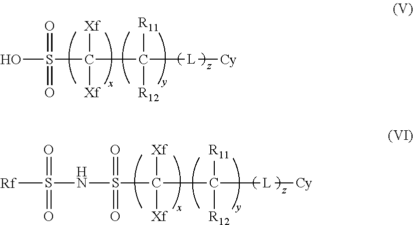

In the formulas,

Each Xf independently represents a fluorine atom or an alkyl group substituted with at least one fluorine atom.

Each of R₁₁ and R₁₂ independently represents a hydrogen atom, a fluorine atom or an alkyl group.

Each L independently represents a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, and more preferably a fluorine atom or CF₃. In particular, it is preferred that both Xfs are a fluorine atom.

Each of R₁₁ and R₁₂ independently represents a hydrogen atom, a fluorine atom or an alkyl group. The alkyl group may have a substituent (preferably a fluorine atom) and preferably has 1 to 4 carbon atoms. The alkyl group is more preferably a perfluoroalkyl group having 1 to 4 carbon atoms. Specific examples of the alkyl group having a substituent of R₁₁ and R₁₂ may include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, and among them, CF₃ is preferred.

L represents a divalent linking group. Examples of the divalent linking group may include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms) or a divalent linking group formed by combining a plurality of these groups, and the like. Among them, —COO—, —OCO—, —CONH—, —NHCO—, —CO—, —O—, —SO₂—, —COO-alkylene group-, —OCO-alkylene group-, —CONH-alkylene group- or —NHCO-alkylene group- is preferred, and —COO—, —OCO—, —CONH—, —SO₂—, —COO-alkylene group- or —OCO-alkylene group- is more preferred.

Cy represents a cyclic organic group. Examples of the cyclic organic group may include an alicyclic group, an aryl group and a heterocyclic group.

The alicyclic group may be monocyclic or polycyclic. Examples of the monocyclic alicyclic group may include a monocyclic cycloalkyl group such as a cyclopentyl group, a cyclohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group and an adamantyl group, is preferred from the viewpoint of restraining diffusion in film during a PEB (post-exposure baking) process and enhancing the MEEF (Mask Error Enhancement Factor).

The aryl group may be monocyclic or polycyclic. Examples of the aryl group may include a phenyl group, a naphthyl group, a phenanthryl group and an anthryl group. Among them, a naphthyl group having relatively low light absorbance at 193 nm is preferred.

The heterocyclic group may be monocyclic or polycyclic, but a polycyclic heterocyclic group may further suppress the diffusion of an acid. In addition, the heterocyclic group may have aromaticity or may not have aromaticity. Examples of the heterocyclic ring having aromaticity may include a furan ring, a thiophene ring, a benzofuran ring, a benzothiophene ring, a dibenzofuran ring, a dibenzothiophene ring and a pyridine ring. Examples of the heterocyclic ring having no aromaticity may include a tetrahydropyran ring, a lactone ring, a sultone ring and a decahydroisoquinoline ring. The heterocyclic ring in the heterocyclic group is particularly preferably a furan ring, a thiophene ring, a pyridine ring or a decahydroisoquinoline ring. Furthermore, examples of the lactone ring or the sultone ring may include the above-described lactone structure or a sultone structure exemplified in the resin (A).

The cyclic organic group may have a substituent. Examples of the substituent may include an alkyl group (may be straight or branched, and preferably has 1 to 12 carbon atoms), a cycloalkyl group (may be monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonate ester group. Furthermore, the carbon constituting the cyclic organic group (the carbon contributing to ring formation) may be carbonyl carbon.

x is preferably 1 to 8, and among them, preferably 1 to 4, and particularly preferably 1. y is preferably 0 to 4, and more preferably 0. z is preferably 0 to 8, and among them, preferably 0 to 4.

Examples of the group having a fluorine atom, which is represented by Rf, may include an alkyl group having at least one fluorine atom, a cycloalkyl group having at least one fluorine atom, and an aryl group having at least one fluorine atom.

The alkyl group, the cycloalkyl group and the aryl group may be substituted with a fluorine atom, or may be substituted with another substituent including a fluorine atom. When Rf is a cycloalkyl group having at least one fluorine atom or an aryl group having at least one fluorine atom, examples of the another substituent including a fluorine atom include an alkyl group substituted with at least one fluorine atom.

Further, the alkyl group, the cycloalkyl group and the aryl group may be further substituted with a substituent including no fluorine atom. Examples of the substituent may include those including no fluorine atom among those for Cy described above.

Examples of the alkyl group having at least one fluorine atom, which is represented by Rf, may include the same as those described above as the alkyl group substituted with at least one fluorine atom, which is represented by Xf. Examples of the cycloalkyl group having at least one fluorine atom, which is represented by Rf, may include a perfluorocyclopentyl group and a perfluorocyclohexyl group. Examples of the aryl group having at least one fluorine atom, which is represented by Rf, may include a perfluorophenyl group.

In addition, the non-nucleophilic anion is also preferably an anion represented by any one of the following Formulas (B-1) to (B-3).

First, an anion represented by the following Formula (B-1) will be described.

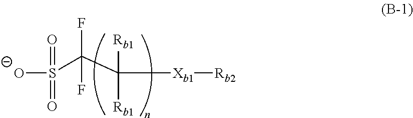

In Formula (B-1),

Each R_{b1} independently represents a hydrogen atom, a fluorine atom or a trifluoromethyl group (CF₃).

n represents an integer of 1 to 4.

n is preferably an integer of 1 to 3, and more preferably 1 or 2.

X_{b1} represents a single bond, an ether bond, an ester bond (—OCO— or —COO—), or a sulfonate ester bond (—OSO₂— or —SO₃—).

X_{b1} is preferably an ester bond (—OCO— or —COO—), or a sulfonate ester bond (—OSO₂— or —SO₃—).

R_{b2} represents a substituent having 6 or more carbon atoms.

The substituent having 6 or more carbon atoms for R_{b2} is preferably a bulky substituent, and examples thereof include an alkyl group, an alicyclic group, an aryl group, a heterocyclic group and the like, which have 6 or more carbon atoms.

The alkyl group having 6 or more carbon atoms for R_{b2} may be straight or branched and is preferably a straight or branched alkyl group having 6 to 20 carbon atoms, and examples thereof may include a straight or branched hexyl group, a straight or branched heptyl group, a straight or branched octyl group, and the like. From the viewpoint of being bulky, the branched alkyl group is preferred.

The alicyclic group having 6 or more carbon atoms for R_{b2} may be monocyclic or polycyclic. Examples of the monocyclic alicyclic group may include a monocyclic cycloalkyl group such as a cyclohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group and an adamantyl group, is preferred from the viewpoint of restraining diffusion in the film during a PEB (post-exposure baking) process and enhancing the MEEF (Mask Error Enhancement Factor).

The aryl group having 6 or more carbon atoms for R_{b2} may be monocyclic or polycyclic. Examples of the aryl group may include a phenyl group, a naphthyl group, a phenanthryl group and an anthryl group. Among them, a naphthyl group having relatively low light absorbance at 193 nm is preferred.

The heterocyclic group having 6 or more carbons for R_{b2} may be monocyclic or polycyclic, but a polycyclic heterocyclic group may further suppress the diffusion of an acid. Furthermore, the heterocyclic group may have aromaticity or may not have aromaticity. Examples of the heterocyclic ring having aromaticity may include a benzofuran ring, a benzothiophene ring, a dibenzofuran ring and a dibenzothiophene ring. Examples of the heterocyclic ring having no aromaticity may include a tetrahydropyran ring, a lactone ring and a decahydroisoquinoline ring. The heterocyclic ring in the heterocyclic group is particularly preferably a benzofuran ring or a decahydroisoquinoline ring. Further, examples of the lactone ring may include the above-described lactone structure exemplified in the resin (P).

The substituent having 6 or more carbon atoms for R_{b2} may further have a substituent. Examples of the further substituent may include an alkyl group (may be straight or branched, and preferably has 1 to 12 carbon atoms), a cycloalkyl group (may be any one of monocyclic, polycyclic or spirocyclic, and preferably has 3 to 20 carbon atoms), an aryl group (preferably has 6 to 14 carbon atoms), a hydroxyl group, an alkoxy group, an ester group, an amide group, a urethane group, a ureido group, a thioether group, a sulfonamide group and a sulfonate ester group. Furthermore, the carbon constituting the above-described alicyclic group, aryl group or heterocyclic group (the carbon contributing to ring formation) may be carbonyl carbon.

Subsequently, an anion represented by the following Formula (B-2) will be described.

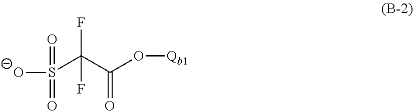

In Formula (B-2),

Q_{b1} represents a group having a lactone structure, a group having a sultone structure or a group having a cyclic carbonate structure.

Examples of the lactone structure and the sultone structure for Q_{b1} may include the same lactone structure and the same sultone structure as in the repeating unit having the lactone structure and the sultone structure, which are previously described in the paragraph of resin (P). Specifically, examples thereof may include the lactone structure represented by any one of Formulas (LC1-1) to (LC1-17), or the sultone structure represented by any one of Formulas (SL1-1) to (SL1-3).

The lactone structure or the sultone structure may be directly bonded to an oxygen atom of the ester group in Formula (B-2), but the lactone structure or the sultone structure may be bonded to an oxygen atom of an ester group through an alkylene group (for example, a methylene group and an ethylene group). In that case, a group having the lactone structure or the sultone structure may be an alkyl group having the lactone structure or the sultone structure as a substituent.

The cyclic carbonate structure for Q_{b1} is preferably a 5- to 7-membered cyclic carbonate structure.

The cyclic carbonate structure may be directly bonded to an oxygen atom of the ester group in Formula (B-2), but the cyclic carbonate structure may be bonded to an oxygen atom of an ester group through an alkylene group (for example, a methylene group and an ethylene group). In that case, a group having the cyclic carbonate structure may be an alkyl group having a cyclic carbonate structure as a substituent.

Subsequently, an anion represented by the following Formula (B-3) will be described.

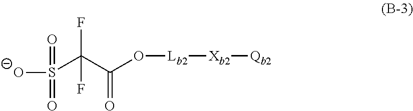

In Formula (B-3),

L_{b2} represents an alkylene group having 1 to 6 carbon atoms, and an alkylene having 1 to 4 carbon atoms is preferred.

X_{b2} represents an ether bond or an ester bond (—OCO— or —COO—).

Q_{b2} represents an alicyclic group or a group containing an aromatic ring.

The alicyclic group for Q_{b2} may be monocyclic or polycyclic. Examples of the monocyclic alicyclic group may include a monocyclic cycloalkyl group such as a cyclopentyl group, a cyclohexyl group and a cyclooctyl group. Examples of the polycyclic alicyclic group may include a polycyclic cycloalkyl group such as a norbornyl group, a tricyclodecanyl group, a tetracyclodecanyl group, a tetracyclododecanyl group and an adamantyl group. Among them, an alicyclic group with a bulky structure having 7 or more carbon atoms, such as a norbornyl group, a tricyclodecanyl group, a tetracyclodecanyl group, a tetracyclododecanyl group, and an adamantyl group, is preferred.

The aromatic ring in the group containing an aromatic ring for Q_{b2} is preferably an aromatic ring having 6 to 20 carbon atoms, examples thereof may include a benzene ring, a naphthalene ring, a phenanthrene ring, an anthracene ring and the like, and among them, a benzene ring or a naphthalene ring is more preferred. The aromatic ring may be substituted with at least one fluorine atom, and examples of the aromatic ring substituted with at least one fluorine atom may include a perfluorophenyl group and the like.

The aromatic ring may be directly bonded to X_{b2}, but may be bonded to X_{b2} through an alkylene group (for example, a methylene group and an ethylene group).

In that case, a group containing the aromatic ring may be an alkyl group having the aromatic ring as a substituent.

Examples of the organic group represented by R₂₀₁, R₂₀₂ and R₂₀₃ may include corresponding groups in the compounds (ZI-1), (ZI-2), (ZI-3) and (Z1-4) to be described below.

Meanwhile, a compound having a plurality of structures represented by Formula (ZI) may be used. For example, it is possible to use a compound having a structure in which at least one of R₂₀₁ to R₂₀₃ in a compound represented by Formula (ZI) is bonded to at least one of R₂₀₁ to R₂₀₃ in another compound represented by Formula (ZI) through a single bond or a linking group.

In addition, examples of a preferred (ZI) component include compounds (ZI-1), (ZI-2), (ZI-3) and (ZI-4) to be described below.

Compound (ZI-1) is an arylsulfonium compound in which at least one of R₂₀₁ to R₂₀₃ in Formula (ZI) is an aryl group, that is, a compound having arylsulfonium as a cation.

In the arylsulfonium compound, all of R₂₀₁ to R₂₀₃ may be an aryl group or some of R₂₀₁ to R₂₀₃ may be an aryl group, with the remaining being an alkyl group or a cycloalkyl group.

Examples of the arylsulfonium compound may include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group and a naphthyl group, and more preferably a phenyl group. The aryl group may be an aryl group having a heterocyclic structure having an oxygen atom, a nitrogen atom, a sulfur atom and the like. Examples of the heterocyclic structure may include a pyrrole residue, a furan residue, a thiophene residue, an indole residue, a benzofuran residue, a benzothiophene residue and the like. When the arylsulfonium compound has two or more aryl groups, each aryl group may be same as or different.

The alkyl group or the cycloalkyl group, which the arylsulfonium compound has, if necessary, is preferably a straight or branched alkyl group having 1 to 15 carbon atoms and a cycloalkyl group having 3 to 15 carbon atoms.

The aryl group, the alkyl group and the cycloalkyl group of R₂₀₁ to R₂₀₃ may have, as a substituent, an alkyl group (for example, having from 1 to 15 carbon atoms), a cycloalkyl group (for example, having from 3 to 15 carbon atoms), an aryl group (for example, having from 6 to 14 carbon atoms), an alkoxy group (for example, having from 1 to 15 carbon atoms), a halogen atom, a hydroxyl group or a phenylthio group. The substituent is preferably a straight or branched alkyl group having 1 to 12 carbon atoms, a cycloalkyl group having 3 to 12 carbon atoms, and a straight, branched or cyclic alkoxy group having 1 to 12 carbon atoms, and more preferably an alkyl group having 1 to 4 carbon atoms and an alkoxy group having 1 to 4 carbon atoms. The substituent may be substituted with any one of three R₂₀₁ to R₂₀₃ or may be substituted with all of the three. Furthermore, when R₂₀₁ to R₂₀₃ are an aryl group, the substituent is preferably substituted at the p-position of the aryl group.

Subsequently, compound (ZI-2) will be described.

Compound (ZI-2) is a compound represented by the following Formula (ZI-2). That is, compound (ZI-2) is a compound in which each of R₂₀₁ to R₂₀₃ in Formula (ZI) independently represents an organic group having no aromatic ring. Here, the aromatic ring also includes an aromatic ring containing a heteroatom.

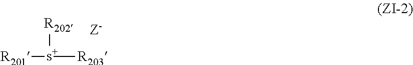

In Formula (ZI-2),

Each of R₂₀₁′ to R₂₀₃′ independently represents an organic group having no aromatic ring.

Z⁻ represents a non-nucleophilic anion.

The organic group containing no aromatic ring as R₂₀₁′ to R₂₀₃′ has generally 1 to 30 carbon atoms, and preferably 1 to 20 carbon atoms.

Each of R₂₀₁′ to R₂₀₃′ independently represents preferably an alkyl group, a cycloalkyl group, an allyl group or a vinyl group, more preferably a straight or branched 2-oxoalkyl group, a 2-oxocycloalkyl group and an alkoxycarbonylmethyl group, and particularly preferably a straight or branched 2-oxoalkyl group.

Preferred examples of the alkyl group and the cycloalkyl group of R₂₀₁′ to R₂₀₃′ may include a straight or branched alkyl group having 1 to 10 carbon atoms and a cycloalkyl group having 3 to 10 carbon atoms. More preferred examples of the alkyl group may include a 2-oxoalkyl group and an alkoxycarbonylmethyl group. More preferred examples of the cycloalkyl group may include a 2-oxocycloalkyl group.

The 2-oxoalkyl group may be either straight or branched, and preferred examples thereof include a group having >C═O at the 2-position of the aforementioned alkyl group.

Preferred examples of the 2-oxocycloalkyl group may include a group having >C═O at the 2-position of the aforementioned cycloalkyl group.

Preferred examples of the alkoxy group in the alkoxycarbonylmethyl group may include an alkoxy group having 1 to 5 carbon atoms.

R₂₀₁′ to R₂₀₃′ may be further substituted with a halogen atom, an alkoxy group (for example, having 1 to 5 carbon atoms), a hydroxyl group, a cyano group or a nitro group.

Subsequently, the compound (ZI-3) will be described.

The compound (ZI-3) is a compound represented by the following Formula (ZI-3), and a compound having a phenacylsulfonium salt structure.

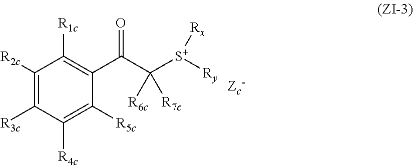

In Formula (ZI-3),

Each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, R_{5c} and R_{6c}, R_{6c} and R_{7c}, R_{5c} and Rₓ, and Rₓ and R_{y} may be bonded to each other to form a ring structure, respectively, and the ring structure may include an oxygen atom, a sulfur atom, a ketone group, an ester bond and an amide bond.

Examples of the ring structure may include an aromatic or non-aromatic hydrocarbon ring, an aromatic or non-aromatic heterocyclic ring, or a polycyclic condensed ring formed by combining two or more of these rings. The ring structure includes a 3- to 10-membered ring and is preferably a 4- to 8-membered ring, and more preferably a 5- or 6-membered ring.

Examples of the group formed by bonding of any two or more of R_{1c} to R_{5c}, R_{6c} and R_{7c}, and Rₓ and R_{y} may include a butylene group, a pentylene group and the like.

The group formed by bonding of R_{5c} and R_{6c} and R_{5c} and Rₓ is preferably a single bond or an alkylene group, and examples of the alkylene group may include a methylene group, an ethylene group and the like.

Zc⁻ represents a non-nucleophilic anion, and examples thereof may include the non-nucleophilic anion which is the same as Z⁻ in Formula (ZI).

The alkyl group as R_{1c} to R_{7c} may be either straight or branched, examples thereof may include an alkyl group having 1 to 20 carbon atoms, and preferably a straight or branched alkyl group having 1 to 12 carbon atoms, and examples of the cycloalkyl group may include a cycloalkyl group having 3 to 10 carbon atoms.

The aryl group as R_{1c} to R_{5c} is preferably an aryl group having 5 to 15 carbon atoms, and examples thereof may include a phenyl group and a naphthyl group.

The alkoxy group as R_{1c} to R_{5c} may be straight, branched or cyclic and examples thereof may include an alkoxy group having 1 to 10 carbon atoms, preferably a straight or branched alkoxy group having 1 to 5 carbon atoms, and a cyclic alkoxy group having 3 to 10 carbon atoms.

Specific examples of the alkoxy group in the alkoxycarbonyl group as R_{1c} to R_{5c} are the same as the specific examples of the alkoxy group as R_{1c} to R_{5c}.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R_{5c}.

Specific examples of the aryl group in the aryloxy group and the arylthio group as R_{1c} to R_{5c} are the same as the specific examples of the aryl group as R_{1c} to R_{5c}.

Any one of R_{1c} to R_{5c} is preferably a straight or branched alkyl group, a cycloalkyl group, or a straight, branched or cyclic alkoxy group, and the sum of carbon numbers of R_{1c} to R_{5c} is more preferably from 2 to 15. Accordingly, the solvent solubility is more enhanced, and thus, generation of particles during storage is suppressed.

Examples of the ring structure which may be formed by any two or more of R_{1c} to R_{5c} bonded to each other may include preferably a 5- or 6-membered ring, and particularly preferably a 6-membered ring (for example, a phenyl ring).

Examples of the ring structure which may be formed by R_{5c} and R_{6c} bonded to each other may include a 4-membered or greater ring (particularly preferably a 5- or 6-membered ring) formed together with the carbonyl carbon atom and the carbon atom in Formula (I) by R_{5c} and R_{6c} bonded to each other to form a single bond or an alkylene group (a methylene group, an ethylene group or the like).

The aryl group as R_{6c} to R_{7c} preferably has 5 to 15 carbon atoms, and examples thereof include a phenyl group and a naphthyl group.

An aspect in which both R_{6c} and R_{7c} are an alkyl group is preferred. In particular, an aspect in which each of R_{6c} and R_{7c} is a straight or branched alkyl group having 1 to 4 carbon atoms is preferred, and an aspect in which both are a methyl group is particularly preferred.

Furthermore, when R_{6c} and R_{7c} are bonded to each other to form a ring, the group formed by bonding of R_{6c} and R_{7c} is preferably an alkylene group having 2 to 10 carbon atoms, and examples thereof may include an ethylene group, a propylene group, a butylene group, a pentylene group, a hexylene group and the like. Further, the ring formed by bonding of R_{6c} and R_{7c} may have a heteroatom such as oxygen atom in the ring.

Examples of the alkyl group and the cycloalkyl group as Rₓ and R_{y} may include the alkyl group and the cycloalkyl group in R_{1c} to R_{7c}.

Examples of the 2-oxoalkyl group and the 2-oxocycloalkyl group as Rₓ and R_{y} may include a group having >C═O at the 2-position of the alkyl group and the cycloalkyl group as R_{1c} to R_{7c}.

Examples of the alkoxy group in the alkoxycarbonylalkyl group as Rₓ and R_{y} may include the same alkoxy group as R_{1c} to R_{5c}, and examples of the alkyl group may include an alkyl group having 1 to 12 carbon atoms, and preferably a straight alkyl group having 1 to 5 carbon atoms.

The allyl group as Rₓ and R_{y} is not particularly limited, but is preferably an unsubstituted allyl group, or an allyl group substituted with a monocyclic or polycyclic cycloalkyl group (preferably a cycloalkyl group having from 3 to 10 carbon atoms).

The vinyl group as Rₓ and R_{y} is not particularly limited, but is preferably an unsubstituted vinyl group, or a vinyl group substituted with a monocyclic or polycyclic cycloalkyl group (preferably a cycloalkyl group having 3 to 10 carbon atoms).

Examples of the ring structure which may be formed by R_{5c} and Rₓ bonded to each other may include a 5-membered or greater membered ring (particularly preferably a 5-membered ring) formed together with a sulfur atom and a carbonyl carbon atom in Formula (I) by R_{5c} and Rₓ bonded to each other to form a single bond or an alkylene group (a methylene group, an ethylene group and the like).

Examples of the ring structure which may be formed by Rₓ and R_{y} bonded to each other may include a 5- or 6-membered ring, particularly preferably a 5-membered ring (that is, a tetrahydrothiophene ring), which is formed together with a sulfur atom in Formula (ZI-3) by divalent Rₓ and R_{y} (for example, a methylene group, an ethylene group, a propylene group and the like).

Each of Rₓ and R_{y} is an alkyl group or a cycloalkyl group having preferably 4 or more carbon atoms, more preferably 6 or more carbon atoms, and still more preferably 8 or more carbon atoms.

Each of R_{1c} to R_{7c} and Rₓ and R_{y} may further have a substituent, and examples of the further substituent may include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group and the like.

In Formula (ZI-3), it is more preferred that each of R_{1c}, R_{2c}, R_{4c} and R_{5c} independently represents a hydrogen atom and R_{3c} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

A cation of the compound represented by Formula (ZI-2) or (ZI-3) in the present invention includes the following specific examples.

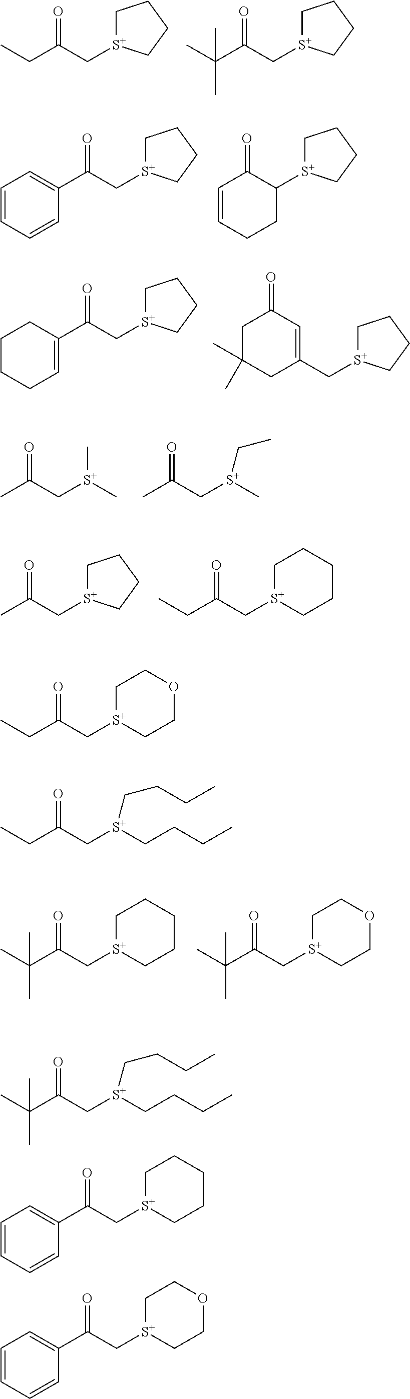

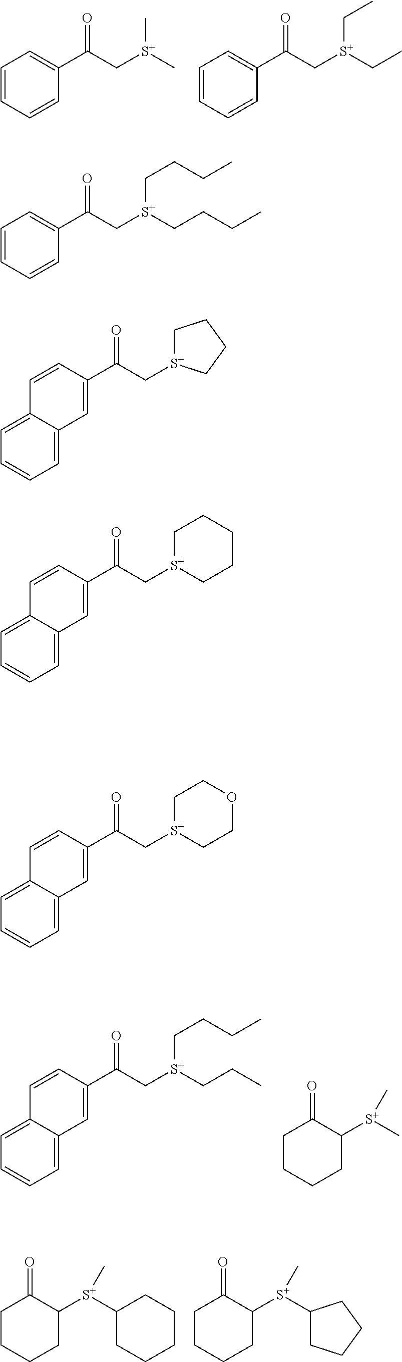

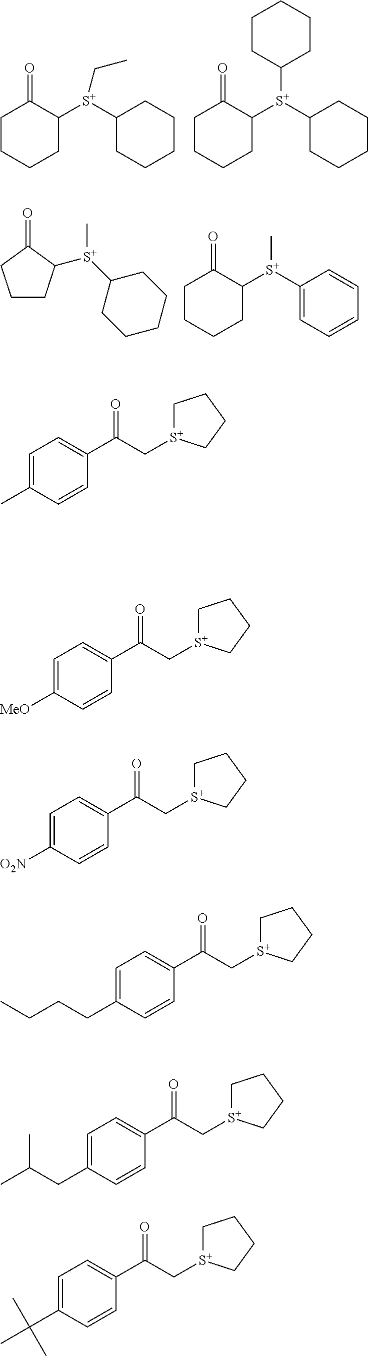

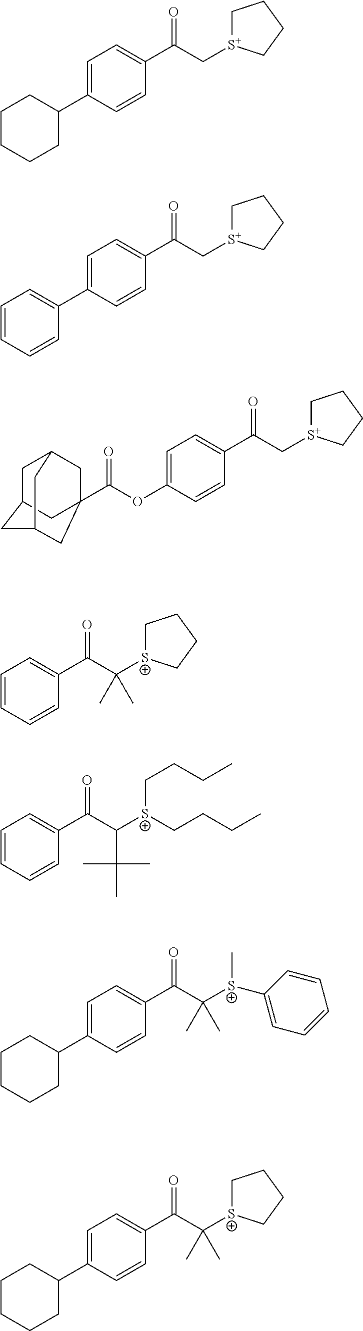

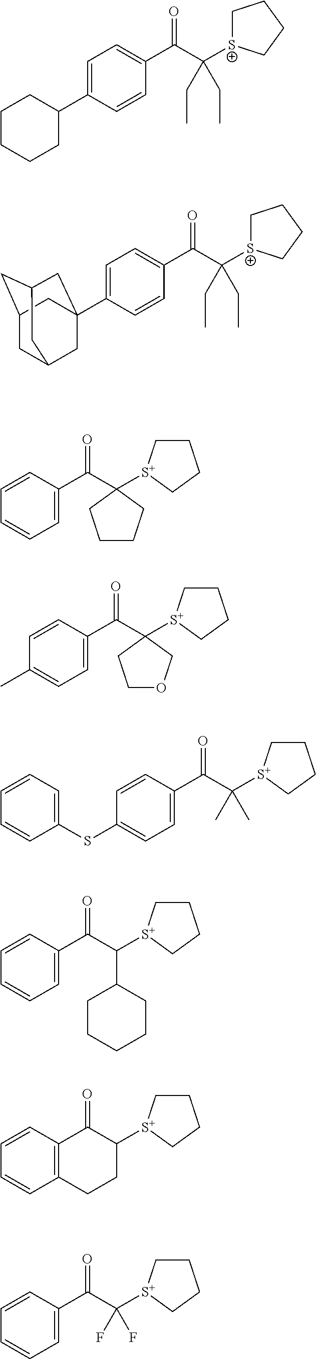

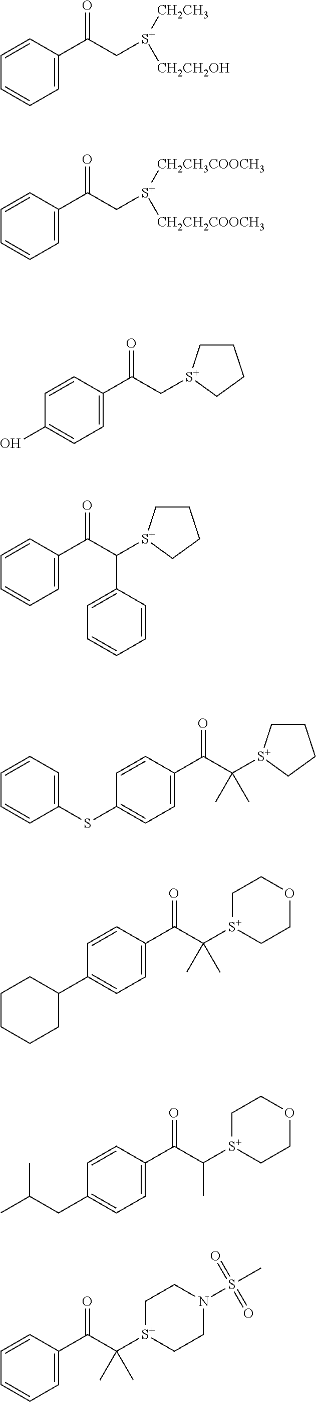

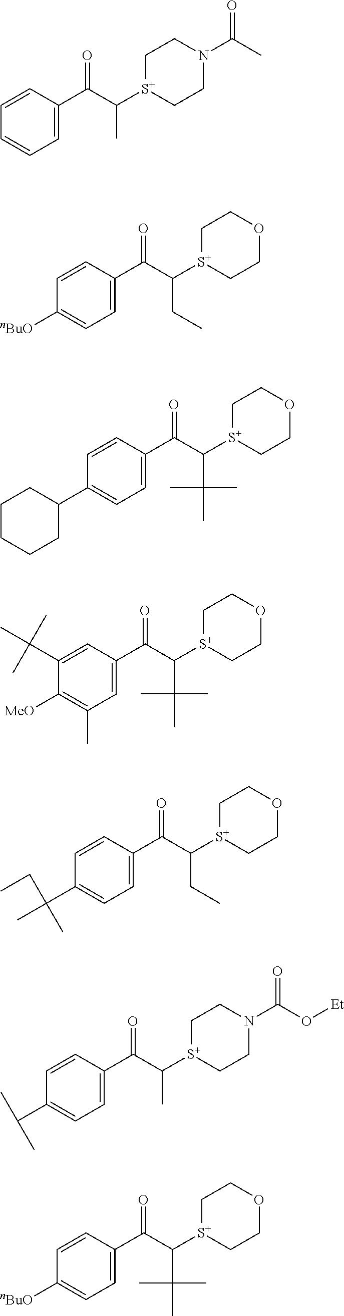

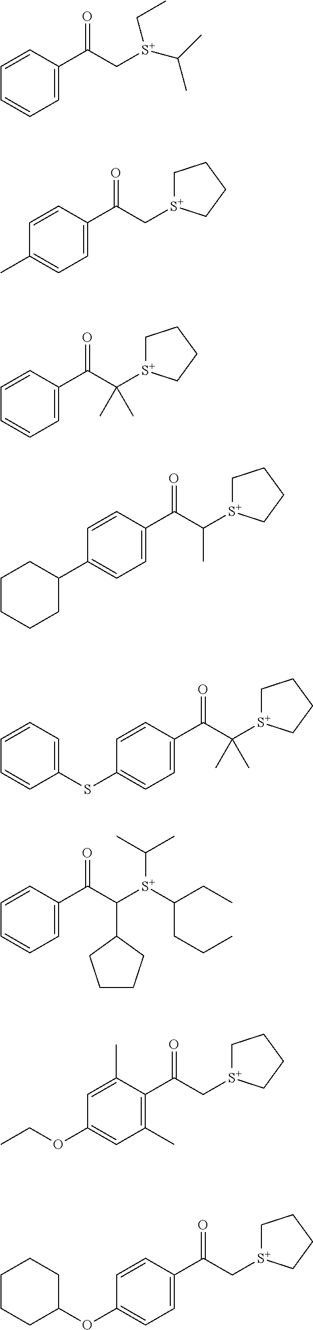

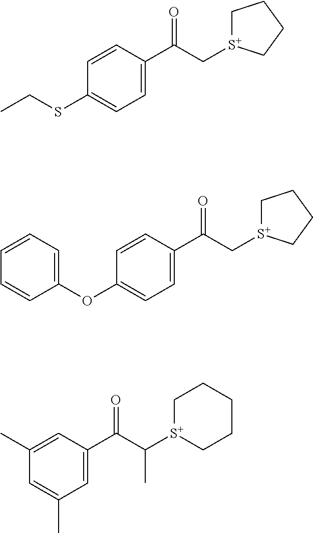 [SMILES: CCSc1ccc(C(=O)C[S+]2CCCC2)cc1 ; O=C(C[S+]1CCCC1)c1ccc(Oc2ccccc2)cc1 ; Cc1cc(C)cc(C(=O)C(C)[S+]2CCCCC2)c1]

Subsequently, compound (ZI-4) will be described.

Compound (ZI-4) is represented by the following Formula (ZI-4).

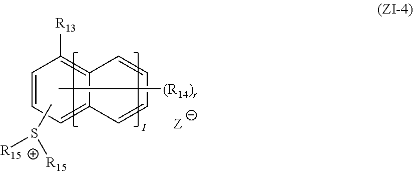

In Formula (ZI-4),

R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have a substituent.

When a plurality of R₁₄ is present, each R₁₄ independently represents a hydroxyl group, an alkyl group, a cycloalkyl group, an alkoxy group, an alkoxycarbonyl group, an alkylcarbonyl group, an alkylsulfonyl group, a cycloalkylsulfonyl group or a group having a cycloalkyl group. These groups may have a substituent.

Each R₁₅ independently represents an alkyl group, a cycloalkyl group or a naphthyl group. Two of R₁₅ may be bonded to each other to form a ring. These groups may have a substituent.

l represents an integer of 0 to 2.

r represents an integer of 0 to 8.

Z⁻ represents a non-nucleophilic anion, and examples thereof may include the same as the non-nucleophilic anion of Z⁻ in Formula (ZI).

In Formula (ZI-4), the alkyl group of R₁₃, R₁₄ and R₁₅ is preferably a straight or branched alkyl group having 1 to 10 carbon atoms.

Examples of the cycloalkyl group of R₁₃, R₁₄ and R₁₅ may include a monocyclic or polycyclic cycloalkyl group (preferably a cycloalkyl group having 3 to 20 carbon atoms).

The alkoxy group of R₁₃ and R₁₄ is preferably a straight or branched alkoxy group having 1 to 10 carbon atoms.

The alkoxycarbonyl group of R₁₃ and R₁₄ is preferably a straight or branched alkoxycarbonyl group having from 2 to 11 carbon atoms.

Examples of the group having a cycloalkyl group of R₁₃ and R₁₄ may include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ has a total carbon number of preferably 7 or more, and more preferably 7 to 15, and preferably has a monocyclic cycloalkyl group.

The alkoxy group having a monocyclic or polycyclic cycloalkyl group of R₁₃ and R₁₄ has preferably a total carbon number of 7 or more, and more preferably a total carbon number from 7 to 15, and is preferably an alkoxy group having a monocyclic cycloalkyl group.

Specific examples of the alkyl group in the alkylcarbonyl group of R₁₄ may include those of the above-described alkyl group as R₁₃ to R₁₅.

The alkylsulfonyl group and the cycloalkylsulfonyl group of R₁₄ are preferably straight, branched or cyclic and have 1 to 10 carbon atoms.

Examples of the substituent which may be possessed by each of the groups may include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group and the like.

Examples of the alkoxy group may include a straight, branched or cyclic alkoxy group having 1 to 20 carbon atoms, and the like.

Examples of the alkoxyalkyl group may include a straight, branched or cyclic alkoxyalkyl group having 2 to 21 carbon atoms.

Examples of the alkoxycarbonyl group may include a straight, branched or cyclic alkoxycarbonyl group having 2 to 21 carbon atoms and the like.

Examples of the alkoxycarbonyloxy group may include a straight, branched or cyclic alkoxycarbonyloxy group having 2 to 21 carbon atoms, and the like.

Examples of the ring structure which may be formed by two R₁₅'s bonded to each other may include a 5- or 6-membered ring formed together with the sulfur atom in Formula (ZI-4) by two R₁₅'s, and particularly preferably a 5-membered ring (that is, a tetrahydrothiophene ring), and may be condensed with an aryl group or a cycloalkyl group. The divalent R₁₅ may have a substituent, and examples of the substituent may include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like. As for the substituent on the ring structure, a plurality of substituents may be present, and the substituents may be bonded to each other to form a ring (an aromatic or non-aromatic hydrocarbon ring, an aromatic or non-aromatic heterocyclic ring, a polycyclic condensed ring formed by combining two or more of these rings or the like).

In Formula (ZI-4), R₁₅ is preferably a methyl group, an ethyl group, a naphthyl group, a divalent group capable of forming a tetrahydrothiophene ring structure together with the sulfur atom by two R₁₅'s bonded to each other, and the like.

The substituent which may be possessed by R₁₃ and R₁₄ is preferably a hydroxyl group, an alkoxy group, an alkoxycarbonyl group or a halogen atom (particularly a fluorine atom).

l is preferably 0 or 1, and more preferably 1.

r is preferably 0 to 2.

A cation of the compound represented by Formula (ZI-4) in the present invention may include the following specific examples.

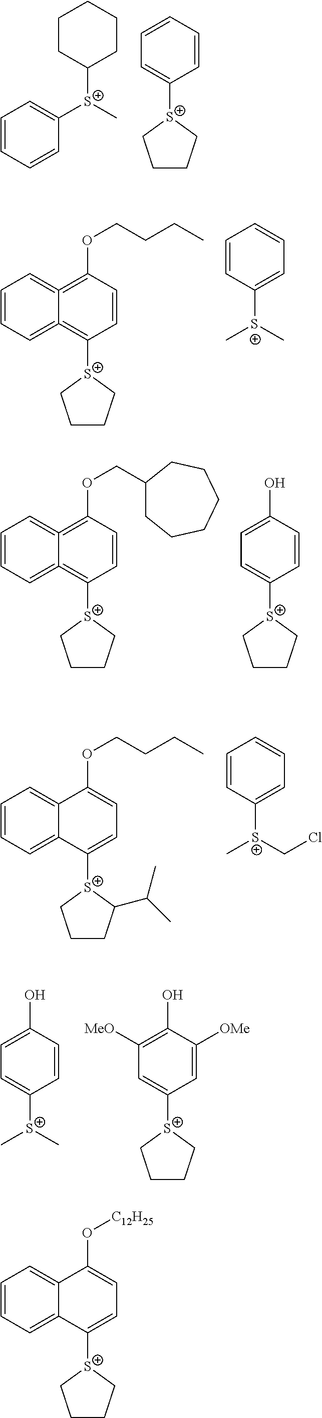

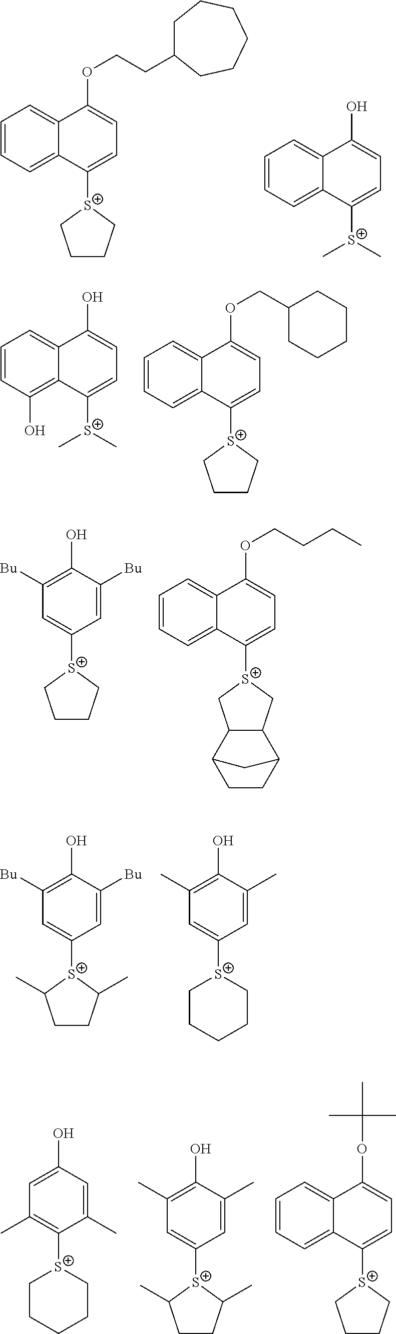

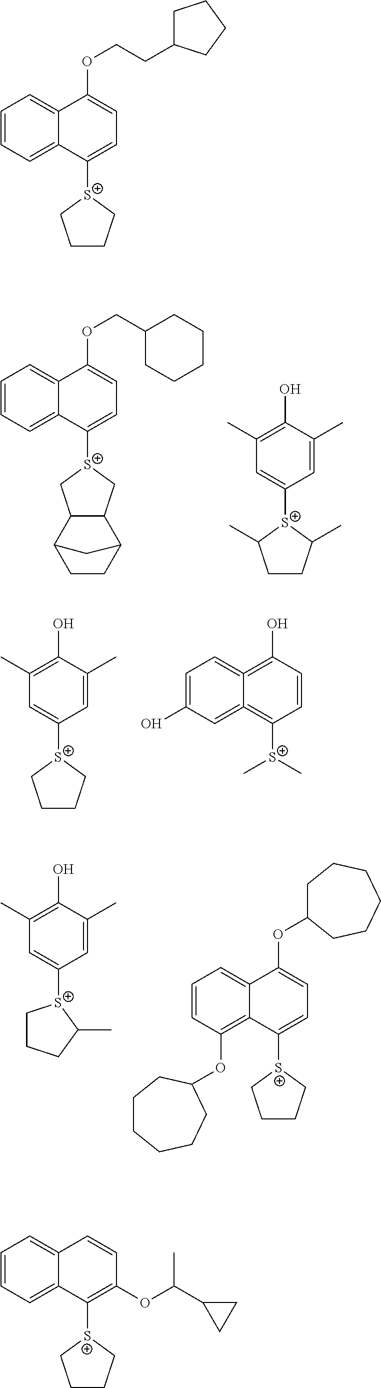

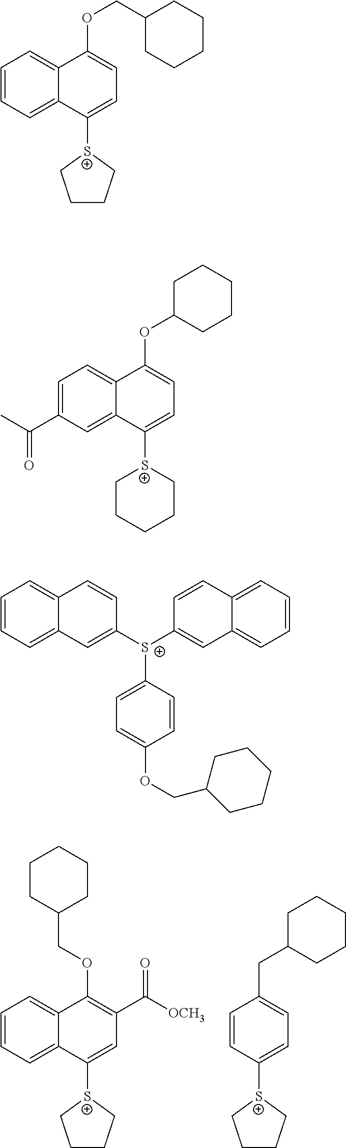 [SMILES: c1ccc2c([S+]3CCCC3)ccc(OCC3CCCCC3)c2c1 ; CC(=O)c1ccc2c(OC3CCCCC3)ccc([S+]3CCCCC3)c2c1 ; c1ccc2cc([S+](c3ccc(OCC4CCCCC4)cc3)c3ccc4ccccc4c3)ccc2c1 ; COC(=O)c1cc([S+]2CCCC2)c2ccccc2c1OCC1CCCCC1 ; c1cc([S+]2CCCC2)ccc1CC1CCCCC1]

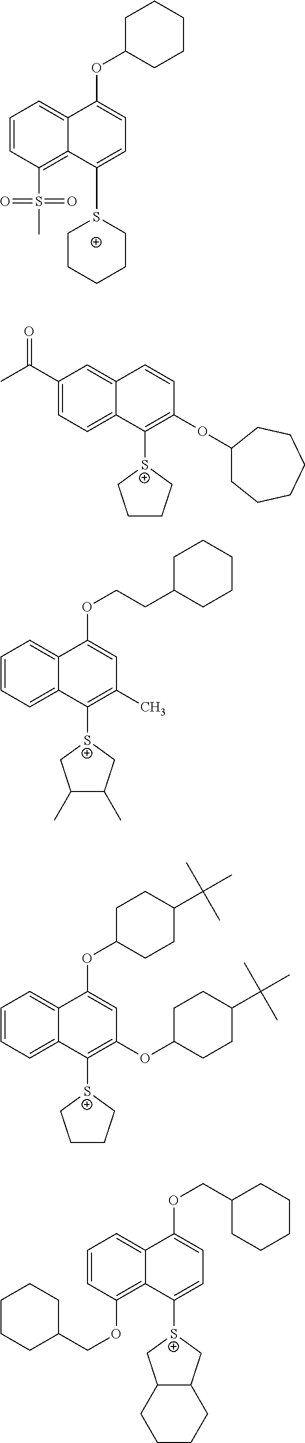

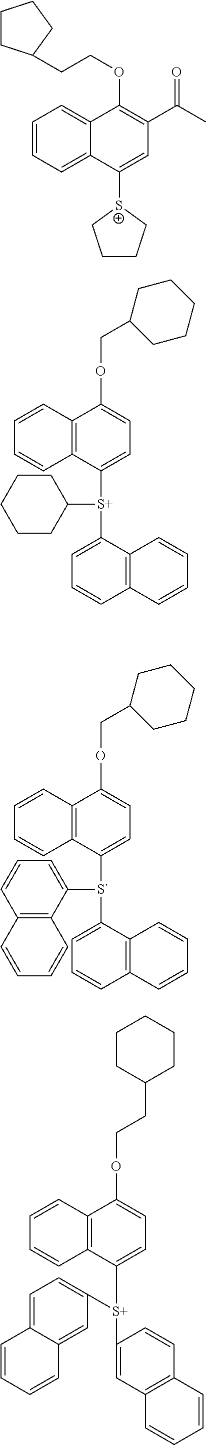

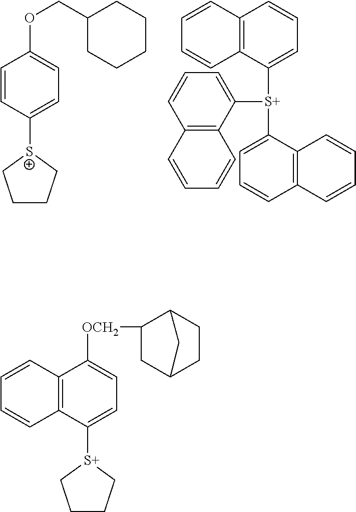

Subsequently, Formulas (ZII) and (ZIII) will be described.

In Formulas (ZII) and (ZIII),

Each of R₂₀₄ to R₂₀₇ independently represents an aryl group, an alkyl group or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure having an oxygen atom, a nitrogen atom, a sulfur atom or the like. Examples of the structure of the aryl group having a heterocyclic structure may include pyrrole, furan, thiophene, indole, benzofuran, benzothiophene and the like.

The alkyl group and the cycloalkyl group in R₂₀₄ to R₂₀₇ are preferably a straight or branched alkyl group having 1 to 10 carbon atoms and a cycloalkyl group having 3 to 10 carbon atoms, respectively.

The aryl group, the alkyl group and the cycloalkyl group of R₂₀₄ to R₂₀₇ may have a substituent. Examples of the substituent which may be possessed by the aryl group, the alkyl group and the cycloalkyl group of R₂₀₄ to R₂₀₇ may include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a phenylthio group and the like.

Z⁻ represents a non-nucleophilic anion, and examples thereof may include the same as the non-nucleophilic anion of Z⁻ in Formula (ZI).

Examples of the acid generator may further include compounds represented by the following Formulas (ZIV), (ZV) and (ZVI).

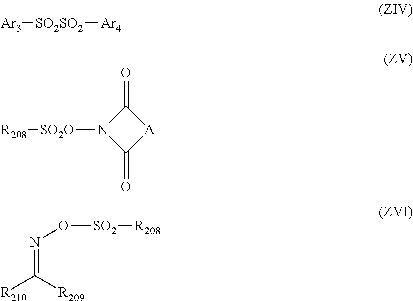

In Formulas (ZIV) to (ZVI),

Each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group as R₂₀₁, R₂₀₂ and R₂₀₃ in Formula (ZI-1).

Specific examples of the alkyl group and cycloalkyl group of R₂₀₈, R₂₀₉ and R₂₁₀ are the same as specific examples of the alkyl group and cycloalkyl group as R₂₀₁, R₂₀₂ and R₂₀₃ in Formula (ZI-2).

Examples of the alkylene group of A may include an alkylene group having 1 to 12 carbon atoms, examples of the alkenylene group of A include an alkenylene group having 2 to 12 carbon atoms, and examples of the arylene group of A may include an arylene group having 6 to 10 carbon atoms.

Among the acid generators, the compounds represented by Formulas (ZI) to (ZIII) are more preferred.

Further, the acid generator is preferably a compound capable of generating an acid having either a sulfonic acid group or an imide group, more preferably a compound capable of generating a monovalent perfluoroalkanesulfonic acid, or a compound capable of generating an aromatic sulfonic acid substituted with a monovalent fluorine atom or a fluorine atom-containing group, or a compound capable of generating an imide acid substituted with a monovalent fluorine atom or a fluorine atom-containing group, and still more preferably a sulfonium salt of fluoro-substituted alkanesulfonic acid, fluorine-substituted benzenesulfonic acid, fluorine-substituted imide acid or fluorine-substituted methide acid. The acid generator which may be used is particularly preferably a fluoro-substituted alkanesulfonic acid, a fluoro-substituted benzenesulfonic acid, or a fluoro-substituted imide acid, in which the acid generated has a pKa of −1 or less, and the sensitivity is enhanced.

The actinic ray-sensitive or radiation-sensitive resin composition of the present invention preferably contains the compound represented by Formula (ZI-2), (ZI-3) or (ZI-4) as an acid generator, and accordingly, may be much better in exposure latitude and uniformity of a local pattern dimension.

Among the acid generators, particularly preferred examples will be described below.

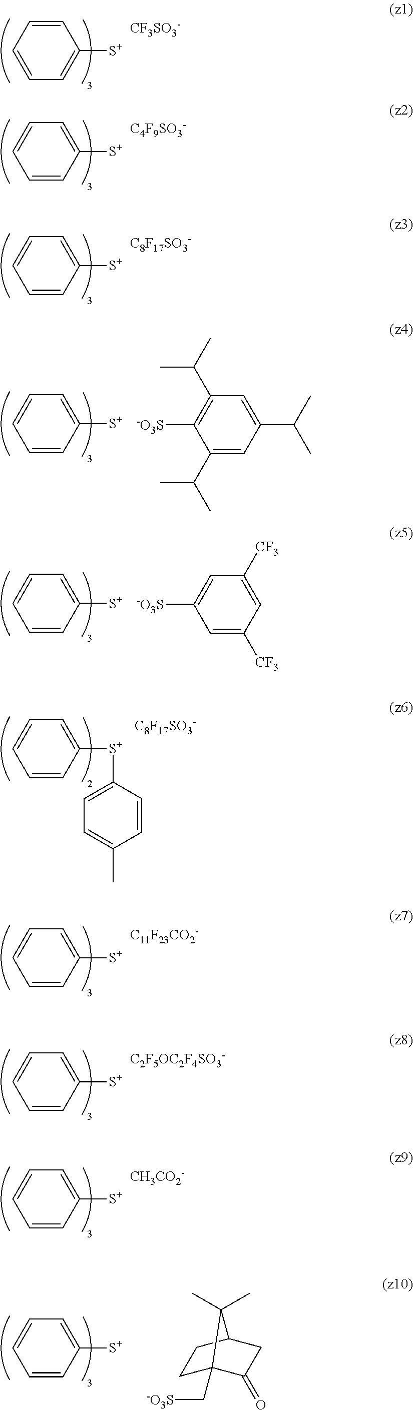

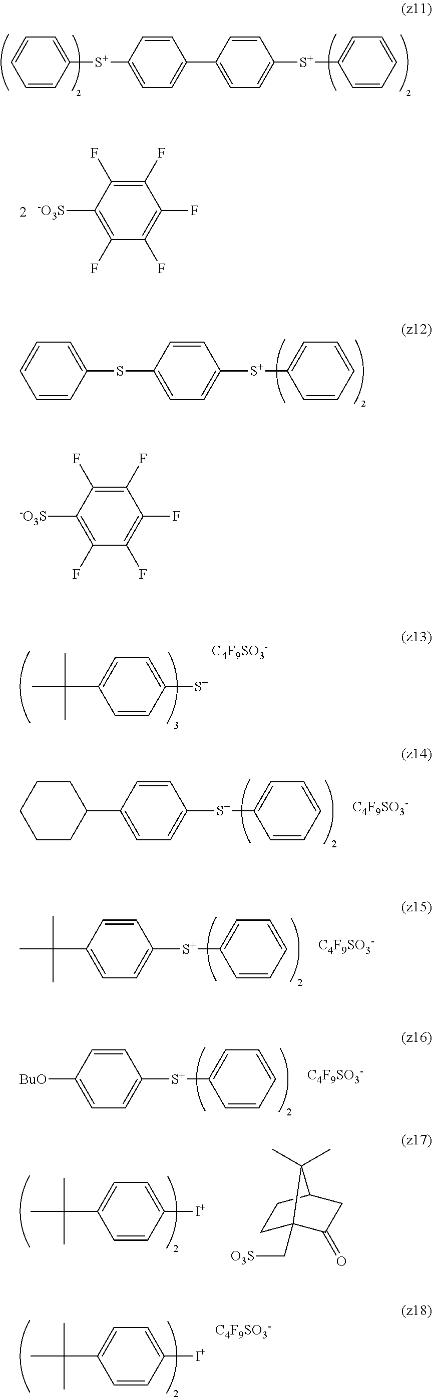

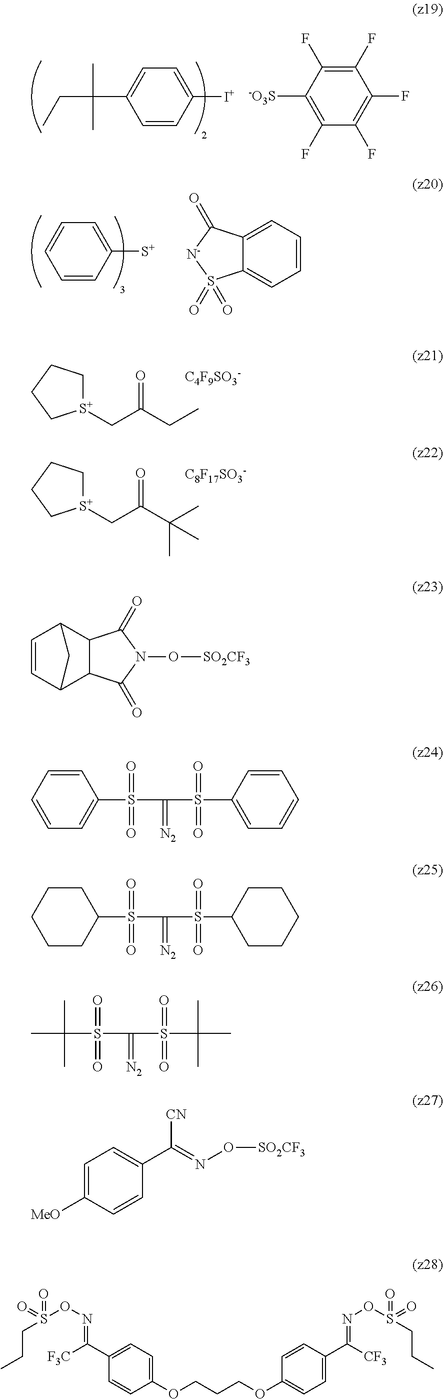

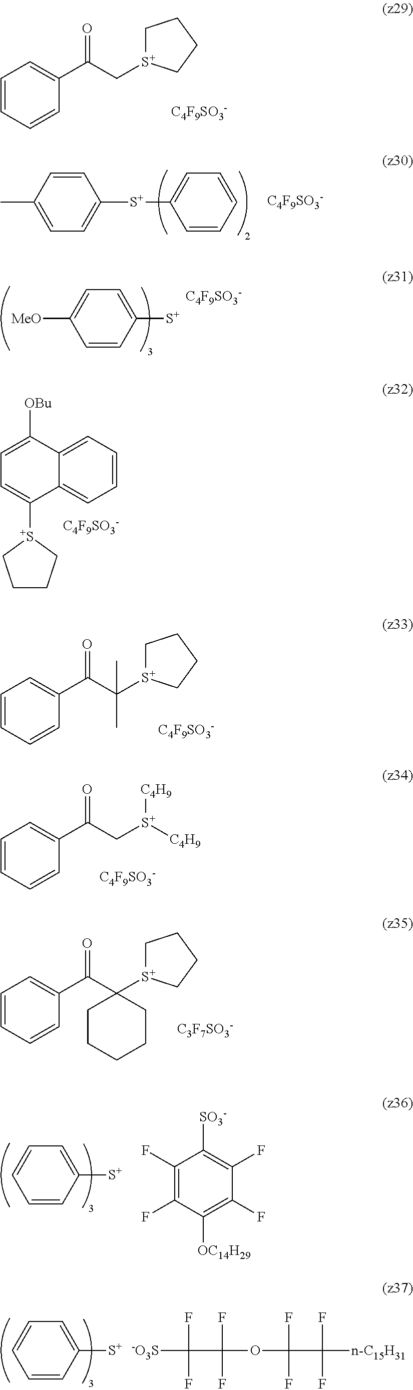

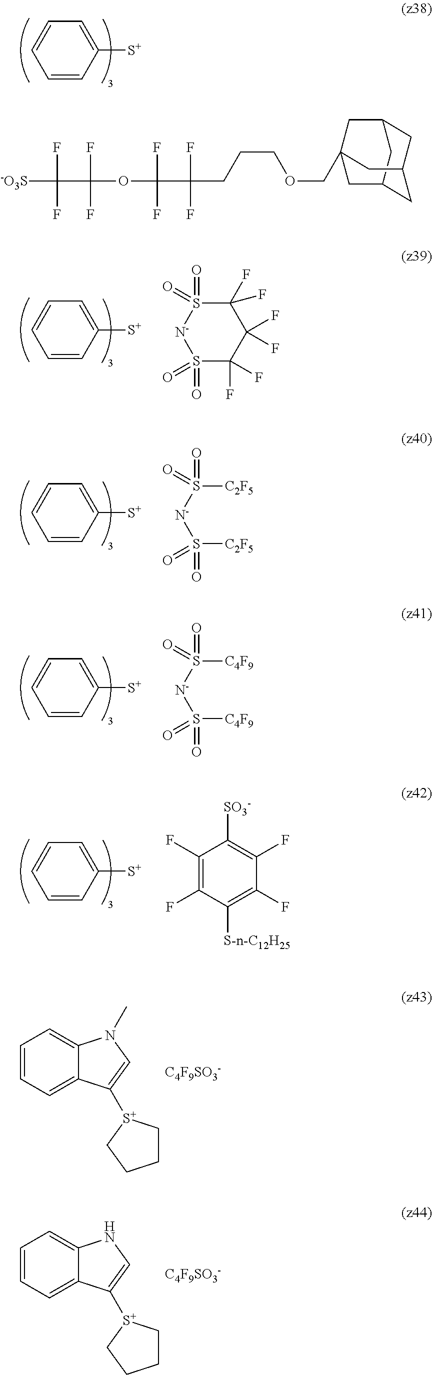

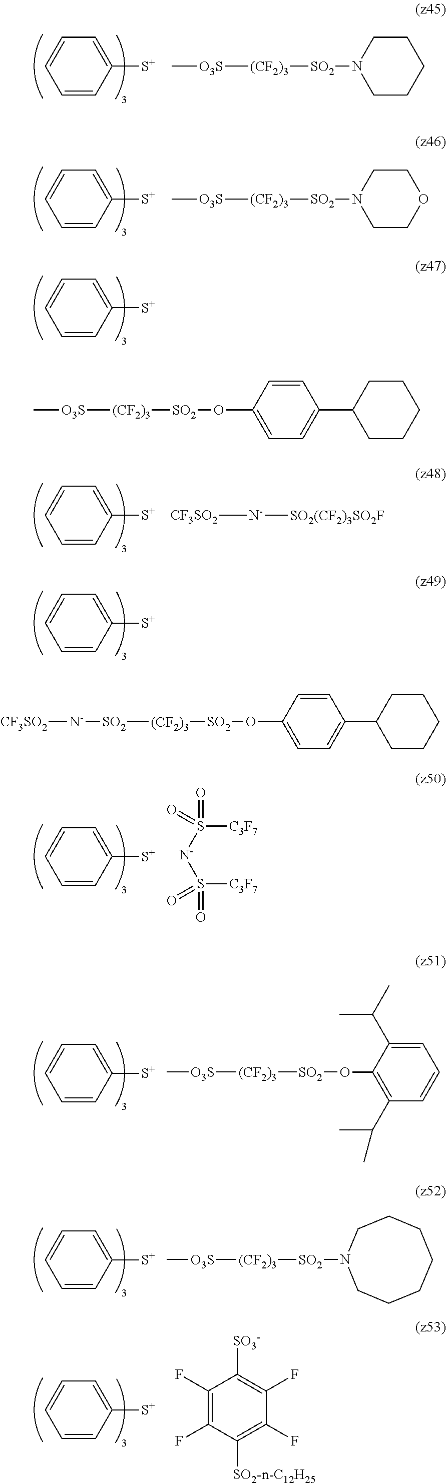

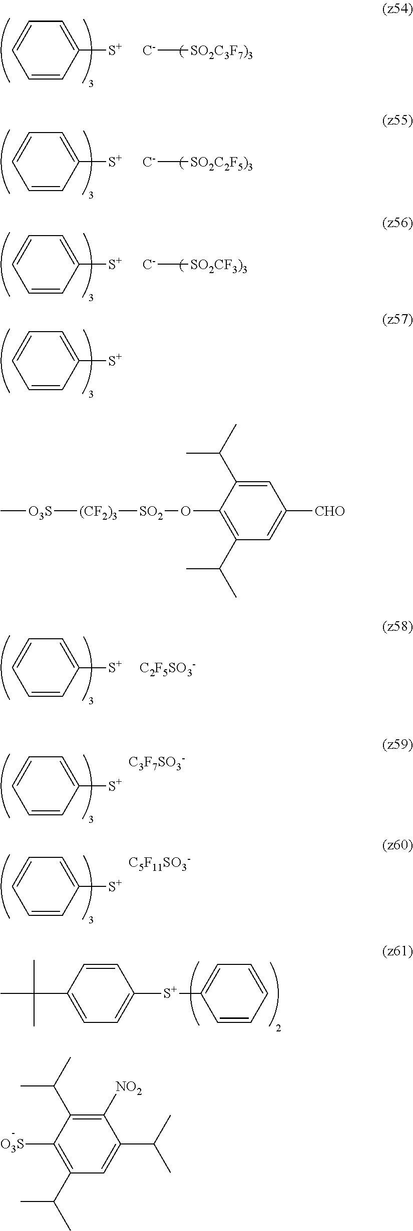

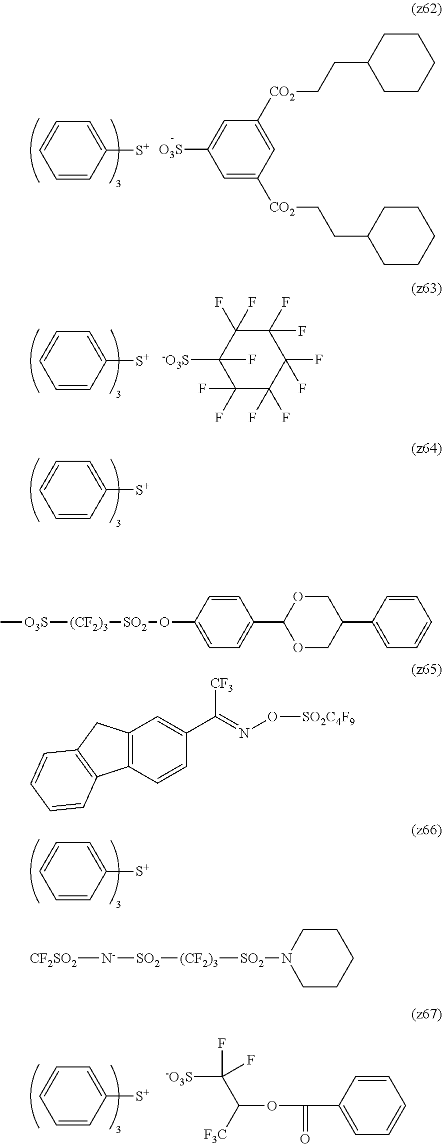

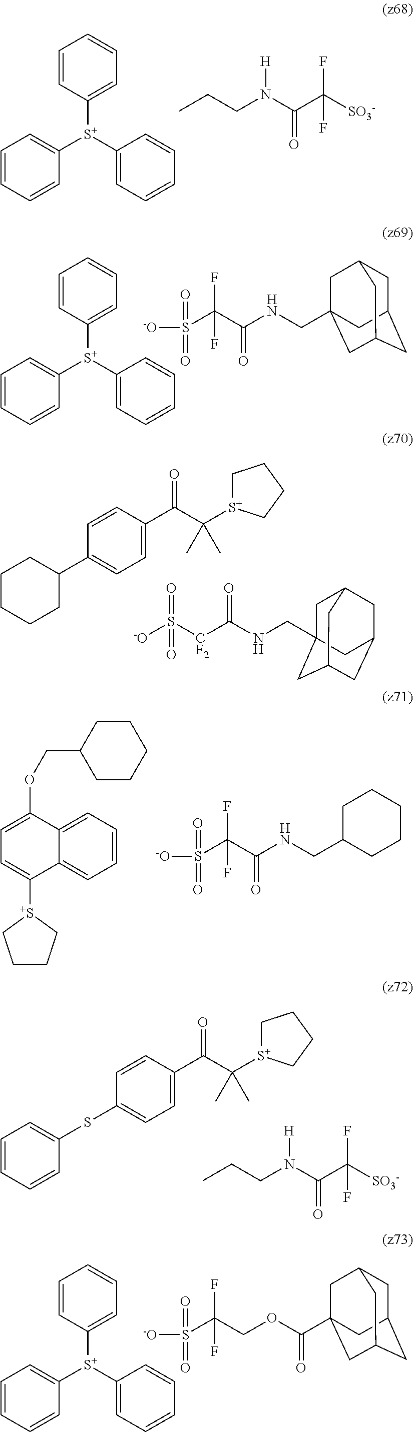

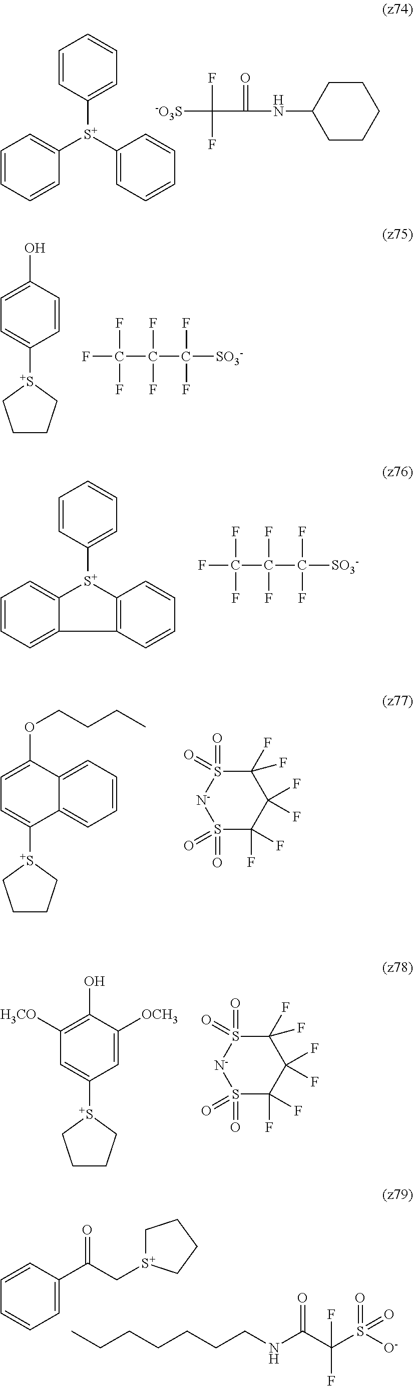

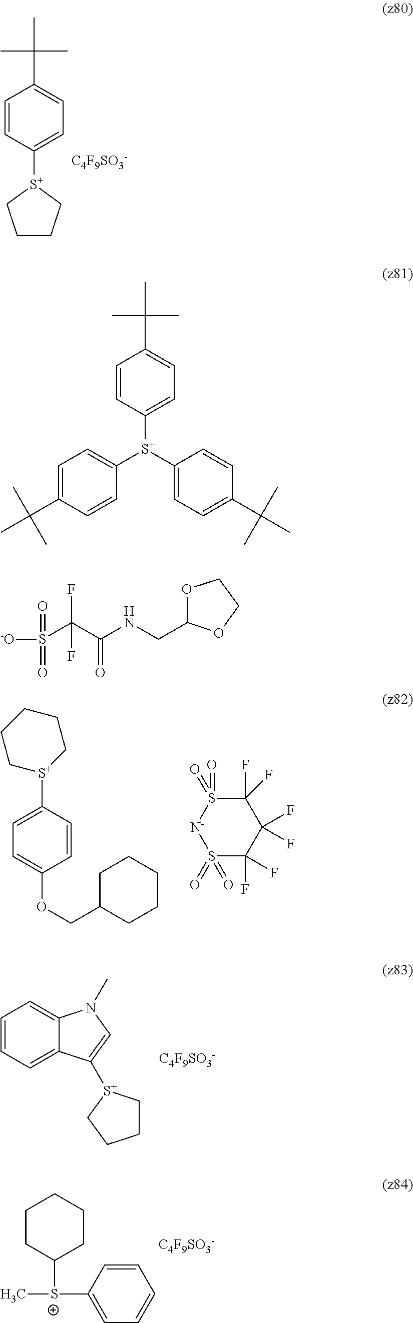

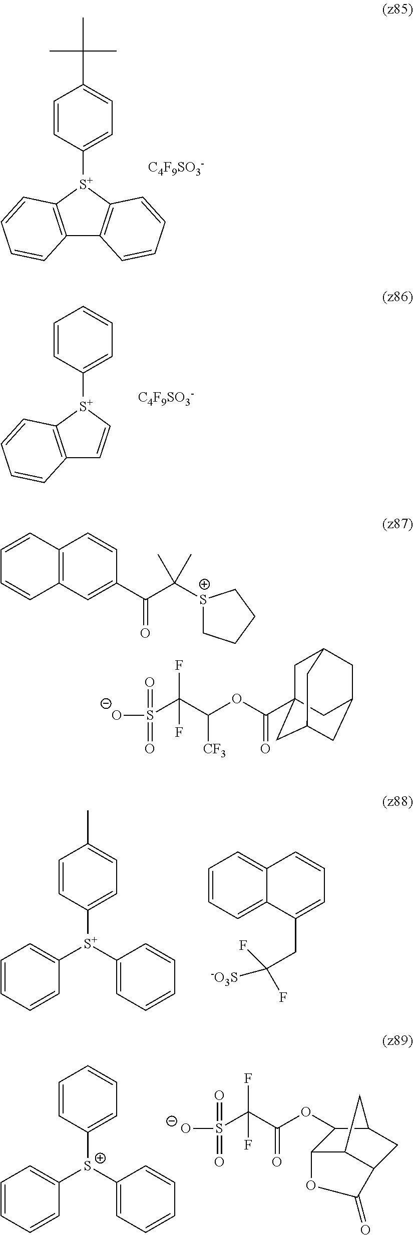

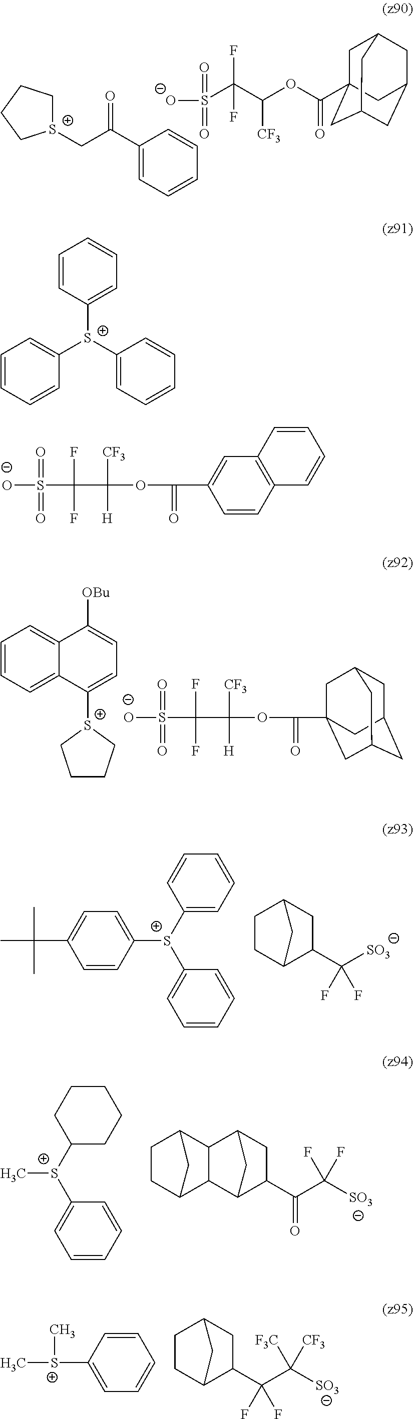

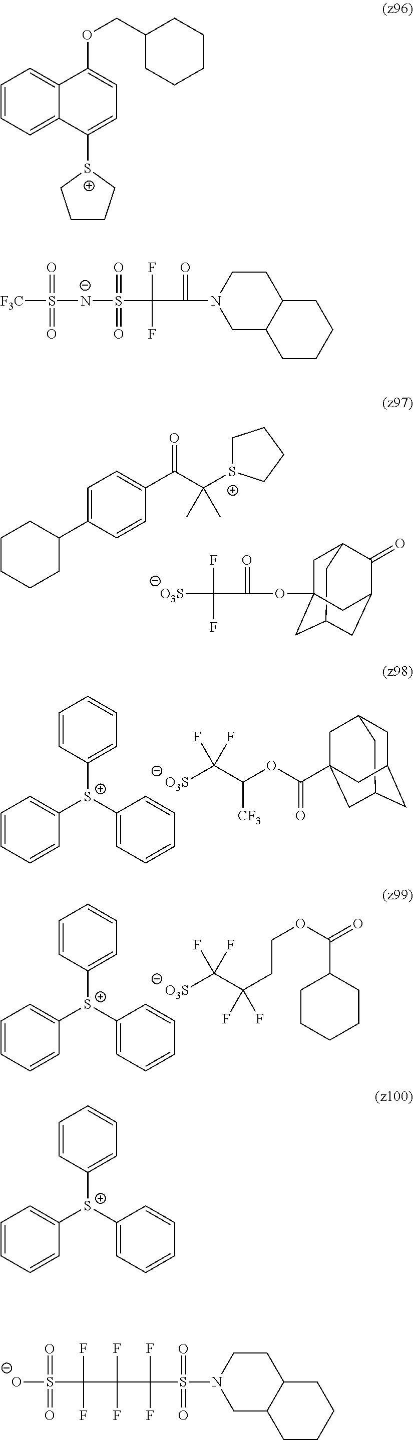

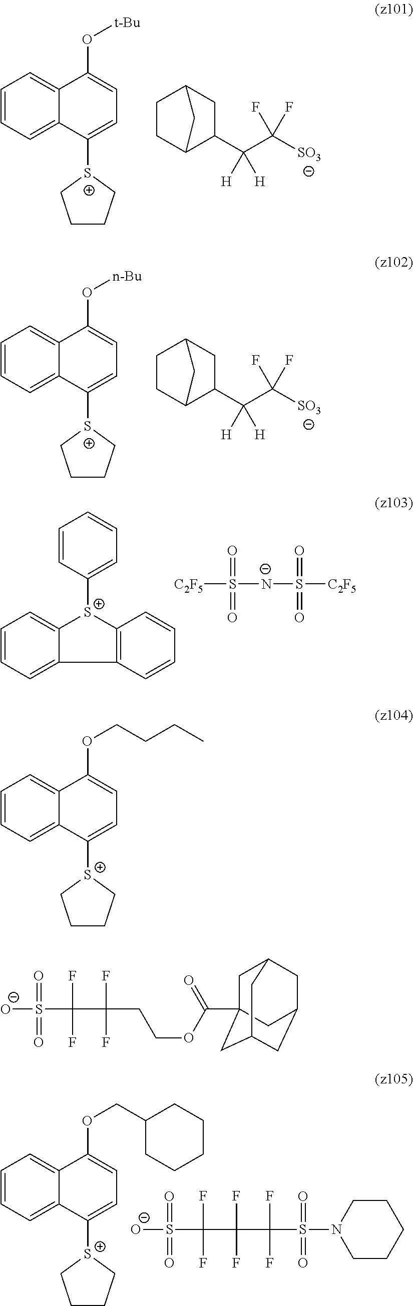

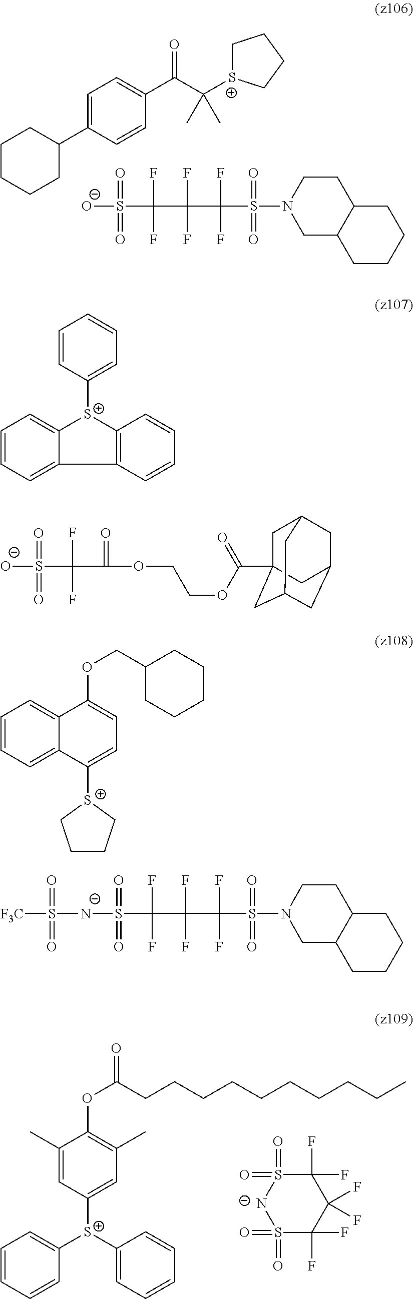

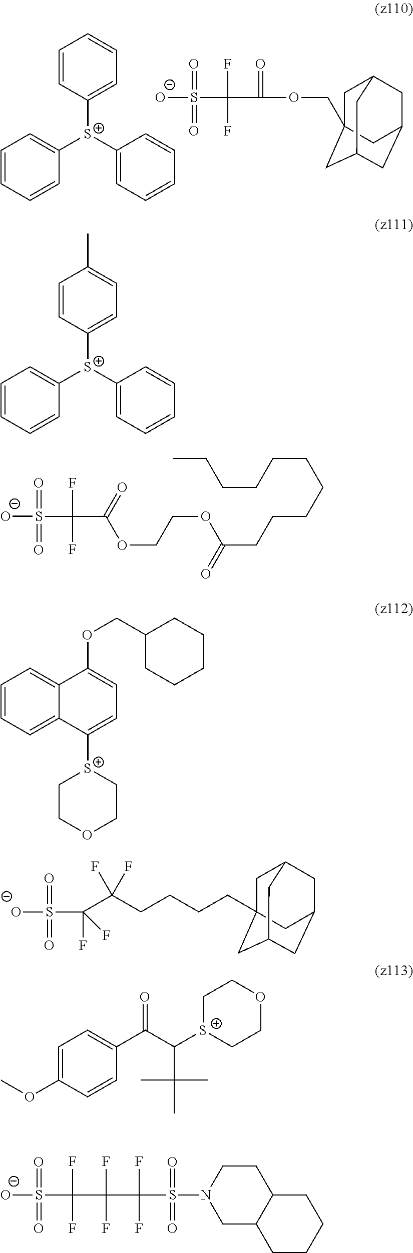

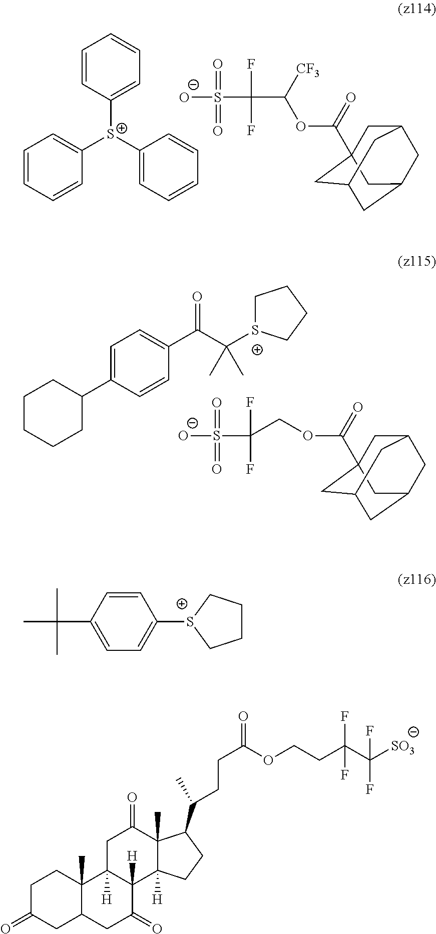

In addition, particularly preferred examples of compound (B) having the anion represented by any one of Formulas (B-1) to (B-3) will be described below, but the present invention is not limited thereto.

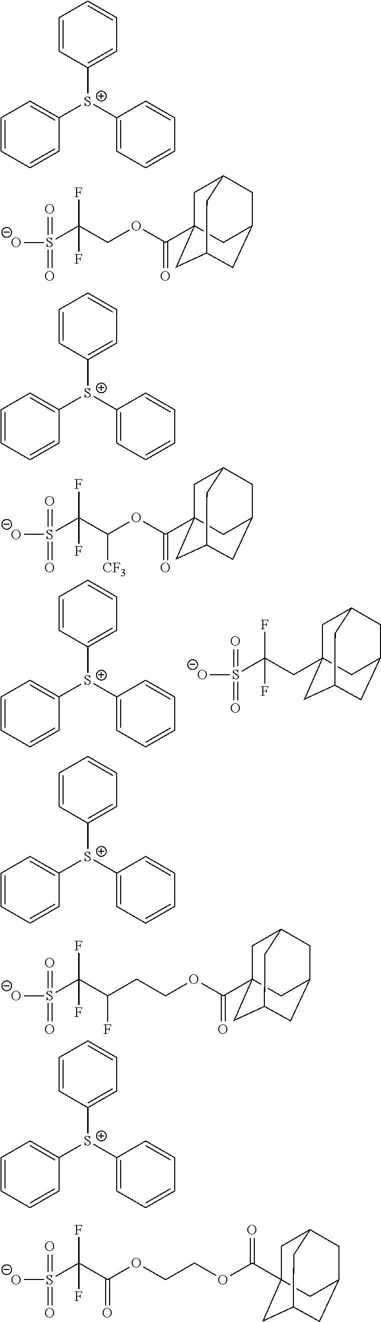

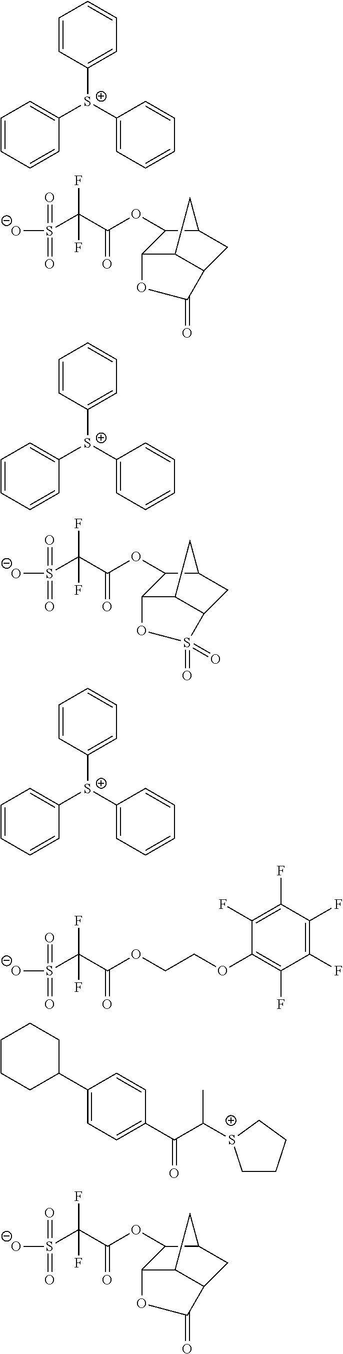

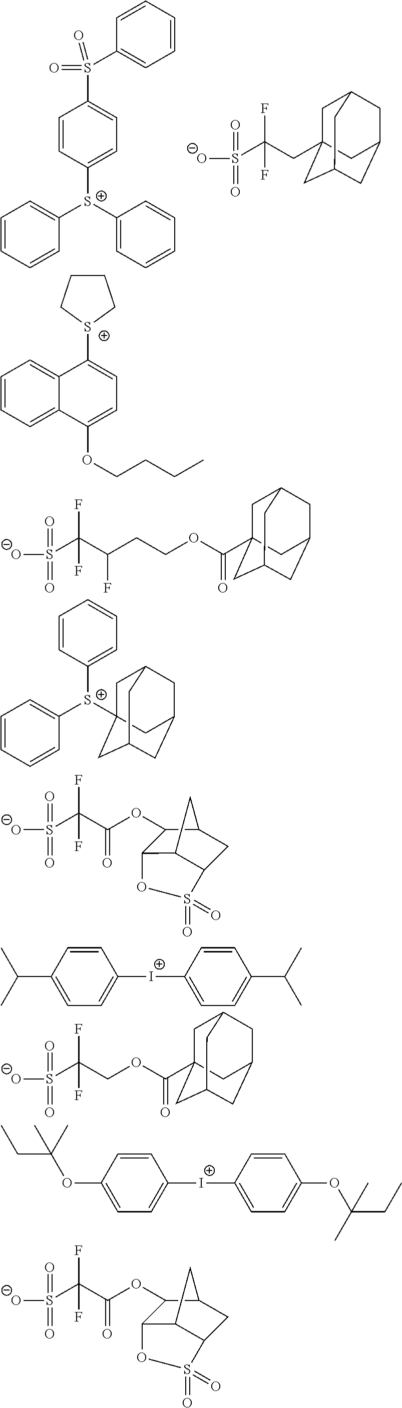

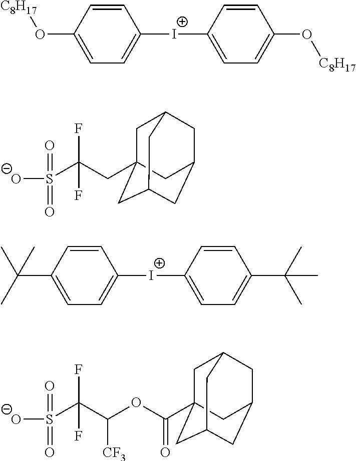

The acid generator may be synthesized by a publicly known method, and may be synthesized in accordance with the method described in, for example, Japanese Patent Application Laid-open No. 2007-161707, [0200] to [0210] of Japanese Patent Application Laid-open No. 2010-100595, [0051] to [0058] of International Publication No. 2011/093280, [0382] to [0385] of International Publication No. 2008/153110, Japanese Patent Application Laid-open No. 2007-161707 and the like.

The acid generator may be used either alone or in combination of two or more thereof.

The content of the compound capable of generating an acid upon irradiation with an actinic ray or radiation (except for the case represented by Formula (ZI-3) or (ZI-4)) in the composition is preferably 0.1 to 30% by mass, more preferably 0.5 to 25% by mass, still more preferably 3 to 20% by mass, and particularly preferably 3 to 15% by mass, based on the total solid content of the actinic ray-sensitive or radiation-sensitive resin composition (I).

Furthermore, when the acid generator is represented by Formula (ZI-3) or (ZI-4), the content thereof is preferably 5 to 35% by mass, more preferably from 8 to 30% by mass, still more preferably from 9 to 30% by mass, and particularly preferably from 9 to 25% by mass, based on the total solid content of the composition.

[4] Hydrophobic Resin (D)

Particularly when applied to liquid immersion exposure, the actinic ray-sensitive or radiation-sensitive resin composition according to the present invention may contain a hydrophobic resin (hereinafter, also referred to as a “hydrophobic resin (D)” or simply referred to as a “resin (D)”). Further, the hydrophobic resin (D) is preferably a resin different from the resin (A) and the resin (A1).

Accordingly, when the hydrophobic resin (D) is unevenly distributed on the film top layer and the immersion medium is water, the static/dynamic contact angle of the resist film surface against water may be enhanced, thereby enhancing an immersion liquid follow-up property.

It is preferred that the hydrophobic resin (D) is designed to be unevenly distributed at the interface as previously described, but unlike a surfactant, the hydrophobic resin (D) does not need to have a hydrophilic group in the molecule thereof, and may not contribute to the mixing of polar/non-polar materials homogeneously.

From the viewpoint of uneven distribution on the film top layer, the hydrophobic resin (D) has preferably one or more of “a fluorine atom”, “a silicon atom” and “a CH₃ partial structure contained in a side chain moiety of a resin”, and more preferably two or more thereof.

When the hydrophobic resin (D) includes a fluorine atom and/or a silicon atom, the fluorine atom and/or the silicon atom in the hydrophobic resin (D) may be included in the main chain of the resin, and may be included in the side chain thereof.

When the hydrophobic resin (D) includes a fluorine atom, the hydrophobic resin (D) is preferably a resin having an alkyl group having a fluorine atom, a cycloalkyl group having a fluorine atom, or an aryl group having a fluorine atom as a partial structure having a fluorine atom.

The alkyl group (having preferably 1 to 10 carbon atoms, and more preferably 1 to 4 carbon atoms) having a fluorine atom is a straight or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group in which at least one hydrogen atom in an aryl group such as a phenyl group and a naphthyl group is substituted with a fluorine atom, and may further have a substituent other than a fluorine atom.

Preferred examples of the alkyl group having a fluorine atom, the cycloalkyl group having a fluorine atom and the aryl group having a fluorine atom include groups represented by the following Formulas (F2) to (F4), but the present invention is not limited thereto.

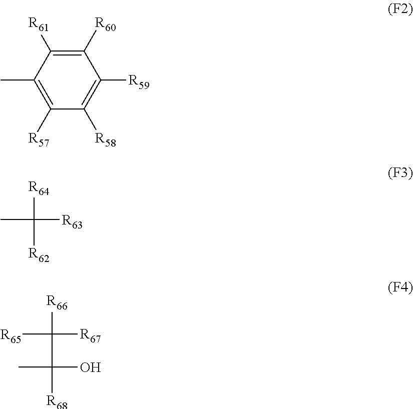

In Formulas (F2) to (F4),

Each of R₅₇ to R₆₈ independently represents a hydrogen atom, a fluorine atom or an alkyl group (straight or branched). However, each of at least one of R₅₇ to R₆₁, at least one of R₆₂ to R₆₄ and at least one of R₆₅ to R₆₈ independently represents a fluorine atom or an alkyl group (preferably having 1 to 4 carbon atoms) in which at least one hydrogen atom is substituted with a fluorine atom.

All of R₅₇ to R₆₁ and R₆₅ to R₆₇ are preferably a fluorine atom. R₆₂, R₆₃ and R₆₈ are preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be bonded to each other to form a ring.

Specific examples of the group represented by Formula (F2) may include a p-fluorophenyl group, a pentafluorophenyl group, a 3,5-di(trifluoromethyl)phenyl group and the like.

Specific examples of the group represented by Formula (F3) may include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. A hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred, and a hexafluoroisopropyl group and a heptafluoroisopropyl group are more preferred.

Specific examples of the group represented by Formula (F4) may include —C(CF₃)₂OH, —C(C₂F₅)₂OH, —C(CF₃)(CH₃)OH, —CH(CF₃)OH and the like, and —C(CF₃)₂OH is preferred.

The partial structure including a fluorine atom may be bonded directly to the main chain and further may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

Hereinafter, specific examples of the repeating unit having a fluorine atom will be described, but the present invention is not limited thereto.

In the specific examples, X₁ represents a hydrogen atom, —CH₃, —F or —CF₃. X₂ represents —F or —CF₃.

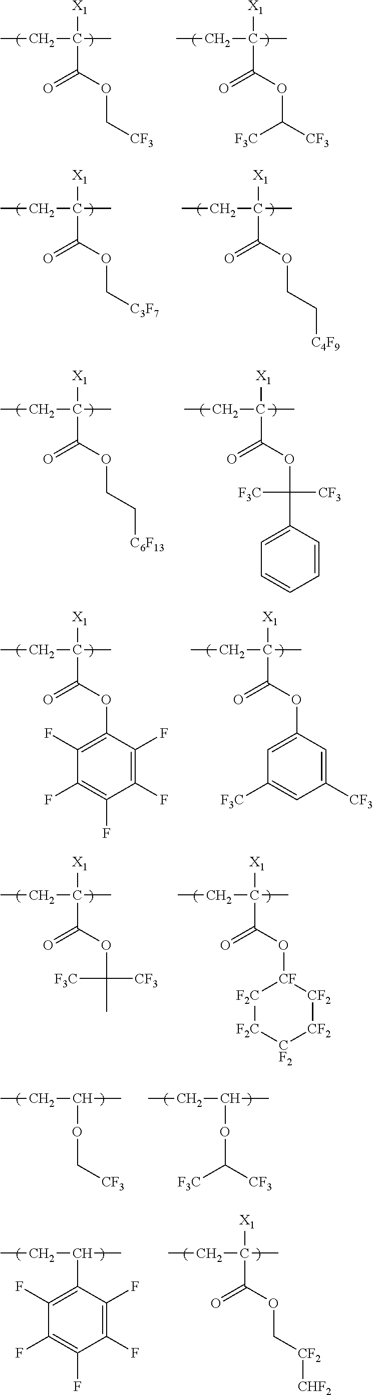

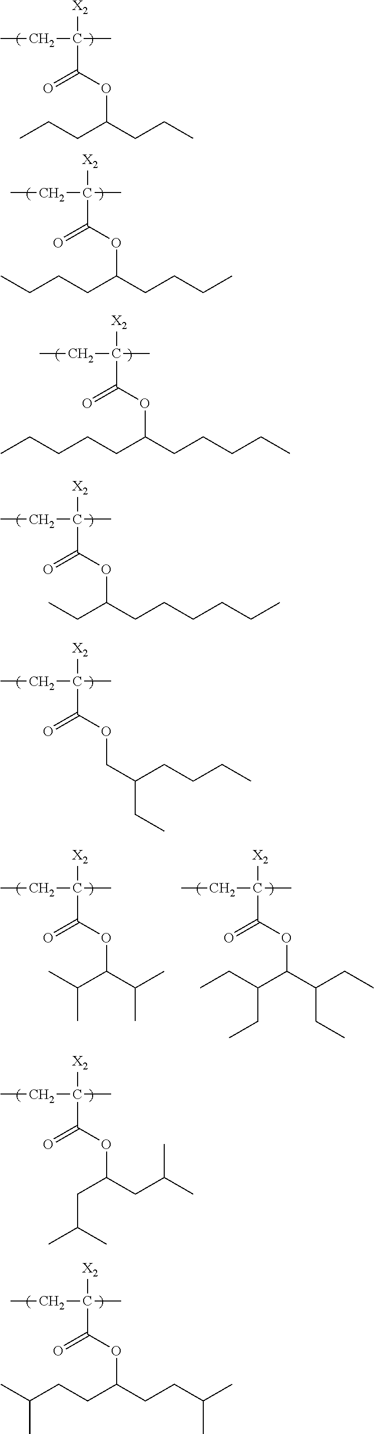

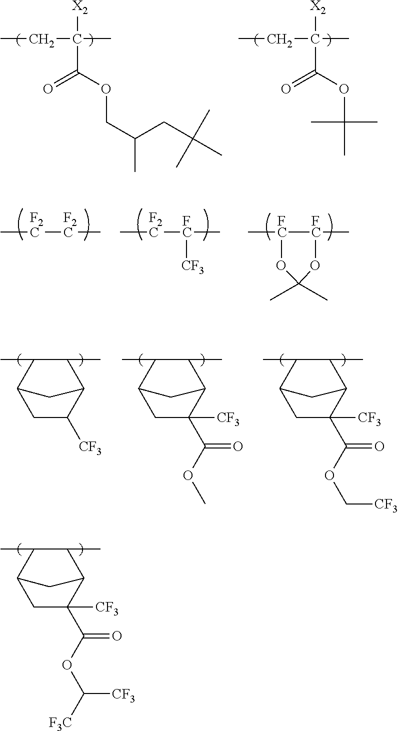

The hydrophobic resin (D) may contain a silicon atom. The hydrophobic resin (D) is preferably a resin having an alkylsilyl structure (preferably a trialkylsilyl group) or a cyclic siloxane structure as a partial structure having a silicon atom.

Specific examples of the alkylsilyl structure or the cyclic siloxane structure may include groups represented by the following Formulas (CS-1) to (CS-3) and the like.

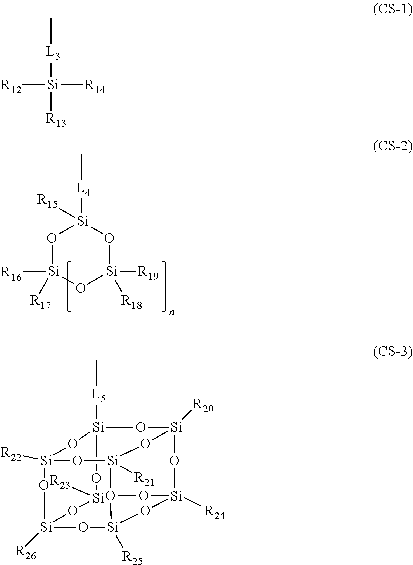

In Formulas (CS-1) to (CS-3),

Each of R₁₂ to R₂₆ independently represents a straight or branched alkyl group (preferably having 1 to 20 carbon atoms) or a cycloalkyl group (preferably having 3 to 20 carbon atoms).

Each of L₃ to L₅ represents a single bond or a divalent linking group. Examples of the divalent linking group may include a sole group or a combination of two or more groups (preferably having a total carbon number of 12 or less), selected from the group consisting of an alkylene group, a phenylene group, an ether bond, a thioether bond, a carbonyl group, an ester bond, an amide bond, a urethane bond and an urea bond.

n represents an integer of 1 to 5. n is preferably an integer of 2 to 4.

Hereinafter, specific examples of the repeating unit having a group represented by Formulas (CS-1) to (CS-3) will be shown, but the present invention is not limited thereto. Meanwhile, in the specific examples, X₁ represents a hydrogen atom, —CH₃, —F, or —CF₃.

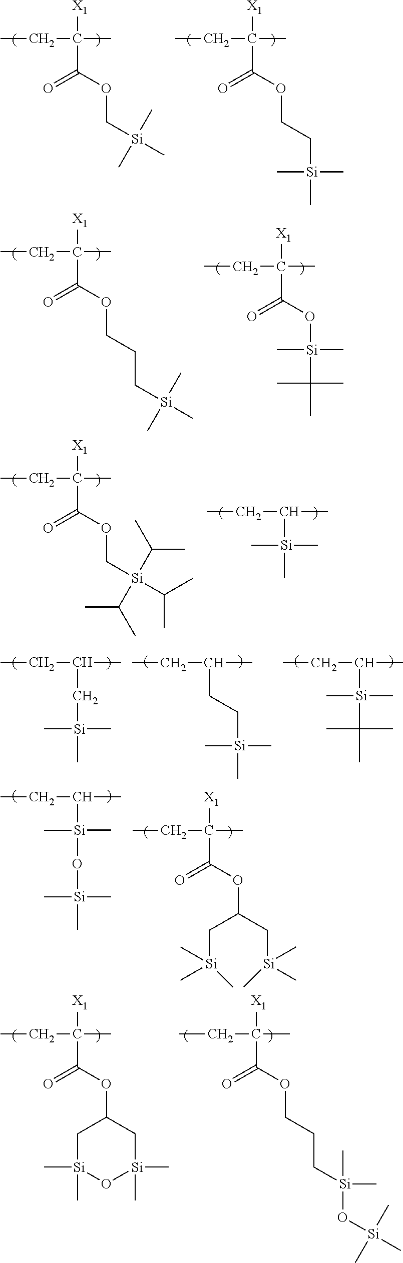

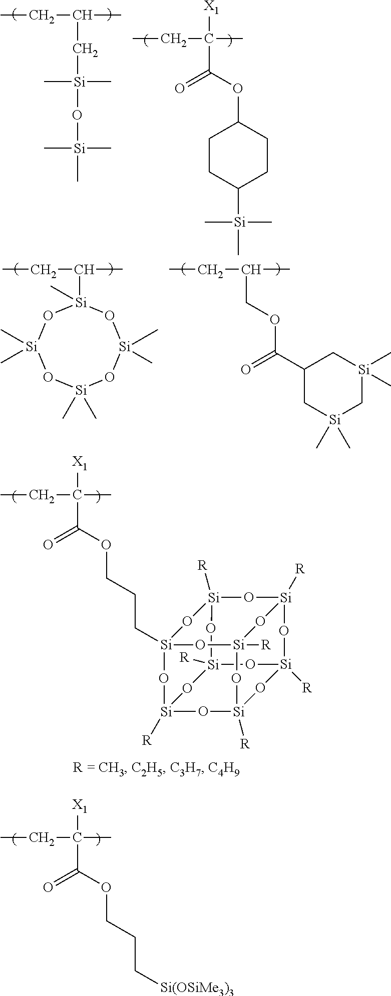

Further, as described above, it is preferred that hydrophobic resin (D) also includes a CH₃ partial structure in the side chain moiety thereof.

Here, the CH₃ partial structure (hereinafter, simply referred to as a “side chain CH₃ partial structure”), which the side chain moiety in the resin (D) has, includes a CH₃ partial structure that an ethyl group, a propyl group and the like have.

Meanwhile, a methyl group (for example, an α-methyl group of the repeating unit having a methacrylic acid structure) directly bonded to the main chain of the resin (D) slightly contributes to the surface uneven distribution of the resin (D) due to the effects of the main chain and thus is not included in the CH₃ partial structure in the present invention.

More specifically, when resin (D) includes a repeating unit derived from a monomer having a polymerizable moiety having a carbon-carbon double bond, such as, for example, a repeating unit represented by the following Formula (M) and when R₁₁ to R₁₄ are a CH₃ “as it is”, the CH₃ is not included in the CH₃ partial structure in the present invention that the side chain moiety has.

Meanwhile, the CH₃ partial structure present through any atom from the C—C main chain is assumed to correspond to a CH₃ partial structure in the present invention. For example, when R₁₁ is an ethyl group (CH₂CH₃), R₁₁ is assumed to have “one” of the CH₃ partial structures in the present invention.

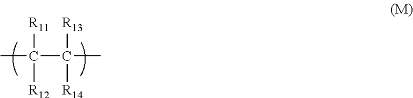

In Formula (M),

Each of R₁₁ to R₁₄ independently represents a side chain moiety.

Examples of R₁₁ to R₁₄ in the side chain moiety may include a hydrogen atom, a monovalent organic group and the like.

Examples of the monovalent organic group for R₁₁ to R₁₄ may include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group and the like, and these groups may further have a substituent.

The hydrophobic resin (D) is preferably a resin having a repeating unit having a CH₃ partial structure at the side chain moiety thereof, and more preferably has at least one repeating unit (x) of a repeating unit represented by the following Formula (II) and a repeating unit represented by the following Formula (III) as the repeating unit.

Hereinafter, the repeating unit represented by Formula (II) will be described in detail.

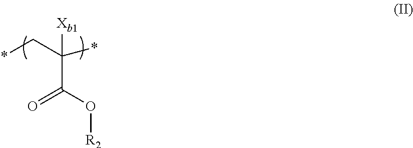

In Formula (II), X_{b1} represents a hydrogen atom, an alkyl group, a cyano group or a halogen atom, and R₂ represents an organic group which is stable against an acid and has one or more CH₃ partial structures. Here, more specifically, the organic group which is stable against an acid is preferably an organic group which does not have “a group capable of decomposing by the action of an acid to generate a polar group” previously described with respect to the resin (A).

The alkyl group of X_{b1} is preferably an alkyl group having 1 to 4 carbon atoms, and examples thereof include a methyl group, an ethyl group, a propyl group, a hydroxymethyl group, a trifluoromethyl group and the like, but a methyl group is preferred.

X_{b1} is preferably a hydrogen atom or a methyl group.

Examples of R₂ may include an alkyl group, a cycloalkyl group, an alkenyl group, a cycloalkenyl group, an aryl group and an aralkyl group, which have one or more CH₃ partial structures. The aforementioned cycloalkyl group, alkenyl group, cycloalkenyl group, aryl group and aralkyl group may further have an alkyl group as a substituent.

R₂ is preferably an alkyl group or an alkyl-substituted cycloalkyl group, which has one or more CH₃ partial structures.

As R₂, the organic group, which has one or more CH₃ partial structures and is stable against an acid, preferably has 2 to 10 CH₃ partial structures, and more preferably 2 to 8 CH₃ partial structures.

The alkyl group having one or more CH₃ partial structures in R₂ is preferably a branched alkyl group having 3 to 20 carbon atoms.

The cycloalkyl group having one or more CH₃ partial structures in R₂ may be monocyclic or polycyclic. Specific examples thereof may include groups having a monocyclo, bicyclo, tricyclo and tetracyclo structure having 5 or more carbon atoms, and the like. The carbon number thereof is preferably 6 to 30, and particularly preferably 7 to 25.

The alkenyl group having one or more CH₃ partial structures in R₂ is preferably a straight or branched alkenyl group having 1 to 20 carbons, and more preferably a branched alkenyl group.

The aryl group having one or more CH₃ partial structures in R₂ is preferably an aryl group having 6 to 20 carbon atoms, and examples thereof may include a phenyl group and a naphthyl group, and preferably a phenyl group.

The aralkyl group having one or more CH₃ partial structures in R₂ is preferably an aralkyl group having 7 to 12 carbon atoms, and examples thereof may include a benzyl group, a phenethyl group, a naphthylmethyl group and the like.

Preferred specific examples of the repeating unit represented by Formula (II) will be described below. Meanwhile, the present invention is not limited thereto.

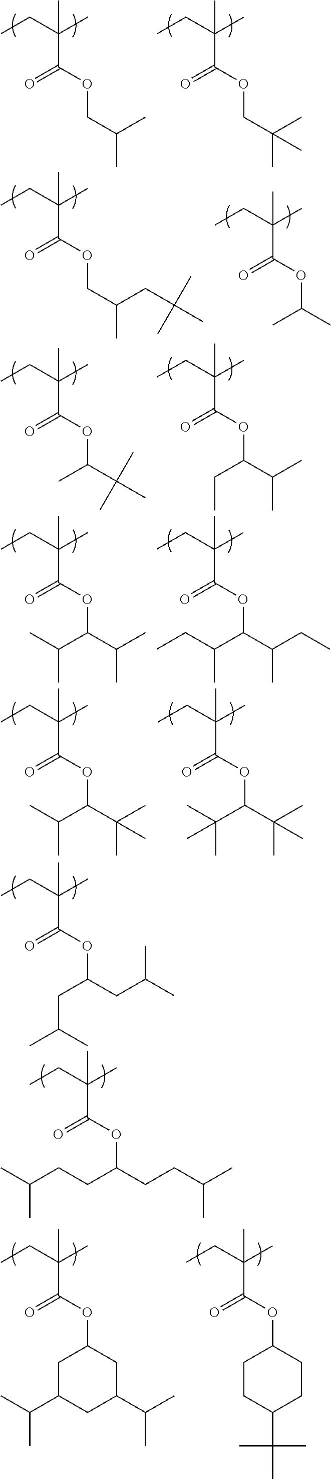

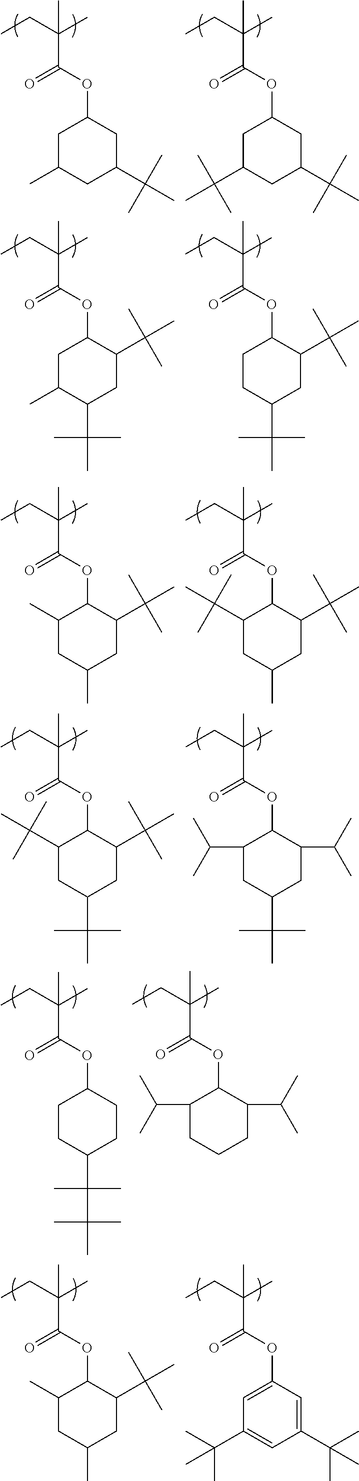

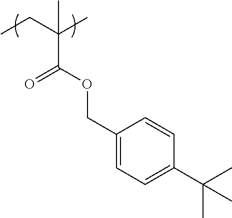

The repeating unit represented by Formula (II) is preferably a repeating unit that is stable against an acid (non-acid-decomposable). Specifically, a repeating unit having no group capable of decomposing by the action of an acid to generate a polar group is preferred.

Hereinafter, the repeating unit represented by Formula (III) will be described in detail.

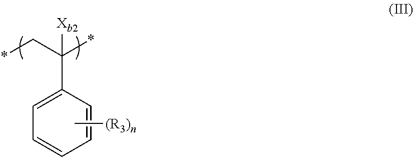

In Formula (III), X_{b2} represents a hydrogen atom, an alkyl group, a cyano group or a halogen atom, R₃ represents an organic group which is stable against an acid and has one or more CH₃ partial structures, and n represents an integer of 1 to 5.

The alkyl group of X_{b2} is preferably an alkyl group having 1 to 4 carbon atoms, and examples thereof may include a methyl group, an ethyl group, a propyl group, a hydroxymethyl group, a trifluoromethyl group or the like, but a hydrogen atom is preferred.

X_{b2} is preferably a hydrogen atom.

Since R₃ is an organic group which is stable against an acid, more specifically, R₃ is preferably an organic group which does not have “a group capable of decomposing by the action of an acid to generate a polar group” described in the resin (A).

Examples of R₃ may include an alkyl group having one or more CH₃ partial structures.

The organic group as R₃, which has one or more CH₃ partial structures and is stable against an acid, preferably has 1 to 10 CH₃ partial structures, more preferably 1 to 8 CH₃ partial structures, and still more preferably 1 to 4 CH₃ partial structures.

The alkyl group having one or more CH₃ partial structures in R₃ is preferably a branched alkyl group having 3 to 20 carbon atoms.

n represents an integer of 1 to 5, more preferably an integer of 1 to 3, and still more preferably 1 or 2.

Preferred specific examples of the repeating unit represented by Formula (III) will be described below, but the present invention is not limited thereto.

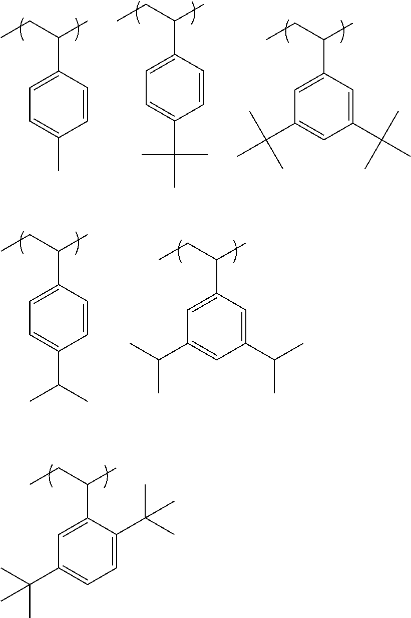

The repeating unit represented by Formula (III) is preferably a repeating unit that is stable against an acid (non-acid-decomposable), and specifically, is preferably a repeating unit having no group capable of decomposing by the action of an acid to generate a polar group.

When the resin (D) includes a CH₃ partial structure in the side chain moiety thereof and particularly has no fluorine atom and silicon atom, a content of at least one repeating unit (x) of the repeating unit represented by Formula (II) and the repeating unit represented by Formula (III) is preferably 90 mol % or more, and more preferably 95 mol % or more, based on all the repeating units of the resin (D). The content is usually 100 mol % or less based on all the repeating units of the resin (D).

The resin (D) contains at least one repeating unit (x) of the repeating unit represented by Formula (II) and the repeating unit represented by Formula (III) in an amount of 90 mol % or more based on all the repeating units of the resin (D), thereby increasing the surface free energy of the resin (D). As a result, it is difficult for the resin (D) to be unevenly distributed on the surface of the resist film, and thus the static/dynamic contact angle of the resist film against water may be certainly enhanced, thereby enhancing an immersion liquid follow-up property.

In addition, even when the hydrophobic resin (D) includes (i) a fluorine atom and/or a silicon atom and even when the hydrophobic resin (D) includes (ii) a CH₃ partial structure in the side chain moiety thereof, the hydrophobic resin (D) may have at least one group selected from the group consisting of following (x) to (z).

(x) an acid group,

(y) a group having a lactone structure, an acid anhydride group or an acid imide group, and

(z) a group capable of decomposing by the action of an acid

Examples of the acid group (x) may include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group and the like.

Preferred examples of the acid group include a fluorinated alcohol group (preferably hexafluoroisopropanol), a sulfonimide group and a bis(alkylcarbonyl)methylene group.

Examples of the repeating unit having the acid group (x) may include a repeating unit, in which the acid group is directly bonded to the main chain of the resin, such as repeating unit by an acrylic acid or a methacrylic acid, or a repeating unit in which the acid group is bonded to the main chain of the resin through a linking group or the like. Furthermore, the repeating unit may also be introduced into the terminal of the polymer chain by using a polymerization initiator or a chain transfer agent each having an acid group at the time of polymerization, and all of these cases are preferred. The repeating unit having the acid group (x) may have at least one of a fluorine atom and a silicon atom.

The content of the repeating unit having the acid group (x) is preferably 1 to 50 mol %, more preferably 3 to 35 mol %, and still more preferably 5 to 20 mol %, based on all the repeating units in the hydrophobic resin (D).

Specific examples of the repeating unit having the acid group (x) will be shown below, but the present invention is not limited thereto. In Formulas, Rₓ represents a hydrogen atom, CH₃, CF₃ or CH₂OH.

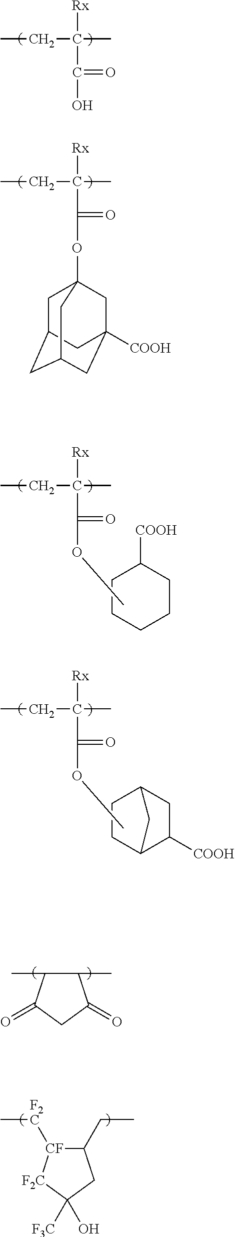

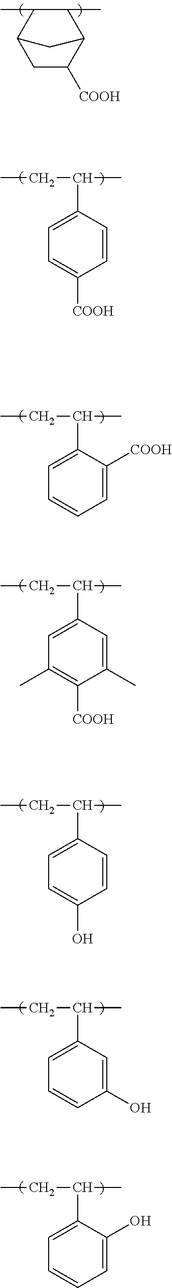

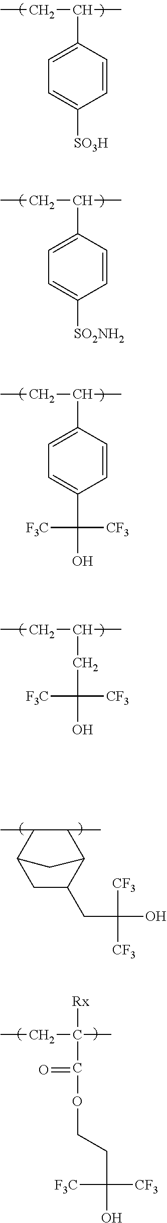

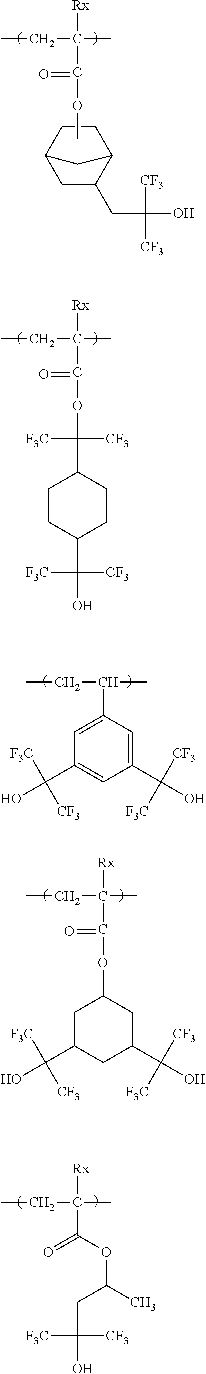

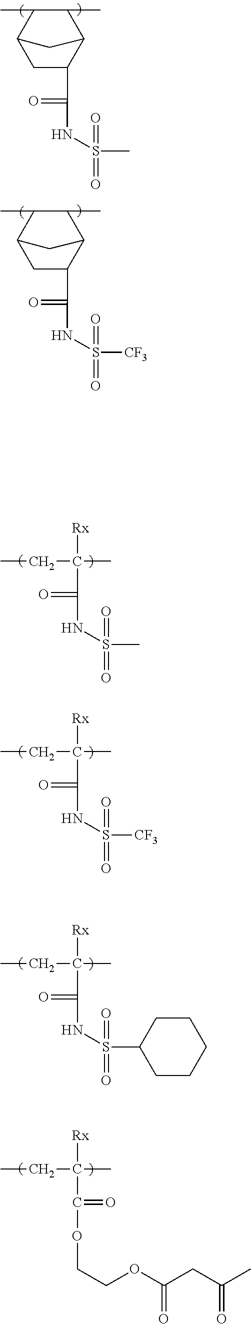

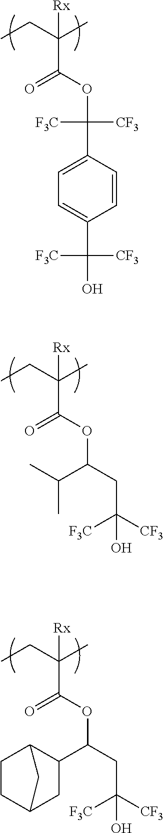

As (y) the group having a lactone structure, the acid anhydride group or the acid imide group, a group having a lactone structure is particularly preferred.

Examples of the repeating unit including these groups may include a repeating unit in which the group is directly bonded to the main chain of the resin, such as a repeating unit by an acrylate ester or a methacrylate ester. Or, the repeating unit may be a repeating unit in which the group is bonded to the main chain of the resin through a linking group. Or, the repeating unit may be introduced into the end of the resin by using a polymerization initiator or a chain transfer agent having the group at the time of polymerization.

Examples of the repeating unit having a group having a lactone structure are the same as those of the repeating unit having a lactone structure, which is previously described in the paragraph of the acid-decomposable resin (A). Also, the repeating unit disclosed in paragraph [0725] of U.S. Patent Application Publication No. 2012/0135348A1 may be suitably used. Preferred examples of the repeating unit having a group having a lactone structure may include the repeating units having a HR-66 to HR-80 as set forth in the following.

The content of the repeating unit having a group having a lactone structure, an acid anhydride group or an acid imide group is preferably 1 to 100 mol %, more preferably 3 to 98 mol %, and still more preferably 5 to 95 mol %, based on all the repeating units in the hydrophobic resin (D).

Examples of the repeating unit having (z) a group capable of decomposing by the action of an acid in the hydrophobic resin (D) are the same as those of the repeating unit having an acid-decomposable group, which is exemplified in the resin (A). The repeating unit having (z) a group capable of decomposing by the action of an acid may have at least one of a fluorine atom and a silicon atom. In the hydrophobic resin (D), the content of the repeating unit having (z) a group capable of decomposing by the action of an acid is preferably 1 to 80 mol %, more preferably 10 to 80 mol %, and still more preferably 20 to 60 mol %, based on all the repeating units in the resin (D).

The hydrophobic resin (D) may further have a repeating unit represented by the following Formula (III).

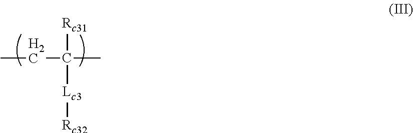

In Formula (III),

R_{c31} represents a hydrogen atom, an alkyl group (which may be substituted with a fluorine atom or the like), a cyano group or a —CH₂—O—Ra_{c2} group. In the formula, Rac₂ represents a hydrogen atom, an alkyl group or an acyl group. R_{c31} is preferably a hydrogen atom, a methyl group, a hydroxymethyl group and a trifluoromethyl group, and particularly preferably a hydrogen atom and a methyl group.

R_{c32} represents a group having an alkyl group, a cycloalkyl group, an alkenyl group, a cycloalkenyl group or an aryl group. These groups may be substituted with a group including a fluorine atom or a silicon atom.

L_{c3} represents a single bond or a divalent linking group.

In Formula (III), the alkyl group of R_{c32} is preferably a straight or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an ether bond, a phenylene group or an ester bond (a group represented by —COO—).

The content of the repeating unit represented by Formula (III) is preferably 1 to 100 mol %, more preferably 10 to 90 mol %, and still more preferably 30 to 70 mol %, based on all the repeating units in the hydrophobic resin.

It is also preferred that the hydrophobic resin (D) further has a repeating unit represented by the following Formula (CII-AB).

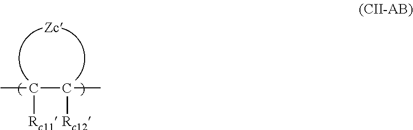

In Formula (CII-AB),

Each of R_{c11}′ and R_{c12}′ independently represents a hydrogen atom, a cyano group, a halogen atom or an alkyl group.

Z_{c}′ includes two carbon atoms (C—C) to which Z_{c}′ is bonded and represents an atomic group for forming an alicyclic structure.

The content of the repeating unit represented by Formula (CII-AB) is preferably 1 to 100 mol %, more preferably 10 to 90 mol %, and still more preferably 30 to 70 mol %, based on all the repeating units in the hydrophobic resin.

Hereinafter, specific examples of the repeating units represented by Formulas (III) and (CII-AB) will be described below, but the present invention is not limited thereto. In the formulas, Ra represents H, CH₃, CH₂OH, CF₃ or CN.

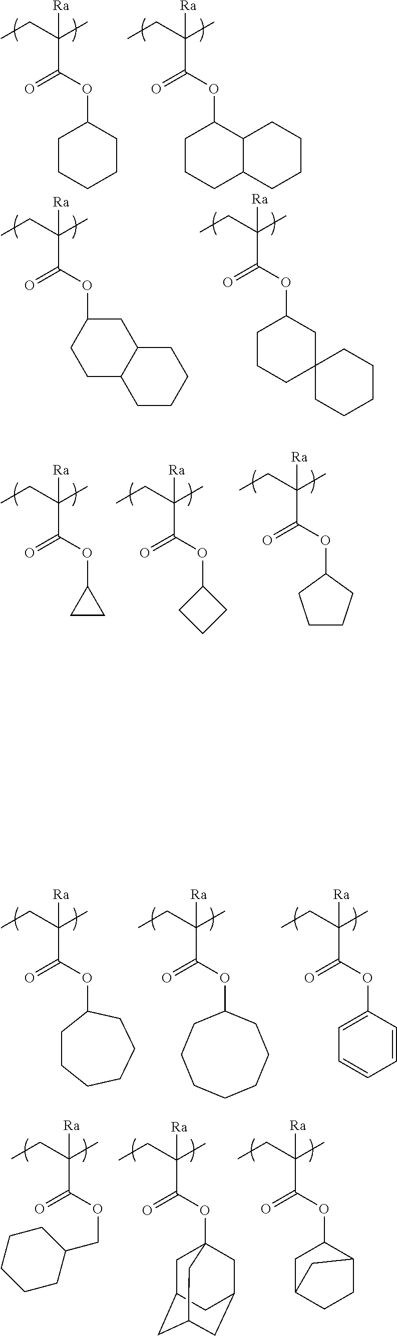

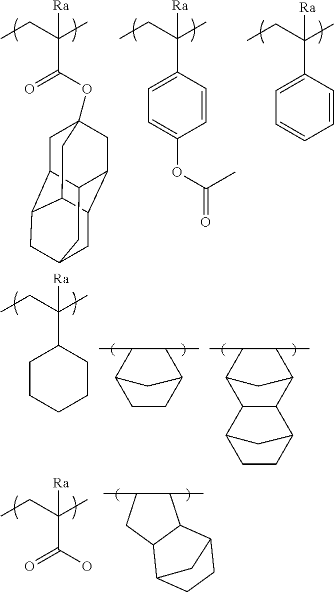

When the hydrophobic resin (D) has a fluorine atom, the content of the fluorine atom is preferably 5 to 80% by mass, and more preferably 10 to 80% by mass, based on the weight average molecular weight of the hydrophobic resin (D). Furthermore, the repeating unit including a fluorine atom is preferably 10 to 100 mol %, and more preferably 30 to 100 mol %, based on all the repeating units included in the hydrophobic resin (D).

When the hydrophobic resin (D) has a silicon atom, the content of the silicon atom is preferably from 2 to 50% by mass, and more preferably 2 to 30% by mass, based on the weight average molecular weight of the hydrophobic resin (D). Further, the repeating unit including a silicon atom is preferably 10 to 100 mol %, and more preferably 20 to 100 mol %, based on all the repeating units included in the hydrophobic resin (D).

Meanwhile, particularly when the resin (D) includes a CH₃ partial structure in the side chain moiety thereof, the form that the resin (D) contains substantially no fluorine atom and silicon atom is also preferred, and in this case, specifically, the content of the repeating unit having a fluorine atom or a silicon atom is preferably 5 mol % or less, more preferably 3 mol % or less, and still more preferably 1 mol % or less, based on all the repeating units in the resin (D), and is ideally 0 mol %, that is, containing no fluorine atom and silicon atom. In addition, it is preferred that the resin (D) is substantially composed of only a repeating unit composed of only an atom selected from a carbon atom, an oxygen atom, a hydrogen atom, a nitrogen atom and a sulfur atom. More specifically, the repeating unit composed only of an atom selected from a carbon atom, an oxygen atom, a hydrogen atom, a nitrogen atom and a sulfur atom is present in an amount of preferably 95 mol % or more, more preferably 97 mol % or more, still more preferably 99 mol % or more, and ideally 100 mol %, based on all the repeating units of the resin (D).

The weight average molecular weight of the hydrophobic resin (D) in terms of standard polystyrene in accordance with the GPC method is preferably 1,000 to 100,000, more preferably 1,000 to 50,000, and still more preferably 2,000 to 15,000.

Furthermore, the hydrophobic resin (D) may be used either alone or in combination of a plurality thereof.

The content of the hydrophobic resin (D) in the composition is preferably 0.01 to 10% by mass, more preferably from 0.05 to 8% by mass, and still more preferably from 0.1 to 7% by mass, based on the total solid content in the composition of the present invention.

In the hydrophobic resin (D), similarly to the resin (A), it is natural that the content of impurities such as metal is small, and the content of residual monomers or oligomer components is preferably 0.01 to 5% by mass, more preferably 0.01 to 3% by mass, and still more preferably 0.05 to 1% by mass. Accordingly, it is possible to obtain an actinic ray-sensitive or radiation-sensitive resin composition free from extraneous substances in liquid and change in sensitivity and the like with time. Further, from the viewpoint of resolution, resist shape, side wall of resist pattern, roughness and the like, the molecular weight distribution (Mw/Mn, also referred to as polydispersity) is in a range of preferably 1 to 5, more preferably 1 to 3, and still more preferably 1 to 2.

As for the resin (D), various commercially available products may be used, and the resin (D) may be synthesized by a conventional method (for example, radical polymerization). Examples of a general synthesis method include a batch polymerization method of dissolving monomer species and an initiator in a solvent and heating the solution, thereby performing the polymerization, a dropping polymerization method of adding dropwise a solution containing monomer species and an initiator to a heated solvent over 1 to 10 hours, and the like, and a dropping polymerization method is preferred.

The reaction solvent, polymerization initiator, reaction conditions (temperature, concentration and the like) and purification method after reaction are the same as those described in the resin (A), but in the synthesis of the hydrophobic resin (D), the reaction concentration is preferably 30 to 50% by mass.

Hereinafter, specific examples of the hydrophobic resin (D) will be shown. In addition, the molar ratio (corresponding to each repeating unit sequentially from the left), the weight average molecular weight and the polydispersity of the repeating unit in each resin are shown in the following Tables.

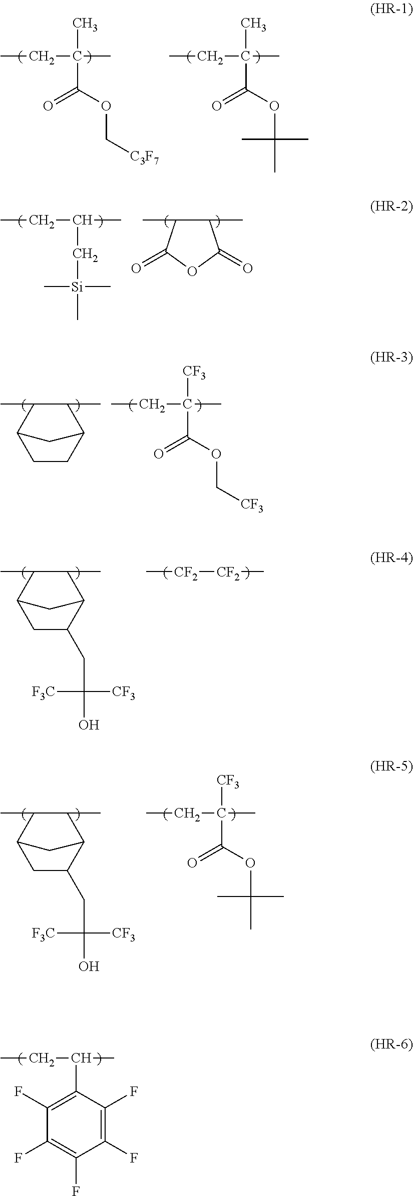

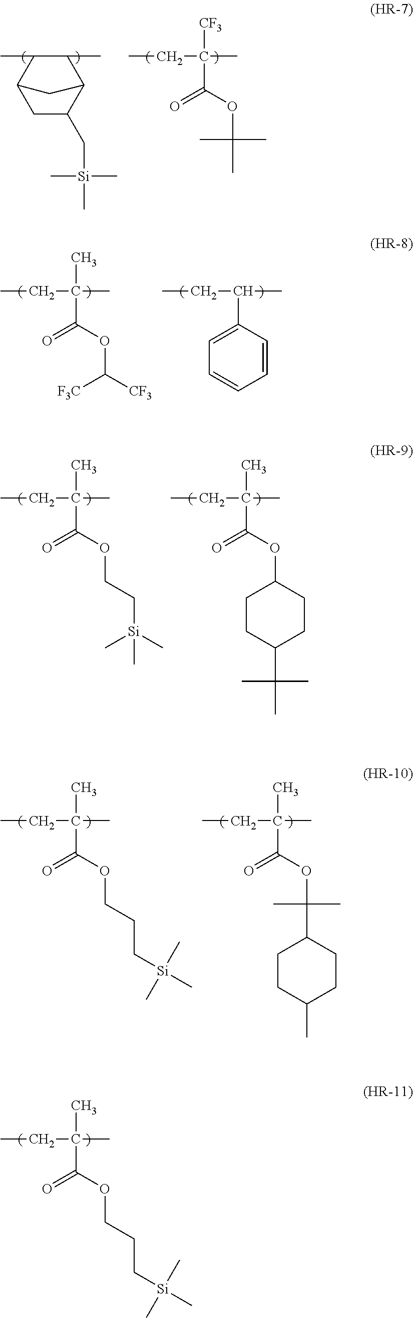

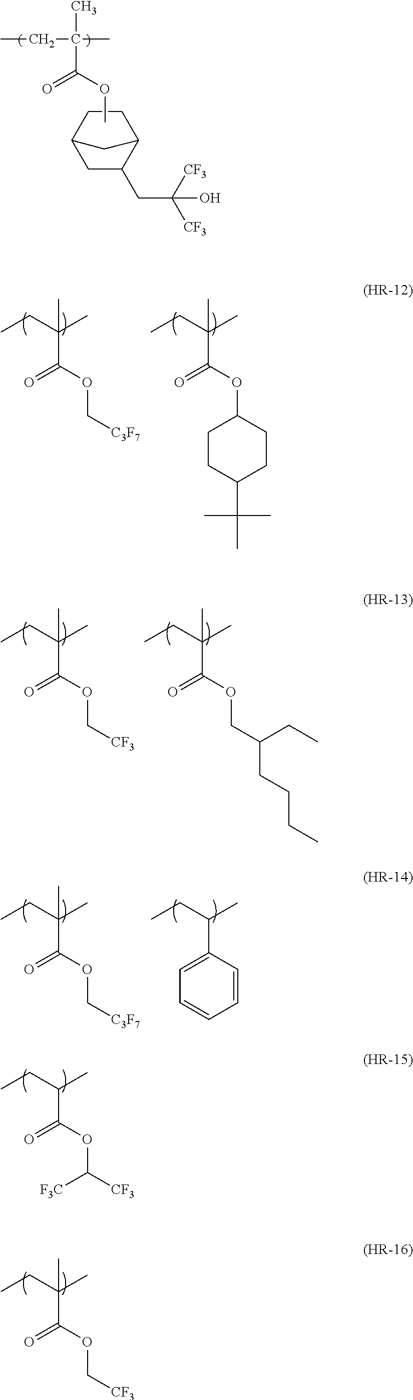

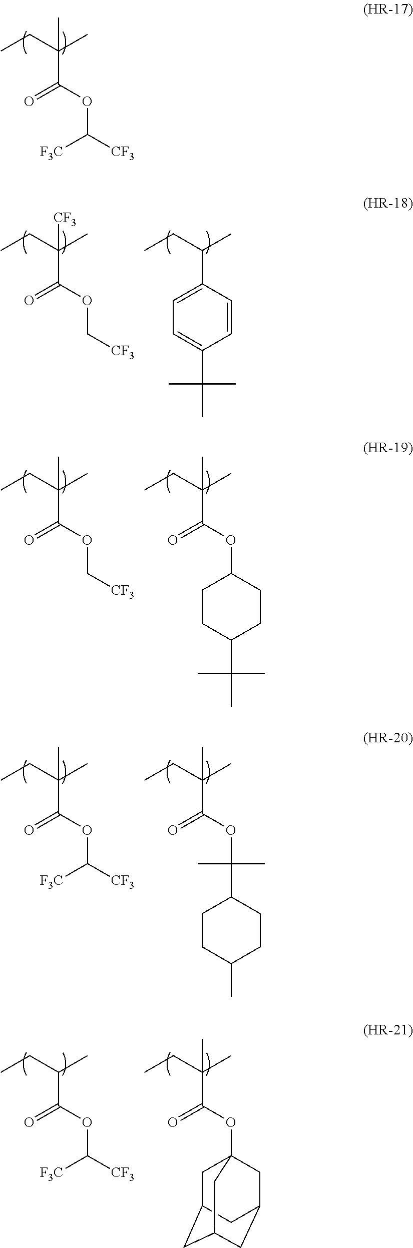

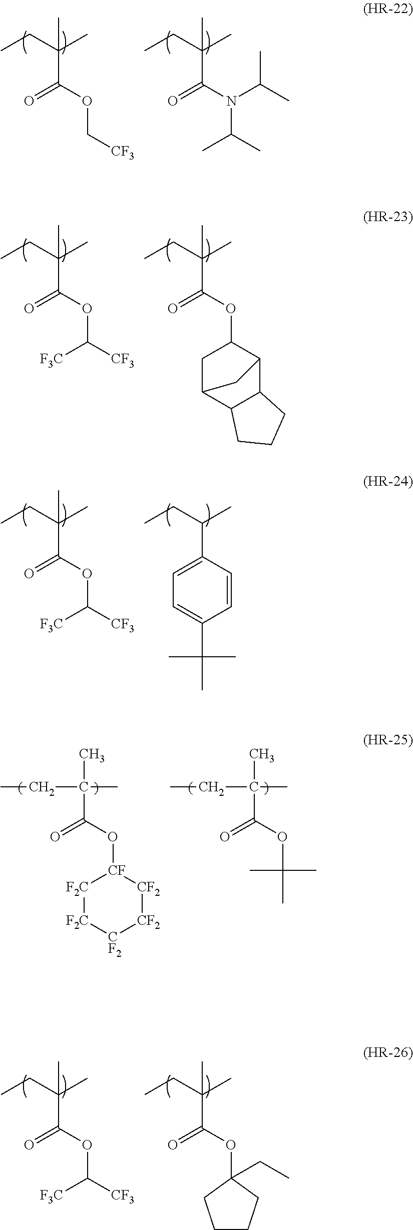

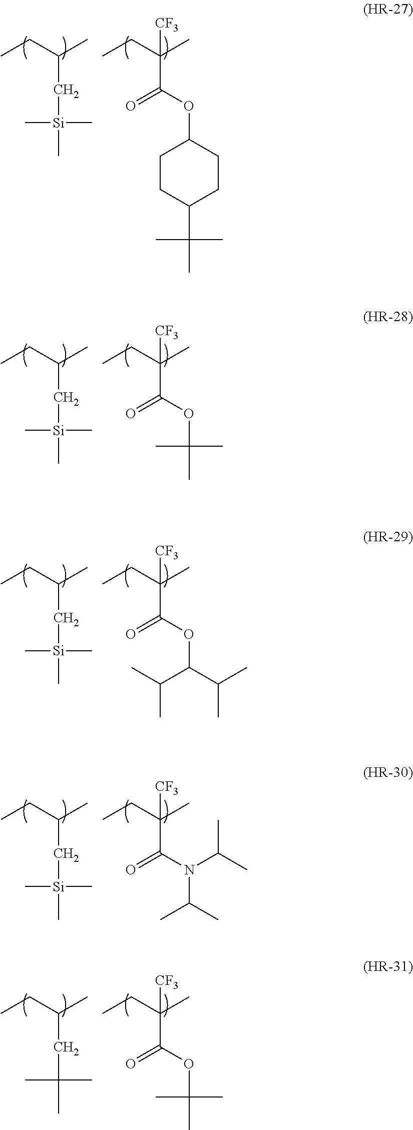

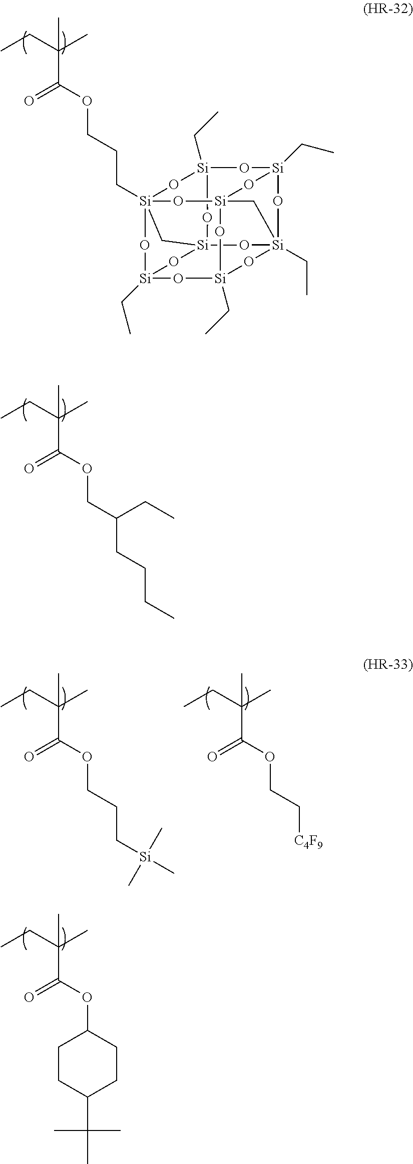

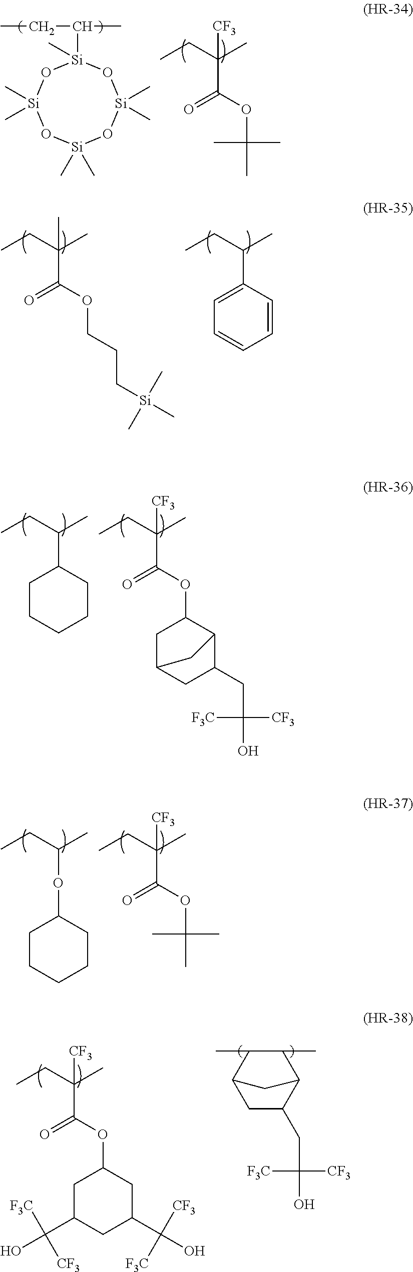

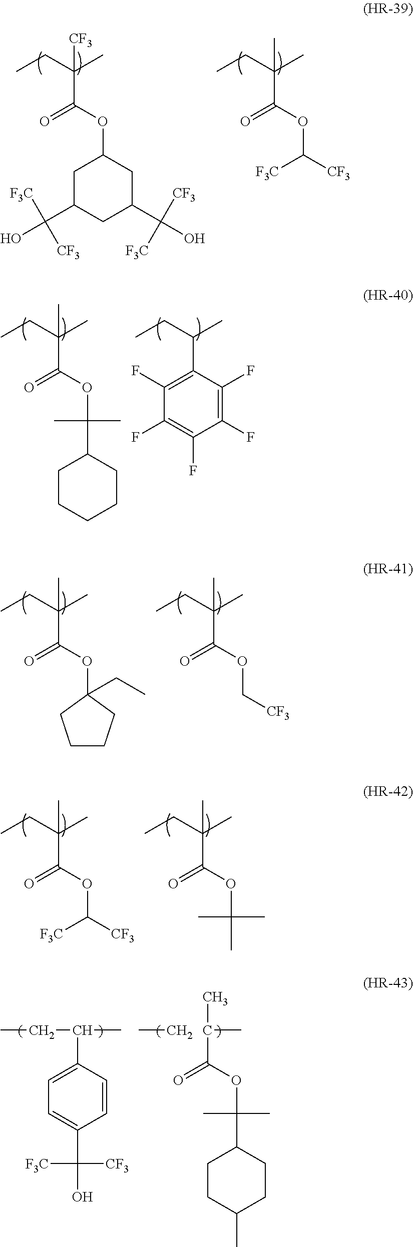

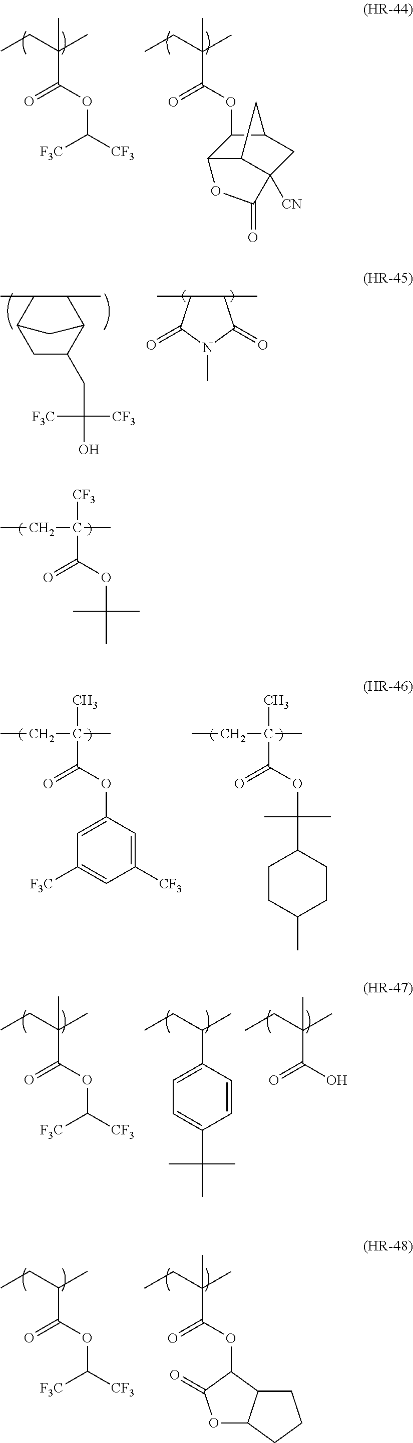

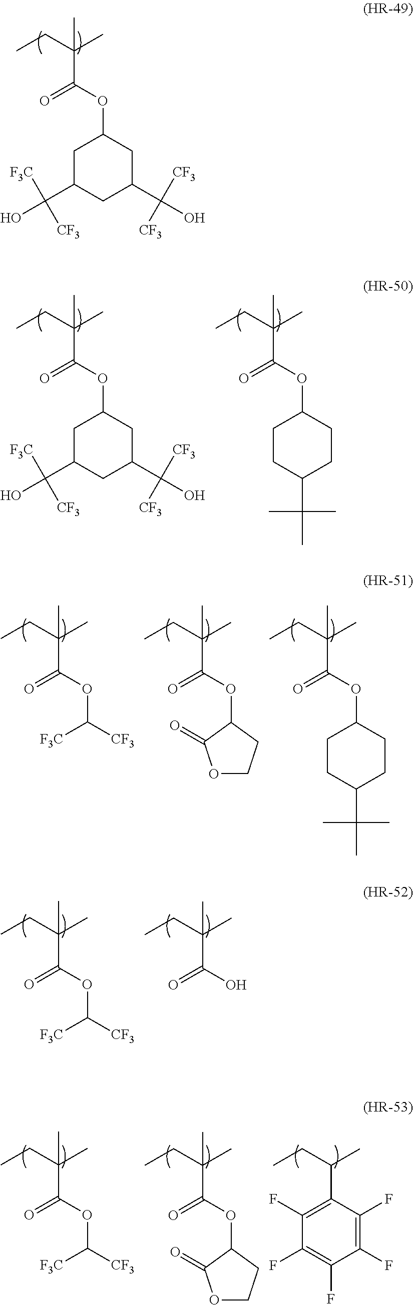

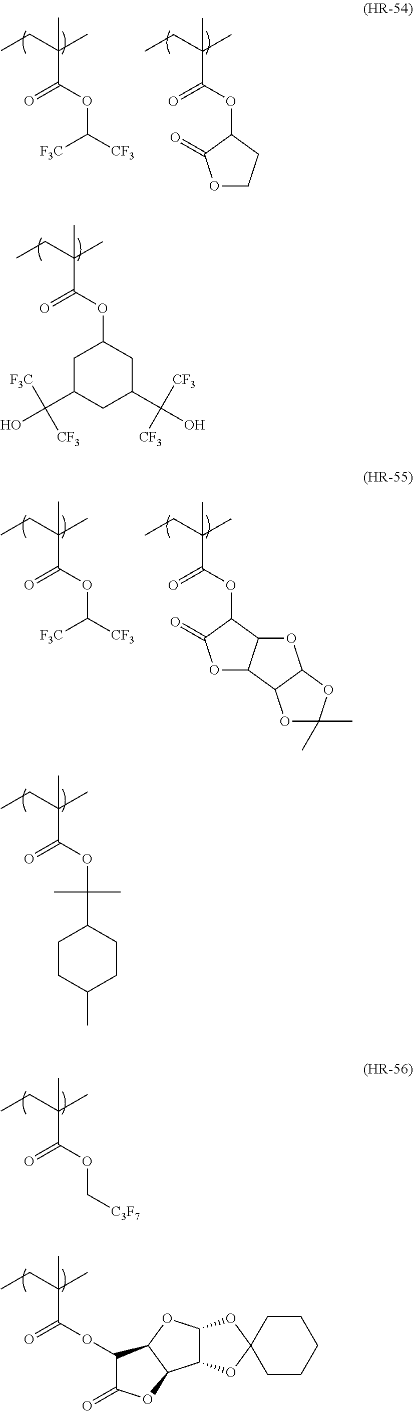

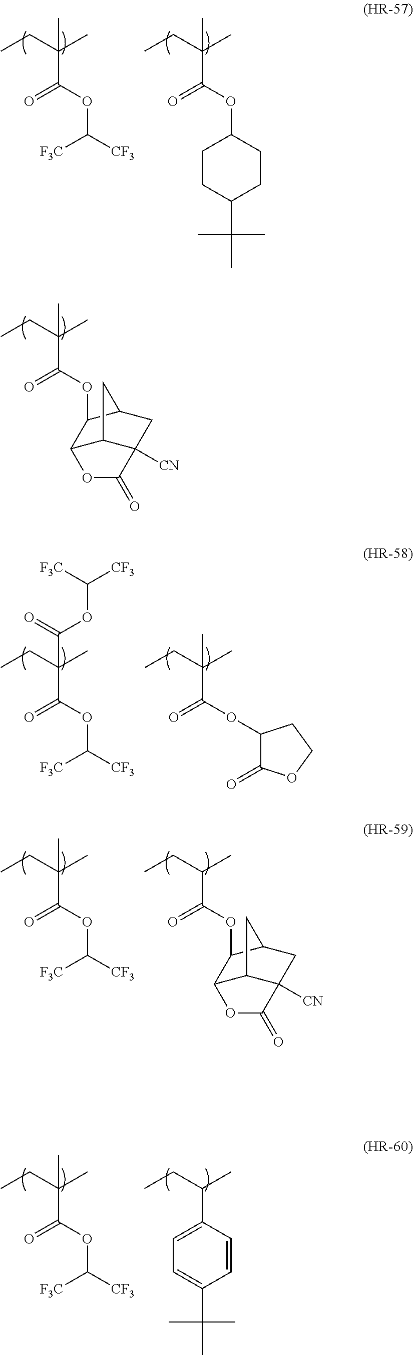

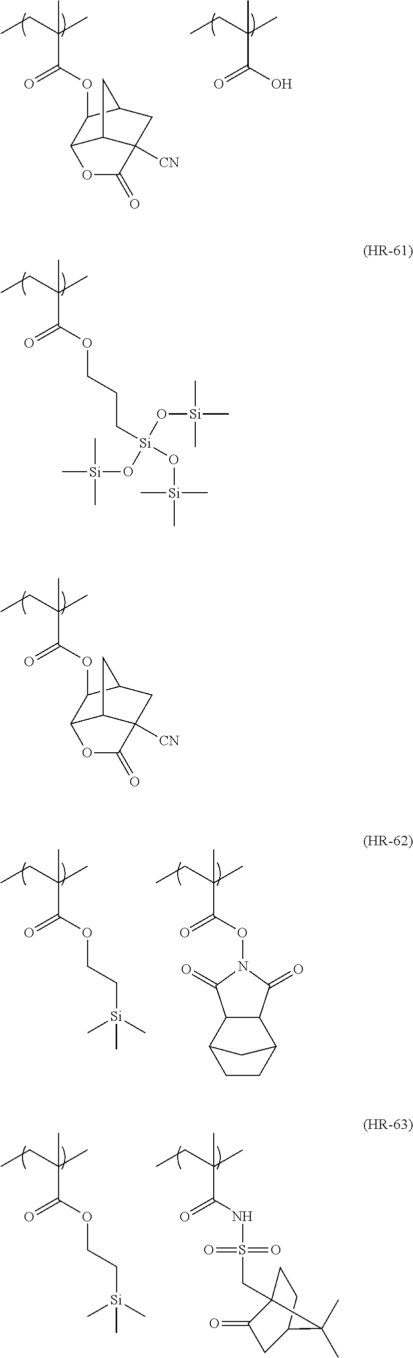

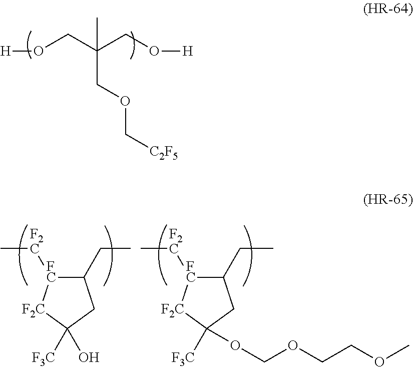

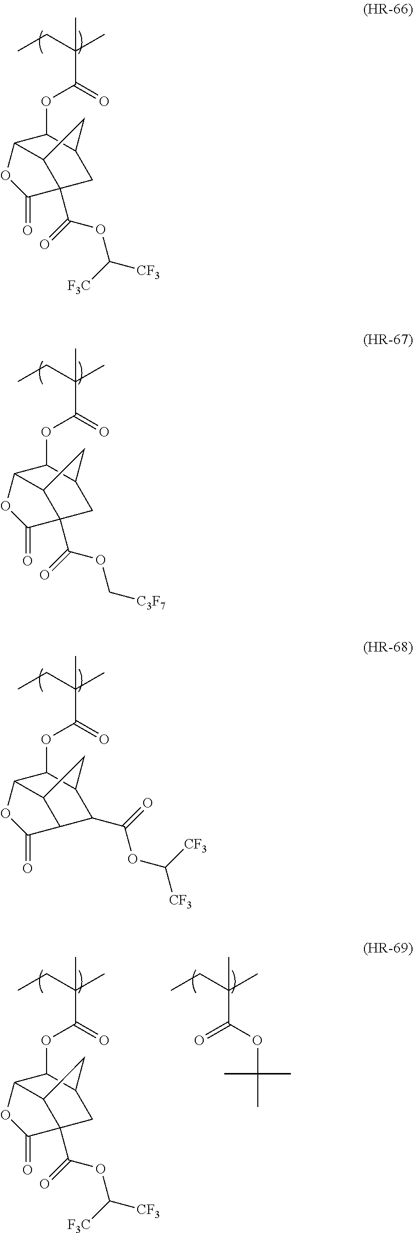

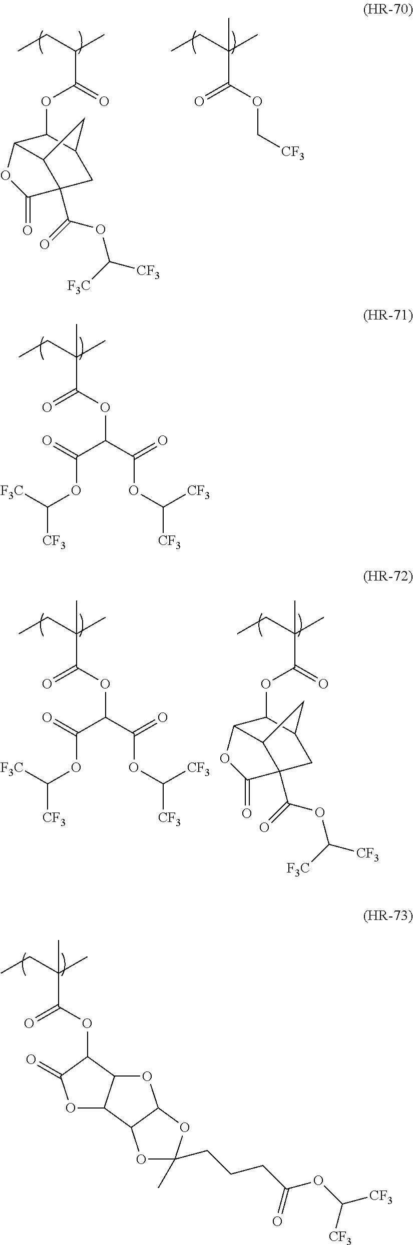

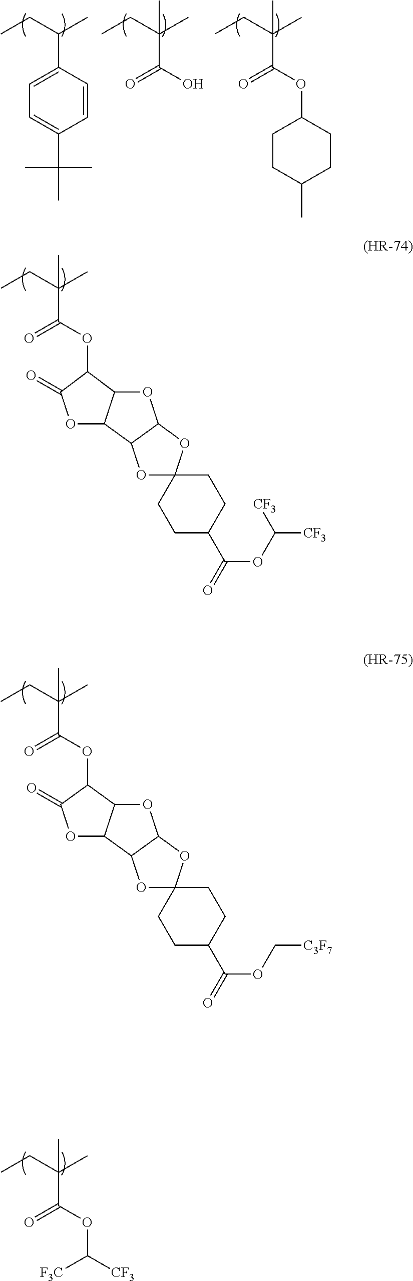

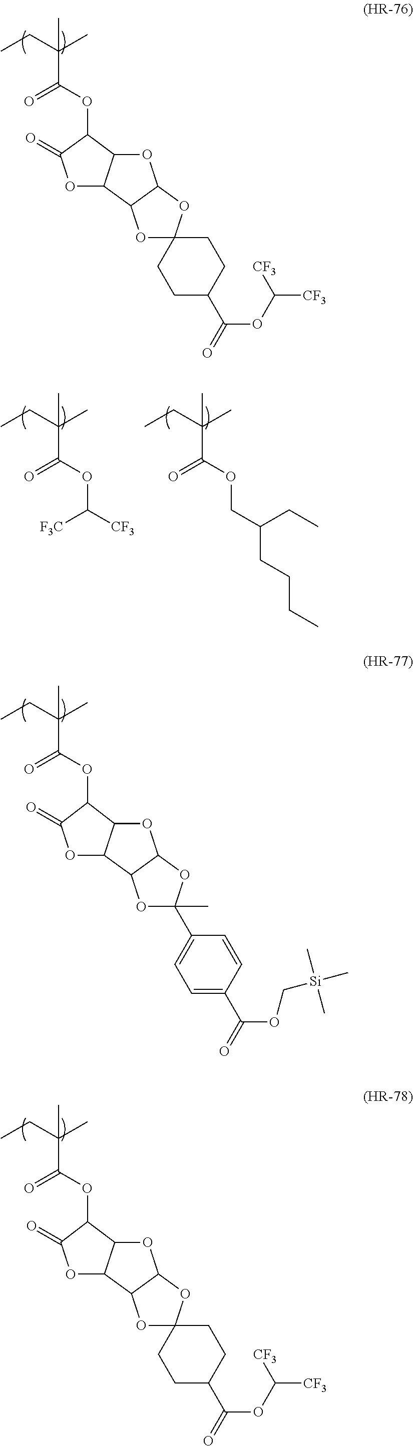

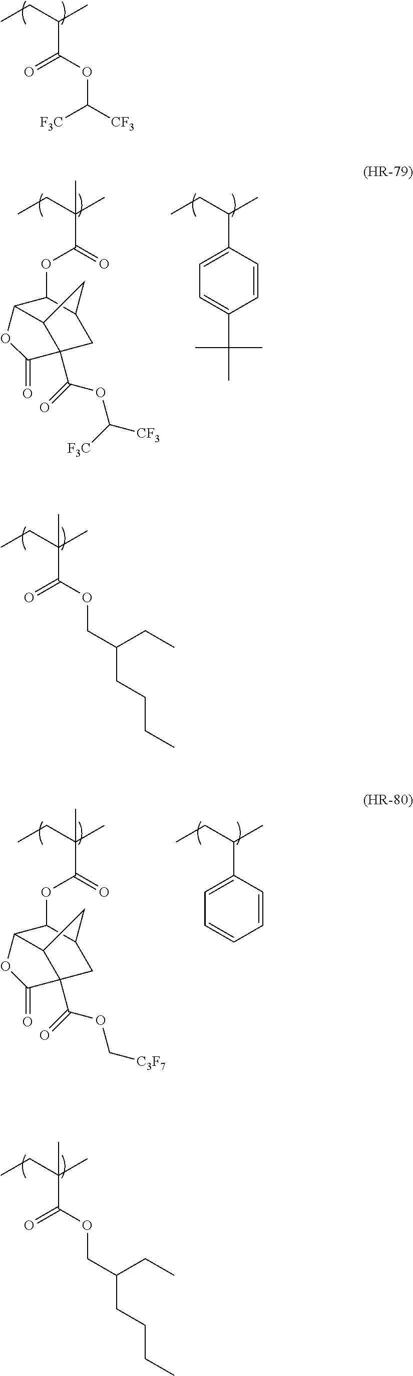

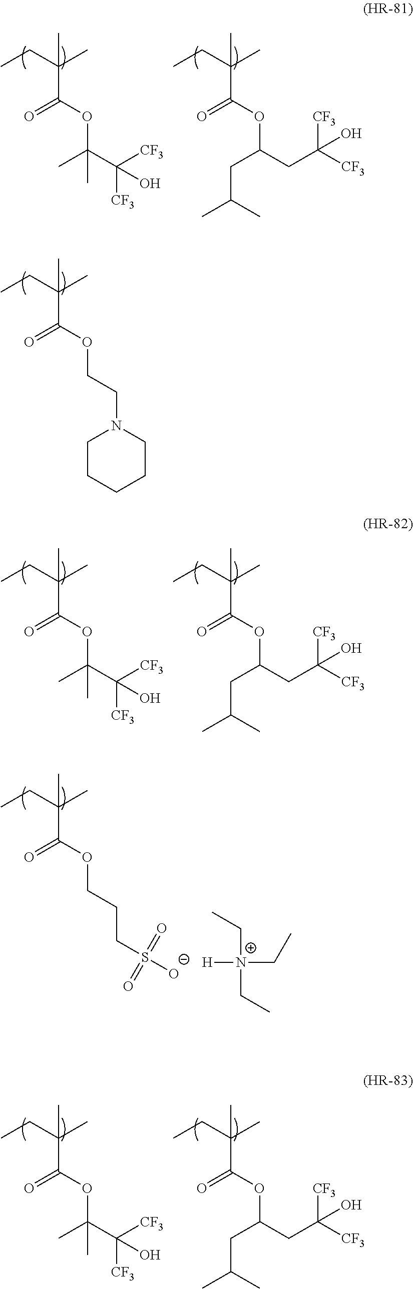

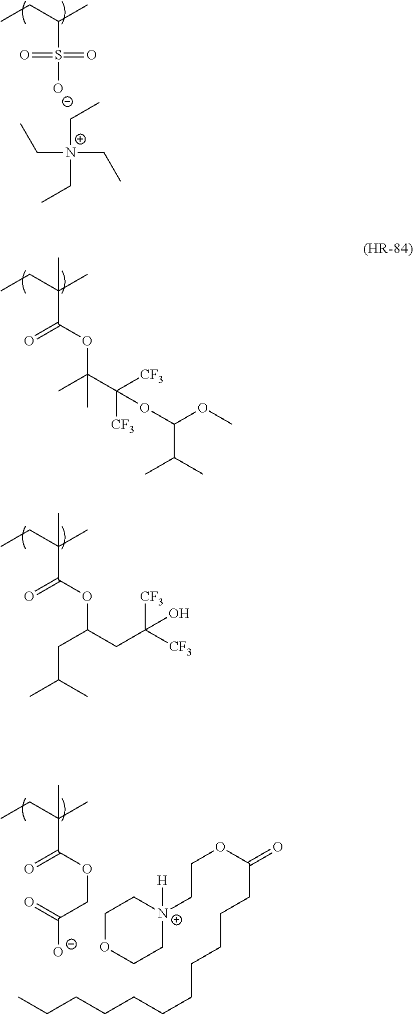

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 2

| Resin | Composition | Mw | Mw/Mn |
|---|---|---|---|
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |

TABLE 3

| Resin | Composition | Mw | Mw/Mn |
|---|---|---|---|
| HR-81 | 35/60/5 | 8600 | 1.99 |
| HR-82 | 35/60/5 | 8700 | 1.71 |
| HR-83 | 35/60/5 | 8100 | 1.81 |
| HR-84 | 35/60/5 | 8900 | 1.89 |

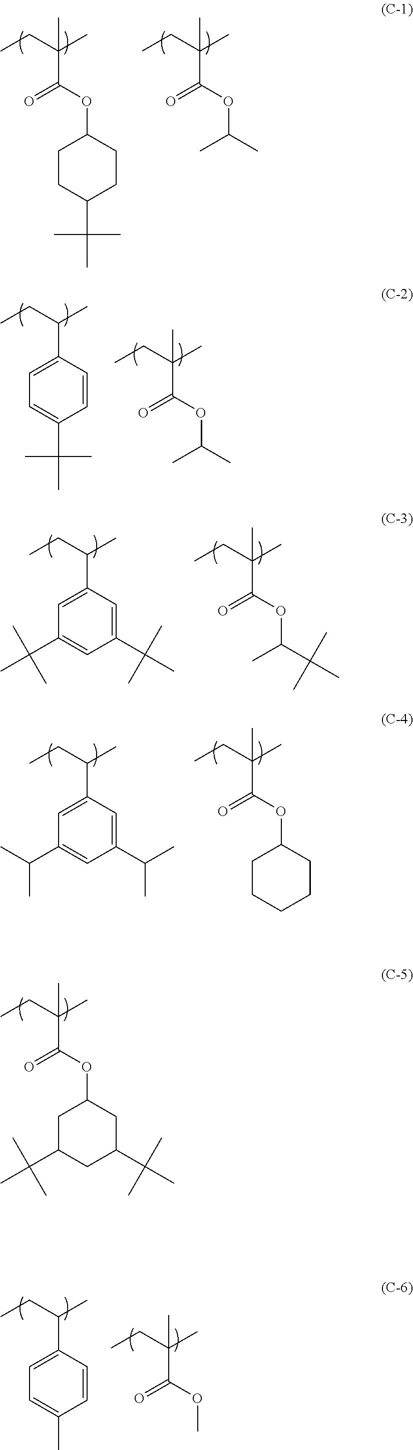

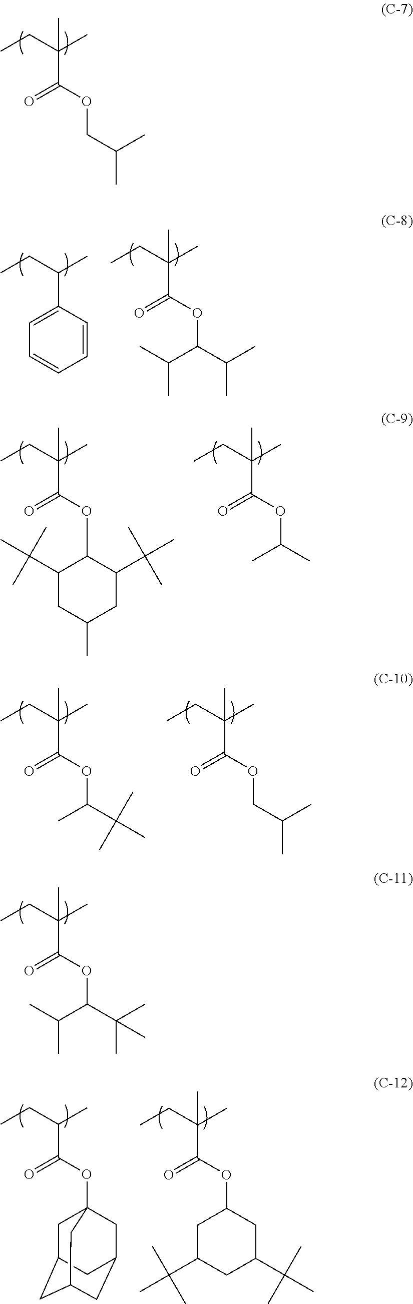

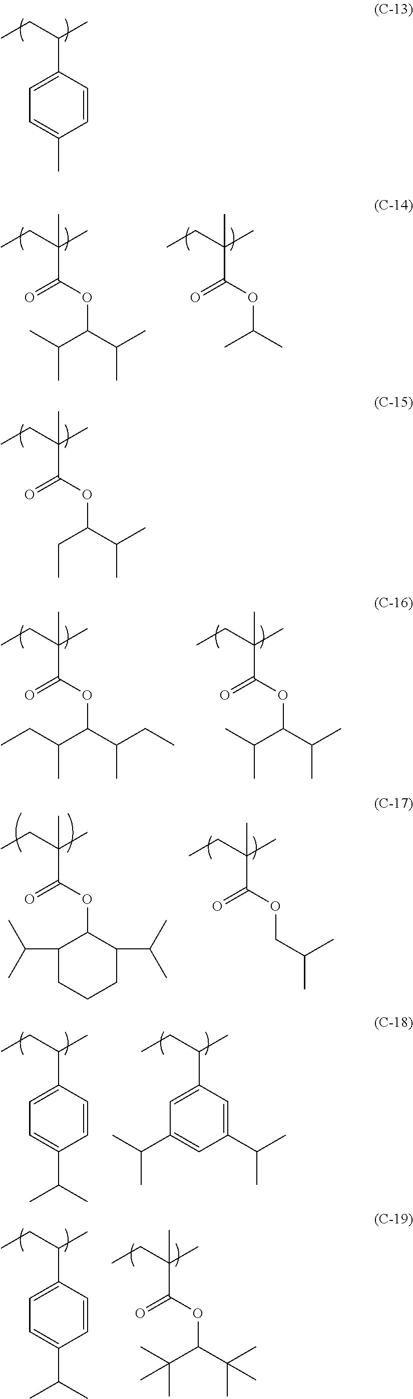

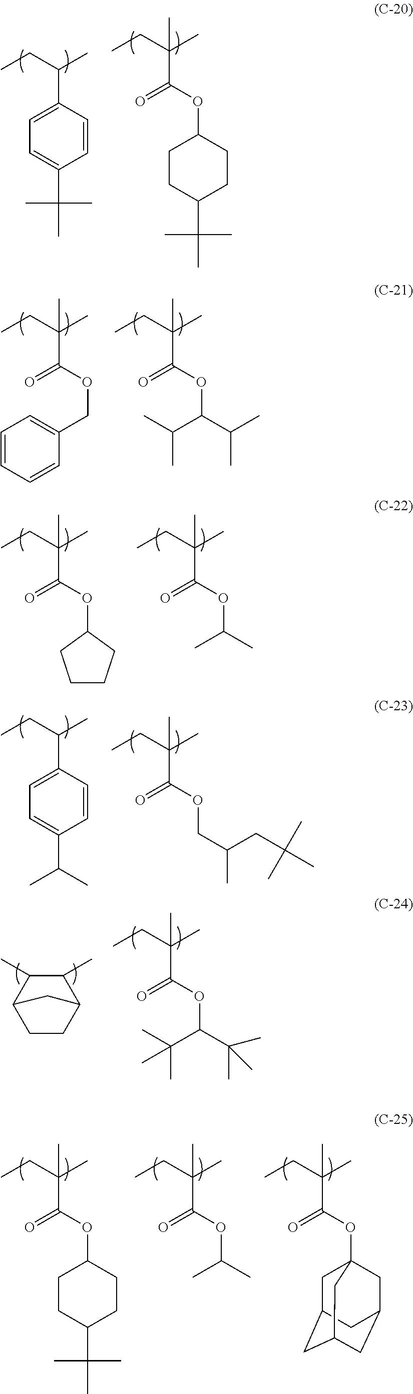

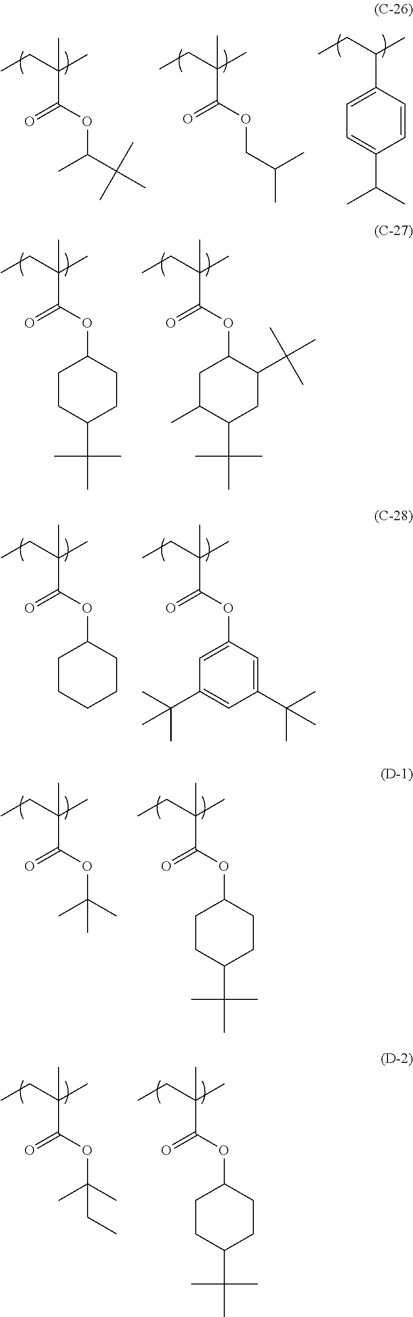

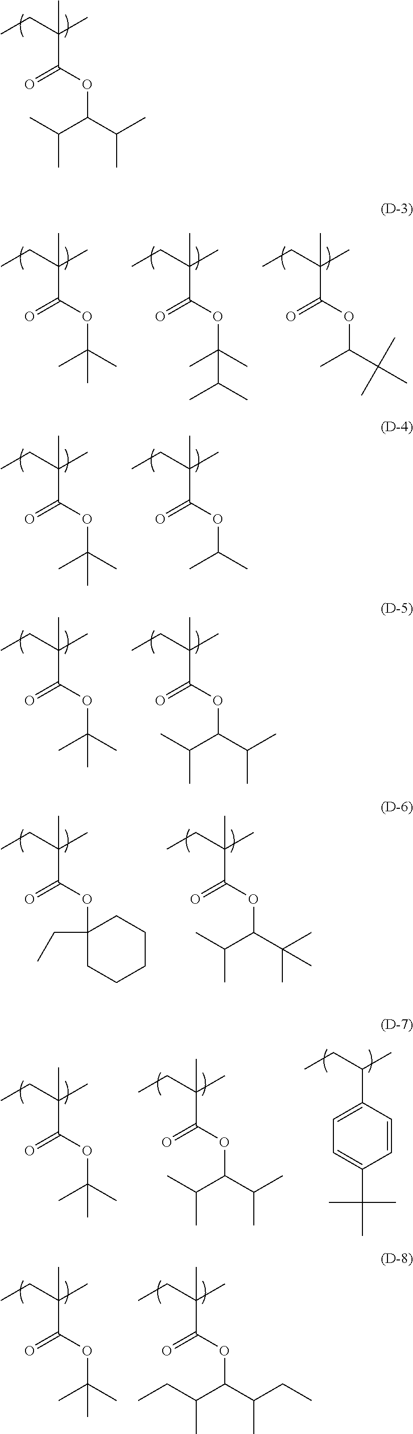

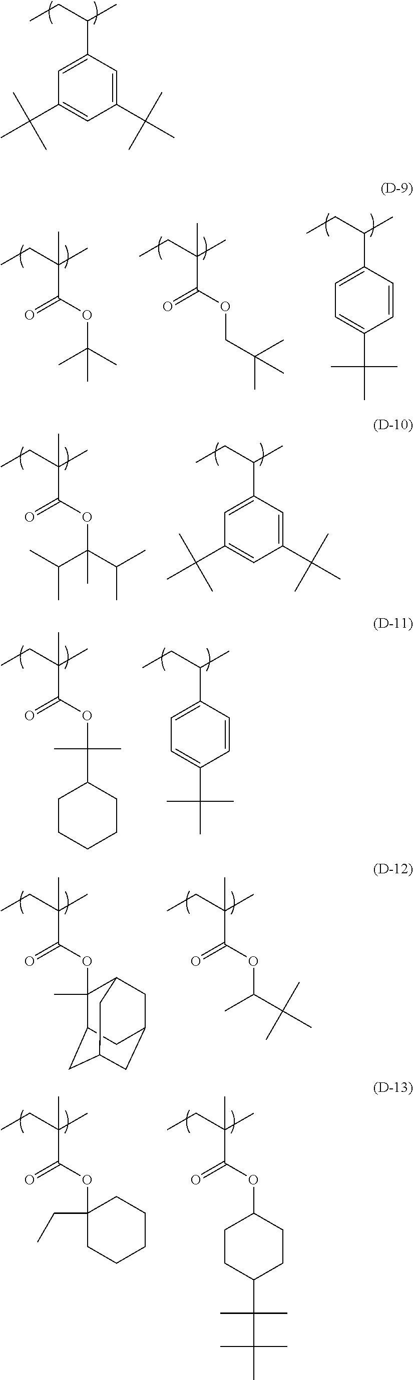

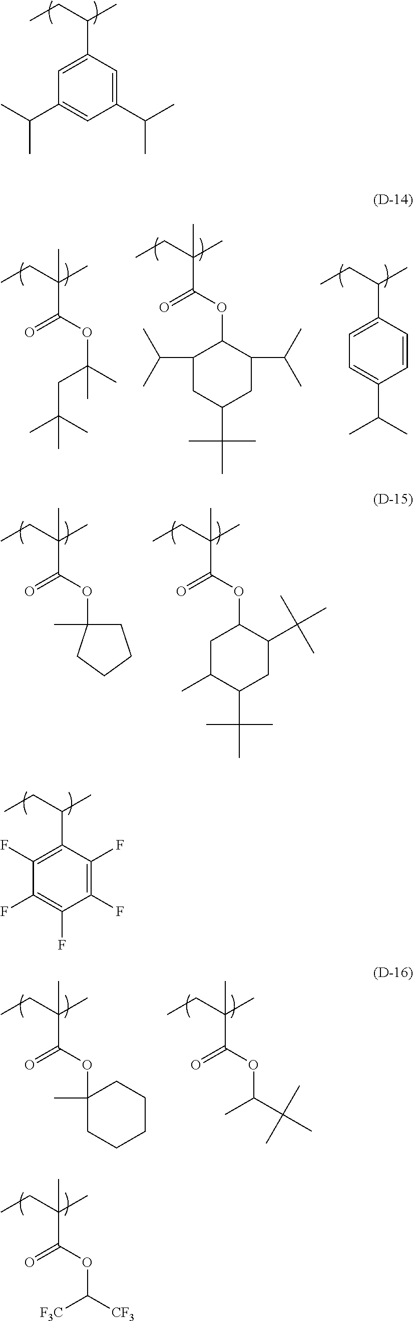

TABLE 4

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 5

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5-1] (N) Basic Compound

The actinic ray-sensitive or radiation-sensitive resin composition of the present invention may contain a basis compound in order to reduce the change in performance with time from exposure to heating.

Preferred examples of the basic compound may include compounds having a structure represented by the following Formulas (A) to (E).

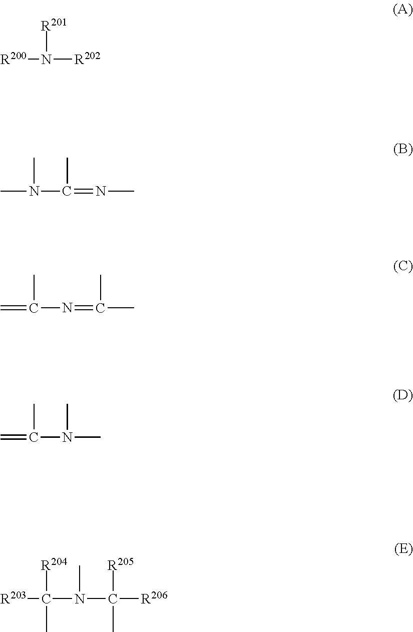

In Formulas (A) and (E), Each of R²⁰⁰, R²⁰¹ and R²⁰² may be same or different and represent a hydrogen atom, an alkyl group (preferably having 1 to 20 carbon atoms), a cycloalkyl group (preferably having 3 to 20 carbon atoms) or an aryl group (having 6 to 20 carbon atoms). Here, R²⁰¹ and R²⁰² may combine with each other to form a ring. R²⁰³, R²⁰⁴, R²⁰⁵ and R²⁰⁶ are same or different and represent an alkyl group having 1 to 20 carbon atoms.

The alkyl group may have a substituent and the alkyl group having a substituent is preferably an aminoalkyl group having 1 to 20 carbon atoms, a hydroxyalkyl group having 1 to 20 carbon atoms or a cyanoalkyl group having 1 to 20 carbon atoms.

The alkyl group in Formulas (A) and (E) is more preferably unsubstituted.

Preferred compounds may include guanidine, aminopyrrolidine, pyrazole, pyrazoline, piperazine, aminomorpholine, aminoalkylmorpholine, piperidine and the like. More preferred compounds may include compounds having an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond, aniline derivatives having a hydroxyl group and/or an ethere bond, and the like.

Examples of the compound having an imidazole structure may include imidazole, 2,4,5-triphenyl imidazole, benzimidazole, 2-phenylbenzimidazole and the like. Examples of the compound having a diazabicyclo structure may include 1,4-diazabicyclo[2,2,2]octane, 1,5-diazabicyclo[4,3,0]nona-5-ene, 1,8-diazabicyclo[5,4,0]undec-7-ene and the like. Examples of the compound having an onium hydroxide structure may include triaryl sulfonium hydroxide, phenacylsulfonium hydroxide, a sulfonium hydroxide having a 2-oxoalkyl group, specifically, triphenyl sulfonium hydroxide, tris(t-butylphenyl)sulfonium hydroxide, bis(t-butyiphenyl) iodonium hydroxide, phenacyl thiophenium hydroxide, 2-oxopropyl thiophenium hydroxide, and the like. Examples of the compound having an onium carboxylate structure include a compound in which the onium moiety of a compound having an onium hydorxide structure has been converted into a carboxylate, such as acetate, adamantane-1-carboxylate and perfluoroalkyl carboxylate. Examples of the compound having a trialkylamine structure may include tri(n-butyl)amine, tri(n-octyl) amine and the like. Examples of the compound having an aniline structure may include 2,6-diisopropylaniline, N,N-dimethylaniline, N,N-dibutyl aniline, N,N-dihexyl aniline and the like. Examples of the alkylamine derivative having a hydroxyl group and/or an ether bond may include ethanolamine, diethanolamine, triethanolamine, tris(methoxyethoxyethyl)amine and the like. Examples of the aniline derivative having a hydroxyl group and/or an ether bond may include N, N-bis (hydroxyethyl) aniline and the like.

Preferred basic compounds may further include an amine compound having a phenoxy group, an ammonium salt compound having a phenoxy group, an amine compound having a sulfonic ester group and an ammonium salt compound having a sulfonate ester group. Examples of these compounds may include the compounds (C1-1) to (C3-3) illustrated in [0066] of the specification of U.S. Patent Application Publication 2007/0224539 A1.

Also, the following compounds are also preferred as the basic compound.

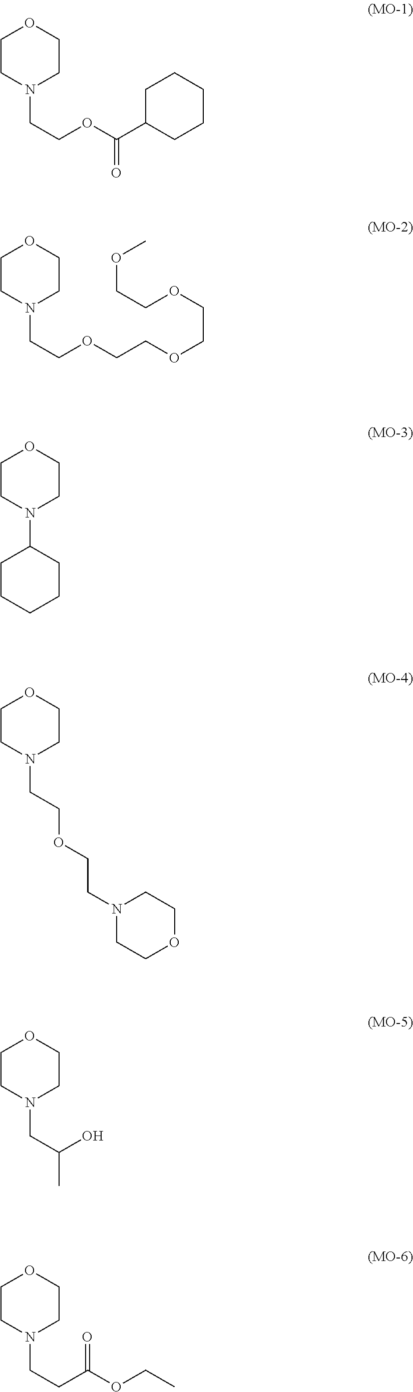

As the basic compound, in addition to the above-mentioned compounds, the compound described in [0180] to [0225] of Japanese Patent Application Laid-open No. 2011-22560, [0218] to [0219] of Japanese Patent Application Laid-open No. 2012-137735 and [0416] to [0438] of International Publication WO2011/158687A1.

The compounds of the present invention may include an onium salt represented by the following Formula (6A) or (6B) as a basic compound. The onium salt is expected to control the diffusion of the generated acid in relation to the acid strength of the photo-acid generating agent commonly used in the resist composition.

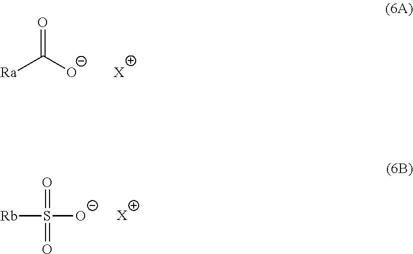

In Formula (6A),

Ra represents an organic group, but, the group in which a fluorine atom is substituted to the carbon atom directly bonded to the carboxylic acid group in the formula is excluded.

X⁺ represents an onium cation.

In Formula (6B),

Rb represents an organic group, but, the group in which fluorine atom is substituted to the carbon atom directly bonded to the sulfonic acid groups in the formula is excluded.

X⁺ represents an onium cation.

The organic groups represented by Ra and Rb are preferably those in which atoms directly bonded to a carboxylic acid group or a sulfonic acid group in the formula is a carbon atom. However, in this case, in order to make a relatively weaker acid than the acid generated from the abovementioned photoacid generator, a fluorine atom is not be substituted on the carbon atom bonded directly to a sulfonic acid group or a carboxylic acid group.

Examples of the organic group represented by Ra and Rb may include an alkyl group having 1 to 20 carbon atoms, a cycloalkyl group having 3 to 20 carbon atoms, an aryl group having 6 to 30 carbon atoms, an aralkyl group having 7 to 30 carbon atoms or a heterocyclic group having a carbon number of 3 to 30, and the like. In these groups, some or all of hydrogen atoms may be substituted.

The substituent which the alkyl group, the cycloalkyl group, the aryl group, the aralkyl group and the heterocyclic group may have include, for example, a hydroxyl group, a halogen atom, an alkoxy group, a lactone group, an alkylcarbonyl group and the like.

Examples of the onium cation represented by X⁺ in Formulas (6A) and (6B) may include a sulfonium cation, an ammonium cation, an iodonium cation, a phosphonium cation, a diazonium cation and the like. Among them, a sulfonium cation is more preferred.

Examples of the sulfonium cation may include preferably an aryl sulfonium cation having at least one aryl group, and more preferably a triaryl sulfonium cation. The aryl group may have a substituent. The aryl group is preferably a phenyl group.

Examples of the sulfonium cation and iodonium cation may include preferably a sulfonium cation structure site in the compounds (ZI-1), (ZI-2), (ZI-3) and (ZI-4) as the above-described compound (B).

The specific structure of the onium salt represented by Formula (6A) or (6B) is shown below.

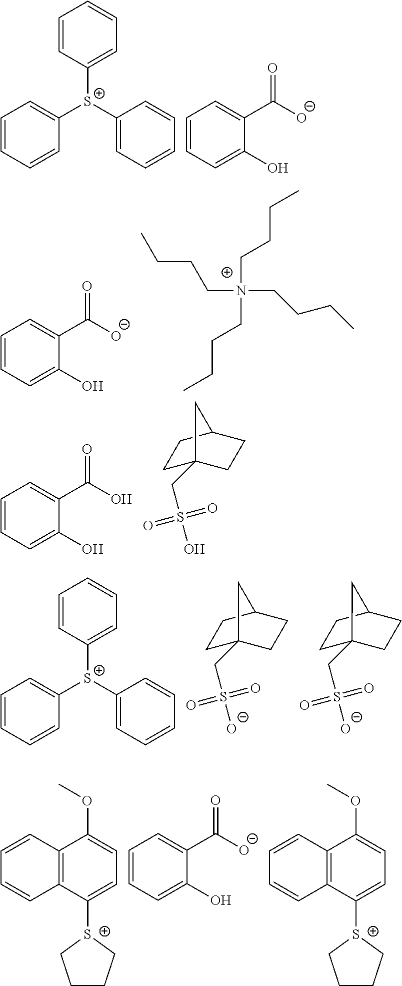

In addition, the chemically amplified resist composition of the present invention may also preferably use a compound having both an onium salt structure and an acid anion structure in one molecule (hereinafter, referred to as betaine compound), such as compounds included in Formula (I) of Japanese Patent Laid-open No. 2012-189977, compounds represented by Formula (I) of Japanese Patent Laid-open No. 2013-6827, compounds represented by Formula (I) of Japanese Patent Laid-open No. 2013-8020, and compounds represented by Formula (I) of Japanese Patent Laid-open No. 2012-252124. The onium salt structure includes sulfonium, iodonium, or ammonium structures, and preferably a sulfonium or iodonium salt structure. Further, the acid anion structure is preferably a sulfonate anion or a carboxylate anion. Example of the compounds may be exemplified below.

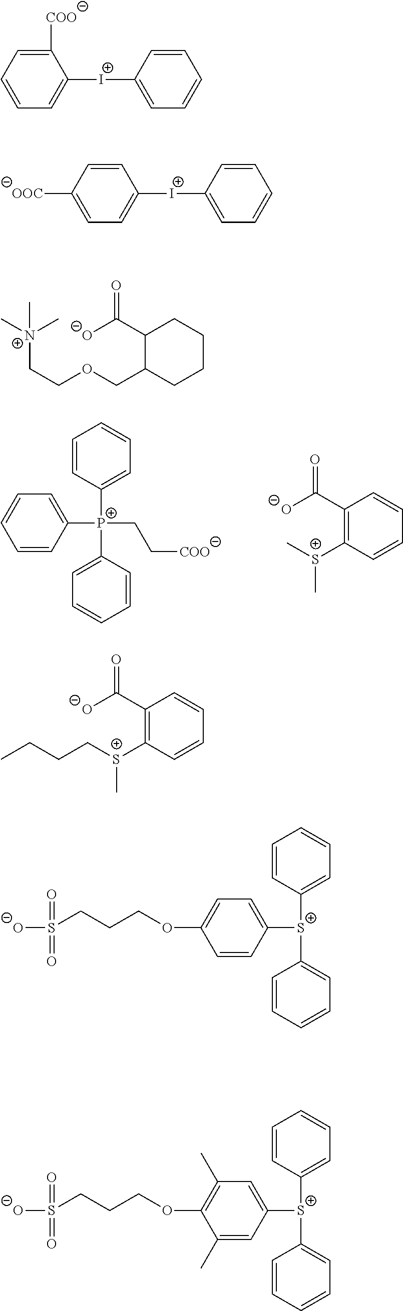

These basic compounds may be used either alone or in combination of two or more thereof.

The compositions of the present invention may or may not contain a basic compound. However, in the case of containing the basic compound, the content of the basic compounds is usually 0.001 to 10% by mass and preferably 0.01 to 5% by mass, based on the solid content of the actinic ray-sensitive or radiation-sensitive resin composition.

The ratio of the acid generator to the basic compound is preferably acid generator/basic compound (molar ratio)=2.5 to 300. In other words, the molar ratio is preferably 2.5 or more from the viewpoint of the sensitivity and resolution. The molar ratio is preferably 300 or less from the viewpoint of suppressing the reduction in resolution due to thickening of the resist pattern with time after exposure until heat treatment. The acid generator/basic compound (molar ratio) is more preferably 5.0 to 200 and more preferably 7.0 to 150.

[5-2] Compound (N′) having a basic functional group or an ammonium group, and a group capable of generating an acidic functional group upon irradiation with actinic ray or radiation

The actinic ray-sensitive or radiation-sensitive resin composition of the present invention may contains a compound (N′) having a basic functional group or an ammonium group, and a group capable of generating an acidic functional group upon irradiation with actinic ray or radiation. The compound (N′) is preferably a compound (N′-1) having typically a basic functional group or an ammonium group containing a nitrogen atom, and a group capable of generating an acidic functional group upon irradiation with actinic ray or radiation as described in Japanese Patent Application Laid-open Nos. 2006-330098 and 2011-100105. That is, the compound (N′) is a basic compound having a group capable of generating an acidic functional group upon irradiation with functional group and an active ray or radiation, or an ammonium salt compound having an ammonium group and an acidic functional group upon irradiation of an active ray or radiation.

Specific examples of the compound (N′) are shown below, but the present invention is not limited thereto.

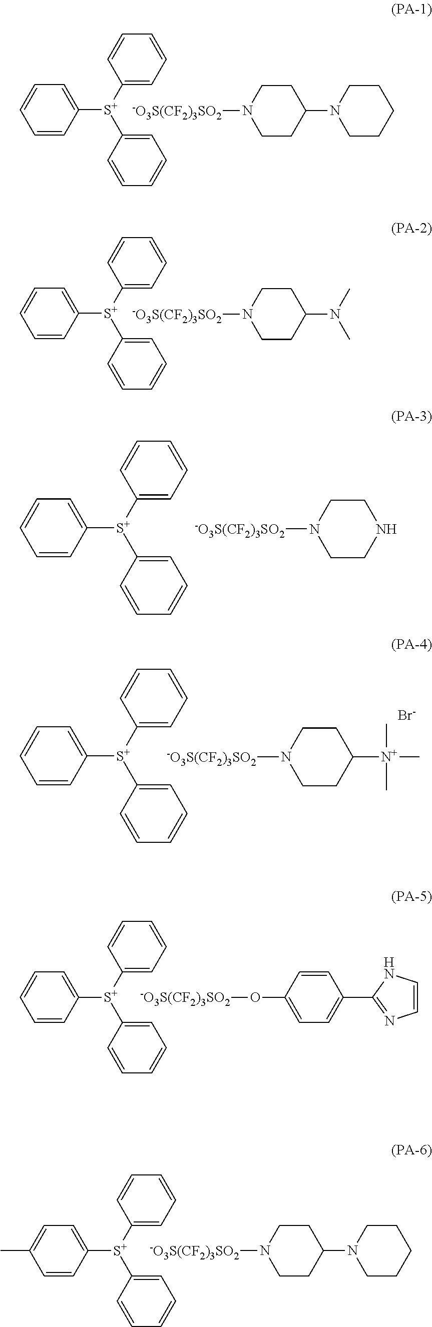

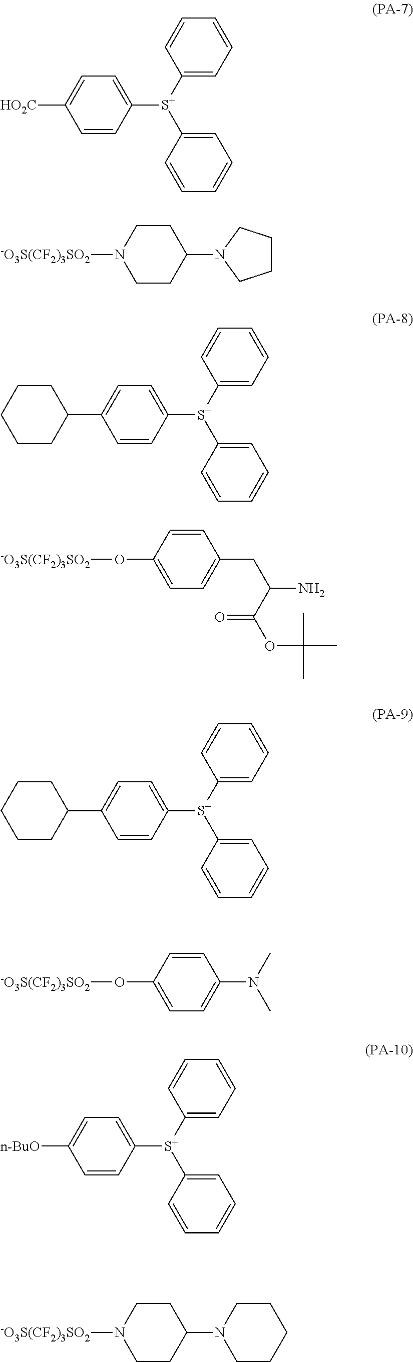

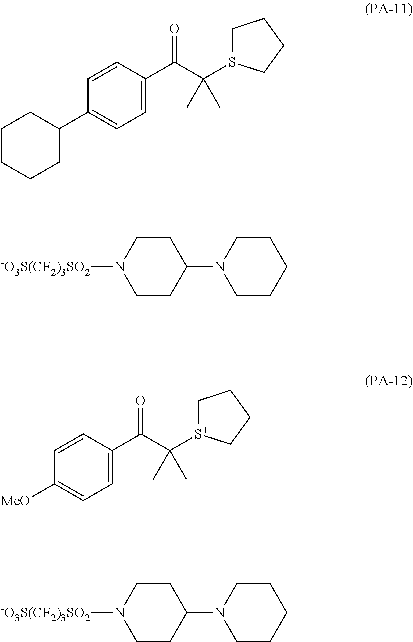

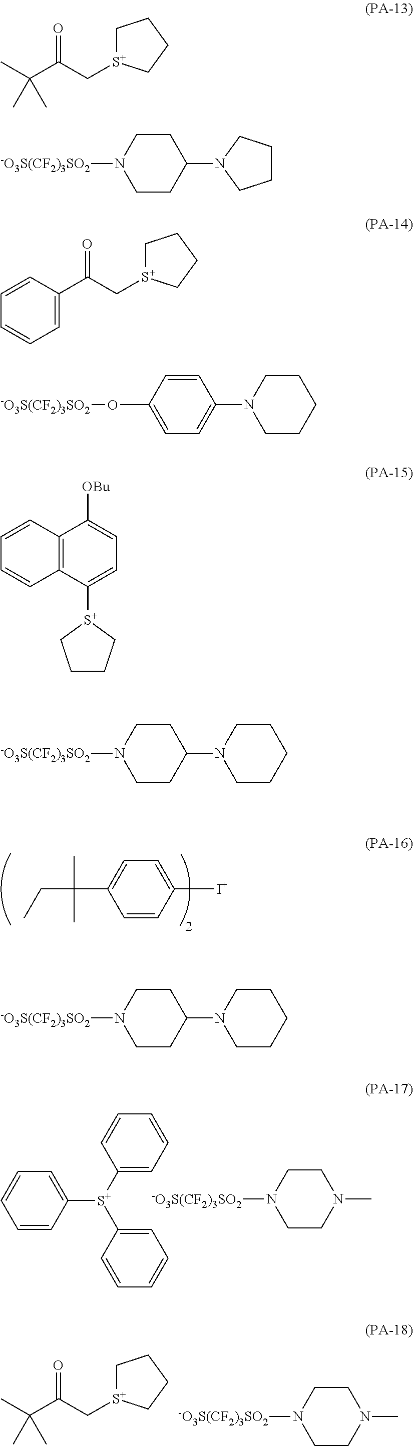

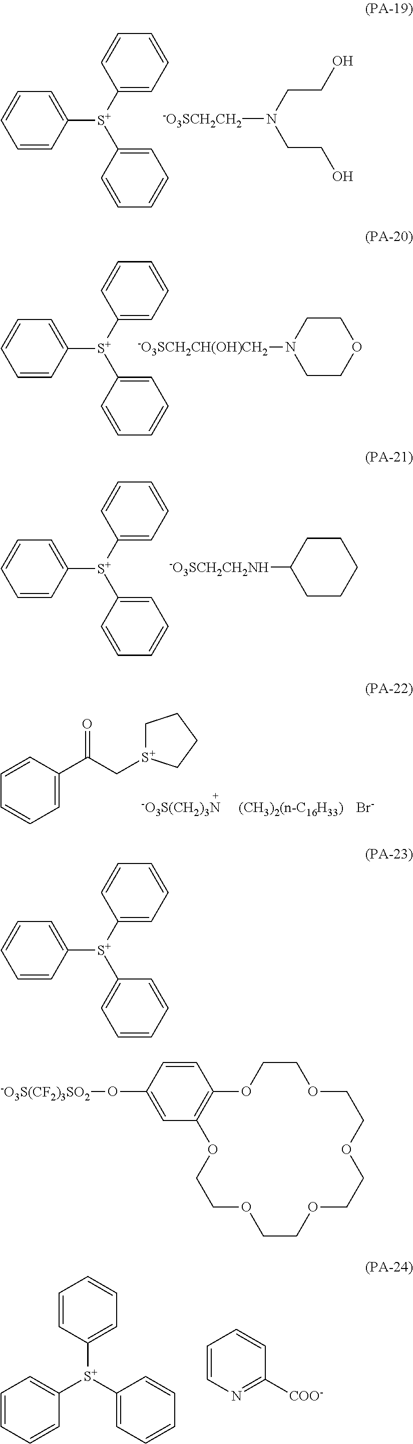

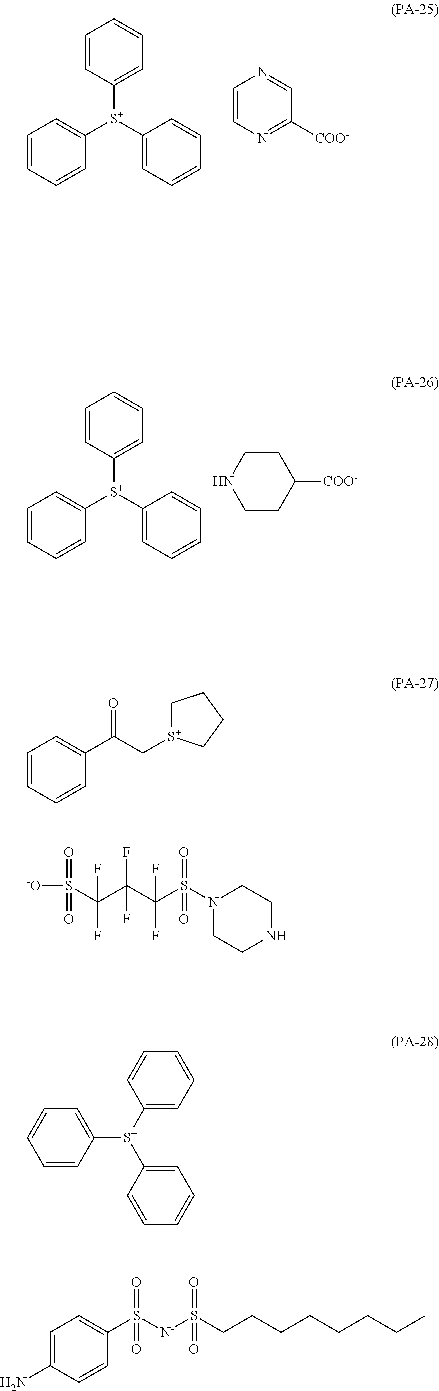

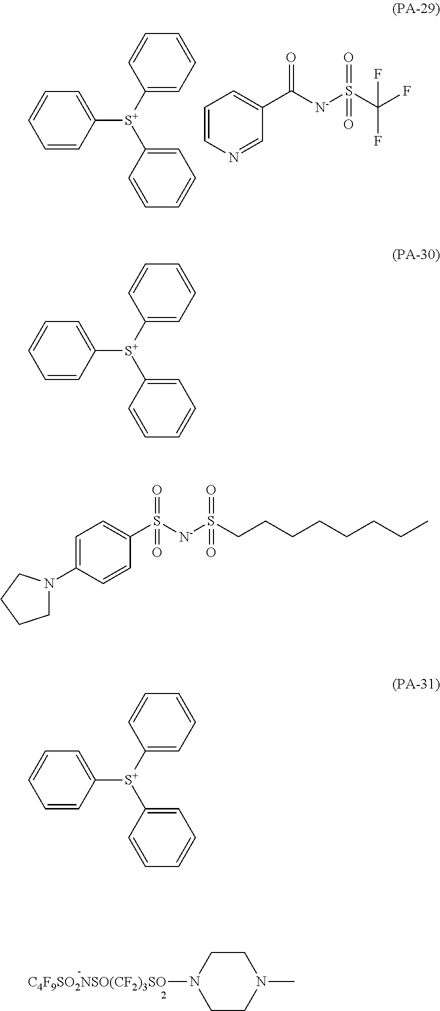

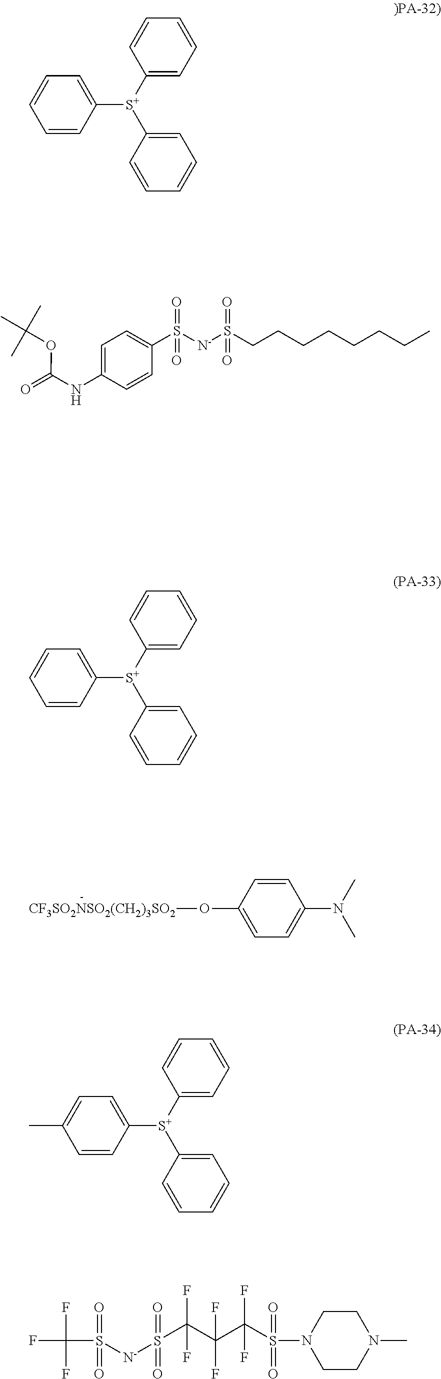

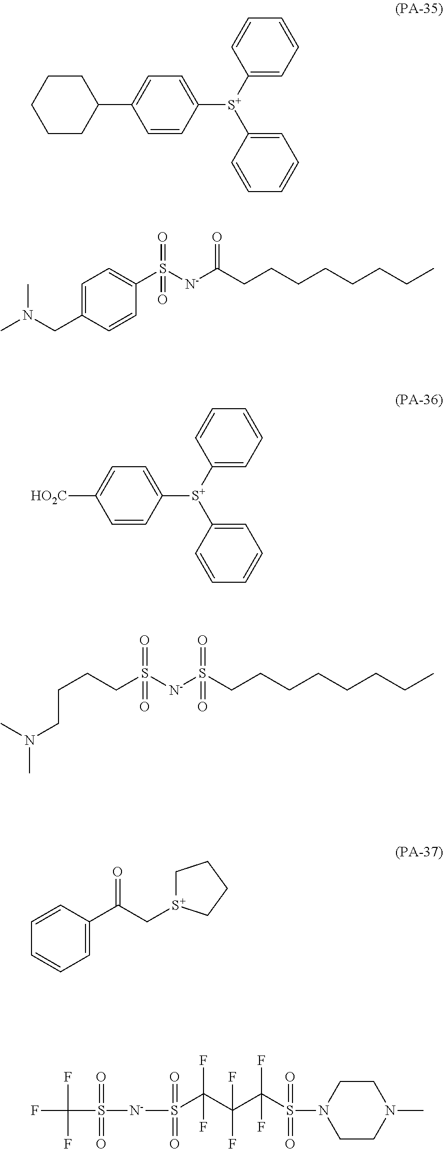

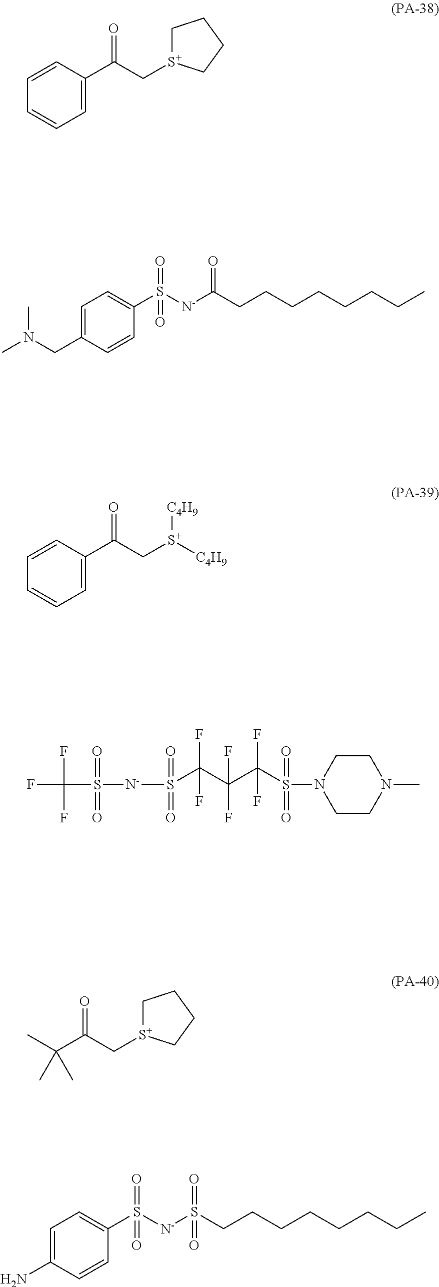

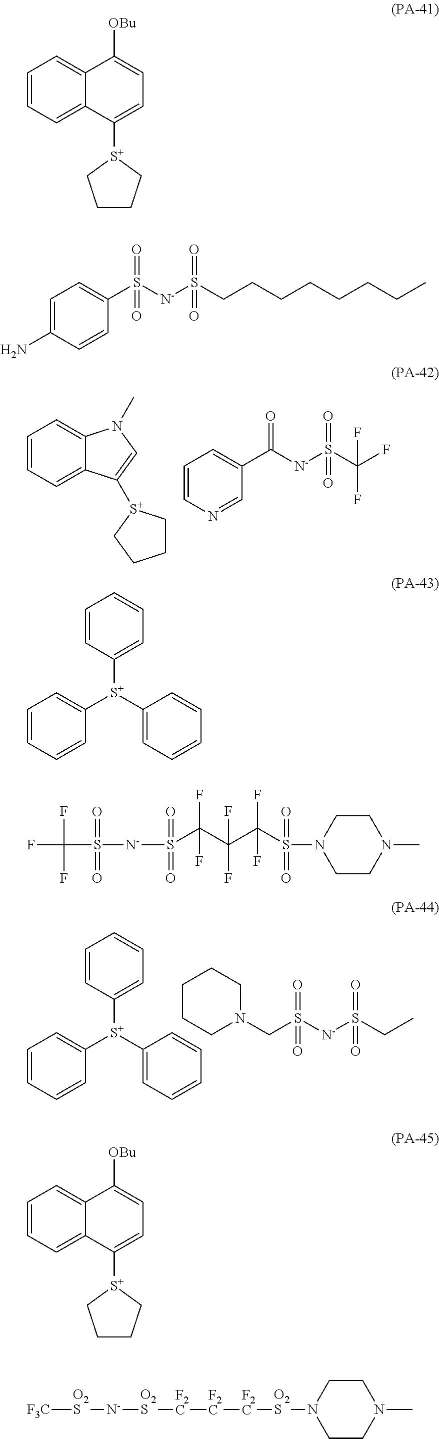

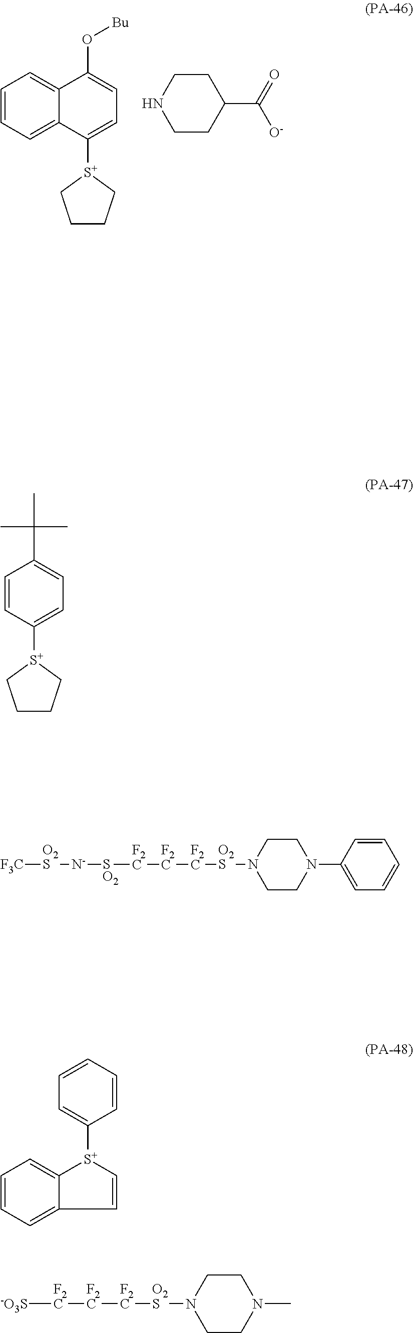

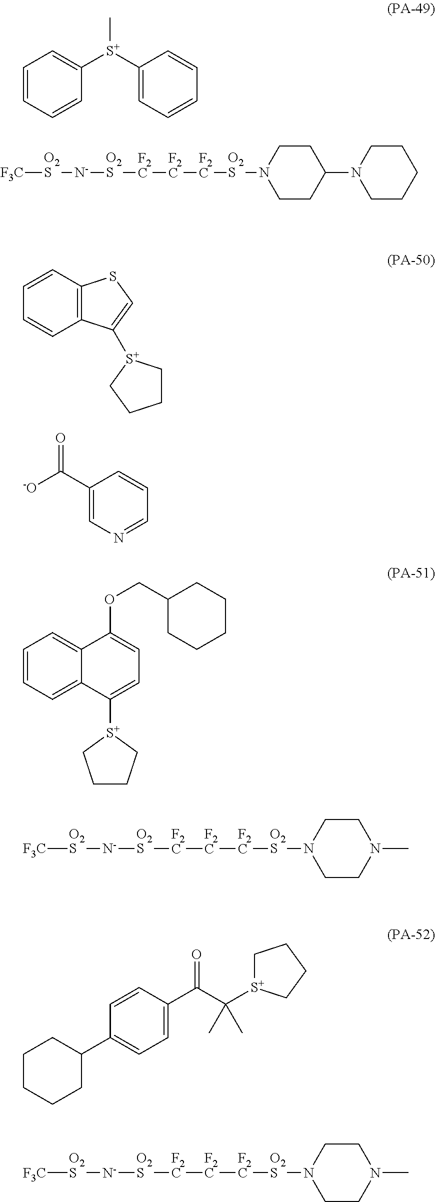

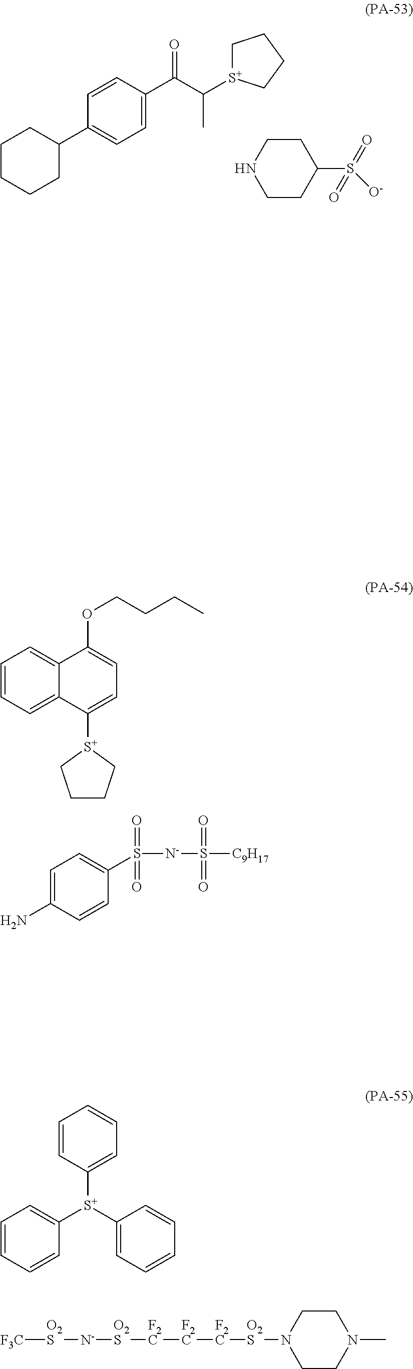

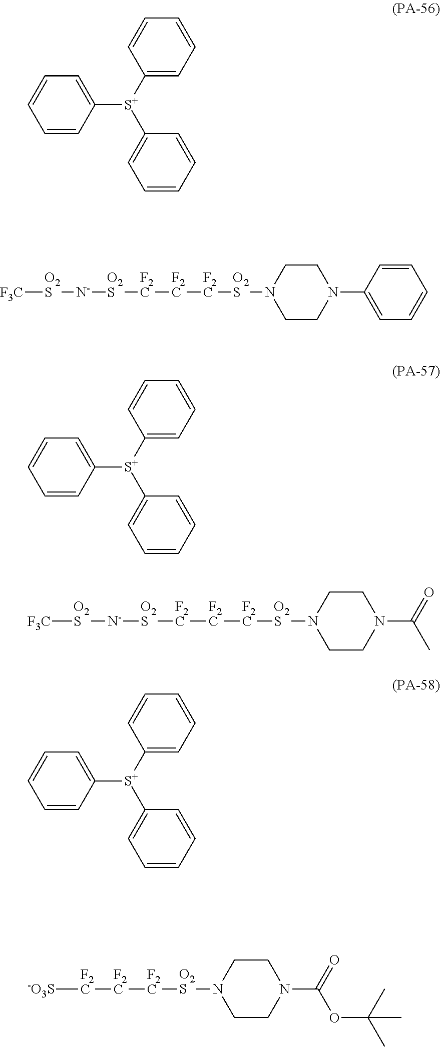

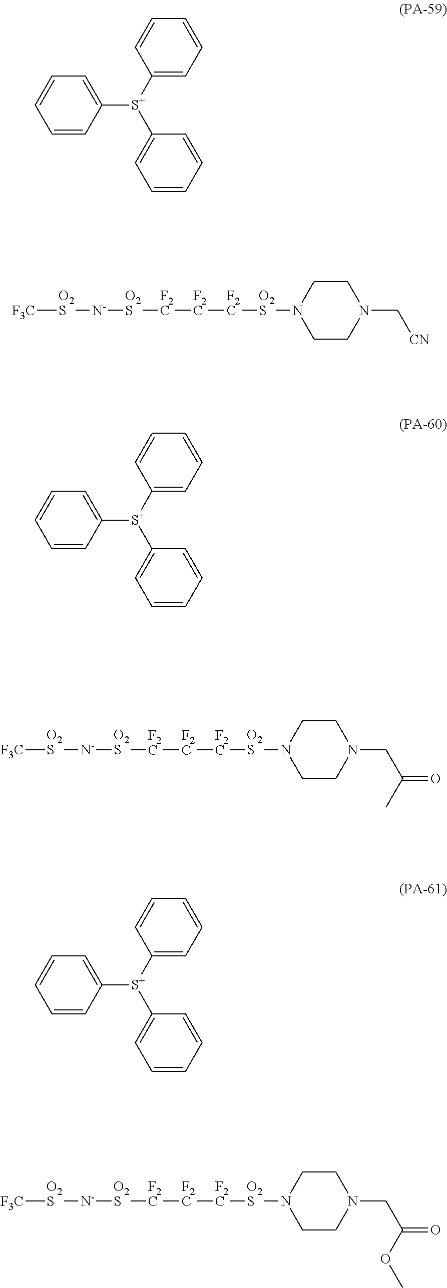 [SMILES: c1ccc([S+](c2ccccc2)c2ccccc2)cc1 ; N#CCN1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; CC(=O)CN1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; COC(=O)CN1CCN(S(=O)(=O)C(F)(F)C(F)(F)C(F)(F)S(=O)(=O)[N-]S(=O)(=O)C(F)(F)F)CC1]

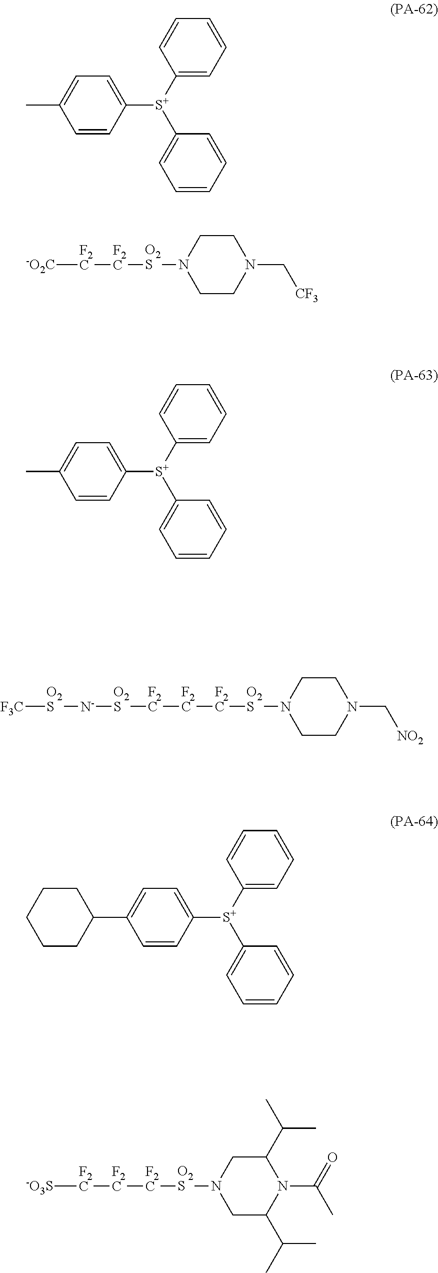

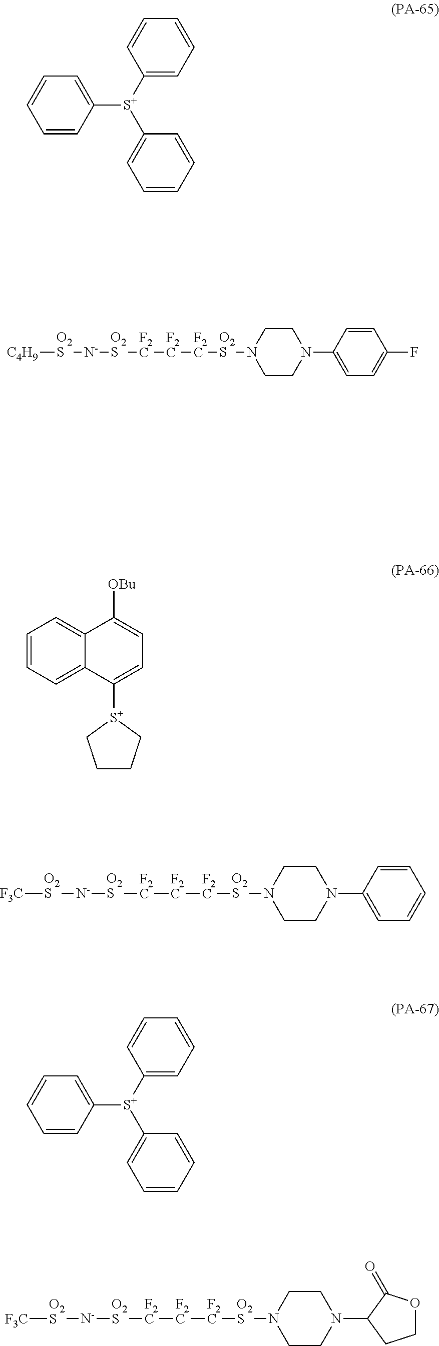

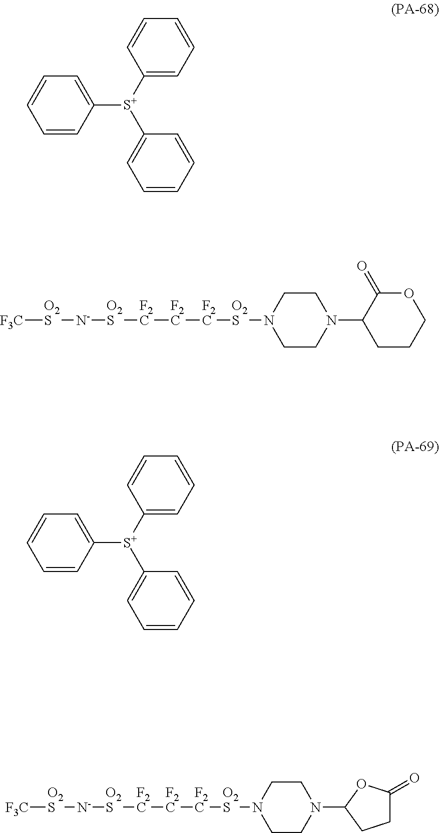 [SMILES: c1ccc([S+](c2ccccc2)c2ccccc2)cc1 ; O=C1OCCCC1N1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; O=C1CCC(N2CCN(S(=O)(=O)C(F)(F)C(F)(F)C(F)(F)S(=O)(=O)[N-]S(=O)(=O)C(F)(F)F)CC2)O1]

Synthesis of these compounds may particularly be equivalent to the synthesis examples described in Japanese Patent Application Laid-open Nos. 2006-330098 and 2011-100105.

The actinic ray-sensitive or radiation-sensitive resin composition of the present invention may or may not contain the compound (N′). However, in the case of containing the compound (N′), the content thereof is preferably 0.1 to 20% by mass and more preferably 0.1 to 10% by mass, based on the solid content of the actinic ray-sensitive or radiation-sensitive resin composition.

[5-3] Low molecular compound (N″) having a nitrogen atom and having a group capable of leaving by the action of an acid

The compositions of the present invention has a nitrogen atom and may contain a compound having a group capable of leaving by the action of an acid (hereinafter, also referred to as “compound (N″)”)

The group capable of leaving by the action of an acid is not particularly limited, but an acetal group, a carbonate group, a carbamate group, a tertiary ester group, a tertiary hydroxyl group, or a hemiaminal ether group is preferred. A carbamate group or a hemiaminal ether group is particularly preferred.

The molecular weight of the compound (N″) having a group capable of leaving by the action of an acid is preferably 100 to 1000, more preferably 100 to 700, and particularly preferably 100 to 500.

The compound (N″) is preferably an amine derivatives having a group capable of leaving by the action of an acid on the nitrogen atom.

The compound (N″) may have a carbamate group having a protective group on the nitrogen atom. The protective group constituting the carbamate group may be represented by the following Formula (d-1).

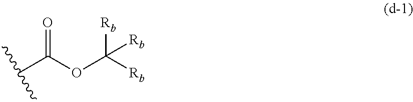

In Formula (d-1),

Each Rb independently represents a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). Rb's may be linked to each other to form a ring.

An alkyl group, a cycloalkyl group, an aryl group or an aralkyl group, represented by R1, may be substituted with a hydroxyl group, a cyano group, an amino group, a pyrrolidino group, a piperidino group, a morpholino group, a functional group such as an oxo group, an alkoxy group, a halogen atom. The alkoxyalkyl group represented by Rb is also the same.

Rb is preferably a straight or branched alkyl group, a cycloalkyl group, or an aryl group, and more preferably a straight or branched alkyl group, or a cycloalkyl group.

Examples of the ring formed by two Rb's linked to each other may include an alicyclic hydrocarbon group, an aromatic hydrocarbon group, and a heterocyclic hydrocarbon group or derivatives thereof.

A specific structure of the group represented by Formula (d-1) may include the structure disclosed in [0466] of U.S. Patent Application Publication No. 2012/0135348A1, but is not limited thereto.

The compound (N″) is particularly preferably the compound having a structure represented by the following Formula (6).

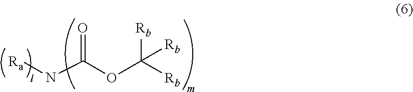

In Formula (6), Rₐ represents a hydrogen atom, an alkyl group, a cycloalkyl group, an aryl group or an aralkyl group. When 1 is 2, two Rₐ's may be same or different, and two Rₐ may be bonded to each other to form a heterocyclic hydrocarbon group together with a nitrogen atom in the formula. The heterocyclic hydrocarbon group may contain a heteroatom other than a nitrogen atom in the formula.

Rb is the same as Rb in Formula (d-1) and preferred example is the same.

l is an integer of 0 to 2, m is an integer of 1 to 3, and l+m=3.

In Formula (6), each of the alkyl group, the cycloalkyl group, the aryl group or the aralkyl group represented by Ra may be substituted with the same group as the group previously described as a group in which the alkyl group, the cycloalkyl group, the aryl group or the aralkyl group represented by Rb may be substituted.

Preferred examples of the alkyl group, the cycloalkyl group, the aryl group or the aralkyl group represented by Ra (the alkyl group, the cycloalkyl group, the aryl group or the aralkyl group may be substituted with the above-described group) includes the same group as the preferred examples previously described for Rb.

In addition, examples of the heterocyclic hydrocarbon group (preferably having from 1 to 20 carbon atoms) formed by Rₐ's bonded to each other may include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, a group in which the group derived from the heterocyclic compound is substituted with one or more kinds of or one or more of straight or branched groups derived from alkane, groups derived from cycloalkane, groups derived from aromatic compounds, groups derived from heterocyclic compounds and functional groups such as a hydroxyl group, a cyano group, an amino group, a pyrrolidino group, a piperidino group, a morpholino group and an oxo group, and the like.

Specific examples of particularly preferred compounds (N″) of the present invention may include the compounds disclosed in paragraph [0475] of U.S. Patent Application Publication No. 2012/0135348A1, but not limited thereto.

The compound represented by Formula (6) may be synthesized as described in Japanese Patent Application Laid-open Nos. 2007-298569 and 2009-199021.

In the present invention, the low-molecular compound (N″) having a group capable of leaving by the action of an acid on the nitrogen atom may be used either alone or in combination of two or more thereof.

The content of the compound (N″) in the actinic ray-sensitive or radiation-sensitive resin composition of the present invention is preferably 0.001 to 20% by mass, more preferably 0.001 to 10% by mass and more preferably 0.01 to 5% by mass, based on the total solid of the composition.

[6] Solvent (E)

Examples of the solvent, which may be used at the time of preparing the actinic ray-sensitive or radiation-sensitive resin composition in the present invention, may include an organic solvent such as alkylene glycol monoalkyl ether carboxylate, alkylene glycol monoalkyl ether, alkyl ester lactate, alkyl alkoxypropionate, cyclic lactone (preferably having 4 to 10 carbon atoms), a monoketone compound (preferably having 4 to 10 carbon atoms) which may have a ring, alkylene carbonate (propylene carobonate, etc.), alkyl alkoxyacetate and alkyl pyruvate.

Specific examples of these solvents may include those described in [0441] to [0455] of U.S. Patent Application Publication No. 2008/0187860.

In the present invention, the organic solvent may use a mixed solvent in which a solvent containing a hydroxyl group and a solvent containing no hydroxyl group in the structure thereof are mixed.

As the solvent containing a hydroxyl group and the solvent containing no hydroxyl group, the above-described exemplary compound may be appropriately selected, but the solvent containing a hydroxyl group is preferably alkylene glycol monoalkyl ether, alkyl lactate and the like, and more preferably propylene glycol monomethyl ether (PGME, another name 1-methoxy-2-propanol) and ethyl lactate. Further, the solvent containing no hydroxyl group is preferably alkylene glycol monoalkyl ether acetate, alkyl alkoxypropionate, a monoketone compound which may contain a ring, a cyclic lactone, alkyl acetate and the like, and among them, propylene glycol monomethyl ether acetate (PGMEA, another name 1-methoxy-2-acetoxypropane), propylene glycol monomethyl ether propionate, ethyl ethoxypropionate, propylene carbonate, 2-heptanone, γ-butyrolactone, cyclohexanone and butyl acetate are particularly preferred, and propylene glycol monomethyl ether acetate, ethyl ethoxypropionate and 2-heptanone are most preferred.

The mixing ratio (by mass) of the solvent containing a hydroxyl group to the solvent containing no hydroxyl group is 1/99 to 99/1, preferably 10/90 to 90/10, and more preferably 20/80 to 60/40. A mixed solvent in which the solvent containing no hydroxyl group is contained in an amount of 50% by mass or more is particularly preferred in view of coating uniformity.

The solvent preferably includes propylene glycol monomethyl ether acetate, and a single solvent of propylene glycol monomethyl ether acetate (PGMEA) or a mixed solvent of two or more containing propylene glycol monomethyl ether acetate (PGMEA) is preferred. Preferred specific examples of the mixed solvent may include a mixed solvent containing PGMEA and ketone solvents (cyclohexanone, 2-heptanone, etc.), a mixed solvent containing PGMEA and lactone-based solvent (γ-butyrolactone, etc.), a mixed solvent containing PGMEA and PGME, a mixed solvent containing three kinds of PGMEA, a ketone-based solvent, and a lactone-based solvent, and a mixed solvent containing three kinds of PGMEA, PGME, and a ketone-based solvent, but is not limited thereto.

[7] Surfactant (F)

The actinic ray-sensitive or radiation-sensitive resin composition in the present invention may or may not contain a surfactant, but when the composition contains a surfactant, it is more preferred that the composition contains any one of fluorine and/or silicone-based surfactants (a fluorine-based surfactant, a silicone-based surfactant and a surfactant having both a fluorine atom and a silicon atom), or two or more thereof.

The actinic ray-sensitive or radiation-sensitive resin composition in the present invention contains a surfactant, thereby imparting a resist pattern with adhesion and reduced development defects due to improved sensitivity and resolution when using an exposure light source with a wavelength of 250 nm or less, particularly 220 nm or less.

Examples of the fluorine-based and/or silicone-based surfactants may include surfactants described in [0276] of U.S. Patent Application Publication No. 2008/0248425, such as F-Top EF301 and EF303 (manufactured by Shin-Akita Chemical Co., Ltd.), Fluorad FC430, 431 and 4430 (manufactured by Sumitomo-3M Co., Ltd.), Megafac F171, F173, F176, F189, F113, F110, F177, F120 and R08 (manufactured by DIC Corporation), Surflon S-382, SC101, 102, 103, 104, 105 and 106 and KH-20 (manufactured by Asahi Glass Co., Ltd.), Troysol S-366 (manufactured by Troy Chemical Corp.), GF-300 and GF-150 (manufactured by TOAGOSEI Chemical Industry Co., Ltd.), Surflon S-393 (manufactured by Seimi Chemical Co., Ltd.), F-Top EF121, EF122A, EF122B, RF122C, EF125M, EF135M, EF351, EF352, EF801, EF802 and EF601 (manufactured by JEMCO Inc.), PF636, PF656, PF6320 and PF6520 (manufactured by OMNOVA Solutions, Inc.), FTX-204G, 208G, 218G, 230G, 204D, 208D, 212D, 218D and 222D (manufactured by NEOS Corporation) and the like. In addition, polysiloxane polymer KP-341 (manufactured by Shin-Etsu Chemical Co., Ltd.) may also be used as the silicone-based surfactant.

Furthermore, in addition to those publicly known surfactants described above, it is possible to use a surfactant using a polymer having a fluoro-aliphatic group derived from a fluoro-aliphatic compound which is prepared by a telomerization method (also referred to as a telomer method) or an oligomerization method (also referred to as an oligomer method) as the surfactant. The fluoro-aliphatic compound may be synthesized by the method described in Japanese Patent Application Laid-Open No. 2002-90991.

Examples of a surfactant corresponding to the above-described surfactant may include Megafac F178, F-470, F-473, F-475, F-476 and F-472 (manufactured by DIC Corporation), a copolymer of an acrylate having a C₆Fi₃ group (or methacrylate) with a (poly(oxyalkylene))acrylate (or methacrylate), a copolymer of an acrylate having a C₃F₇ group (or methacrylate) with a (poly(oxyethylene))acrylate (or methacrylate) and a (poly(oxypropylene))acrylate (or methacrylate), and the like.

Further, in the present invention, it is also possible to use a surfactant other than the fluorine-based and/or silicone-based surfactant, described in [0280] of U.S. Patent Application Publication No. 2008/0248425.

These surfactants may be used either alone or in combination of several thereof.

When the actinic ray-sensitive or radiation-sensitive resin composition contains a surfactant, the amount of surfactant used is preferably 0.0001 to 2% by mass, and more preferably 0.0005 to 1% by mass, based on the total amount of the actinic ray-sensitive or radiation-sensitive resin composition (excluding the solvent).

Meanwhile, by adjusting the amount of surfactant added to 10 ppm or less based on the total amount of actinic ray-sensitive or radiation-sensitive resin composition (excluding the solvent), the surface uneven distribution of the hydrophobic resin is increased, and accordingly, the surface of the resist film may be made to be more hydrophobic, thereby enhancing the water follow-up property at the time of liquid immersion exposure.

From the viewpoint of enhancing the resolution, the actinic ray-sensitive or radiation-sensitive resin composition in the present invention is used preferably in a film thickness of 30 to 250 nm, and more preferably in a film thickness of 30 to 200 nm. Such a film thickness may be achieved by setting a solid concentration in the composition to an appropriate range to have an appropriate viscosity, thereby enhancing coatability and film-formation property.

The solid content concentration of the actinic ray-sensitive or radiation-sensitive resin composition in the present invention is usually 1.0 to 10% by mass, preferably 2.0 to 5.7% by mass, and more preferably 2.0 to 5.3% by mass. By setting the solid content concentration to the above-described range, the resist solution may be uniformly applied on a substrate and a resist pattern having excellent line width roughness may be formed. The reason is not clear, but it is thought that by setting the solid content concentration to 10% by mass or less and preferably 5.7% by mass or less, aggregation of materials, particularly, a photo-acid generator, in the resist solution is suppressed, and as a result, a uniform resist film may be formed.

The solid content concentration is a weight percentage of the weight of other resist components excluding the solvent, based on the total weight of the actinic ray-sensitive or radiation-sensitive resin composition.

The actinic ray-sensitive or radiation-sensitive resin composition in the present invention is used by dissolving the aforementioned components in a predetermined organic solvent, preferably in the mixed solvent, filtering the solution through a filter, and then applying the filtered solution on a predetermined support (substrate). The filter used for filtration is preferably a polytetrafluoroethylene-, polyethylene- or nylon-made filter having a pore size of 0.1 μm or less, more preferably 0.05 μm or less, and still more preferably 0.03 μm or less. In the filtration through a filter, as described in, for example, Japanese Patent Application Laid-Open No. 2002-62667, circulating filtration may be performed, or the filtration may be performed by connecting a plurality of kinds of filters in series or in parallel. In addition, the composition may be filtered a plurality of times. Furthermore, a deaeration treatment or the like may be applied to the composition before or after filtration through a filter.

[8] Pattern Forming Method

Next, the pattern forming method according to the present invention is described.

The pattern forming method (negative-type pattern forming method) of the present invention at least includes:

(a) a process of forming a film (resist film) by the aforementioned actinic ray-sensitive or radiation-sensitive resin composition,

(b) a process of irradiating (exposing) the actinic ray-sensitive or radiation-sensitive resin composition on the film, and

(c) a process of performing development using an organic solvent-containing developer to form a negative-type pattern.

The exposure in the process (b) may be liquid immersion exposure.

It is preferred that the pattern forming method of the present invention includes (d) a process of heating after (b) the exposure process.

The pattern forming method of the present invention may further comprise (e) a process of performing development using an alkali developer. By including this process, as described in FIG. 1 to FIG. 11 of U.S. Pat. No. 8,227,183 B2 and the like, it is possible to obtain a half of the pattern of the optical image of the mask. In addition, the order of steps (c) and the step (e) is not particularly limited

The pattern forming method of the present invention may include plural times of (b) the exposure process.

The pattern forming method of the present invention may include plural times of (e) a heating process.

The resist film of the present invention is formed of the actinic ray-sensitive or radiation-sensitive resin composition according to the present invention as described above, and more specifically, the film formed by coating the actinic ray-sensitive or radiation-sensitive resin composition on a substrate is preferred. In the pattern forming method of the present invention, the process of forming a film by the actinic ray-sensitive or radiation-sensitive resin composition on the substrate, the process of exposing the film, and the process of performing development may be performed by a generally known method.

It is also preferred that the method includes, after film formation, a pre-baking process (PB) before the exposure process.

Further, it is also preferred that the method includes a post-exposure baking process (PEB) after the exposure process and before the development process.

As for the heating temperature, both PB and PEB are performed preferably at 70 to 130° C., and more preferably at 80 to 120° C.

The heating time is preferably 30 to 300 seconds, more preferably 30 to 180 seconds, and still more preferably 30 to 90 seconds.

The heating may be performed using a means equipped with a typical exposure•developing machine or may be performed using a hot plate or the like.

By means of baking, the reaction in the exposed portion is accelerated, and thus the sensitivity or a pattern profile is improved.

The light source wavelength used in the exposure apparatus in the present invention is not limited, but examples thereof include an infrared light, a visible light, an ultraviolet light, a far ultraviolet light, an extreme-ultraviolet light, X-ray, an electron beam and the like, and the light source wavelength is preferably a far ultraviolet light at a wavelength of preferably 250 nm or less, more preferably 220 nm or less, and particularly preferably from 1 nm to 200 nm. Specific examples thereof include a KrF excimer laser (248 nm), an ArF excimer laser (193 nm), an F₂ excimer laser (157 nm), an X-ray, an EUV (13 nm), an electron beam and the like, and a KrF excimer laser, an ArF excimer laser, an EUV or an electron beam is preferred, and an ArF excimer laser is more preferred.

In addition, in the process of performing exposure of the present invention, a liquid immersion exposure method may be applied.

Immersion exposure method may be bonded to super-resolution techniques such as a phase shift method and a modified illumination method.

In the case of performing liquid immersion exposure, a process of washing the surface of the film with an aqueous chemical solution may be performed (1) before forming the film on a substrate and then performing exposure and/or (2) after the process of exposing the film through a liquid for liquid immersion but before the process of heating the film.

The liquid for liquid immersion is preferably a liquid which is transparent to light at the exposure wavelength and has a temperature coefficient of refractive index as small as possible in order to minimize the distortion of an optical image projected on the film, and particularly, when the exposure light source is an ArF excimer laser (wavelength; 193 nm), water is preferably used from the viewpoint of easy availability and easy handlability in addition to the above-described viewpoint.

When water is used, an additive (liquid) capable of decreasing the surface tension of water and also increasing the interfacial activity may be added in a small ratio. It is preferred that the additive does not dissolve the resist layer on the wafer and has only a negligible effect on the optical coat at the undersurface of the lens element.

Such an additive is preferably an aliphatic alcohol having a refractive index almost equal to that of, for example, water, and specific examples thereof include methyl alcohol, ethyl alcohol, isopropyl alcohol and the like. By adding an alcohol having a refractive index almost equal to that of water, even when the alcohol component in water is evaporated and the content concentration thereof is changed, it is possible to obtain an advantage in that the change in the refractive index of the liquid as a whole may be made very small.

Meanwhile, when a substance opaque to light at 193 nm or an impurity greatly differing from water in the refractive index is incorporated, the incorporation leads to distortion of the optical image projected on the resist, and thus, the water used is preferably distilled water. Furthermore, pure water filtered through an ion exchange filter or the like may also be used.

The electrical resistance of water used as the liquid for liquid immersion is preferably 18.3 MΩcm or more, and TOC (organic concentration) is preferably 20 ppb or less and the water is preferably subjected to deaeration treatment.

Further, the lithography performance may be enhanced by raising the refractive index of the liquid for liquid immersion. From this viewpoint, an additive for raising the refractive index may be added to water, or heavy water (D₂O) may be used in place of water.

The receding contact angle of the resist film formed using the actinic ray-sensitive or radiation-sensitive resin composition according to the present invention is 70° or more at a temperature of 23±3° C. and a humidity of 45±5% and it is suitable in the case of exposing to light via a liquid immersion medium. The receding contact angle of the film is preferably 75° to 90°, and more preferably 75 to 85°.

When the receding contact angle is too small, it may not be suitably used when it is exposed to light via an immersion medium, and it is impossible to sufficiently exhibit the effect of the water remaining (watermark) defect reduction. In order to achieve the preferred receding contact angle, it is preferable to include the hydrophobic resin (HR) in the actinic ray-sensitive or radiation-sensitive composition. Alternatively, it is also possible to improve the receding contact angle by forming a coating layer by a hydrophobic resin composition (so-called “top coat”) on the resist film.

In the liquid immersion exposure process, the liquid for liquid immersion needs to move on a wafer following the movement of an exposure head that scans on the wafer at a high speed and forms an exposure pattern, and thus the contact angle of the liquid for liquid immersion for the resist film in a dynamic state is important, and the resist requires a performance of following the high-speed scanning of the exposure head, while a liquid droplet no longer remains.

In the present invention, the substrate on which the film is formed is not particularly limited, and it is possible to use an inorganic substrate such as silicone, SiN, SiO₂ or SiN, a coating-type inorganic substrate such as SOG, or a substrate generally used in the process of manufacturing a semiconductor such as IC or manufacturing a liquid crystal or a circuit board such as a thermal head or in the lithography process of other photo-fabrication processes. Furthermore, if necessary, an organic antireflection film may be formed between the film and the substrate. As the anti-reflection film, a known organic or inorganic anti-reflection film may be appropriately used.

When the pattern forming method of the present invention further includes a process of performing development using an alkali developer, it is possible to use an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine as the alkali developer.

Furthermore, alcohols and a surfactant may be added to the alkaline aqueous solution each in an appropriate amount and the mixture may be used.

The alkali concentration of the alkali developer is usually 0.1 to 20% by mass.

The pH of the alkali developer is usually 10.0 to 15.0.

In particular, an aqueous solution of 2.38% by mass of tetramethylammonium hydroxide is preferred.

As for the rinse liquid in the rinse treatment performed after the alkali development, pure water is used, and an appropriate amount of a surfactant may be added thereto to use the mixture.

Further, after the development treatment or rinse treatment, a treatment of removing the developer or rinse liquid adhering on the pattern by a supercritical fluid may be performed.

As the developer (hereinafter, also referred to as an organic-based developer) in the process of performing development using an organic solvent-containing developer to form a negative-type pattern, a polar solvent such as a ketone-based solvent, an ester-based solvent, an alcohol-based solvent, an amide-based solvent and an ether-based solvent, and a hydrocarbon-based solvent may be used.

Examples of the ketone-based solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate and the like.

Examples of the ester-based solvent may include methyl acetate, butyl acetate, ethyl acetate, isopropyl acetate, pentyl acetate, isopentyl acetate, amyl acetate, cyclohexyl acetate, isobutyl isobutyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate and the like.

Examples of the alcohol-based solvent may include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol, or a glycol-based solvent such as ethylene glycol, diethylene glycol and triethylene glycol, or a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol, and the like.

Examples of the ether-based solvent may include, in addition to the glycol ether-based solvents, dioxane, tetrahydrofuran, phenetol, dibutyl ether and the like.

As the amide-based solvent, it is possible to use N-methyl-2-pyrrolidone, N,N-dimethylacetamide, N,N-dimethylformamide, hexamethylphosphoric triamide, 1,3-dimethyl-2-imidazolidinone and the like.

Examples of the hydrocarbon-based solvent may include an aromatic hydrocarbon-based solvent such as toluene and xylene, and an aliphatic hydrocarbon-based solvent such as pentane, hexane, octane and decane.

A plurality of the solvents may be mixed, or the solvents may be used by mixing with a solvent other than those described above or with water. However, in order to sufficiently exhibit the effects of the present invention, the moisture content of the entire developer is preferably less than 10% by mass, and it is more preferred that the developer contains substantially no moisture.

That is, the amount of the organic solvent used in the organic-based developer is preferably 90% by mass to 100% by mass, and preferably 95% by mass to 100% by mass, based on the total amount of the developer.

In particular, the organic-based developer is preferably a developer containing at least one of the organic solvents selected from the group consisting of a ketone-based solvent, an ester-based solvent, an alcohol-based solvent, an amide-based solvent and an ether-based solvent.

The vapor pressure of the organic-based developer is preferably 5 kPa or less, more preferably 3 kPa or less, and particularly preferably 2 kPa or less, at 20° C. By setting the vapor pressure of the organic-based developer to 5 kPa or less, evaporation of the developer on a substrate or in a development cup is suppressed so that temperature uniformity in the wafer plane is enhanced, and as a result, the dimensional uniformity in the wafer plane is improved.

In the organic-based developer, a surfactant may be added in an appropriate amount, if necessary.

The surfactant is not particularly limited but, for example, ionic or nonionic fluorine-based and/or silicon-based surfactant and the like may be used. Examples of the fluorine and/or silicone-based surfactants may include surfactants described in Japanese Patent Application Laid-open Nos. S62-36663, S61-226746, S61-226745, S62-170950, S63-34540, H7-230165, H8-62834, H9-54432, and H9-5988 and U.S. Pat. Nos. 5,405,720, 5,360,692, 5,529,881, 5,296,330, 5,436,098, 5,576,143, 5,294,511 and 5,824,451, and a nonionic surfactant is preferred. The nonionic surfactant is not particularly limited, but a fluorine-based surfactant or a silicone-based surfactant is more preferably used.

The amount of the surfactant used is usually 0.001 to 5% by mass, preferably 0.005 to 2% by mass, and more preferably 0.01 to 0.5% by mass, based on the total amount of the developer.

In addition, the organic developer may include a nitrogen-containing compound as described in particular in [0032] to [0063] of Japanese Patent Application Laid-open No. 2013-11833.

As for the developing method, it is possible to apply, for example, a method of dipping a substrate in a bath filled with a developer for a predetermined time (dipping method), a method of raising a developer on a substrate surface sufficiently by the effect of a surface tension and keeping the substrate still for a predetermined time, thereby performing development (puddle method), a method of spraying a developer on a substrate surface (spraying method), a method of continuously ejecting a developer on a substrate spinning at a constant speed while scanning a developer ejecting nozzle at a constant rate (dynamic dispense method) and the like.

When the above-described various developing methods include a process of ejecting a developer toward a resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, and still more preferably 1 mL/sec/mm² or less. The flow velocity has no particular lower limit, but is preferably 0.2 mL/sec/mm² or more in consideration of throughput.

By setting the ejection pressure of the ejected developer to the aforementioned range, pattern defects resulting from the resist scum after development may be significantly reduced.

Details on the mechanism are not clear, but it is thought that it is because the pressure imposed on the resist film by the developer is decreased by setting the ejection pressure to the above-described range, so that the resist film•resist pattern is suppressed from being inadvertently cut or collapsing.

Further, the ejection pressure (mL/sec/mm²) of the developer is the value at the outlet of the development nozzle in the developing apparatus.

Examples of the method for adjusting the ejection pressure of the developer may include a method of adjusting the ejection pressure by a pump or the like, a method of supplying a developer from a pressurized tank and adjusting the pressure to change the ejection pressure and the like.

In addition, after the process of performing development using an organic solvent-containing developer, a process of stopping the development while replacing the solvent with another solvent may be performed.

It is preferred that a process of rinsing the resist using a rinse liquid is included after the process of performing development using an organic solvent-containing developer.

The rinse liquid used in the rinse process after the process of performing development using an organic solvent-containing developer is not particularly limited as long as the rinse liquid does not dissolve the resist pattern, and a solution including a general organic solvent may be used. As for the rinse liquid, a rinse liquid containing at least one of the organic solvents selected from the group consisting of a hydrocarbon-based solvent, a ketone-based solvent, an ester-based solvent, an alcohol-based solvent, an amide-based solvent and an ether-based solvent is preferably used.

Specific examples of the hydrocarbon-based solvent, the ketone-based solvent, the ester-based solvent, the alcohol-based solvent, the amide-based solvent and the ether-based solvent are the same as those described above with regard to the organic solvent-containing developer.

After the process of performing development using an organic solvent-containing developer, a rinse process using a rinse liquid containing at least one of organic solvents selected from the group consisting of a ketone-based solvent, an ester-based solvent, an alcohol-based solvent and an amide-based solvent is more preferably performed, a rinse process using a rinse liquid containing an alcohol-based solvent or an ester-based solvent is still more preferably performed, a rinse process using a rinse liquid containing a monohydric alcohol is particularly preferably performed, and a rinse process using a rinse liquid containing a monohydric alcohol having 5 or more carbon atoms is most preferably performed.

Here, examples of the monohydric alcohol used in the rinse process may include a straight, branched or cyclic monohydric alcohol, and specifically, it is possible to use 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol and the like, and as the particularly preferred monohydric alcohol having 5 or more carbon atoms, it is possible to use 1-hexanol, 2-hexanol, 4-methyl-2-pentanol, 1-pentanol, 3-methyl-1-butanol and the like.

A plurality of the components may be mixed, or the components may be used by being mixed with an organic solvent other than those described above.

The moisture content in the rinse liquid is preferably 10% by mass or less, more preferably 5% by mass or less, and particularly preferably 3% by mass or less. By setting the water content ratio to 10% by mass or less, good development characteristics may be obtained.

The vapor pressure of the rinse liquid used after the process of performing development using an organic solvent-containing developer is preferably 0.05 kPa to 5 kPa, more preferably 0.1 kPa to 5 kPa, and most preferably 0.12 kPa to 3 kPa, at 20° C. By setting the vapor pressure of the rinse liquid to 0.05 kPa to 5 kPa, the temperature uniformity in the wafer plane is enhanced, and furthermore, swelling caused by penetration of the rinse liquid is suppressed, and as a result, the dimensional uniformity in the wafer plane is improved.

The rinse liquid may also be used by adding an appropriate amount of a surfactant thereto.

In the rinse process, the wafer subjected to development using an organic solvent-containing developer is rinsed by using the aforementioned rinse liquid including an organic solvent. The method of rinse treatment is not particularly limited, but it is possible to apply, for example, a method of continuously ejecting a rinse liquid on a substrate spinning at a constant speed (spin coating method), a method of dipping a substrate in a bath filled with a rinse liquid for a predetermined time (dipping method), a method of spraying a rinse liquid on a substrate surface (spraying method), and the like, and among them, it is preferred that the rinse treatment is performed by the spin coating method and after the rinse, the substrate is spun at a rotational speed of 2,000 rpm to 4,000 rpm to remove the rinse liquid from the substrate. Furthermore, it is also preferred that a heating process (post bake) is included after the rinse process. The developer and rinsing liquid remaining between patterns and in the inside of the pattern are removed by the bake. The heating process after the rinsing process is performed at usually 40 to 160° C., and preferably 70 to 95° C., for usually 10 seconds to 3 minutes, and preferably 30 to 90 seconds.

The pattern obtained from the pattern forming method of the present invention is generally preferably used as an etching mask of a semiconductor device, but it is also used for other applications. Other applications include, for example, a guide pattern formation in the DSA (Directed Self-Assembly) (see, for example, ACS Nano Vol. 4 No. 8 Page 4815-4823), used as a core material of the so-called spacer process (core) (see, from example, Japanese Patent Application Laid-open No. H3-270227 and Japanese Patent Application Laid-open No. 2013-164509), and the like.

Further, the present invention also relates to a method for manufacturing an electronic device, comprising the aforementioned pattern forming method of the present invention, and an electronic device manufactured by this manufacturing method.

The electronic device of the present invention is suitably mounted on electric electronic devices (such as home appliances, OA•media-related devices, optical devices and communication devices).

### EXAMPLES

### Synthesis Example

### Resin (P-1)

Under nitrogen flow, 31.2 g of cyclohexanone was introduced into a three-neck flask and heated at 80° C. Then, the following monomer 1 (3.96 g) and the monomer 2 (11.79 g) were dissolved in cyclohexanone (58.0 g) to prepare a monomer solution. Further, 0.37 g (2.0 mol % relative to the total weight of the monomer) of a polymerization initiator V-601 (Wako Pure Chemical Industries, Ltd.) was added thereto. The dissolved solution was added dropwise over 6 hours into the flask. After completion of the dropwise addition, the solution was further reacted at 80° C. for 2 hours. The reaction solution was allowed to cool, a mixed solvent of heptane 661 g/ethyl acetate 73 g was then added dropwise and subjected to precipitation. The precipitated powder was collected by filtration and dried to obtain 12.1 g of Resin (P-1). The weight average molecular weight (Mw: in terms of polystyrene) obtained from the GPC (carrier: tetrahydrofuran (THF)) of the obtained resin (P-1) was Mw=13,800 with a polydispersity Mw/Mn=1.72. The composition ratio (mole ratio) measured by ¹³C-NMR was 20/80.

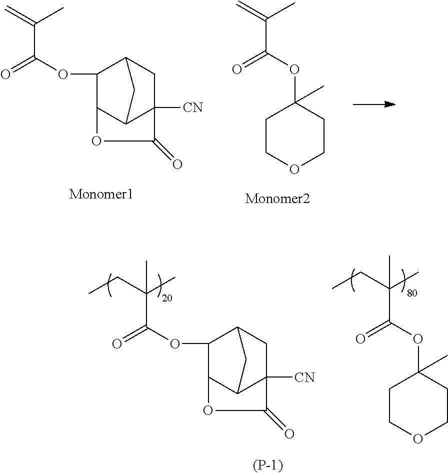

Hereinafter, Resins (P-2) to (P-13) were synthesized in the same manner as Resin (P-1).

The structure, composition ratio (molar ratio) of the repeating unit, mass average molecular weight and polydispersity of the synthesized resins will be shown below.

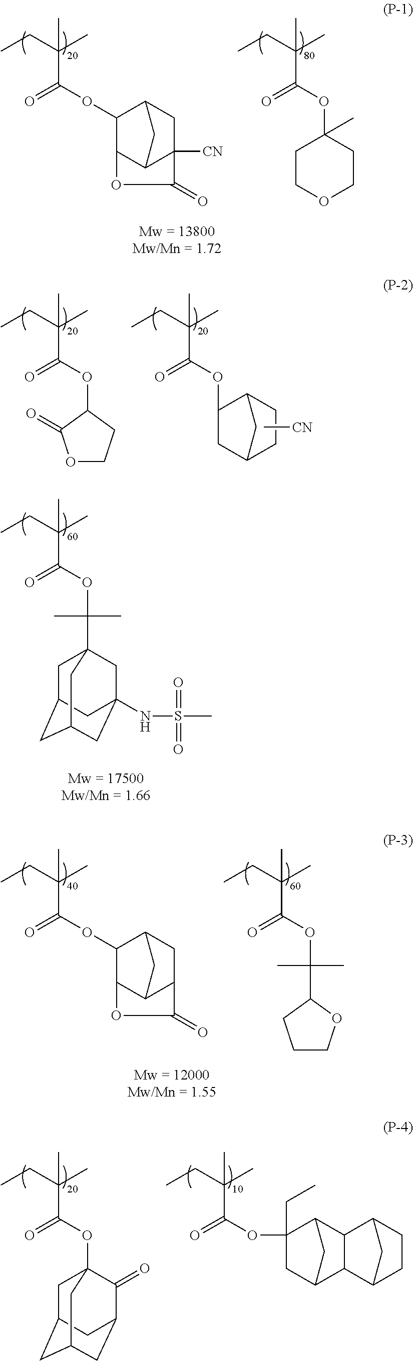

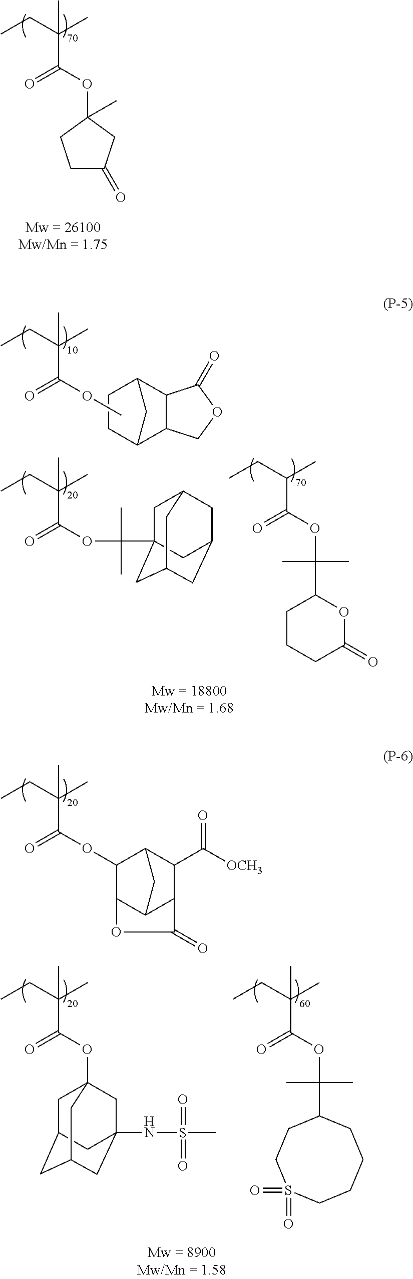

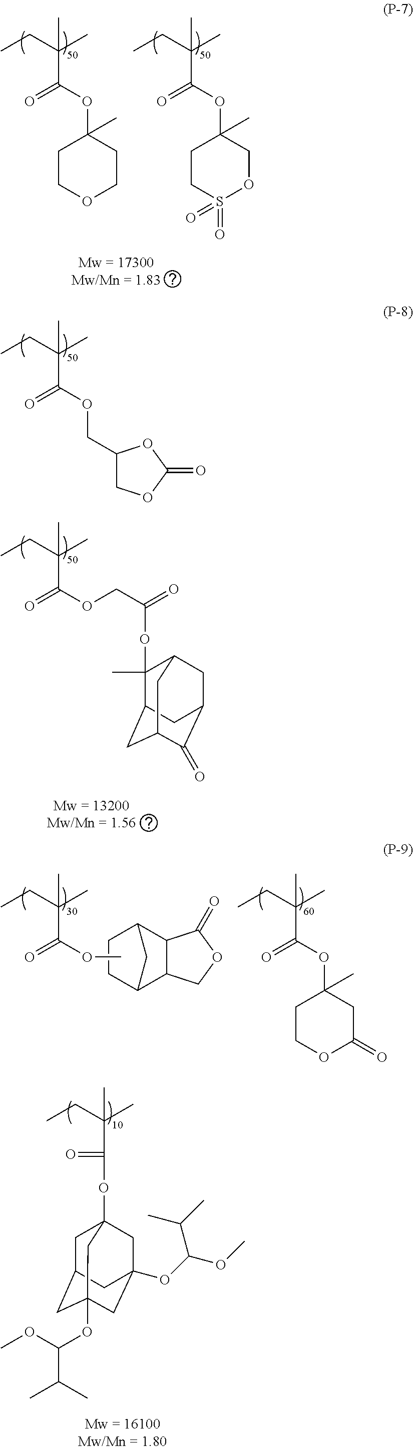

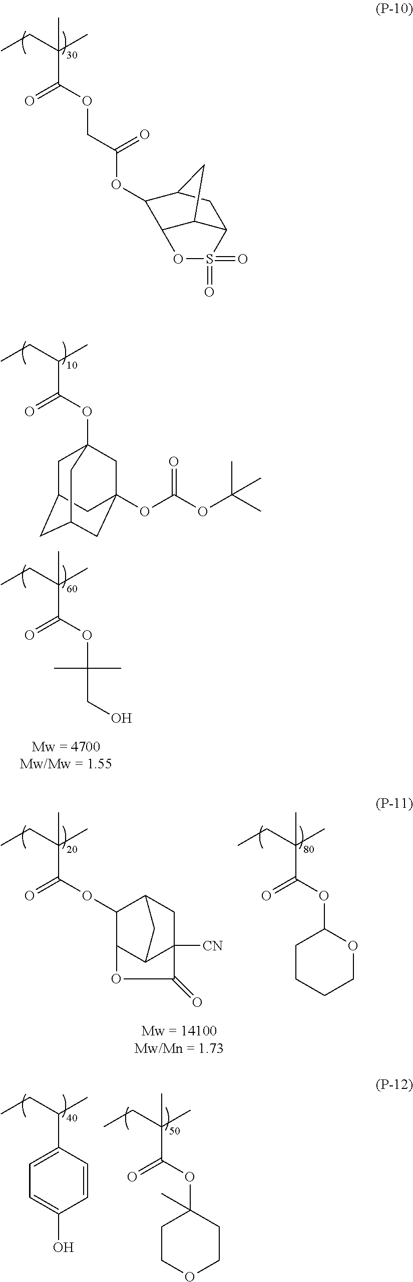

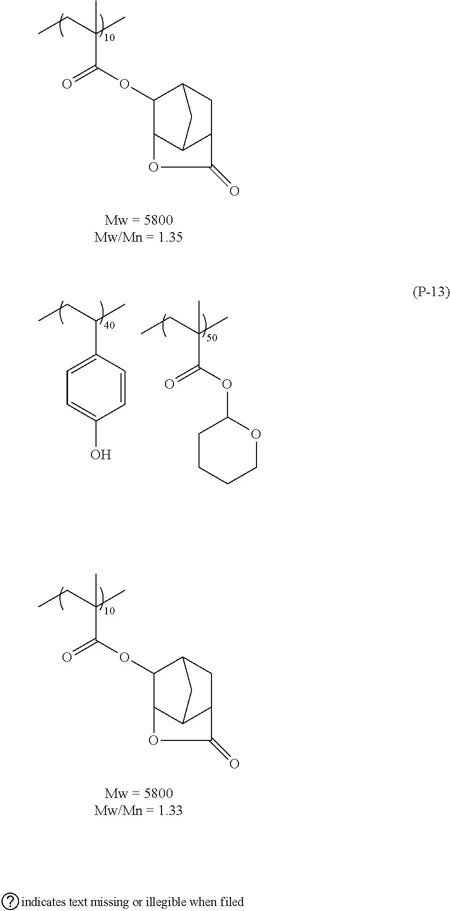

<Acid Generator>

The following compounds were used as the acid generator.

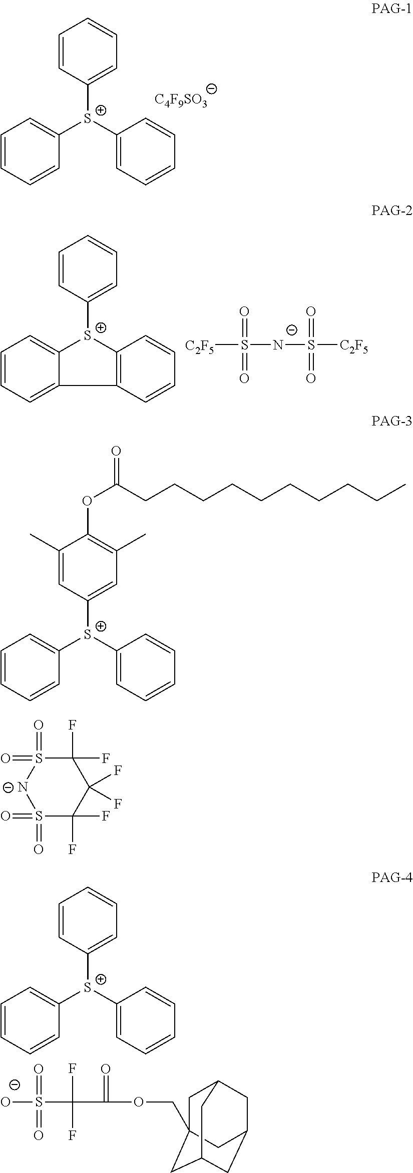

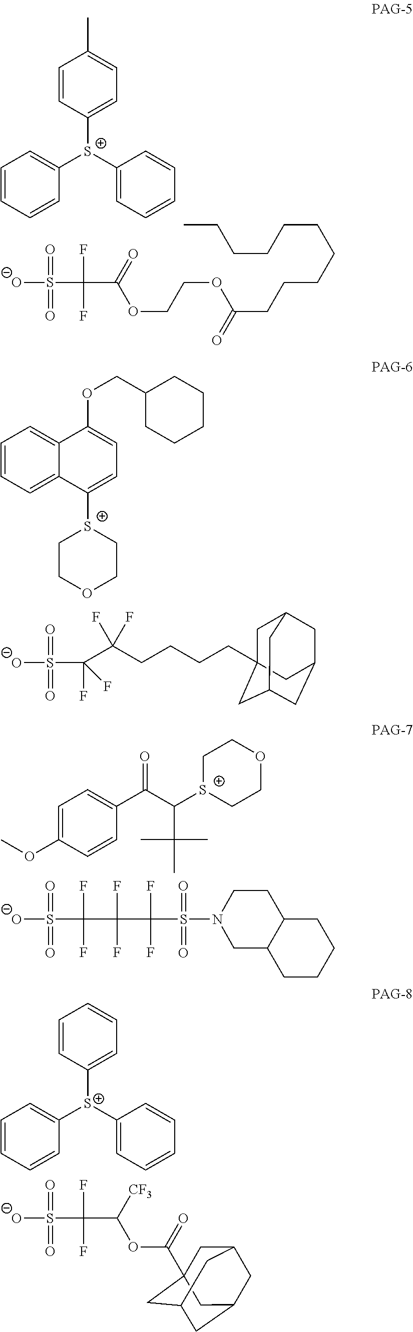

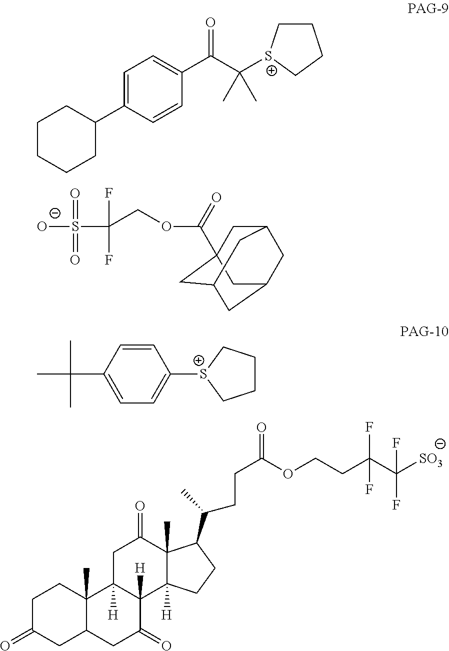

<Basic compound (N), a compound (N′) having a basic functional group or an ammonium group, and a group capable of generating an acidic functional group upon irradiation with actinic ray or radiation, and a low molecular compound (N″) having a nitrogen atom and also having a group capable of leaving by the action of an acid>

The following compounds were used as the compound (N), the compound (N′) and the compound (N″).

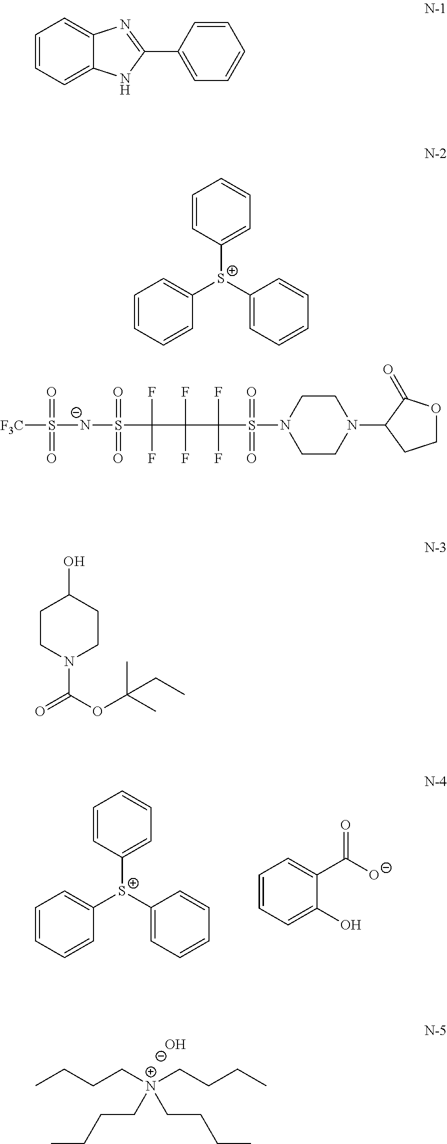

<Hydrophobic Resin>

As the hydrophobic resin, Resins (HR-1) to (HR-84), (C-1) to (C-28), (D-1) to (D-16), previously exemplified were appropriately selected and used.

<Surfactant>

The followings were used as the surfactant.

W-1: Megafac F176 (manufactured by DIC Corporation; fluorine-based)

W-2: PolyFox PF-6320 (manufactured by OMNOVA Solutions Inc.; fluorine-based)

W-3: Polysiloxane Polymer KP-341 (manufactured by Shin-Etsu Chemical Co., Ltd.; silicone-based)

W-4: Troysol S-366 (manufactured by Troy Chemical Corp.)

W-5: KH-20 (manufactured by Asahi Glass Co., Ltd.)

<Solvent>

The followings were used as the solvent.

(Group a)

SL-1: Propylene glycol monomethyl ether acetate (PGMEA)

SL-2: Propylene glycol monomethyl ether propionate

SL-3: 2-Heptanone

(Group b)

SL-4: Ethyl lactate

SL-5: Propylene glycol monomethyl ether (PGME)

SL-6: Cyclohexanone

(Group c)

SL-7: γ-butyrolactone

SL-8: Propylene carbonate

<Developer>

The followings were used as the developer.

SG-1: butyl acetate

SG-2: diisobutyl ketone

SG-3: cyclohexyl acetate

SG-4: isobutyl isobutyrate

SG-5: isopentyl acetate

SG-6: phenetole

SG-7: dibutyl ether

SG-8: 2-nonanone

<Rinse Liquid>

The followings were used as the rinse liquid.

SR-1: 4-methyl-2-pentanol

SR-2: 1-hexanol

SR-3: butyl acetate

### Examples 1 to 33 and Comparative Example 1

### ArF Immersion Exposure and Organic Solvent Development

<Preparation of Resist>

The components shown in the following Table 6 were dissolved in the solvent shown in the same Table to have a solid content of 3.8% by mass, and each was filtered through a polyethylene filter having a pore size of 0.03 μm to prepare an actinic ray-sensitive or radiation-sensitive resin composition (resist composition). An organic antireflection film ARC29SR (manufactured by Nissan Chemical Industries, Ltd.) was applied on a silicon wafer and baked at 205° C. for 60 seconds to form an antireflection film having a film thickness of 95 nm. The actinic ray-sensitive or radiation-sensitive resin composition was applied thereon and baked (PB: prebake) at 100° C. over 60 seconds to form a resist film having a film thickness of 100 nm.

The obtained wafer was subjected to pattern exposure by using an ArF excimer laser liquid immersion scanner (manufactured by ASML Co., Ltd.; XT1700i, NA 1.20, C-Quad, outer sigma 0.900, inner sigma 0.812, XY deflection) through a halftone mask having a square arrangement in which a hole size was 45 nm and a pitch between holes was 90 nm (here, for negative image formation, the portion corresponding to the holes are shielded). As the liquid for liquid immersion, ultrapure water was used. Thereafter, heating (PEB: Post Exposure Bake) was performed at 105° C. for 60 seconds. Subsequently, the wafer was developed by performing puddling using the developer described in the following Table 1 for 30 seconds, and then rinsed by performing puddling using the rinse liquid described in the following Table 1 for 30 seconds (however, in Example 27, rinsing was not performed). Subsequently, a contact hole pattern of 45 nm was obtained by spinning the wafer at a rotational speed of 4,000 rpm for 30 seconds.

[Exposure Latitude (EL, %)]

A hole size was observed by a critical dimension scanning electron microscope (SEM) (manufactured by Hitachi, Ltd., S-9380 II), and an optimal exposure amount at the time of resolving a contact hole pattern having a hole size of 45 nm was defined as the sensitivity (Eₒₚₜ)(mJ/cm²). An exposure amount was obtained when the obtained optimal exposure amount (Eₒₚₜ) was used as a reference and subsequently, the hole size became 45 nm±10% (that is, 40.5 nm and 49.5 nm) which was a target value. Moreover, an exposure latitude (EL, %), defined as the following equation, was calculated. The larger EL value is, the smaller the change in performance due to change in exposure amount is, indicating that EL was good.

[EL(%)]=[(exposure amount when the hole size was 40.5 nm)−(exposure amount when the hole size was 49.5 nm)]/Eₒₚₜ×100

[Uniformity of Local Pattern Dimension (Local CDU, Nm)]

Within one shot exposed as the optimal exposure amount in the exposure latitude evaluation, in twenty sites having an interval of 1 μm therebetween, hole sizes at arbitrary 25 points in each site, that is, 500 points in total were measured and a standard deviation thereof was obtained to calculate 3σ. The smaller the value is, the smaller the variation in dimension is, indicating that the performance was good.

[Pattern Portion Thickness (Nm)]

The cross-sectional shape of each pattern at the optimum exposure amount described above was observed using a scanning electron microscope (manufactured by Hitachi, Ltd., S-4800). The pattern height for the resist remaining portion in the hole pattern was measured. The larger the value is, the lower the film reduction is, indicating that it was good.

[Line Width Roughness (LWR, Nm)]

The obtained wafer was exposed through a 6% halftone mask having a line width of 45 nm (a 1:1 line-and-space pattern) by using an ArF excimer laser immersion scanner (manufactured by ASML Co., Ltd.; XT1700i, NA1.20). As the liquid for liquid immersion, ultrapure water was used. Thereafter, heating was performed at 105° C. for 60 seconds, and the wafer was developed by puddling using the developer described in the following Table 6 for 30 seconds and then rinsed by puddling with the rinse liquid described in the following Table 6 for 30 seconds, while rotating the wafer at a rotation speed of 1000 rpm. In the observation of the resulting line width of 45 nm (a 1:1 line-and-space resist pattern), a wide space was measured at any point, when observed at a top pattern portion using a scanning electron microscope (SEM, manufactured by Hitachi, Ltd., S-938011). The observed variation was evaluated with 3σ. The smaller the value is, the better the performance is.

TABLE 6

| | | | MW of | | | | | | | | |
|---|---|---|---|---|---|---|---|---|---|---|---|
| | | | leaving | Compound | | Compound | | Hydrophobic | | | Mass |
| Ex. | Resin | (g) | product | (B) | (g) | (N), (N′), (N″) | (g) | Resin (E) | (g) | Solvent | ratio |
| Ex. 1 | P-1 | 10 | 98.14 | PAG-8 | 1.04 | N-3 | 0.08 | D-12 | 0.06 | SL-1/SL-5 | 60/40 |
| Ex. 2 | P-2 | 10 | 269.40 | PAG-1 | 1.50 | N-1 | 0.13 | HR-16 | 0.06 | SL-1 | 100 |
| Ex. 3 | P-3 | 10 | 122.17 | PAG-9 | 1.50 | N-1 | 0.12 | D-4 | 0.06 | SL-1/SL-5 | 60/40 |
| Ex. 4 | P-4 | 10 | 96.13 | PAG-3 | 1.28 | N-3 | 0.08 | HR-59 | 0.06 | SL-1/SL-4 | 90/10 |
| Ex. 5 | P-5 | 10 | 140.18 | PAG-10 | 1.50 | N-1 | 0.15 | C-10 | 0.06 | SL-1/SL-5 | 60/40 |
| Ex. 6 | P-6 | 10 | 202.31 | PAG-2 | 1.04 | N-4 | 0.12 | C-14 | 0.06 | SL-1/SL-3 | 60/40 |
| Ex. 7 | P-7 | 10 | 148.18 | PAG-2 | 0.51 | N-1 | 0.12 | HR-39 | 0.06 | SL-1/SL-5 | 60/40 |
| Ex. 8 | P-8 | 10 | 162.23 | PAG-4 | 2.39 | N-2 | 0.41 | HR-83 | 0.06 | SL-1/SL-8 | 70/30 |
| Ex. 9 | P-9 | 10 | 112.13 | PAG-3 | 1.28 | N-2 | 0.45 | HR-84 | 0.06 | SL-1/SL-7 | 60/40 |
| Ex. 10 | P-10 | 10 | 72.11 | PAG-4 | 2.39 | N-1 | 0.12 | HR-51 | 0.06 | SL-5/SL-6 | 30/70 |
| Ex. 11 | P-1 | 10 | 98.14 | PAG-5 | 1.45 | N-3 | 0.09 | D-1 | 0.06 | SL-1/SL-2 | 60/40 |
| Ex. 12 | P-1/P-5 | 5/5 | 98.14/140.18 | PAG-6 | 1.04 | N-1 | 0.11 | D-4/C-10 | 0.04/0.02 | SL-1/SL-5 | 60/40 |
| Ex. 13 | P-3 | 10 | 122.17 | PAG-1/PAG-7 | 0.55/0.70 | N-2 | 0.42 | HR-81 | 0.06 | SL-1/SL-5 | 60/40 |
| C. Ex. 1 | P-11 | 10 | 84.12 | PAG-8 | 1.04 | N-3 | 0.08 | D-12 | 0.06/ | SL-1/SL-5 | 60/40 |

| | | | | | | | Local ODU | | Pattern portion | LWR |
|---|---|---|---|---|---|---|---|---|---|---|
| Ex. | Surfactant | (g) | Developer | Mass ratio | Rinse liquid | Mass ratio | (nm) | EL (%) | Thickness (nm) | (nm) |
| Ex. 1 | W-4 | 0.003 | SG-1 | 100 | SR-1 | 100 | 4.1 | 19.3 | 86 | 4.6 |
| Ex. 2 | W-1 | 0.003 | SG-4 | 100 | SR-1 | 100 | 5.5 | 17.7 | 76 | 5.2 |
| Ex. 3 | W-5 | 0.003 | SG-7 | 100 | SR-1 | 100 | 4.4 | 19.0 | 83 | 4.9 |
| Ex. 4 | W-1 | 0.003 | SG-1 | 100 | SR-3 | 100 | 4.6 | 19.1 | 84 | 4.9 |
| Ex. 5 | W-1 | 0.003 | SG-5 | 100 | SR-1 | 100 | 4.3 | 19.4 | 85 | 4.7 |
| Ex. 6 | W-1 | 0.003 | SG-1 | 100 | SR-1 | 100 | 4.9 | 18.9 | 81 | 5.0 |
| Ex. 7 | W-4 | 0.003 | SG-8 | 100 | SR-1 | 100 | 4.2 | 19.3 | 84 | 4.5 |
| Ex. 8 | W-1 | 0.003 | SG-2 | 100 | — | — | 5.7 | 18.1 | 80 | 5.4 |
| Ex. 9 | W-3 | 0.003 | SG-5 | 100 | SR-1 | 100 | 4.7 | 19.0 | 81 | 4.9 |
| Ex. 10 | W-5 | 0.003 | SG-6 | 100 | SR-1/SR-3 | 90/10 | 4.6 | 18.8 | 81 | 5.0 |
| Ex. 11 | W-2 | 0.003 | SG-3 | 100 | SR-1 | 100 | 4.4 | 19.0 | 82 | 5.0 |
| Ex. 12 | W-2 | 0.003 | SG-1 | 100 | SR-2 | 100 | 4.4 | 19.0 | 84 | 5.0 |
| Ex. 13 | W-1 | 0.003 | SG-1/SG-4 | 50/50 | SR-3 | 100 | 4.3 | 19.1 | 83 | 4.7 |
| C. Ex. 1 | W-4 | 0.003 | SG-1 | 100 | SR-1 | 100 | 6.4 | 15.5 | 71 | 6.3 |

As is apparent from the results shown in Table 6, Examples 1 to 13 using the resin in which the leaving group in the acid-decomposable group has a group having a polar group and a quaternary carbon atom directly bonded to the ester group in the carboxyl group are excellent in uniformity of a local pattern dimension, exposure latitude, pattern portion thickness, and line width roughness, as compared with Comparative Example 1 using the resin in which the leaving group in the acid-decomposable group does not have a quaternary carbon atom directly bonded to the —COO— group in the carboxyl group.

Also, it is seen that in Examples 1, 4, 5, 7 and 12 using the resin in which the content of the repeating unit (p) having an acid-decomposable group is 80 mot % or more based on the total repeating units of the resin, the pattern portion thickness is excellent.

Further, it is seen that in Examples 1 and 3 to 13 using the resin (A) in which the molecular weight of the leaving product resulting from the repeating unit (p1) by the action of an acid is 250 or less, the pattern portion thickness is more excellent.

### Example 14 and Comparative Example 2

### EUV Exposure and Organic Solvent Development

(Preparation of Resist)

The resist film having a film thickness of 100 nm was formed in the same manner as in Example 1 except that the components shown in Table 7 were dissolved in an amount of 3.8% by weight as the solid in a solvent shown in the same Table, and the obtained solution was filtered with a polyethylene filter having a pore size of 0.03 μm to prepare an actinic ray-sensitive or radiation-sensitive resin composition.

The coated wafer of the resist film was subjected to pattern exposure with the exposure mask (line/space=1/1), using an EUV exposure apparatus (Manufactured by Exitech, Micro Exposure Tool, NA0.3, Quadrupole, outer sigma 0.68, inner sigma 0.36). After irradiation, the wafer was heated on a hot plate at 110° C. for 60 seconds, developed by puddling with the developer described in Table 7 below for 30 minutes, rinsed with a rinse liquid described in Table 7 below, rotated at the rotational speed of 4000 rpm for 30 seconds and then baked at 90° C. for 60 seconds to obtain a resist pattern having a line width of 50 nm (line/space=1:1).

[Line Width Roughness (LWR, Nm)]

The 1:1 line and space pattern with a line width of 50 nm was observed using a scanning electron microscope (manufactured by Hitachi Ltd., S-9380). Then, the equidistant 50 points included in the length direction of 2 μm, the distance between the actual edges with the reference line where the edge should be present was measured. Then, the standard deviation of this distance was calculated with 3σ. This 3σ was set as “LWR (nm)”. It is seen that the smaller this value is, the better the roughness characteristics are.

TABLE 7

| | | | MW of | | | | | | | | | | | | |
|---|---|---|---|---|---|---|---|---|---|---|---|---|---|---|---|
| | | | leaving | Compound | | Compound | | | Mass | | | Mass | Rinse | Mass | LWR |
| Ex. | Resin | (g) | product | (B) | (g) | (N), (N′), (N″) | (g) | Solvent | ratio | Surfactant | Developer | ratio | liquid | ratio | (nm) |
| Ex. 14 | P-12 | 10 | 98.14 | PAG-1 | 1.50 | N-5 | 0.06 | SL-1/SL-5 | 60/40 | W-1 | SG-1 | 100 | SR-1 | 100 | 4.9 |
| C. Ex. 2 | P-13 | 10 | 84.12 | PGA-1 | 1.50 | N-5 | 0.06 | SL-1/SL-5 | 60/40 | W-1 | SG-1 | 100 | SR-1 | 100 | 6.3 |

As is apparent from the results shown in Table 7, Examples 1 to 13 using the resin in which the leaving group in the acid-decomposable group has a group having a polar group and a quaternary carbon atom directly bonded to the ester group in the carboxyl group have excellent local line width roughness, as compared with Comparative Example 2 using the resin in which the leaving group in the acid-decomposable group does not have a quaternary carbon atom directly bonded to the —COO— group in the carboxyl group.

Using the resist of Example 1, the mask pattern of line and space was exposed with reference to Example 7 of U.S. Pat. No. 8,227,183B, and then both alkali development and butyl acetate development were performed. In this evaluation, it was possible to form a half of the pitch of the mask pattern.

Furthermore, in Example 1, evaluation was performed in the same manner as Example 1 except that a small amount of tri-n-octylamine was added to the developer (butyl acetate). In this regard, it was possible to perform a good pattern formation.

### INDUSTRIAL APPLICABILITY

According to the present invention, it is possible to provide a pattern forming method, an actinic ray-sensitive or radiation-sensitive resin composition used therefor, a method of manufacturing an electronic device using same, and an electronic device, which are excellent in roughness performance such as line width roughness, uniformity of a local pattern dimension, and exposure latitude and which may suppress film thickness reduction, so called film reduction, of the pattern portion formed during development.

Although the present invention has been described with reference to detailed and specific aspects, it is obvious to those skilled in the art that various changes or modifications may be made without departing from the spirit and scope of the present invention.

The present application is based on Japanese Patent Application (Patent Application No. 2013-052275) filed on Mar. 14, 2013, the content of which is incorporated herein by reference.

What is claimed is:

1. A pattern forming method comprising:
(i) forming a film by using an actinic ray-sensitive or radiation-sensitive resin composition containing (A) a resin containing a repeating unit (p) having a structure in which a polar group is protected by a leaving group capable of decomposing and leaving by an action of an acid, and (B) a compound capable of generating an acid upon irradiation with an actinic ray or radiation;
(ii) exposing the film; and
(iii) developing the film exposed, by using an organic solvent-containing developer to form a negative pattern,
wherein the repeating unit (p) contains a repeating unit (p1) having a structure in which a hydrogen atom in a carboxyl group is substituted by a leaving group capable of decomposing and leaving by the action of an acid, and
the leaving group in the repeating unit (p1) contains a group having a polar group and a quaternary carbon atom directly bonded to the —COO— group in the carboxyl group.

2. The pattern forming method according to claim 1,
wherein a molecular weight of a leaving product produced from the repeating unit (p1) by the action of an acid is 250 or less.

3. The pattern forming method according to claim 1,
wherein a content of the repeating unit (p) is 55 mol % or more based on a total repeating unit of the resin (A).

4. The pattern forming method according to claim 1,
wherein a content of the repeating unit (p) is 80 mol % or more based on a total repeating unit of the resin (A).

5. The pattern forming method according to claim 1,
wherein the polar group contained in the leaving group is a hydroxyl group, a keto group, a cyano group, a sulfoxide group, a sulfonyl group, a sulfonamide group, a nitro group, an amide group, a urethane group, a carbonate group, a carboxylic acid group, an ether group, a thioether group, a lactone ring, a sultone ring, or a group formed by combining two or more thereof.

6. The pattern forming method according to claim 1,
wherein a weight average molecular weight of the resin (A) is 15,000 or more.

7. The pattern forming method according to claim 1,
wherein the compound (B) is a compound capable of generating an organic acid represented by Formula (V) or (VI) upon irradiation with actinic rays or radiation: 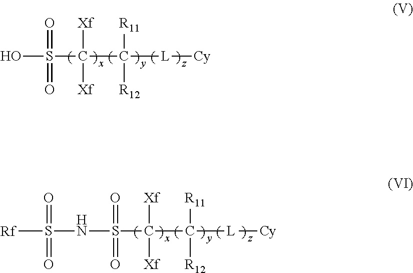
wherein in Formulas (V) and (VI),
each Xf independently represents a fluorine atom or an alkyl group substituted with at least one fluorine atom,
each L independently represents a divalent linking group,
each of R₁₁ and R₁₂ independently represents a hydrogen atom, a fluorine atom or an alkyl group,
Cy represents a cyclic organic group,
Rf is a group containing a fluorine atom,
x represents an integer of 1 to 20,
y represents an integer of 0 to 10, and
z represents an integer of 0 to 10.

8. The pattern forming method according to claim 1,
wherein the resin (A) is a resin having, as the repeating unit (p1), a repeating unit represented by Formula (p1a), (p1b) or (p1c): 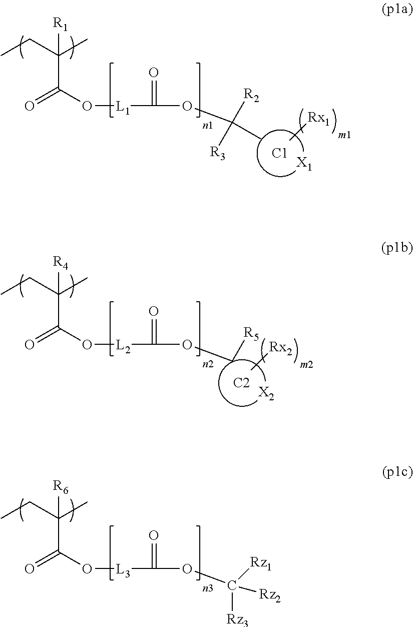
wherein in Formula (p1a),
R₁ represents a hydrogen atom, an alkyl group, a halogen atom, a cyano group or an alkyloxy carbonyl group,
each of R₂ and R₃ independently represents an alkyl group or a cycloalkyl group,
L₁ represents an alkylene group in which some of carbon atoms may be substituted with an ether group,
C1 represents a cyclic hydrocarbon group, and
X₁ represents, in the cyclic hydrocarbon group, a single bond, an ether group, a thioether group, an ester group, a sulfonate ester group, an amide group, a sulfonamide group or a keto group,
Rx₁ represents, as the polar group contained in the leaving group in the repeating unit (p1), a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed by combining two or more thereof,
n₁ represents an integer of 0 to 3, and
m₁ represents an integer of 0 to 3, provided that when m₁ is 0, X₁ represents, as the polar group contained in the leaving group in the repeating unit (p1), an ether group, a thioether group, an ester group, a sulfonate ester group, an amide group, a sulfonamide group or a keto group,
in Formula (p1b), R₄ represents a hydrogen atom, an alkyl group, a halogen atom, a cyano group or an alkyloxycarbonyl group,
R₅ represents an alkyl group or a cycloalkyl group,
L₂ represents an alkylene group in which some of carbon atoms may be substituted with an ether group,
C2 represents a cyclic hydrocarbon group,
X₂ represents, in the cyclic hydrocarbon group, a single bond, an ether group, a thioether group, an ester group, a sulfonate ester group or a keto group,
Rₓ₂ represents, as the polar group contained in the leaving group in the repeating unit (p1), a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed in combination of two or more thereof,
n₂ represents an integer of 0 to 3, and
m₂ represents an integer of 0 to 3, provided that when m₂ is 0, X₂ represents, the polar group contained in the leaving group in the repeating unit (p1), an ether group, a thioether group, an ester group, a sulfonate ester group, an amide group, a sulfonamide group, or a keto group,
in Formula (p1c), R₆ represents a hydrogen atom, an alkyl group, a halogen atom, a cyano group or an alkyloxycarbonyl group,
R₅ represents an alkyl group or a cycloalkyl group,
L₃ represents an alkylene group that some of carbon atoms may be substituted with an ether group,
each of R_{z1} to R_{z3} independently represents an alkyl group, provided that at least one of R_{z1} to R_{z3} has, as the polar group contained in the leaving group in the repeating unit (p1), a hydroxyl group, a keto group, a cyano group, a sulfoxide group, a sulfonyl group, a sulfonamide group, a nitro group, an amide, an urethane group, a carbonate group, a carboxylic acid group, an ether group or a thioether group, and
n₃ represents an integer of 0 to 3.

9. The pattern forming method according to claim 1,
wherein the actinic ray-sensitive or radiation-sensitive resin composition further contains a compound (N′) having a basic functional group or an ammonium group, and a group capable of generating an acidic functional group upon irradiation with actinic ray or radiation.

10. The pattern forming method according to claim 1,
wherein the developer is a developer containing at least one organic solvent selected from the group consisting of a ketone-based solvent, an ester-based solvent, an alcohol-based solvent, an amide-based solvent and an ether-based solvent.

11. An actinic ray-sensitive or radiation-sensitive resin composition, for use in a pattern forming method for forming a negative pattern by developing a film with an organic solvent-containing developer, the resin composition comprising:
(A) a resin having a repeating unit (p) having a structure in which a polar group is protected with a leaving group capable of decomposing and leaving by an action of an acid; and
(B) a compound capable of generating an acid upon irradiation with actinic ray or radiation,
wherein the repeating unit (p) contains a repeating unit (p1) having a structure in which a hydrogen atom in a carboxyl group is substituted by a leaving group capable of decomposing and leaving by the action of an acid, and
the leaving group in the repeating unit (p1) contains a group having a polar group and a quaternary carbon atom directly bonded to the —COO— group in the carboxyl group.

12. The actinic ray-sensitive or radiation-sensitive resin composition according to claim 11,
wherein a molecular weight of a leaving product produced from the repeating unit (p1) by the action of an acid is 250 or less.

13. The actinic ray-sensitive or radiation-sensitive resin composition according to claim 11,
wherein a content of the repeating unit (p) is 55 mol % or more based on a total repeating unit of the resin (A).

14. The actinic ray-sensitive or radiation-sensitive resin composition according to claim 11,
wherein a content of the repeating unit (p) is 80 mol % or more based on a total repeating unit of the resin (A).

15. The actinic ray-sensitive or radiation-sensitive resin composition according to claim 11,
wherein the polar group contained in the leaving group is a hydroxyl group, a keto group, a cyano group, a sulfoxide group, a sulfonyl group, a sulfonamide group, a nitro group, an amide group, a urethane group, a carbonate group, a carboxylic acid group, an ether group, a thioether group, a lactone ring, a sultone ring, or a group formed by combining two or more thereof.

16. The actinic ray-sensitive or radiation-sensitive resin composition according to claim 11,
wherein a weight average molecular weight of the resin (A) is 15,000 or more.

17. The actinic ray-sensitive or radiation-sensitive resin composition according to claim 11,
wherein the compound (B) is a compound capable of generating an organic acid represented by Formula (V) or (VI) upon irradiation with actinic rays or radiation: 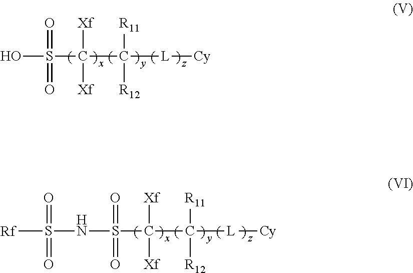
wherein in Formulas (V) and (VI),
each Xf independently represents a fluorine atom or an alkyl group substituted with at least one fluorine atom,
each L independently represents a divalent linking group,
each of R₁₁ and R₁₂ independently represents a hydrogen atom, a fluorine atom or an alkyl group,
Cy represents a cyclic organic group,
Rf is a group containing a fluorine atom,
x represents an integer of 1 to 20,
y represents an integer of 0 to 10, and
z represents an integer of 0 to 10.

18. The actinic ray-sensitive or radiation-sensitive resin composition according to claim 11,
wherein the resin (A) is a resin having, as the repeating unit (p1), a repeating unit represented by Formula (p1a), (p1b) or (p1c): 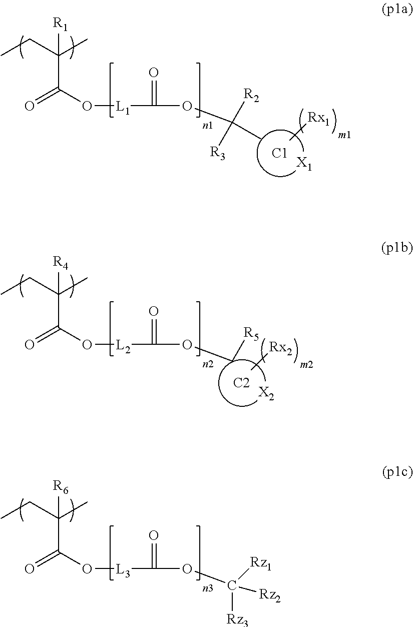
wherein in Formula (p1a),
R₁ represents a hydrogen atom, an alkyl group, a halogen atom, a cyano group or an alkyloxy carbonyl group,
each of R₂ and R₃ independently represents an alkyl group or a cycloalkyl group,
L₁ represents an alkylene group in which some of carbon atoms may be substituted with an ether group,
C1 represents a cyclic hydrocarbon group, and
X₁ represents, in the cyclic hydrocarbon group, a single bond, an ether group, a thioether group, an ester group, a sulfonate ester group, an amide group, a sulfonamide group or a keto group,
Rx₁ represents, as the polar group contained in the leaving group in the repeating unit (p1), a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed by combining two or more thereof,
n₁ represents an integer of 0 to 3, and
m₁ represents an integer of 0 to 3, provided that when m₁ is 0, X₁ represents, as the polar group contained in the leaving group in the repeating unit (p1), an ether group, a thioether group, an ester group, a sulfonate ester group, an amide group, a sulfonamide group or a keto group,
in Formula (p1 b), R₄ represents a hydrogen atom, an alkyl group, a halogen atom, a cyano group or an alkyloxycarbonyl group,
R₅ represents an alkyl group or a cycloalkyl group,
L₂ represents an alkylene group in which some of carbon atoms may be substituted with an ether group,
C2 represents a cyclic hydrocarbon group,
X₂ represents, in the cyclic hydrocarbon group, a single bond, an ether group, a thioether group, an ester group, a sulfonate ester group or a keto group,
Rₓ₂ represents, as the polar group contained in the leaving group in the repeating unit (p1), a monovalent group having a hydroxyl group, a keto group, a cyano group, a sulfoxide group, a sulfonyl group, a sulfonamide group, a nitro group, an amide group, an urethane group, a carbonate group, a carboxylic acid group, an ether group, a thioether group or a group formed in combination of two or more thereof,
n₂ represents an integer of 0 to 3, and
m₂ represents an integer of 0 to 3, provided that when m₂ is 0, X₂ represents, the polar group contained in the leaving group in the repeating unit (p1), an ether group, a thioether group, an ester group, a sulfonate ester group, an amide group, a sulfonamide group, or a keto group,
in Formula (p1c), R₆ represents a hydrogen atom, an alkyl group, a halogen atom, a cyano group or an alkyloxycarbonyl group,
R₅ represents an alkyl group or a cycloalkyl group,
L₃ represents an alkylene group that some of carbon atoms may be substituted with an ether group,
each of R_{z1} to R_{z3} independently represents an alkyl group, provided that at least one of R_{z1} to R_{z3} has, as the polar group contained in the leaving group in the repeating unit (p1), a hydroxyl group, a keto group, a cyano group, a sulfoxide group, a sulfonyl group, a sulfonamide group, a nitro group, an amide, an urethane group, a carbonate group, a carboxylic acid group, an ether group or a thioether group, and
n₃ represents an integer of 0 to 3.

19. The actinic ray-sensitive or radiation-sensitive resin composition according to claim 11,
wherein the actinic ray-sensitive or radiation-sensitive resin composition further contains a compound (N′) having a basic functional group or an ammonium group, and a group capable of generating an acidic functional group upon irradiation with actinic ray or radiation.

20. A method of manufacturing an electronic device comprising the pattern forming method according to claim 1.

21. An electronic device manufactured from the method of manufacturing an electronic device according to claim 20.
